(19) United States
(12) Patent Application Publication
(10) Pub. No.: US 2023/0309402 A1
(43) Pub. Date: Sep. 28, 2023

(54) LIGHT EMITTING DEVICE AND FUSED POLYCYCLIC COMPOUND FOR THE LIGHT EMITTING DEVICE

(71) Applicant: Samsung Display Co., Ltd., Yongin-si (KR)

(72) Inventors: MUN-KI SIM, Seoul (KR); SERAN KIM, Suwon-si (KR); TAEIL KIM, Hwaseong-si (KR); JANG YEOL BAEK, Yongin-si (KR); MinJae SUNG, Hwaseong-si (KR); MINJUNG JUNG, Hongcheon-gun (KR)

(73) Assignee: Samsung Display Co., Ltd., Yongin-si (KR)

(21) Appl. No.: 18/096,107

(22) Filed: Jan. 12, 2023

(30) Foreign Application Priority Data
Mar. 25, 2022 (KR) 10-2022-0037158

(51) Int. Cl. H10K 85/60; C07F 5/02; H10K 85/40; C07F 7/08; H10K 85/30; H10K 50/11

(52) U.S. Cl. CPC H10K 85/658; C07F 5/027; H10K 85/6572; H10K 85/6574; H10K 85/636; H10K 85/652; H10K 85/40; C07F 7/0812; H10K 85/346; H10K 50/11; C07B 2200/05

(57) ABSTRACT

Embodiments provide a light emitting device that includes a first electrode, a second electrode facing the first electrode, and an emission layer disposed between the first electrode and the second electrode, wherein the emission layer includes a first compound represented by Formula 1, which is explained in the specification:

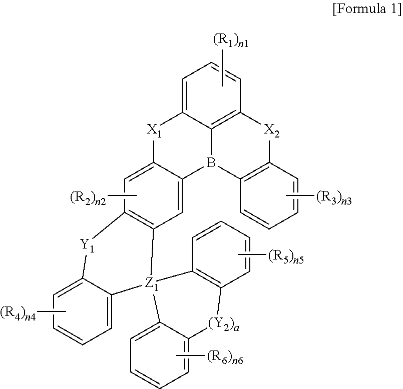

### CROSS-REFERENCE TO RELATED APPLICATION(S)

This application claims priority to and benefits of Korean Patent Application No. 10-2022-0037158 under 35 U.S.C. § 119, filed on Mar. 25, 2022 in the Korean Intellectual Property Office, the entire contents of which are incorporated herein by reference.

### BACKGROUND

### 1. Technical Field

The disclosure relates to a light emitting device and a fused polycyclic compound for the light emitting device.

### 2. Description of the Related Art

Active development continues for an organic electroluminescence display apparatus as an image display apparatus. Unlike liquid crystal display apparatuses and the like, the organic electroluminescence display apparatus is a so-called self-luminescent display apparatus in which holes and electrons respectively injected from a first electrode and a second electrode recombine in an emission layer, so that a luminescent material including an organic compound in the emission layer emits light to achieve display.

In the application of an organic electroluminescence device to a display apparatus, there is a demand for an organic electroluminescence device having a low driving voltage, high luminous efficiency, and a long service life, and continuous development is required on materials for an organic electroluminescence device which are capable of stably attaining such characteristics.

In order to implement a highly efficient organic electroluminescence device, technologies pertaining to phosphorescence emission using triplet state energy or to delayed fluorescence using triplet-triplet annihilation (TTA) in which singlet excitons are generated by collision of triplet excitons are being developed, and development is currently directed to thermally activated delayed fluorescence (TADF) materials using delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting device in which luminous efficiency and device service life are improved.

The disclosure also provides a fused polycyclic compound capable of improving luminous efficiency and service life of a light emitting device.

An embodiment provides a light emitting device which may include a first electrode, a second electrode facing the first electrode, and an emission layer disposed between the first electrode and the second electrode, wherein the emission layer includes a first compound represented by Formula 1:

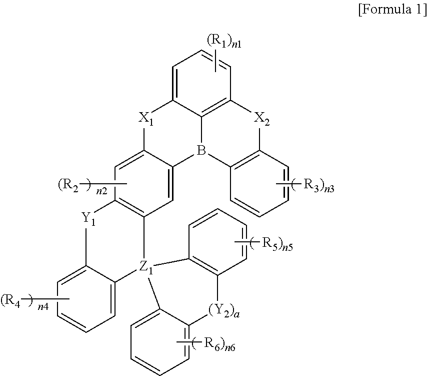

In Formula 1, X₁ and X₂ may each be N(R₇); Y₁ may be a direct linkage or O; Y₂ may be a direct linkage, O, or N(R₈); Z₁ may be C or Si; when Z₁ is Si, Y₁ may be O; R₁ to R₈ may each independently be a hydrogen atom, a deuterium atom, a halogen atom, a substituted or unsubstituted amine group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring; a may be 0 or 1; when a is 0, R₄ may not be a substituted or unsubstituted amine group; n1 may be an integer from 0 to 3; n2 may be an integer from 0 to 2; n3 and n4 may each independently be an integer from 0 to 4; n5 and n6 may each independently be an integer from 0 to 5; the sum of a and n5 may be 5 or less; and the sum of a and n6 may be 5 or less.

In an embodiment, the first compound represented by Formula 1 may be represented by any one of Formula 2-1 to Formula 2-4:

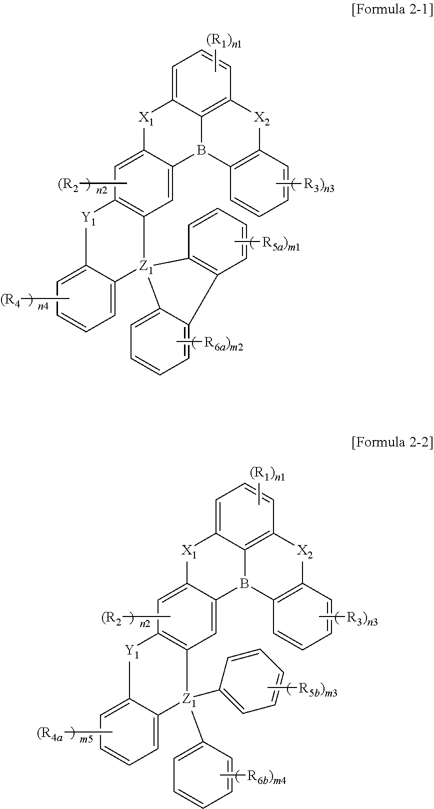

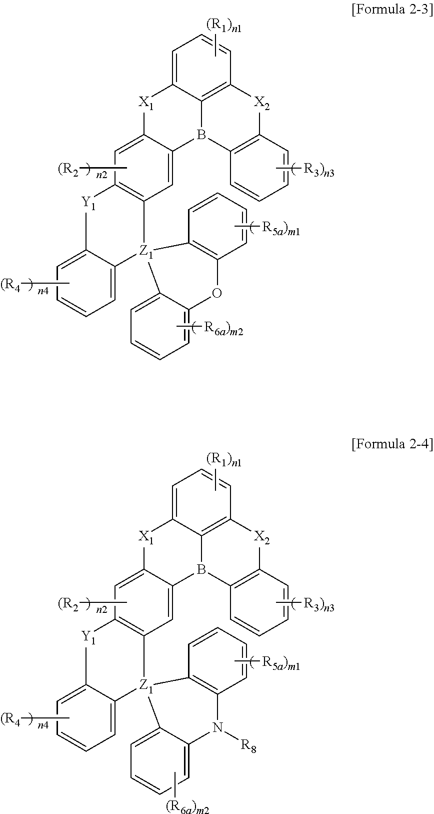

In Formula 2-1 to Formula 2-4, R₅ₐ, R₆ₐ, R_{5b}, and R_{6b} may each independently be a hydrogen atom, a deuterium atom, a halogen atom, a substituted or unsubstituted amine group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms; R₄ₐ may be a hydrogen atom, a deuterium atom, a halogen atom, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms; m1, m2, and m5 may each independently be an integer from 0 to 4; and m3 and m4 may each independently be an integer from 0 to 5.

In Formula 2-1 to Formula 2-4, X₁, X₂, Y₁, Z₁, R₁ to R₄, and n1 to n4 are each the same as defined in Formula 1.

In an embodiment, the first compound represented by Formula 1 may be represented by any one of Formula 3-1 to Formula 3-3:

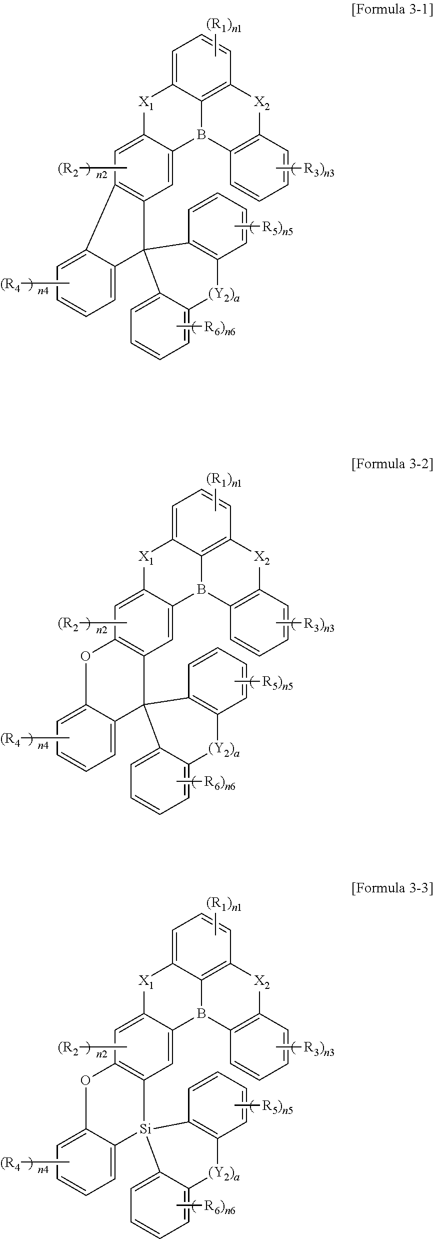

In Formula 3-1 to Formula 3-3, X₁, X₂, Y₂, a, R₁ to R₆, and n1 to n6 are each the same as defined in Formula 1.

In an embodiment, the first compound represented by Formula 1 may be represented by any one of Formula 4-1 to Formula 4-6:

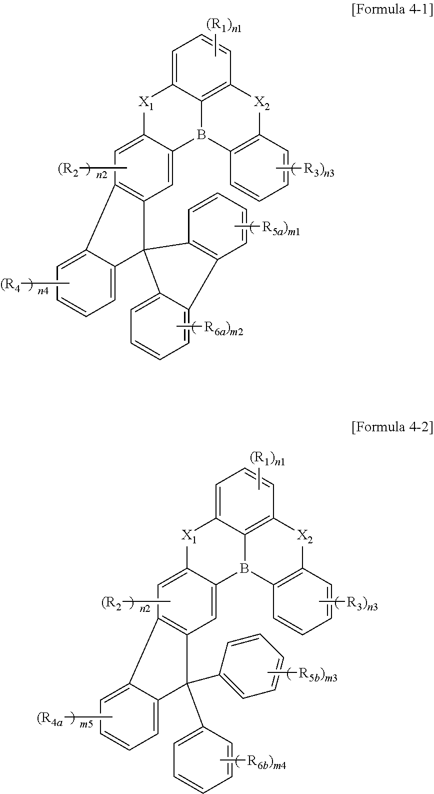

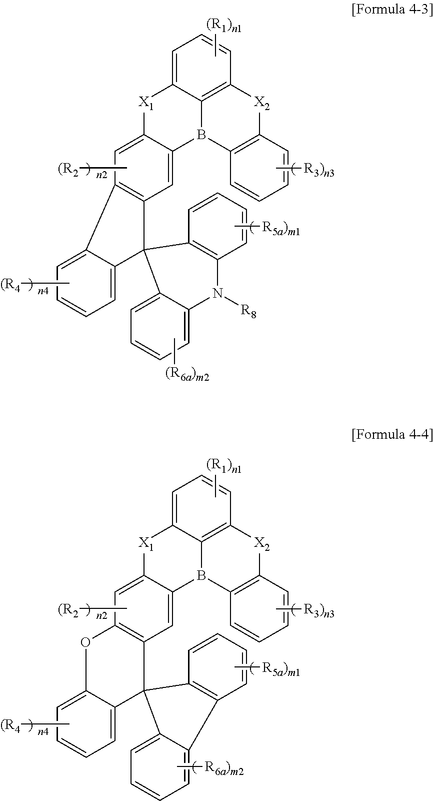

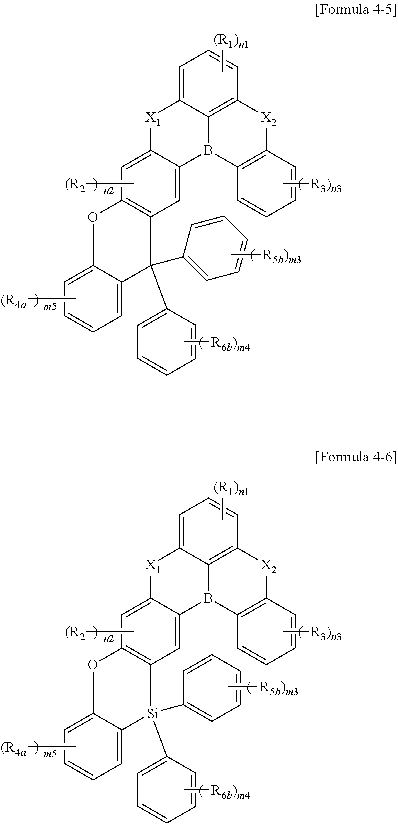

In Formula 4-1 to Formula 4-6, R₅ₐ, R₆ₐ, R_{5b}, and R_{6b} may each independently be a hydrogen atom, a deuterium atom, a halogen atom, a substituted or unsubstituted amine group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms; R₄ₐ may be a hydrogen atom, a deuterium atom, a halogen atom, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms; m1, m2, and m5 may each independently be an integer from 0 to 4; and m3 and m4 may each independently be an integer from 0 to 5.

In Formula 4-1 to Formula 4-6, X₁, X₂, R₁ to R₄, and n1 to n4 are each the same as defined in Formula 1.

In an embodiment, the first compound represented by Formula 1 may be represented by any one of Formula 5-1 to Formula 5-3:

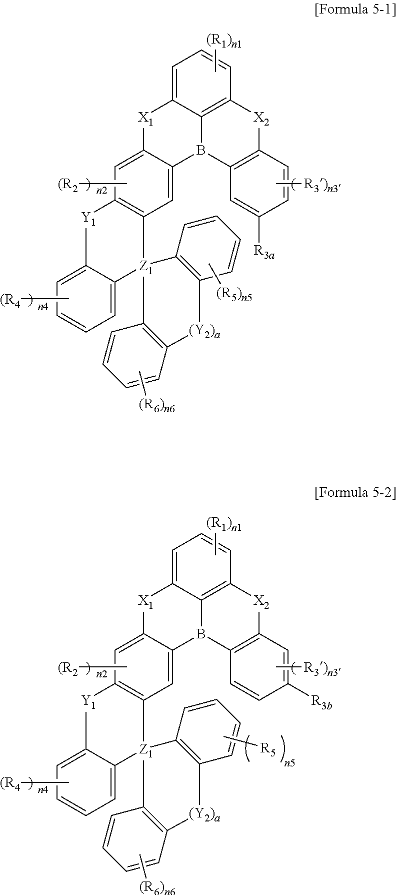

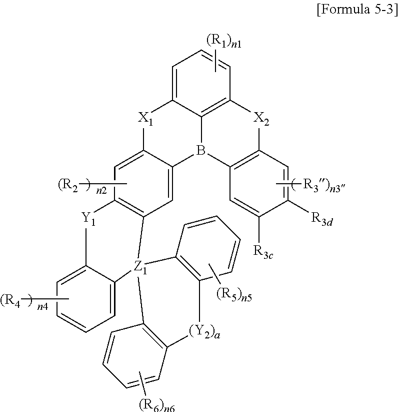

In Formula 5-1 to Formula 5-3, R₃ₐ and R_{3b} may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; R₃′ and R₃″ may each independently a hydrogen atom, a deuterium atom, a halogen atom, a substituted or unsubstituted amine group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms; n3′ may be an integer from 0 to 3; n3″ may be an integer from 0 to 2; and R_{3c} and R_{3d} each represent a bonding position of a moiety represented by Formula 6:

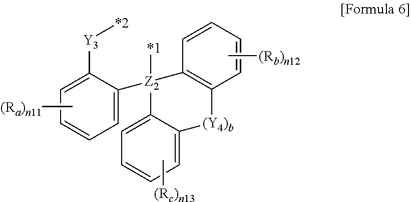

In Formula 6, -*1 is a bonding position to R_{3c} in Formula 5-3; -*2 is a bonding position linked to R_{3d} in Formula 5-3; Y₃ may be a direct linkage or O; Y₄ may be a direct linkage, O, or N(R_{d}); Z₂ may be C or Si; when Z₂ is Si, Y₃ may be O; Rₐ to R_{c} may each independently be a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; n11 to n13 may each independently be an integer from 0 to 4; b may be 0 or 1; when b is 0, R_{b} may not be a substituted or unsubstituted amine group; the sum of b and n12 may be 5 or less; and the sum of b and n13 may be 5 or less.

In Formula 5-1 to Formula 5-3, X₁, X₂, Z₁, Y₁, Y₂, a, R₁, R₂, R₄ to R₆, n1, n2, and n4 to n6 are each the same as defined in Formula 1.

In an embodiment, in Formula 5-1 and Formula 5-2, R₃ₐ and R_{3b} may each independently be a substituted or unsubstituted alkyl group having 1 to 10 carbon atoms, or a group represented by any one of Formula 7-1 to Formula 7-3:

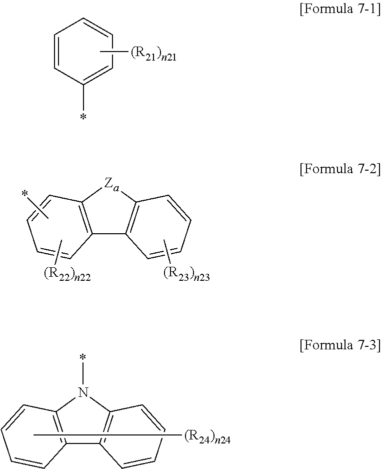

In Formula 7-1 to Formula 7-3, Zₐ may be N(R₂₅) or O; R₂₁ to R₂₅ may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; n21 may be an integer from 0 to 5; n22 may be an integer from 0 to 3; n23 may be an integer from 0 to 4; n24 may be an integer from 0 to 8; and -* is a bonding position to Formula 5-1 or Formula 5-2.

In an embodiment, the first compound represented by Formula 1 may be represented by Formula 8:

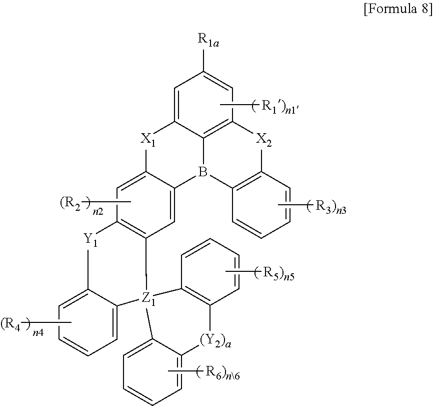

In Formula 8, R₁ₐ may be a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; R₁′ is a hydrogen atom, a deuterium atom, a halogen atom, a substituted or unsubstituted amine group, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and n1′ may be an integer from 0 to 2.

In Formula 8, X₁, X₂, Z₁, Y₁, Y₂, a, R₂ to R₆, and n2 to n6 are each the same as defined in Formula 1.

In an embodiment, in Formula 1, R₁ may be a substituted or unsubstituted alkyl group having 1 to 10 carbon atoms, or a group represented by any one of Formula 9-1 to Formula 9-6:

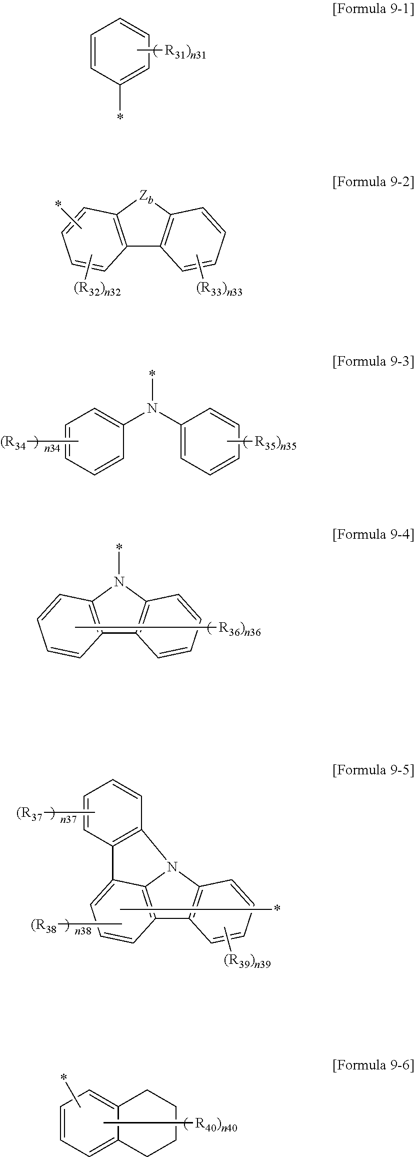

In Formula 9-1 to Formula 9-6, Z_{b} may be N(R₄₁) or O; R₃₁ to R₄₁ may each independently be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; n31 may be an integer from 0 to 5; n32 and n38 may each independently be an integer from 0 to 3; n33, n37, and n39 may each independently be an integer from 0 to 4; n34 and n35 may each independently be an integer from 0 to 5; the sum of n38 and n39 may be 6 or less; n36 may be an integer from 0 to 8; n40 may be an integer from 0 to 11; and -* is a bonding position to Formula 1.

In an embodiment, the first compound represented by Formula 1 may include at least one compound selected from Compound Group 1, which is explained below.

In an embodiment, the emission layer may further include a second compound represented by Formula H-1:

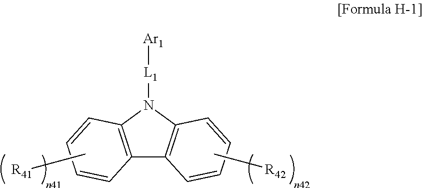

In Formula H-1, L₁ may be a direct linkage, a substituted or unsubstituted arylene group having 6 to 30 ring-forming carbon atoms, or a substituted or unsubstituted heteroarylene group having 2 to 30 ring-forming carbon atoms; Ar₁ may be a substituted or unsubstituted aryl group having 6 to 30 ring-forming carbon atoms, or a substituted or unsubstituted heteroaryl group having 2 to 30 ring-forming carbon atoms; R₄₁ and R₄₂ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring; and n41 and n42 may each independently be an integer from 0 to 4.

In an embodiment, the emission layer may further include a third compound represented by Formula H-2:

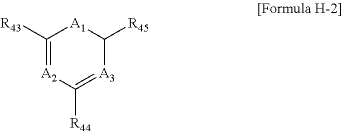

In Formula H-2, A₁ to A₃ may each independently be N or C(R₄₆); at least one of A₁ to A₃ may be N; and R₄₃ to R₄₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring.

In an embodiment, the emission layer may further include a fourth compound represented by Formula D-1:

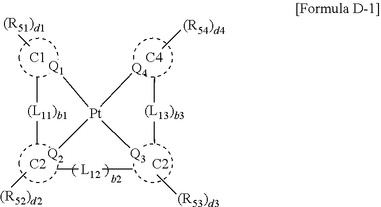

In Formula D-1, Q₁ to Q₄ may each independently be C or N; C1 to C4 may each independently be a substituted or unsubstituted hydrocarbon ring having 5 to 30 ring-forming carbon atoms, or a substituted or unsubstituted heterocycle having 2 to 30 ring-forming carbon atoms; L₁₁ to L₁₃ may each independently be a direct linkage, *—O—*, *—S—*,

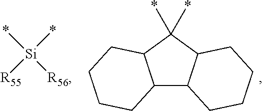

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; b1 to b3 may each independently be 0 or 1; R₅₁ to R₅₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring; and d1 to d4 may each independently be an integer from 0 to 4.

Another embodiment provides a fused polycyclic compound which may be represented by Formula 1, which is explained herein.

In an embodiment, the fused polycyclic compound represented by Formula 1 may be represented by any one of Formula 2-1 to Formula 2-4, which are explained herein.

In an embodiment, the fused polycyclic compound represented by Formula 1 may be represented by any one of Formula 3-1 to Formula 3-3, which are explained herein.

In an embodiment, the fused polycyclic compound represented by Formula 1 may be represented by any one of Formula 4-1 to Formula 4-6, which are explained herein.

In an embodiment, the fused polycyclic compound represented by Formula 1 may be represented by any one of Formula 5-1 to Formula 5-3, which are explained herein.

In an embodiment, in Formula 5-1 and Formula 5-2, R₃ₐ and R_{3b} may each independently be a substituted or unsubstituted alkyl group having 1 to 10 carbon atoms, or a group represented by any one of Formula 7-1 to Formula 7-3, which are explained herein.

In an embodiment, the fused polycyclic compound represented by Formula 1 may be represented by Formula 8, which is explained herein.

In an embodiment, in Formula 1, R₁ may be a substituted or unsubstituted alkyl group having 1 to 10 carbon atoms, or a group represented by any one of Formula 9-1 to Formula 9-6, which are explained herein.

In an embodiment, the fused polycyclic compound represented by Formula 1 may be selected from Compound Group 1, which is explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a plan view of a display apparatus according to an embodiment;

FIG. 2 is a schematic cross-sectional view of a display apparatus according to an embodiment;

FIG. 3 is a schematic cross-sectional view illustrating a light emitting device according to an embodiment;

FIG. 4 is a schematic cross-sectional view illustrating a light emitting device according to an embodiment;

FIG. 5 is a schematic cross-sectional view illustrating a light emitting device according to an embodiment;

FIG. 6 is a schematic cross-sectional view illustrating a light emitting device according to an embodiment;

FIG. 7 is a schematic cross-sectional view of a display apparatus according to an embodiment;

FIG. 8 is a schematic cross-sectional view of a display apparatus according to an embodiment;

FIG. 9 is a schematic cross-sectional view illustrating a display apparatus according to an embodiment; and

FIG. 10 is a schematic cross-sectional view illustrating a display apparatus according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may be interpreted as a group that is bonded to an adjacent group to form a substituted or unsubstituted hydrocarbon ring, or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent substituted for an atom which is substituted with a corresponding substituent, or as a substituent sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear, branched, or cyclic. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, an alkenyl group may be a hydrocarbon group including at least one carbon-carbon double bond in the middle or a terminus of an alkyl group having two or more carbon atoms. The alkenyl group may be linear or branched. Although the number of carbon atoms is not limited, it may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 30 ring-forming carbon atoms.

In the specification, an aryl group may be any functional group or substituent derived from an aromatic hydrocarbon ring. The aryl group may be monocyclic or polycyclic. The number of ring-forming carbon atoms in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a heterocyclic group may be any functional group or substituent derived from a ring that includes at least one of B, O, N, P, S, Si, or Se as a heteroatom. The heterocyclic group may be an aliphatic heterocyclic group or an aromatic heterocyclic group. An aromatic heterocyclic group may be a heteroaryl group. An aliphatic heterocycle or an aromatic heterocycle may each independently be monocyclic or polycyclic.

In the specification, when a heterocyclic group includes two or more heteroatoms, the two or more heteroatoms may be the same as or different from each other. The number of ring-forming carbon atoms in a heterocyclic group may be 2 to 30, 2 to 20, or 2 to 10.

In the specification, examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of the aryl group may be applied to an arylene group, except that the arylene group is a divalent group. In the specification, the above description of the heteroaryl group may be applied to a heteroarylene group except, that the heteroarylene group is a divalent group.

In the specification, a silyl group may be an alkylsilyl group or an arylsilyl group. Examples of a silyl group may include trimethylsilyl, triethylsilyl, t-butyldimethylsilyl, vinyldimethylsilyl, propyldimethylsilyl, triphenylsilyl, diphenylsilyl, phenylsilyl, etc. However, embodiments are not limited thereto.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not limited, but may be, for example, 1 to 20 or 1 to 10. Examples of an oxy group may include methoxy, ethoxy, n-propoxy, isopropoxy, butoxy, pentyloxy, hexyloxy, octyloxy, nonyloxy, decyloxy, benzyloxy, etc., but embodiments are not limited thereto.

In the specification, a boron group may be a boron atom that is bonded to an alkyl group or an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, a triphenylamine group, etc., but embodiments are not limited thereto.

In the specification, a direct linkage may be a single bond.

In the specification, the symbol -* represents a bonding site to a neighboring atom.

Hereinafter, embodiments will be described with reference to the drawings.

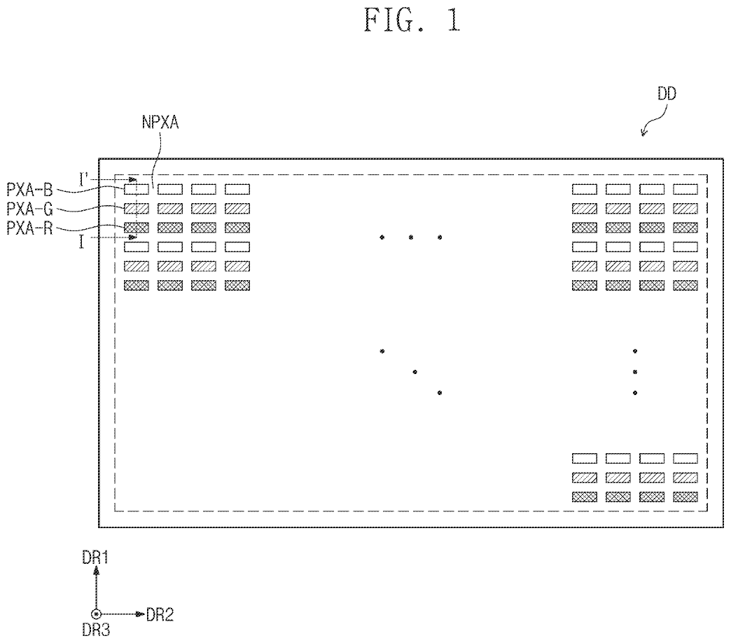

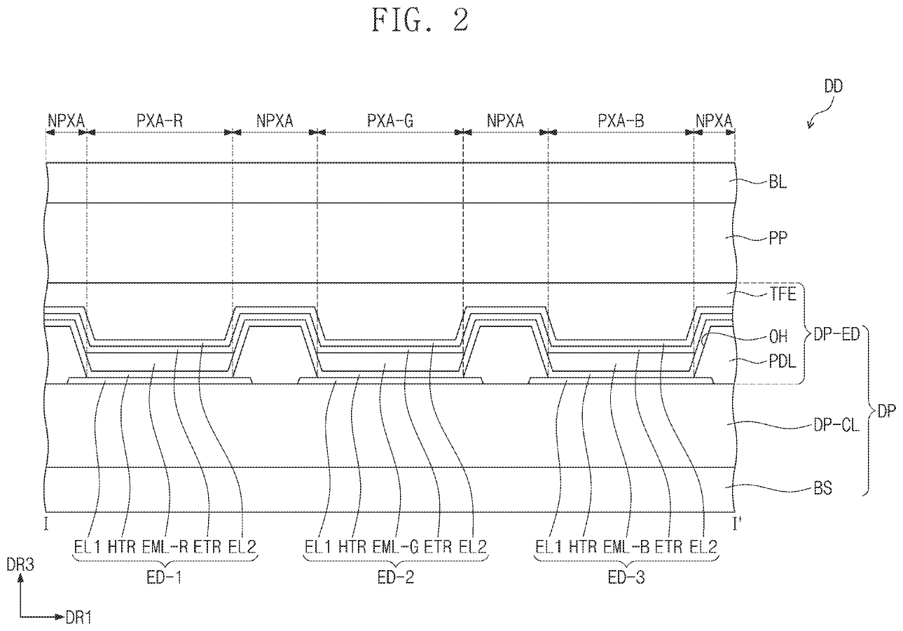

FIG. 1 is a plan view illustrating an embodiment of a display apparatus DD. FIG. 2 is a schematic cross-sectional view of the display apparatus DD according to an embodiment. FIG. 2 is a schematic cross-sectional view illustrating a part taken along line I-I′ of FIG. 1.

The display apparatus DD may include a display panel DP and an optical layer PP disposed on the display panel DP. The display panel DP includes light emitting devices ED-1, ED-2, and ED-3. The display apparatus DD may include multiples of each of the light emitting devices ED-1, ED-2, and ED-3. The optical layer PP may be disposed on the display panel DP and may control light reflected at the display panel DP from an external light. The optical layer PP may include, for example, a polarization layer or a color filter layer. Although not shown in the drawings, in an embodiment, the optical layer PP may be omitted from the display apparatus DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display apparatus DD according to an embodiment may further include a filling layer (not shown). The filling layer (not shown) may be disposed between a display device layer DP-ED and the base substrate BL. The filling layer (not shown) may be an organic material layer. The filling layer (not shown) may include at least one of an acrylic-based resin, a silicone-based resin, or an epoxy-based resin.

The display panel DP may include a base layer BS, a circuit layer DP-CL provided on the base layer BS, and a display device layer DP-ED. The display device layer DP-ED may include a pixel defining film PDL, the light emitting devices ED-1, ED-2, and ED-3 disposed between portions of the pixel defining film PDL, and an encapsulation layer TFE disposed on the light emitting devices ED-1, ED-2, and ED-3.

The base layer BS may provide a base surface on which the display device layer DP-ED is disposed. The base layer BS may be a glass substrate, a metal substrate, a plastic substrate, etc. However, the embodiment is not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). Each of the transistors (not shown) may include a control electrode, an input electrode, and an output electrode. For example, the circuit layer DP-CL may include a switching transistor and a driving transistor for driving the light emitting devices ED-1, ED-2, and ED-3 of the display device layer DP-ED.

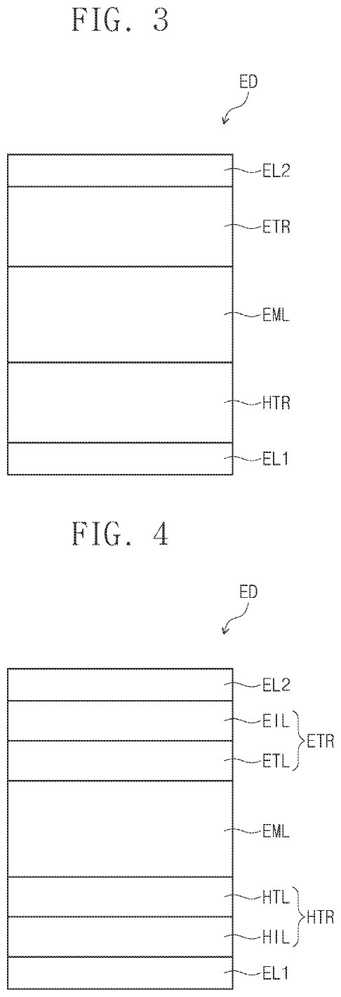

Each of the light emitting devices ED-1, ED-2, and ED-3 may have a structure of a light emitting device ED of an embodiment according to one of FIGS. 3 to 6, which will be described later. The light emitting devices ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting devices ED-1, ED-2, and ED-3 are disposed in openings OH defined in the pixel defining film PDL, and the hole transport region HTR, the electron transport region ETR, and the second electrode EL2 are each provided as a common layer for all of the light emitting devices ED-1, ED-2, and ED-3. However, embodiments are not limited thereto. Although not illustrated in FIG. 2, in an embodiment, the hole transport region HTR and the electron transport region ETR may each be provided by being patterned inside the openings OH defined in the pixel defining film PDL. For example, in an embodiment, the hole transport region HTR, the emission layers EML-R, EML-G, and EML-B, and the electron transport region ETR of the light emitting devices ED-1, ED-2, and ED-3 may each be provided by being patterned by an inkjet printing method.

The encapsulation layer TFE may cover the light emitting devices ED-1, ED-2, and ED-3. The encapsulation layer TFE may seal the display device layer DP-ED. The encapsulation layer TFE may be a thin film encapsulation layer. The encapsulation layer TFE may be formed of a single layer or multiple layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film may protect the display device layer DP-ED from moisture and/or oxygen, and the encapsulation-organic film may protect the display device layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display apparatus DD may include a non-light emitting region NPXA and light emitting regions PXA-R, PXA-G, and PXA-B. The light emitting regions PXA-R, PXA-G, and PXA-B may each be a region in which light respectively generated by the light emitting devices ED-1, ED-2, and ED-3 is emitted. The light emitting regions PXA-R, PXA-G, and PXA-B may be spaced apart from each other in a plan view.

Each of the light emitting regions PXA-R, PXA-G, and PXA-B may be a region separated by the pixel defining film PDL. The non-light emitting areas NPXA may be areas between the adjacent light emitting areas PXA-R, PXA-G, and PXA-B, which correspond to the pixel defining film PDL. For example, in an embodiment, the light emitting regions PXA-R, PXA-G, and PXA-B may each respectively correspond to a pixel. The pixel defining film PDL may separate the light emitting devices ED-1, ED-2, and ED-3. The emission layers EML-R, EML-G, and EML-B of the light emitting devices ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light emitting devices ED-1, ED-2, and ED-3. In the display apparatus DD according to an embodiment illustrated in FIGS. 1 and 2, three light emitting regions PXA-R, PXA-G, and PXA-B, which respectively emit red light, green light, and blue light, are illustrated as an example. For example, the display apparatus DD according to an embodiment may include the red light emitting region PXA-R, the green light emitting region PXA-G, and the blue light emitting region PXA-B, which are separated from each other.

In the display apparatus DD according to an embodiment, the light emitting devices ED-1, ED-2 and ED-3 may emit light having wavelengths different from each other. For example, in an embodiment, the display apparatus DD may include a first light emitting device ED-1 that emits red light, a second light emitting device ED-2 that emits green light, and a third light emitting device ED-3 that emits blue light. For example, the red light emitting region PXA-R, the green light emitting region PXA-G, and the blue light emitting region PXA-B of the display apparatus DD may respectively correspond to the first light emitting device ED-1, the second light emitting device ED-2, and the third light emitting device ED-3.

However, embodiments are not limited thereto, and the first to third light emitting devices ED-1, ED-2, and ED-3 may emit light in a same wavelength range or at least one light emitting device may emit light in a wavelength range that is different from the others. For example, the first to third light emitting devices ED-1, ED-2, and ED-3 may all emit blue light.

The light emitting regions PXA-R, PXA-G, and PXA-B in the display apparatus DD according to an embodiment may be arranged in a stripe configuration. Referring to FIG. 1, the red light emitting regions PXA-R, the green light emitting regions PXA-G, and the blue light emitting regions PXA-B may each be arranged along a second directional axis DR2. In another embodiment, the red light emitting region PXA-R, the green light emitting region PXA-G, and the blue light emitting region PXA-B may be alternately arranged in this order along a first directional axis DR1.

FIGS. 1 and 2 illustrate that the light emitting regions PXA-R, PXA-G, and PXA-B have a similar area to each other, but embodiments are not limited thereto. Thus, the light emitting regions PXA-R, PXA-G, and PXA-B may have different areas from each other according to a wavelength range of emitted light. For example, the areas of the light emitting regions PXA-R, PXA-G, and PXA-B may be areas in a plan view that are defined by the first directional axis DR1 and the second directional axis DR2.

An arrangement configuration of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the display quality characteristics which are required in the display apparatus DD. For example, the light emitting regions PXA-R, PXA-G, and PXA-B may be arranged in a pentile configuration (for example, in a PENTILE™ configuration) or in a diamond configuration (for example, in a Diamond Pixel™ configuration).

In an embodiment, the areas of the light emitting regions PXA-R, PXA-G, and PXA-B may be different from each other. For example, in an embodiment, an area of the green light emitting region PXA-G may be smaller than an area of the blue light emitting region PXA-B, but embodiments are not limited thereto.

Hereinafter, FIGS. 3 to 6 are each a schematic cross-sectional view illustrating a light emitting device according to an embodiment. The light emitting devices ED according to embodiments may each include a first electrode EL1, a hole transport region HTR, an emission layer EML, an electron transport region ETR, and a second electrode EL2 which may be stacked in that order, as shown in FIG. 3.

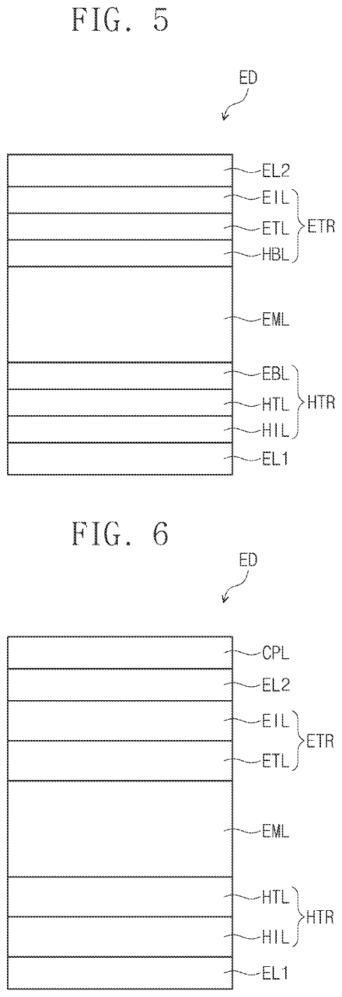

In comparison to FIG. 3, FIG. 4 illustrates a schematic cross-sectional view of a light emitting device ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 illustrates a schematic cross-sectional view of a light emitting device ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 illustrates a schematic cross-sectional view of a light emitting device ED according to an embodiment that includes a capping layer CPL disposed on a second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. For example, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective layer or a transflective layer formed of the above-described materials, and a transparent conductive layer formed of ITO, IZO, ZnO, ITZO, etc. For example, the first electrode EL1 may have a three-layer structure of ITO/Ag/ITO, but embodiments are not limited thereto. The first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR is provided on the first electrode EL1. The hole transport region HTR may include at least one of a hole injection layer HIL, a hole transport layer HTL, a buffer layer (not shown), an emission-auxiliary layer (not shown), or an electron blocking layer EBL. A thickness of the hole transport region HTR may be, for example, in a range of about 50 Å to about 15,000 Å.

The hole transport region HTR may be a layer formed of a single material, a layer formed of a different materials, or a structure including multiple layers formed of a different materials.

For example, the hole transport region HTR may have a single layer structure of a hole injection layer HIL or a hole transport layer HTL, or may have a single layer structure formed of a hole injection material and a hole transport material. In other embodiments, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-2:

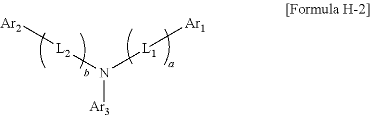

In Formula H-2, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-2, a and b may each independently be an integer from 0 to 10. When a or b is 2 or greater, multiple L₁ groups or multiple L₂ groups may each independently be a substituted or unsubstituted arylene group having 6 to 30 ring-forming carbon atoms, or a substituted or unsubstituted heteroarylene group having 2 to 30 ring-forming carbon atoms.

In Formula H-2, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In Formula H-2, Ar₃ may be a substituted or unsubstituted aryl group having 6 to 30 ring-forming carbon atoms, or a substituted or unsubstituted heteroaryl group having 2 to 30 ring-forming carbon atoms.

In an embodiment, the compound represented by Formula H-2 may be a monoamine compound. In another embodiment, the compound represented by Formula H-2 may be a diamine compound in which at least one of Ar₁ to Ar₃ includes an amine group as a substituent. In still another embodiment, the compound represented by Formula H-2 may be a carbazole-based compound in which at least one of Ar₁ or Ar₂ includes a substituted or unsubstituted carbazole group, or may be a fluorene-based compound in which at least one of Ar₁ or Ar₂ includes a substituted or unsubstituted fluorene group.

The compound represented by Formula H-2 may be any compound selected from Compound Group H. However, the compounds listed in Compound Group H are only examples, and the compounds represented by Formula H-2 are not limited to Compound Group H:

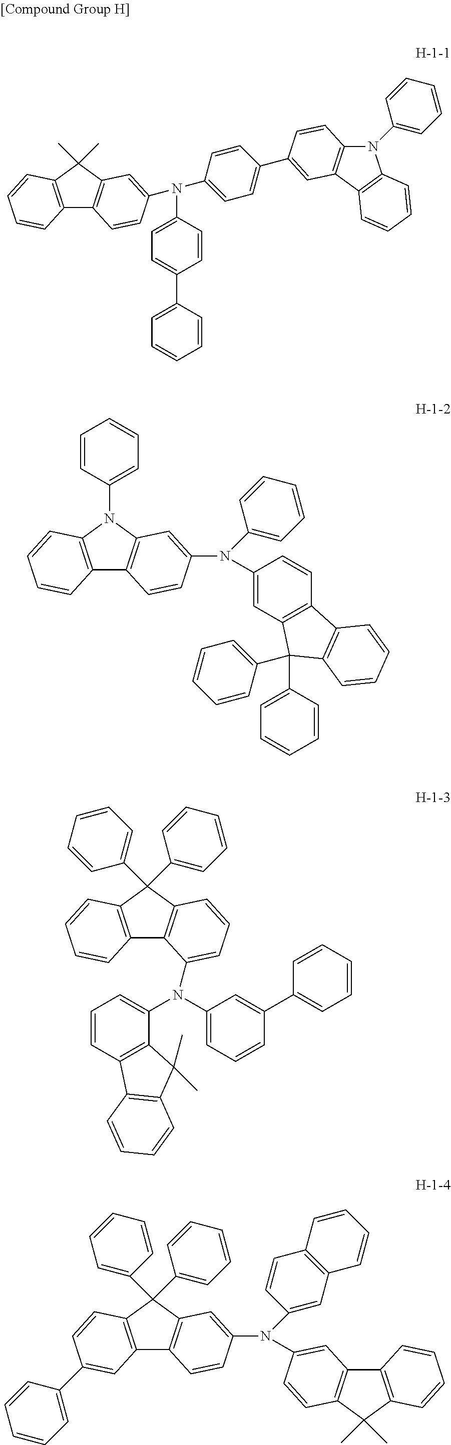 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

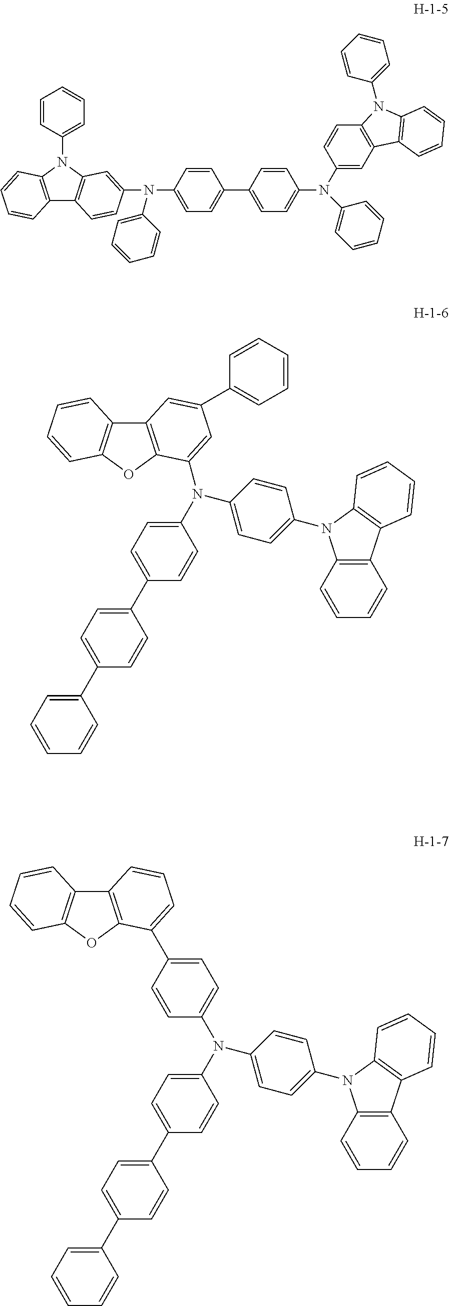 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

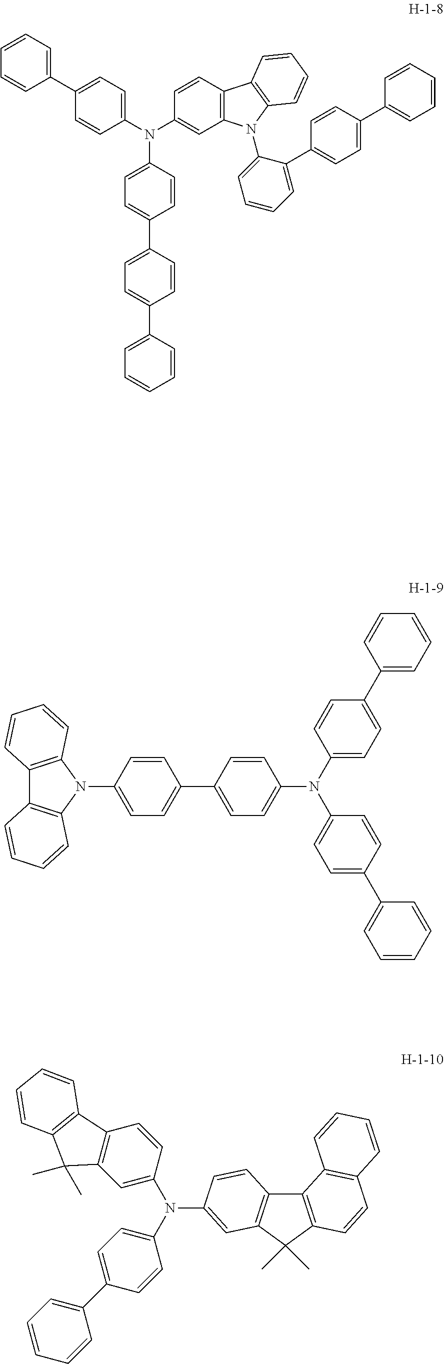 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

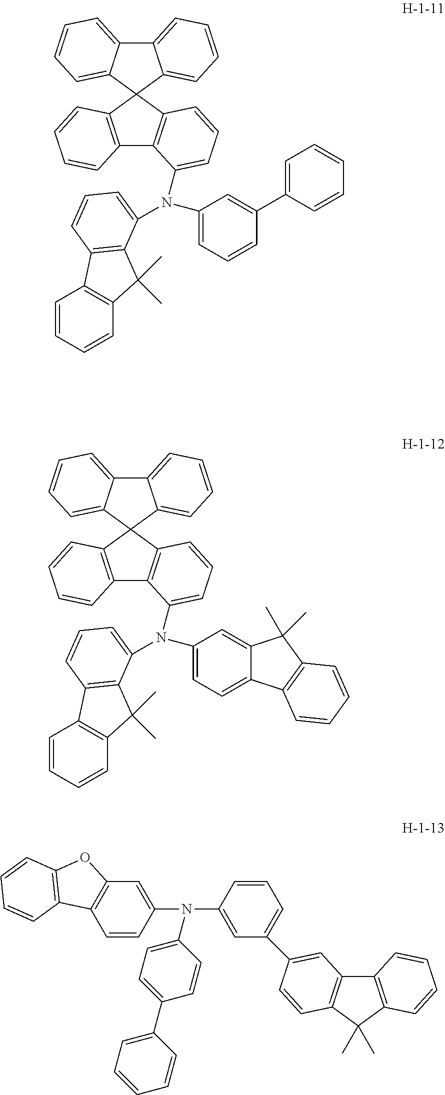 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

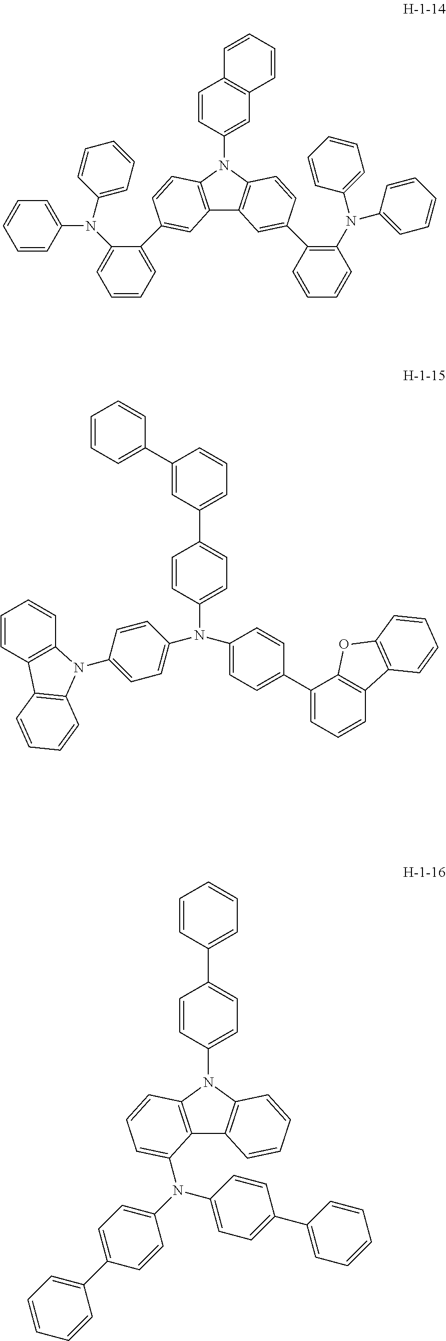 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

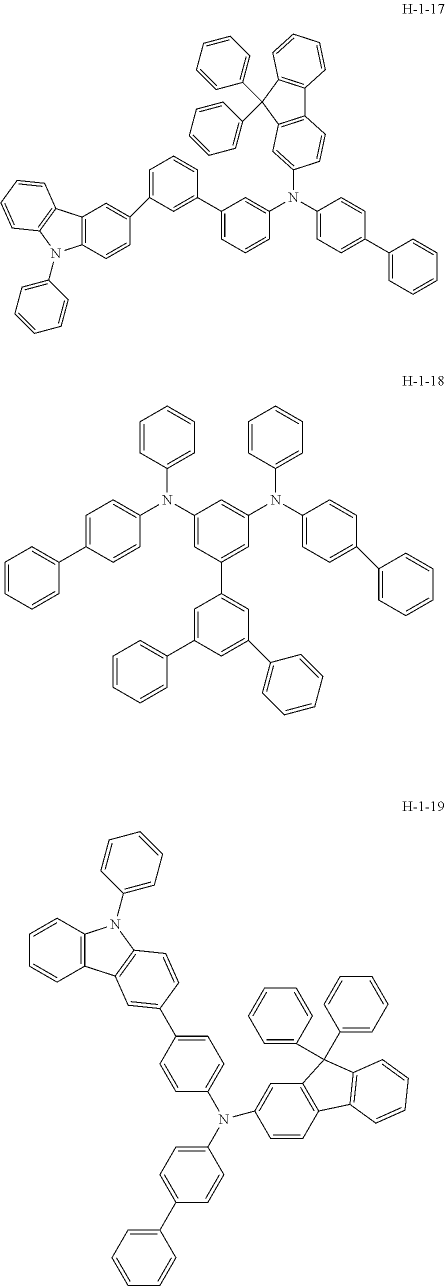 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, or an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have, for example, a thickness in a range of about 30 Å to about 1,000 Å. When the hole transport region HTR includes a hole transport layer HTL, the hole transport layer HTL may have a thickness in a range of about 250 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) or an electron blocking layer EBL, in addition to the hole injection layer HIL and the hole transport layer HTL. The buffer layer (not shown) may compensate for a resonance distance according to a wavelength of light emitted from the emission layer EML and may thus increase light emission efficiency. A material that may be included in the hole transport region HTR may be used as a material to be contained in the buffer layer (not shown). The electron blocking layer EBL may prevent the injection of electrons from the electron transport region ETR to the hole transport region HTR.

The emission layer EML is provided on the hole transport region HTR. The emission layer EML may have a thickness, for example, in a range of about 100 Å to about 1,000 Å. For example, the emission layer EML may have a thickness in a range of about 100 Å to about 300 Å. The emission layer EML may be a layer formed of a single material, a layer formed of different materials, or a structure having multiple layers formed of different materials.

The emission layer EML in the light emitting device ED according to an embodiment may include a fused polycyclic compound according to an embodiment. In an embodiment, the emission layer EML may include the fused polycyclic compound according to an embodiment as a dopant. The fused polycyclic compound according to an embodiment may be a dopant material of the emission layer EML. In the specification, the fused polycyclic compound according to an embodiment, which will be described later, may be referred to as a first compound.

The fused polycyclic compound according to an embodiment may include a structure in which aromatic rings are fused via a boron atom and a nitrogen atom. For example, the fused polycyclic compound according to an embodiment may include a structure in which first to third aromatic rings are fused via a boron atom, a first nitrogen atom, and a second nitrogen atom. The first to third aromatic rings may each be linked to the boron atom, the first aromatic ring and the third aromatic ring may be linked via the first nitrogen atom, and the second aromatic ring and the third aromatic ring may be linked via the second nitrogen atom. The first aromatic ring and the second aromatic ring may be symmetric with respect to the boron atom in the fused ring structure. In the specification, the first to third aromatic rings which are fused via the boron atom and the first and second nitrogen atoms may be referred to as a “fused ring core”.

The fused polycyclic compound according to an embodiment may include a first moiety which is fused at the first aromatic ring. The first moiety may contain a first atom and first to third benzene rings linked to the first atom. In an embodiment, the first atom may be a carbon atom (C) or a silicon atom (Si). Each of the first atom and the first benzene ring of the first moiety may be linked to the first aromatic ring. The first atom may be directly bonded to the first aromatic ring. The first benzene ring may be directly bonded to the first aromatic ring or may be linked to the first aromatic ring via a second atom. However, when the first atom is a silicon atom, the first benzene ring may not be directly bonded to the first aromatic ring, and may be linked to the first aromatic ring via the second atom. In an embodiment, the second atom may be an oxygen atom (O). In the specification, the first atom may be Z₁ in Formula 1, which will be described later, and the second atom may be Y₁ in Formula 1, which will be described later, and in which a direct linkage is excluded.

In the first moiety, the second benzene ring and the third benzene ring may be separated from each other, or may be linked to each other to form a bond. When the second benzene ring and the third benzene ring form a bond, the second benzene ring and the third benzene ring may be directly bonded or may be linked via a third atom. In the specification, the third atom may be Y₂ in Formula 1, which will be described later, and in which a direct linkage is excluded.

The first atom of the first moiety may be linked at a para-position to the first nitrogen atom. The first benzene ring of the first moiety may be linked to the first aromatic ring at an ortho-position with respect to the carbon atom linked to the first atom among carbon atoms constituting the first benzene ring. The first benzene ring of the first moiety may be linked at a para-position to the boron atom. In another embodiment, when the first benzene ring is linked to the first aromatic ring via the second atom, the second atom may be linked at a para-position to the boron atom.

The fused polycyclic compound according to an embodiment may be represented by Formula 1:

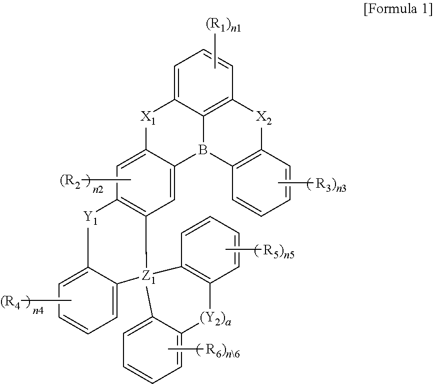

The fused polycyclic compound represented by Formula 1 according to an embodiment may include a structure in which three aromatic rings are fused via one boron atom and two nitrogen atoms. In the specification, the benzene ring with a substituent represented by R₅ in Formula 1 corresponds to the above-described second benzene ring, and the benzene ring with a substituent represented by R₆ in Formula 1 corresponds to the above-described third benzene ring.

In Formula 1, X₁ and X₂ may each be N(R₇).

In Formula 1, Y₁ may be a direct linkage or O.

In Formula 1, Y₂ may be a direct linkage, O, or N(R₈).

In Formula 1, Z₁ may be C or Si. In Formula 1, when Z₁ is Si, Y₁ may be O.

In Formula 1, R₁ to R₈ may each independently be a hydrogen atom, a deuterium atom, a halogen atom, a substituted or unsubstituted amine group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. For example, R₁ and R₃ may each independently be a hydrogen atom, a substituted or unsubstituted arylamine group, a substituted or unsubstituted phenyl group, a substituted or unsubstituted carbazole group, a substituted or unsubstituted dibenzofuran group, a substituted or unsubstituted indolocarbazole group, or a substituted or unsubstituted tetralin group. For example, R₂, R₅, and R₆ may each be a hydrogen atom. For example, R₄ may be a hydrogen atom, or a substituted or unsubstituted phenyl group. For example, R₇ and R₈ may each independently be a substituted or unsubstituted phenyl group, a substituted or unsubstituted biphenyl group, or a substituted or unsubstituted terphenyl group.

In Formula 1, n1 may be an integer from 0 to 3. In Formula 1, if n1 is 0, the fused polycyclic compound may not be substituted with R₁. In Formula 1, a case where n1 is 3 and R₁ groups are all hydrogen atoms may be the same as the case where n1 is 0 in Formula 1. If n1 is 2 or more, multiple R₁ groups may all be the same, or at least one thereof may be different from the others.

In Formula 1, n2 may be an integer from 0 to 2. In Formula 1, if n2 is 0, the fused polycyclic compound may not be substituted with R₂. In Formula 1, a case where n2 is 2 and R₂ groups are all hydrogen atoms may be the same as the case where n2 is 0 in Formula 1. If n2 is 2, multiple R₂ groups may all be the same, or at least one thereof may be different from the others.

In Formula 1, n3 and n4 may each independently be an integer from 0 to 4. In Formula 1, if n3 and n4 are each 0, the fused polycyclic compound may not be substituted with each of R₃ and R₄. In Formula 1, a case where each of n3 and n4 is 4 and R₃ groups and R₄ groups are each hydrogen atoms may be the same as the case where each of n3 and n4 is 0 in Formula 1. When n3 and n4 are each 2 or more, multiple groups of each of R₃ and R₄ may each be the same, or at least one thereof may be different from the others.

In Formula 1, a may be 0 or 1. In Formula 1, when a is 1, Y₂ may be a direct linkage, O, or N(R₈). In Formula 1, a case where a is 0 may be a case where the two benzene rings bonded to Z₁ in Formula 1 are not connected via Y₂.

In Formula 1, n5 and n6 may each independently be an integer from 0 to 5, the sum of a and n5 may be 5 or less, and the sum of a and n6 may be 5 or less. In Formula 1, if n5 and n6 are each 0, the fused polycyclic compound may not be substituted with each of R₅ and R₆. In Formula 1, a case where a is 0, n5 and n6 are each 5, and R₅ groups and R₆ groups are each hydrogen atoms may be the same as the case where a is 0 and n5 and n6 are each 0. In Formula 1, a case where a is 1, n5 and n6 are each 4, and R₅ groups and R₆ groups are each hydrogen atoms may be the same as the case where a is 1 and n5 and n6 are each 0. When n5 and n6 are each 2 or more, multiple groups of each of R₅ and R₆ may each be the same, or at least one thereof may be different from the others.

In Formula 1, when a is 0, the case where R₄ is a substituted or unsubstituted amine group may be excluded. For example, in Formula 1, when a is 0, R₄ may not be a substituted or unsubstituted amine group. For example, when the second benzene ring substituted with R₅ and the third benzene ring substituted with R₆ do not form a bond and are separated, an amine group may not be substituted at the first benzene ring.

The fused polycyclic compounds according to embodiments may include a structure in which the first moiety is fused at a particular position to the fused ring core structure in which the first to third aromatic rings are fused via one boron atom and two nitrogen atoms, and thus may effectively protect the boron atom, thereby achieving high efficiency and long service life. The fused polycyclic compound of an embodiment may have increased luminous efficiency because the intermolecular interaction may be suppressed by the introduction of the first moiety, thereby controlling the formation of aggregation, excimer, or exciplex. The fused polycyclic compound may have a large steric hindrance structure due to the first moiety, thus the distance between adjacent molecules increases, thereby suppressing Dexter energy transfer, TTA, TPQ, etc. so that service life degradation caused by an increase in triplet concentration may be suppressed.

In an embodiment, the fused polycyclic compound represented by Formula 1 may be represented by Formula 1-1:

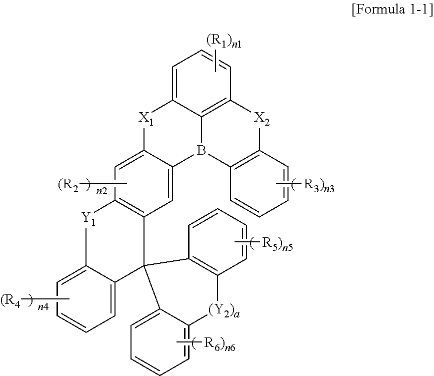

Formula 1-1 represents an embodiment wherein Z₁ is specified in Formula 1. Formula 1-1 represents the case where Z₁ is C in Formula 1.

In Formula 1-1, the second benzene ring substituted with R₅ and the third benzene ring substituted with R₆ may be separated from each other, or they may be connected to each other via Y₂. In Formula 1-1, when a is 0, the second benzene ring may not be bonded to the third benzene ring. In Formula 1-1, when a is 1, the second benzene ring may be bonded to the third benzene ring to form a ring. For example, when a is 1, the second benzene ring substituted with R₅ may be connected via Y₂ to the third benzene ring substituted with R₆ to form a spiro structure.

In the fused polycyclic compound, when the second benzene ring of the first moiety is bonded to the third benzene ring to form a spiro structure, the second benzene ring and the third benzene ring may have a twisted non-coplanar structure at the position of a sp³ carbon, which is the central carbon atom of the spiro structure. Accordingly, orbitals are not distributed in the second benzene ring and the third benzene ring, electron density is trapped in the fused ring core, and thereby an effect of further promoting multiple resonance may be obtained. The central carbon atom of the spiro structure maintains a sp³ regular tetrahedral shape, and is thus hard to rotate, and accordingly, a change in conformation decreases so that a degree of structural relaxation after transition may be reduced. Thus, the fused polycyclic compound may have a decrease in Stokes shift and a full width at half maximum (FWHM), and may achieve blue emission with high color purity when the fused polycyclic compound is applied to a light emitting device.

In Formula 1-1, X₁, X₂, Y₁, Y₂, a, R₁ to R₆, and n1 to n6 are each the same as described in Formula 1.

In an embodiment, the fused polycyclic compound represented by Formula 1 may be represented by any one of Formula 2-1 to Formula 2-4:

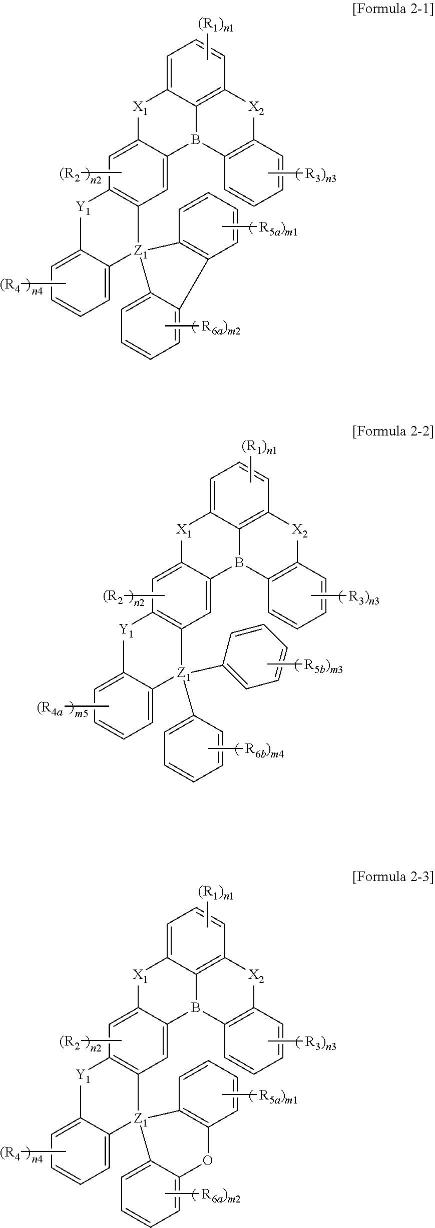

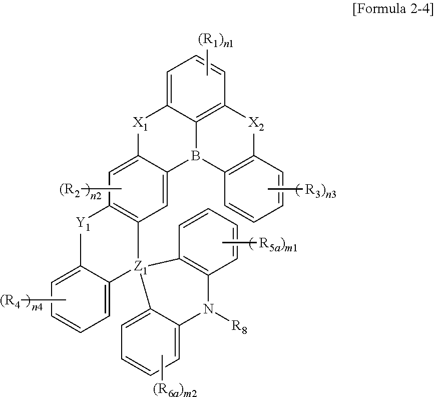

Formula 2-1 to Formula 2-4 each represent a case where the number and type of Y₂ are specified in Formula 1. Formula 2-1 represents the case where a is 1 and Y₂ is a direct linkage in Formula 1. Formula 2-2 represents the case where a is 0 in Formula 1. Formula 2-3 represents the case where a is 1 and Y₂ is O in Formula 1. Formula 2-4 represents the case where a is 1 and Y₂ is N(R₈) in Formula 1.

In Formula 2-1 to Formula 2-4, R₅ₐ, R₆ₐ, R_{5b}, and R_{6b} may each independently be a hydrogen atom, a deuterium atom, a halogen atom, a substituted or unsubstituted amine group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In an embodiment, R₅ₐ, R₆ₐ, R_{5b}, and R_{6b} may each be a hydrogen atom.

In Formula 2-2, R₄ₐ may be a hydrogen atom, a deuterium atom, a halogen atom, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In an embodiment, R₄ₐ may be a hydrogen atom, or a substituted or unsubstituted aryl group having 6 to 30 ring-forming carbon atoms. For example, R₄ₐ may be a hydrogen atom, or a substituted or unsubstituted phenyl group.

In Formula 2-1 to Formula 2-4, m1, m2, and m5 may each independently be an integer from 0 to 4. If m1, m2, and m5 are each 0, the fused polycyclic compound may not be substituted with each of R₅ₐ, R₆ₐ, and R₄ₐ. A case where each of m1, m2, and m5 is 4 and R₅ₐ groups, R₆ₐ groups, and R₄ₐ groups are each a hydrogen atom may be the same as the case where m1, m2, and m5 are each 0. If m1, m2, and m5 are each 2 or more, multiple groups of each of R₅ₐ, R₆ₐ, and R₄ₐ may each be the same, or at least one thereof may be different from the others.

In Formula 2-2, m3 and m4 may each independently be an integer from 0 to 5. If m3 and m4 are each 0, the fused polycyclic compound may not be substituted with each of R_{5b} and R_{6b}. A case where m3 and m4 are each 5 and R_{5b} groups and R_{6b} groups are each hydrogen atoms may be the same as the case where each of m3 and m4 is 0. When m3 and m4 are each 2 or more, multiple groups of each of R_{5b} and R_{6b} may each be the same, or at least one thereof may be different from the others.

In Formula 2-1 to Formula 2-4, X₁, X₂, Y₁, Z₁, R₁ to R₄, and n1 to n4 are each the same as described in Formula 1.

In an embodiment, the first compound represented by Formula 1 may be represented by any one of Formula 3-1 to Formula 3-3:

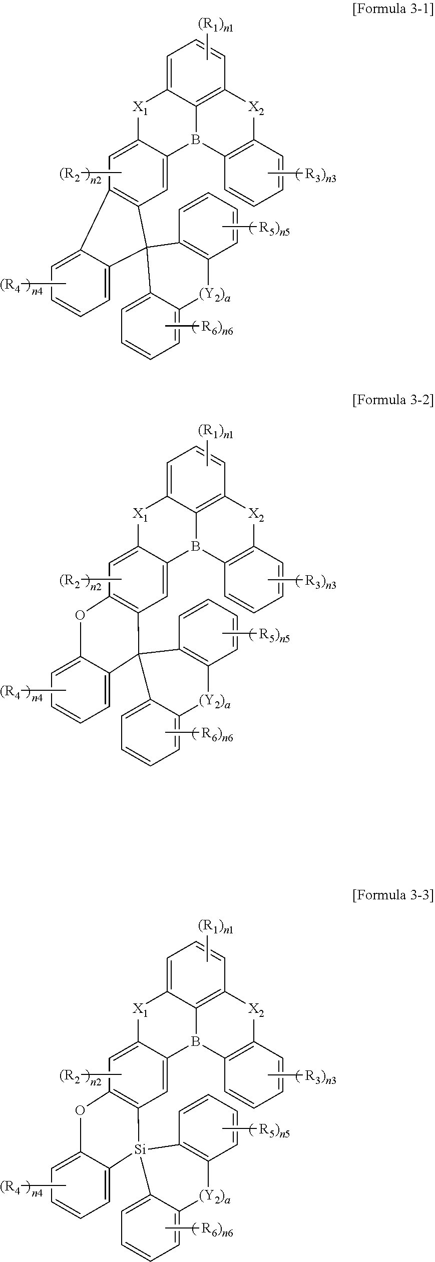

Formula 3-1 to Formula 3-3 each represent a case where Z₁ and Y₁ are specified in Formula 1. Formula 3-1 represents the case where Z₁ is C and Y₁ is a direct linkage in Formula 1. Formula 3-2 represents the case where Z₁ is C and Y₁ is O in Formula 1. Formula 3-3 represents the case where Z₁ is Si and Y₁ is O in Formula 1.

In Formula 3-1 to Formula 3-3, X₁, X₂, Y₂, a, R₁ to R₆, and n1 to n6 are each the same as described in Formula 1.

In an embodiment, the first compound represented by Formula 1 may be represented by any one of Formula 4-1 to Formula 4-6:

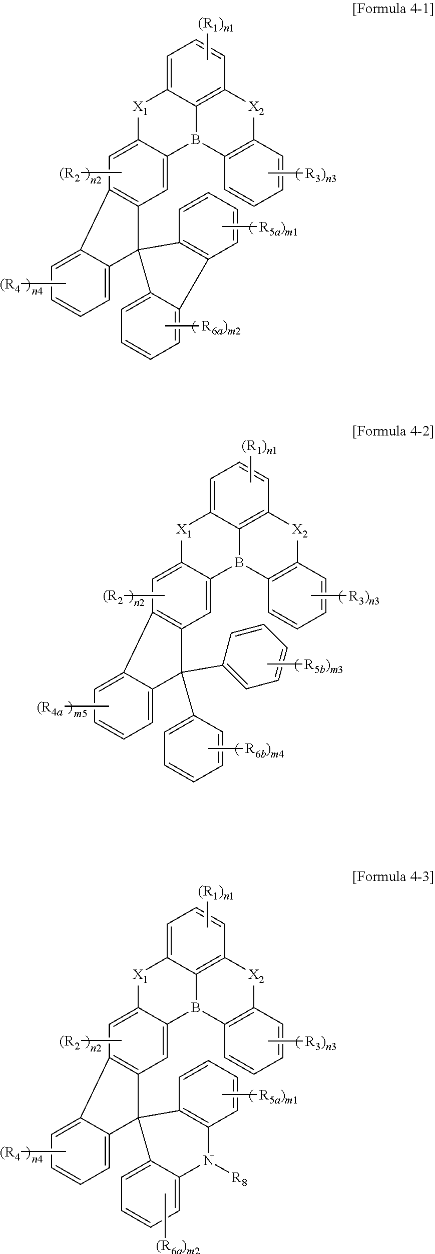

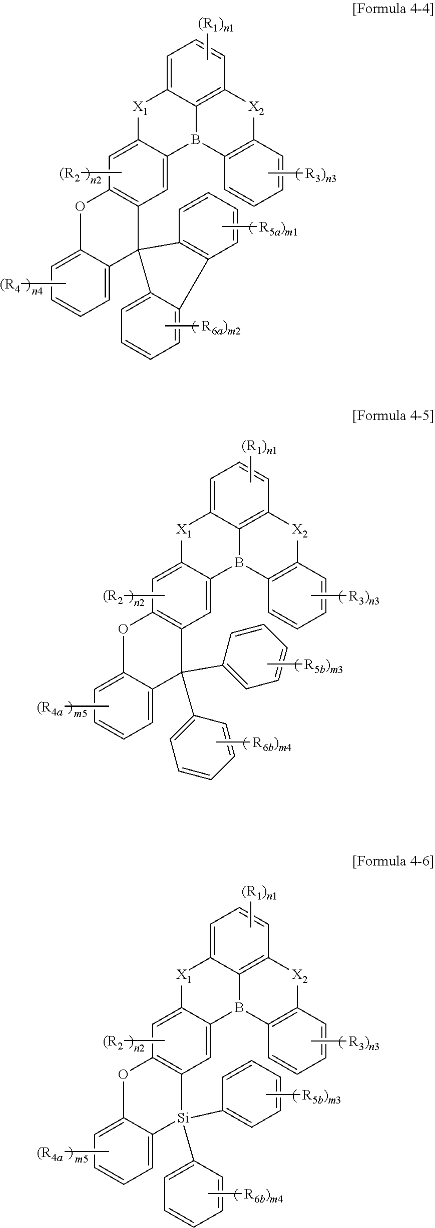

Formula 4-1 to Formula 4-6 each represent a case where Z₁, Y₁, a, and Y₂ are specified in Formula 1. Formula 4-1 represents the case where Z₁ is C, Y₁ is a direct linkage, a is 1, and Y₂ is a direct linkage in Formula 1. Formula 4-2 represents the case where Z₁ is C, Y₁ is a direct linkage, and a is 0 in Formula 1. Formula 4-3 represents the case where Z₁ is C, Y₁ is a direct linkage, a is 1, and Y₂ is N(R₈) in Formula 1. Formula 4-4 represents the case where Z₁ is C, Y₁ is O, a is 1, and Y₂ is a direct linkage in Formula 1. Formula 4-5 represents the case where Z₁ is C, Y₁ is O, and a is 0 in Formula 1. Formula 4-6 represents the case where Z₁ is Si, Y₁ is O, and a is 0 in Formula 1.

In Formula 4-1 to Formula 4-6, R₅ₐ, R₆ₐ, R_{5b}, and R_{6b} may each independently be a hydrogen atom, a deuterium atom, a halogen atom, a substituted or unsubstituted amine group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In an embodiment, R₅ₐ, R₆ₐ, R_{5b}, and R_{6b} may each be a hydrogen atom.

In Formula 4-2, Formula 4-5, and Formula 4-6, R₄ₐ may be a hydrogen atom, a deuterium atom, a halogen atom, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In an embodiment, R₄ₐ may be a hydrogen atom, or a substituted or unsubstituted aryl group having 6 to 30 ring-forming carbon atoms. For example, R₄ₐ may be a hydrogen atom, or a substituted or unsubstituted phenyl group.

In Formula 4-1 to Formula 4-6, m1, m2, and m5 may each independently be an integer from 0 to 4. If m1, m2, and m5 are each 0, the fused polycyclic compound may not be substituted with each of R₅ₐ, R₆ₐ, and R₄ₐ. A case where m1, m2, and m5 are each 4 and R₅ₐ groups, R₆ₐ groups, and R₄ₐ groups are each hydrogen atoms may be the same as the case where m1, m2, and m5 are each 0. If m1, m2, and m5 are each 2 or more, multiple groups of each of R₅ₐ, R₆ₐ, and R₄ₐ may each be the same, or at least one thereof may be different from the others.

In Formula 4-2, Formula 4-5, and Formula 4-6, m3 and m4 may each independently be an integer from 0 to 5. If m3 and m4 are each 0, the fused polycyclic compound may not be substituted with each of R_{5b} and R_{6b}. A case where m3 and m4 are each 5 and R_{5b} groups and R_{6b} groups are each hydrogen atoms may be the same as the case where m3 and m4 are each 0. When m3 and m4 are each 2 or more, multiple groups of each of R_{5b} and R_{6b} may each be the same, or at least one thereof may be different from the others.

In Formula 4-1 to Formula 4-6, X₁, X₂, R₁ to R₄, and n1 to n4 are each the same as described in Formula 1.

In an embodiment, the first compound represented by Formula 1 may be represented by any one of Formula 5-1 to Formula 5-3:

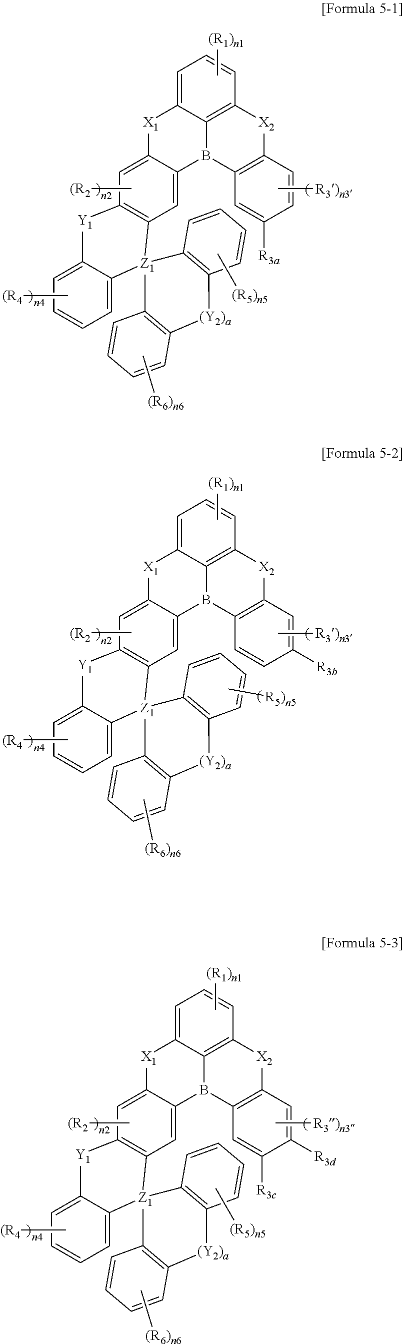

Formula 5-1 and Formula 5-2 each represent a case where the number and substituted position of R₃ are specified in Formula 1. Formula 5-1 represents the case where the substituent represented by R₃ is substituted at a para-position to X₂ in Formula 1. Formula 5-2 represents the case where the substituent represented by R₃ is substituted at a para-position to the boron atom in Formula 1.

Formula 5-3 represents a case where a second moiety is further fused at the fused ring core of Formula 1. The fused polycyclic compound may further include the second moiety which is fused at the second aromatic ring of the fused ring core. The second moiety may contain a fourth atom and fourth to sixth benzene rings linked to the fourth atom. In an embodiment, the fourth atom may be a carbon atom (C) or a silicon atom (Si). The fourth atom and the fourth benzene ring in the second moiety may be linked to the second aromatic ring of the fused ring core. The fourth atom may be directly bonded to the second aromatic ring. The fourth benzene ring of the second moiety may be directly bonded to the second aromatic ring or may be linked to the second aromatic ring via a fifth atom. However, when the fourth atom is a silicon atom, the fourth benzene ring may not be directly bonded to the second aromatic ring, and may be linked to the second aromatic ring via the fifth atom. In an embodiment, the fifth atom may be an oxygen atom (O). In the specification, the fourth atom may be Z₂ in Formula 6, which will be described later, and the fifth atom may be Y₃ in Formula 6, which will be described later, and in which a direct linkage is excluded.

In the second moiety, the fifth benzene ring and the sixth benzene ring may be separated from each other, or may be linked to each other to form a bond. When the fifth benzene ring and the sixth benzene ring form a bond, the fifth benzene ring and the sixth benzene ring may be directly bonded or may be linked via a sixth atom. In the specification, the sixth atom may be Y₄ in Formula 6, which will be described later, and in which a direct linkage is excluded.

The fourth atom of the second moiety may be linked at a para-position to the second nitrogen atom. The fourth benzene ring of the second moiety may be linked to the second aromatic ring at an ortho position with respect to the carbon atom linked to the fourth atom among carbon atoms constituting the fourth benzene ring. The fourth benzene ring of the second moiety may be linked at a para-position to the boron atom. In another embodiment, when the fourth benzene ring is linked to the second aromatic ring via the fifth atom, the fifth atom may be linked at a para-position to the boron atom.

In Formula 5-1 and Formula 5-2, R₃ₐ and R_{3b} may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₃ₐ and R_{3b} may each independently be a substituted or unsubstituted t-butyl group, a substituted or unsubstituted phenyl group, a substituted or unsubstituted dibenzofuran group, or a substituted or unsubstituted carbazole group.

In Formula 5-1 to Formula 5-3, R₃′ and R₃″ may each independently be a hydrogen atom, a deuterium atom, a halogen atom, a substituted or unsubstituted amine group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₃′ and R₃″ may each independently be a hydrogen atom.

In Formula 5-1 and Formula 5-2, n3′ may be an integer from 0 to 3. In Formula 5-1 and Formula 5-2, if n3′ is 0, the fused polycyclic compound may not be substituted with R₃′. In Formula 5-1 and Formula 5-2, a case where n3′ is 3 and R₃′ groups are all hydrogen atoms may be the same as the case where n3′ is 0 in Formula 5-1 and Formula 5-2. If n3′ is 2 or more, multiple R₃′ groups may all be the same, or at least one thereof may be different from the others.

In Formula 5-3, n3″ may be an integer from 0 to 2. In Formula 5-3, if n3″ is 0, the fused polycyclic compound may not be substituted with R₃″. In Formula 5-3, a case where n3″ is 2 and R₃″ groups are all hydrogen atoms may be the same as the case where n3″ is 0 in Formula 5-3. If n3″ is 2, multiple R₃″ may all be the same, or at least one thereof may be different from the others.

In an embodiment, the second moiety may be represented by Formula 6. In Formula 5-3, R_{3c} and R₃ₐ each represent a bonding position of a moiety represented by Formula 6.

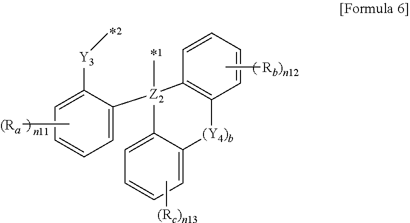

In Formula 6, -*1 is a bonding position to R_{3c} in Formula 5-3, and -*2 is a bonding position to R_{3d} in Formula 5-3.

In Formula 6, Y₃ may be a direct linkage or O.

In Formula 6, Y₄ may be a direct linkage, O, or N(R_{d}).

In Formula 6, Z₂ may be C or Si, and when Z₂ is Si, Y₃ may be O.

In Formula 6, Rₐ to R_{c} may each independently be a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In an embodiment, Rₐ to R_{c} may each independently be a hydrogen atom, or a substituted or unsubstituted aryl group having 6 to 30 ring-forming carbon atoms. For example, Rₐ may be a hydrogen atom, or a substituted or unsubstituted phenyl group. For example, R_{b} and R_{c} may each be a hydrogen atom.

In the specification, the benzene ring substituted with a substituent represented by R_{b} in Formula 6 corresponds to the above-described fifth benzene ring, and the benzene ring substituted with a substituent represented by R_{c} in Formula 6 corresponds to the above-described sixth benzene ring.

In Formula 6, n11 may be an integer from 0 to 4. In Formula 6, if n11 is 0, the fused polycyclic compound may not be substituted with Rₐ. In Formula 6, a case where n11 is 4 and Rₐ groups are all hydrogen atoms may be the same as the case where n11 is 0 in Formula 6. If n11 is 2 or more, multiple Rₐ groups may all be the same, or at least one thereof may be different from the others.

In Formula 6, b may be 0 or 1. In Formula 6, when b is 1, Y₄ may be a direct linkage, O, or N(R_{d}). In Formula 6, a case where b is 0 may be a case where the two benzene rings bonded to Z₂ in Formula 6 are not connected via Y₄.

In Formula 6, n12 and n13 may each independently be an integer from 0 to 4, the sum of b and n12 may be 5 or less, and the sum of b and n13 may be 5 or less. In Formula 6, if b is 0 or 1, and each of n12 and n13 is 0, the fused polycyclic compound may not be substituted with each of R_{b} and R_{c}. In Formula 6, a case where b is 0, n12 and n13 are each 5, and R_{b} groups and R_{c} groups are each hydrogen atoms may be the same as the case where b is 0 and each of n12 and n13 is 0 in Formula 6. In Formula 6, a case where b is 1, n12 and n13 are each 4, and R_{b} groups and R_{c} groups are each hydrogen atoms may be the same as the case where b is 1 and each of n12 and n13 is 0 in Formula 6. When n12 and n13 are each 2 or more, multiple groups of each of R_{b} and R_{c} may each be the same, or at least one thereof may be different from the others.

In Formula 6, when b is 0, a case where Rₐ is a substituted or unsubstituted amine group may be excluded. For example, in Formula 1, when a is 0, Rₐ may not be a substituted or unsubstituted amine group.

In Formula 5-1 to Formula 5-3, X₁, X₂, Z₁, Y₁, Y₂, a, R₁, R₂, R₄ to R₆, n1, n2, and n4 to n6 are each the same as described in Formula 1.

In an embodiment, the second moiety represented by Formula 6 may be represented by Formula 6-1:

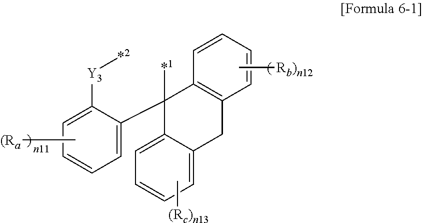

Formula 6-1 represents a case where Z₂ is specified in Formula 6. Formula 6-1 represents the case where Z₂ is C in Formula 6.

In Formula 6-1, the fifth benzene ring substituted with R_{b} and the sixth benzene ring substituted with R_{c} may be separated from each other, or they may be connected to each other via Y₄. In Formula 6-1, when b is 0, the fifth benzene ring may not be bonded to the sixth benzene ring. In Formula 6-1, when b is 1, the fifth benzene ring may be bonded to the sixth benzene ring to form a ring. For example, when b is 1, the fifth benzene ring substituted with R_{b} may be connected via Y₄ to the sixth benzene ring substituted with R_{c} to form a spiro structure.

In Formula 6-1, Rₐ to R_{c}, n11 to n13, Y₃, Y₄, and b are each the same as described in Formula 6.

In an embodiment, in Formula 5-1 and Formula 5-2, R₃ₐ and R_{3b} may each independently be a substituted or unsubstituted alkyl group having 1 to 10 carbon atoms, or a group represented by any one of Formula 7-1 to Formula 7-3:

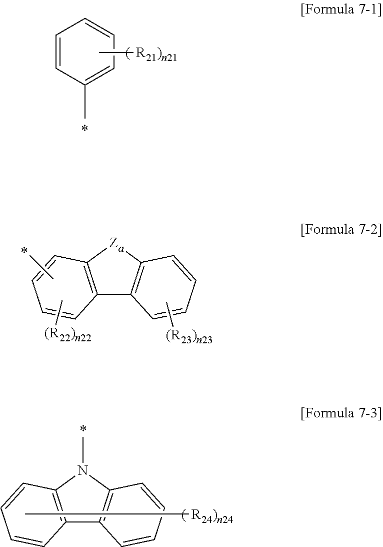

In Formula 7-2, Zₐ may be N(R₂₅) or O.

In Formula 7-1 to Formula 7-3, R₂₁ to R₂₅ may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₂₁ to R₂₅ may each independently be a hydrogen atom, a deuterium atom, a substituted or unsubstituted t-butyl group, or a substituted or unsubstituted carbazole group.

In Formula 7-1, n21 may be an integer from 0 to 5. In Formula 7-1, if n21 is 0, the fused polycyclic compound may not be substituted with R₂₁. In Formula 7-1, a case where n21 is 5 and R₂₁ groups are all hydrogen atoms may be the same as the case where n21 is 0 in Formula 7-1. If n21 is 2 or more, multiple R₂₁ groups may all be the same, or at least one thereof may be different from the others.

In Formula 7-2, n22 may be an integer from 0 to 3. In Formula 7-2, if n22 is 0, the fused polycyclic compound may not be substituted with R₂₂. In Formula 7-2, a case where n22 is 3 and R₂₂ groups are all hydrogen atoms may be the same as the case where n22 is 0 in Formula 7-2. If n22 is 2 or more, multiple R₂₂ groups may all be the same, or at least one thereof may be different from the others.

In Formula 7-2, n23 may be an integer from 0 to 4. In Formula 7-2, if n23 is 0, the fused polycyclic compound may not be substituted with R₂₃. In Formula 7-2, a case where n23 is 4 and R₂₃ groups are all hydrogen atoms may be the same as the case where n23 is 0 in Formula 7-2. If n23 is 2 or more, multiple R₂₃ groups may all be the same, or at least one thereof may be different from the others.

In Formula 7-3, n24 may be an integer from 0 to 8. In Formula 7-3, if n24 is 0, the fused polycyclic compound may not be substituted with R₂₄. In Formula 7-3, a case where n24 is 8 and R₂₄ groups are all hydrogen atoms may be the same as the case where n24 is 0 in Formula 7-3. If n24 is 2 or more, multiple R₂₄ groups may all be the same, or at least one thereof may be different from the others.

In Formula 7-1 to Formula 7-3, -* is a bonding position to Formula 5-1 or Formula 5-2.

In an embodiment, the first compound represented by Formula 1 may be represented by Formula 8:

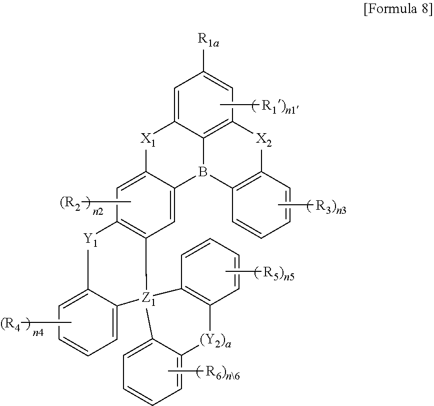

Formula 8 represents a case where a bonding position of R₁ is specified in Formula 1. Formula 8 represents the case where R₁ is bonded at a para-position to the boron atom in Formula 1.

In Formula 8, R₁ₐ may be a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₁ₐ may be a substituted or unsubstituted t-butyl group, a substituted or unsubstituted arylamine group, a substituted or unsubstituted phenyl group, a substituted or unsubstituted dibenzofuran group, a substituted or unsubstituted carbazole group, or a substituted or unsubstituted indolocarbazole group.

In Formula 8, R₁′ may be a hydrogen atom, a deuterium atom, a halogen atom, a substituted or unsubstituted amine group, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₁′ may be a hydrogen atom.

In Formula 8, n1′ may be an integer from 0 to 2. In Formula 8, if n1′ is 0, the fused polycyclic compound may not be substituted with R₁′. In Formula 8, a case where n1′ is 2 and R₁′ groups are all hydrogen atoms may be the same as the case where n1′ is 0 in Formula 8. If n1′ is 2, multiple R₁′ groups may all be the same, or at least one thereof may be different from the others.

In Formula 8, X₁, X₂, Z₁, Y₁, Y₂, a, R₂ to R₆, and n2 to n6 are each the same as described in Formula 1.

In an embodiment, in Formula 1, R₁ may be a substituted or unsubstituted alkyl group having 1 to 10 carbon atoms, or a group represented by any one of Formula 9-1 to Formula 9-6:

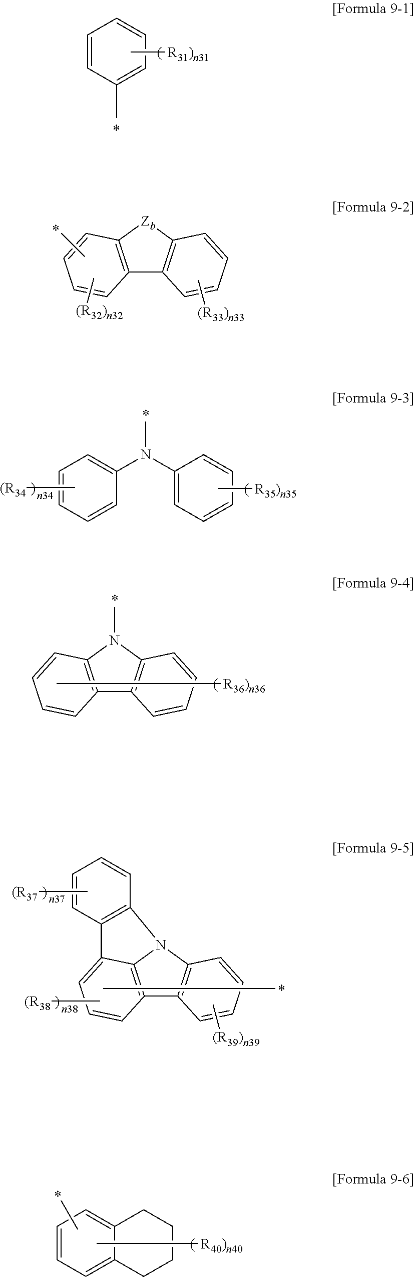

In Formula 9-2, Z_{b} may be N(R₄₁) or O.

In Formula 9-1 to Formula 9-6, R₃₁ to R₄₁ may each independently be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₃₁ to R₄₁ may each independently be a hydrogen atom, a deuterium atom, a cyano group, a substituted or unsubstituted methyl group, or a substituted or unsubstituted carbazole group.

In Formula 9-1 to Formula 9-6, n31 may be an integer from 0 to 5; n32 and n38 may each independently be an integer from 0 to 3; n33, n37, and n39 may each independently be an integer from 0 to 4; n34 and n35 may each independently be an integer from 0 to 5; n36 may be an integer from 0 to 8; n40 may be an integer from 0 to 11; and the sum of n38 and n39 may be 6 or less.

If n31 is 0, the fused polycyclic compound may not be substituted with R₃₁. In Formula 9-1, a case where n31 is 5 and R₃₁ groups are all hydrogen atoms may be the same as the case where n31 is 0 in Formula 9-1. If n31 is 2 or more, multiple R₃₁ groups may all be the same, or at least one thereof may be different from the others.

If n32 and n38 are each 0, the fused polycyclic compound may not be substituted with each of R₃₂ and R₃₈. In Formula 9-2 and Formula 9-5, a case where n32 and n38 are each 3 and R₃₂ groups and R₃₈ groups are each hydrogen atoms may be the same as the case where each of n32 and n38 is 0 in Formula 9-2 and Formula 9-5. When n32 and n38 are each 2 or more, multiple groups of each of R₃₂ and R₃₈ may each be the same, or at least one thereof may be different from the others.

If n33, n37, and n39 are each 0, the fused polycyclic compound may not be substituted with each of R₃₃, R₃₇, and R₃₉. In Formula 9-2 and Formula 9-5, a case where n33, n37, and n39 are each 4 and R₃₃ groups, R₃₇ groups, and R₃₉ groups are each hydrogen atoms may be the same as the case where n33, n37, and n39 are each 0 in Formula 9-2 and Formula 9-5. If n33, n37, and n39 are each 2 or more, multiple groups of each of R₃₃, R₃₇, and R₃₉ may each be the same, or at least one thereof may be different from the others.

If n34 and n35 are each 0, the fused polycyclic compound may not be substituted with each of R₃₄ and R₃₅. In Formula 9-3, a case where n34 and n35 are each 5 and R₃₄ groups and R₃₅ groups are each hydrogen atoms may be the same as the case where n34 and n35 are each 0 in Formula 9-3. When n34 and n35 are each 2 or more, multiple groups of each of R₃₄ and R₃₅ may each be the same, or at least one thereof may be different from the others.

If n36 is 0, the fused polycyclic compound may not be substituted with R₃₆. In Formula 9-4, a case where n36 is 8 and R₃₆ groups are all hydrogen atoms may be the same as the case where n36 is 0 in Formula 9-4. If n36 is 2 or more, multiple R₃₆ groups may all be the same, or at least one thereof may be different from the others.

If n40 is 0, the fused polycyclic compound may not be substituted with R₄₀. In Formula 9-6, a case where n40 is 8 and R₄₀ groups are all hydrogen atoms may be the same as the case where n40 is 0 in Formula 9-6. If n40 is 2 or more, multiple R₄₀ groups may all be the same, or at least one thereof may be different from the others.

In Formula 9-1 to Formula 9-6, -* is a bonding position to Formula 1.

In an embodiment, in Formula 1, R₇ may be a group represented by any one of Formula R7-1 to Formula R7-3:

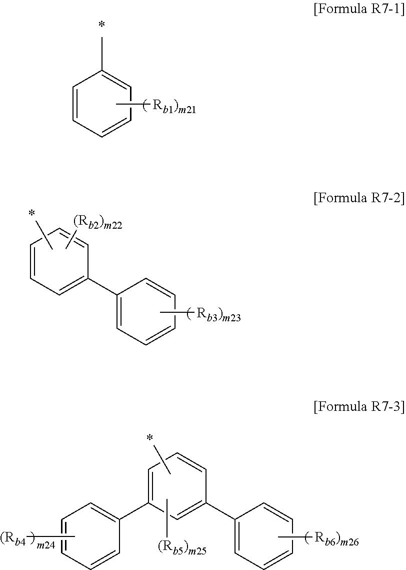

In Formula R7-1 to Formula R7-3, R_{b1} to R_{b6} may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R_{b1} to R_{b7} may each independently be a hydrogen atom, a substituted or unsubstituted t-butyl group, or a substituted or unsubstituted phenyl group.

In Formula R7-1 to Formula R7-3, m21, m23, m24, and m26 may each independently be an integer from 0 to 5. If m21, m23, m24, and m26 are each 0, the fused polycyclic compound may not be substituted with each of R_{b1}, R_{b}s, R_{b4}, and R_{b6}. A case where m21, m23, m24, and m26 are each 5 and R_{b1} groups, R_{b}3 groups, R_{b4} groups, and R_{b}6 groups are each hydrogen atoms may be the same as the case where m21, m23, m24, and m26 are each 0. If m21, m23, m24, and m26 are each 2 or more, multiple groups of each of R_{b1}, R_{b3}, R_{b4}, and R_{b6} may each be the same, or at least one among thereof may be different from the others.

In Formula R7-2, m22 may be an integer from 0 to 4. In Formula R7-2, if m22 is 0, the fused polycyclic compound may not be substituted with R_{b2}. In Formula R7-2, a case where m22 is 4 and R_{b2} groups are all hydrogen atoms may be the same as the case where m22 is 0 in Formula R7-2. If m22 is 2 or more, multiple R_{b2} groups may be all the same, or at least one thereof may be different from the others.

In Formula R7-3, m25 may be an integer from 0 to 3. In Formula R7-3, if m25 is 0, the fused polycyclic compound may not be substituted with R_{b}s. In Formula R7-3, a case where m25 is 3 and R_{b}s groups are all hydrogen atoms may be the same as the case where m25 is 0 in Formula R7-3. If m25 is 2 or more, multiple R_{b5} groups may be all the same, or at least one thereof may be different from the others.

The fused polycyclic compound may be any compound selected from Compound Group 1. The light emitting device ED according to an embodiment may include at least one fused polycyclic compound selected from Compound Group 1 in the emission layer EML.

[Compound Group 1]

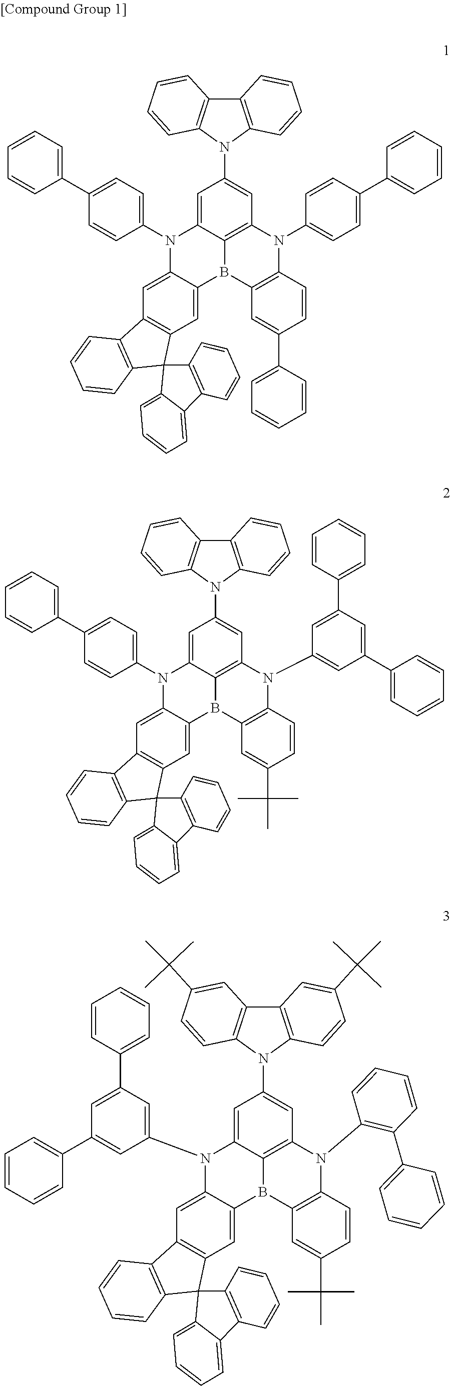 [SMILES: c1ccc(-c2ccc(N3c4ccc(-c5ccccc5)cc4B4c5cc6c(cc5N(c5ccc(-c7ccccc7)cc5)c5cc(-n7c8ccccc8c8ccccc87)cc3c54)-c3ccccc3C63c4ccccc4-c4ccccc43)cc2)cc1 ; CC(C)(C)c1ccc2c(c1)B1c3cc4c(cc3N(c3ccc(-c5ccccc5)cc3)c3cc(-n5c6ccccc6c6ccccc65)cc(c31)N2c1cc(-c2ccccc2)cc(-c2ccccc2)c1)-c1ccccc1C41c2ccccc2-c2ccccc21 ; CC(C)(C)c1ccc2c(c1)B1c3cc4c(cc3N(c3cc(-c5ccccc5)cc(-c5ccccc5)c3)c3cc(-n5c6ccc(C(C)(C)C)cc6c6cc(C(C)(C)C)ccc65)cc(c31)N2c1ccccc1-c1ccccc1)-c1ccccc1C41c2ccccc2-c2ccccc21]

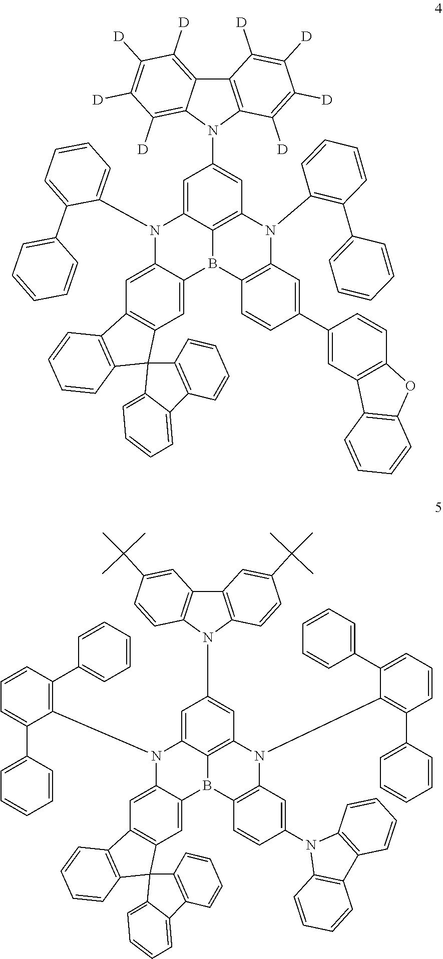 [SMILES: [2H]c1c([2H])c([2H])c2c(c1[2H])c1c([2H])c([2H])c([2H])c([2H])c1n2-c1cc2c3c(c1)N(c1ccccc1-c1ccccc1)c1cc4c(cc1B3c1ccc(-c3ccc5oc6ccccc6c5c3)cc1N2c1ccccc1-c1ccccc1)C1(c2ccccc2-c2ccccc21)c1ccccc1-4 ; CC(C)(C)c1ccc2c(c1)c1cc(C(C)(C)C)ccc1n2-c1cc2c3c(c1)N(c1c(-c4ccccc4)cccc1-c1ccccc1)c1cc4c(cc1B3c1ccc(-n3c5ccccc5c5ccccc53)cc1N2c1c(-c2ccccc2)cccc1-c1ccccc1)C1(c2ccccc2-c2ccccc21)c1ccccc1-4]

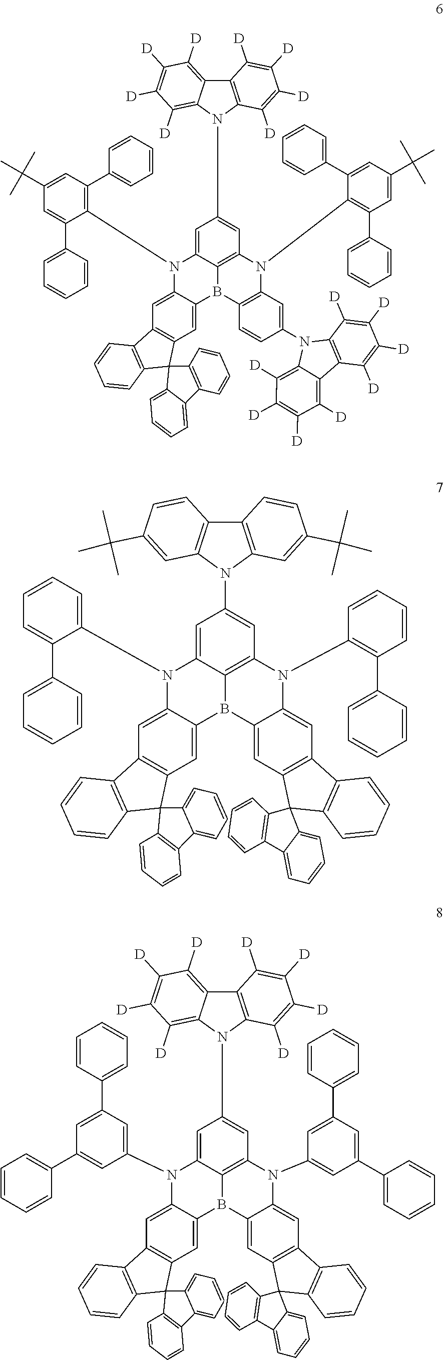

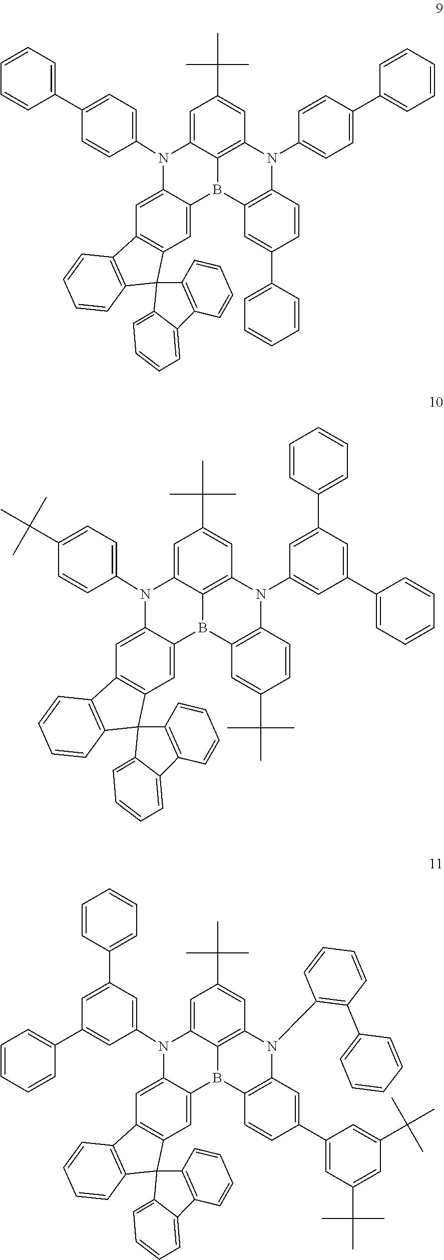 [SMILES: CC(C)(C)c1cc2c3c(c1)N(c1ccc(-c4ccccc4)cc1)c1cc4c(cc1B3c1cc(-c3ccccc3)ccc1N2c1ccc(-c2ccccc2)cc1)C1(c2ccccc2-c2ccccc21)c1ccccc1-4 ; CC(C)(C)c1ccc(N2c3cc4c(cc3B3c5cc(C(C)(C)C)ccc5N(c5cc(-c6ccccc6)cc(-c6ccccc6)c5)c5cc(C(C)(C)C)cc2c53)C2(c3ccccc3-c3ccccc32)c2ccccc2-4)cc1 ; CC(C)(C)c1cc(-c2ccc3c(c2)N(c2ccccc2-c2ccccc2)c2cc(C(C)(C)C)cc4c2B3c2cc3c(cc2N4c2cc(-c4ccccc4)cc(-c4ccccc4)c2)-c2ccccc2C32c3ccccc3-c3ccccc32)cc(C(C)(C)C)c1]

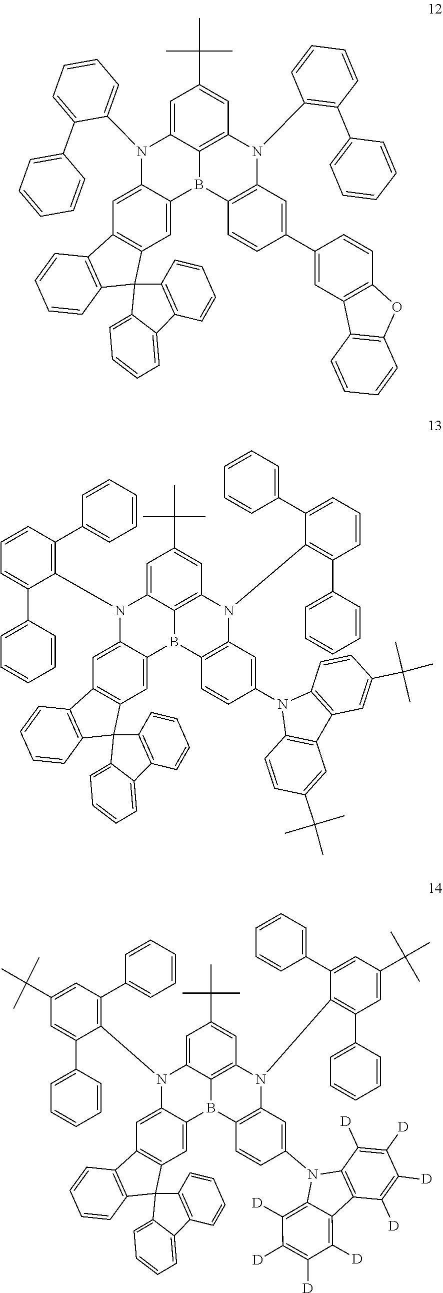

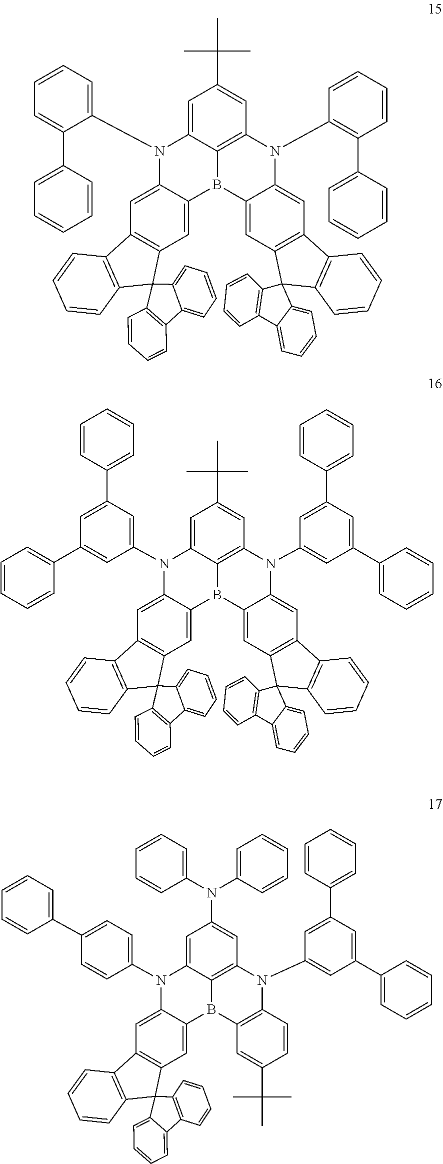 [SMILES: CC(C)(C)c1cc2c3c(c1)N(c1ccccc1-c1ccccc1)c1cc4c(cc1B3c1cc3c(cc1N2c1ccccc1-c1ccccc1)-c1ccccc1[C@]31c2ccccc2-c2ccccc21)[C@@]1(c2ccccc2-c2ccccc21)c1ccccc1-4 ; CC(C)(C)c1cc2c3c(c1)N(c1cc(-c4ccccc4)cc(-c4ccccc4)c1)c1cc4c(cc1B3c1cc3c(cc1N2c1cc(-c2ccccc2)cc(-c2ccccc2)c1)-c1ccccc1[C@]31c2ccccc2-c2ccccc21)[C@@]1(c2ccccc2-c2ccccc21)c1ccccc1-4 ; CC(C)(C)c1ccc2c(c1)B1c3cc4c(cc3N(c3ccc(-c5ccccc5)cc3)c3cc(N(c5ccccc5)c5ccccc5)cc(c31)N2c1cc(-c2ccccc2)cc(-c2ccccc2)c1)-c1ccccc1C41c2ccccc2-c2ccccc21]

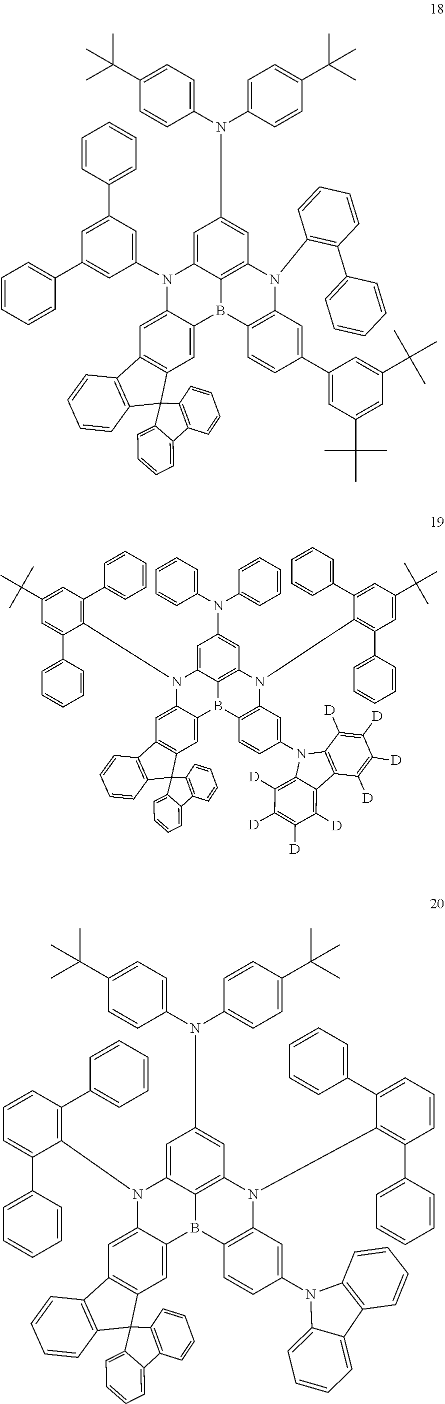

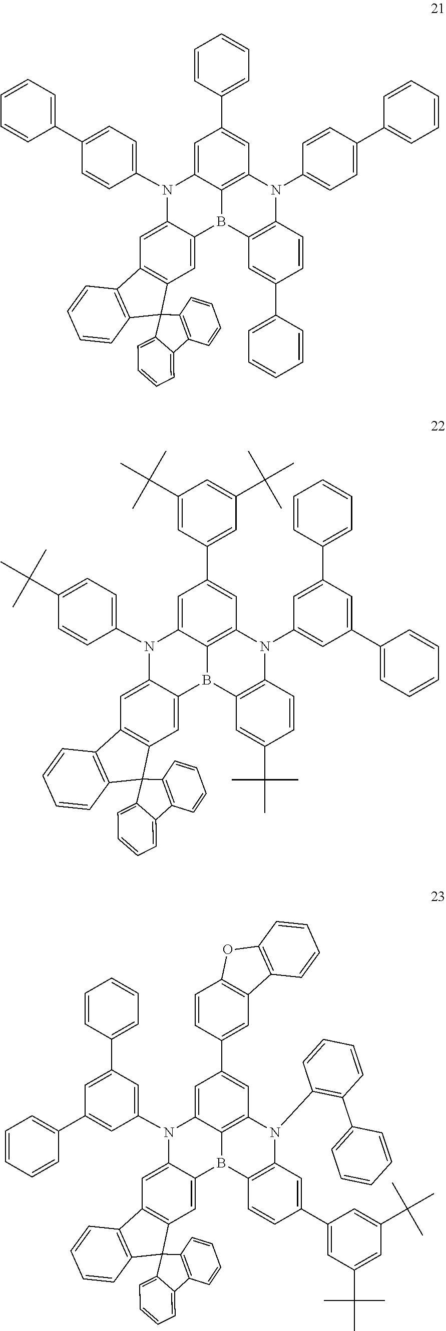 [SMILES: c1ccc(-c2ccc(N3c4ccc(-c5ccccc5)cc4B4c5cc6c(cc5N(c5ccc(-c7ccccc7)cc5)c5cc(-c7ccccc7)cc3c54)-c3ccccc3C63c4ccccc4-c4ccccc43)cc2)cc1 ; CC(C)(C)c1ccc(N2c3cc4c(cc3B3c5cc(C(C)(C)C)ccc5N(c5cc(-c6ccccc6)cc(-c6ccccc6)c5)c5cc(-c6cc(C(C)(C)C)cc(C(C)(C)C)c6)cc2c53)C2(c3ccccc3-c3ccccc32)c2ccccc2-4)cc1 ; CC(C)(C)c1cc(-c2ccc3c(c2)N(c2ccccc2-c2ccccc2)c2cc(-c4ccc5oc6ccccc6c5c4)cc4c2B3c2cc3c(cc2N4c2cc(-c4ccccc4)cc(-c4ccccc4)c2)-c2ccccc2C32c3ccccc3-c3ccccc32)cc(C(C)(C)C)c1]

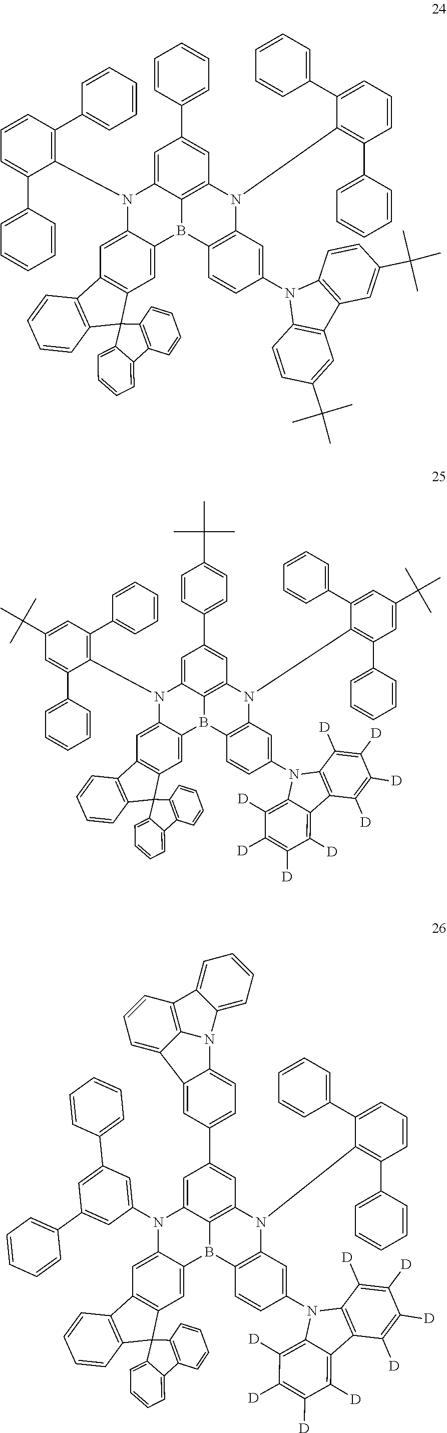

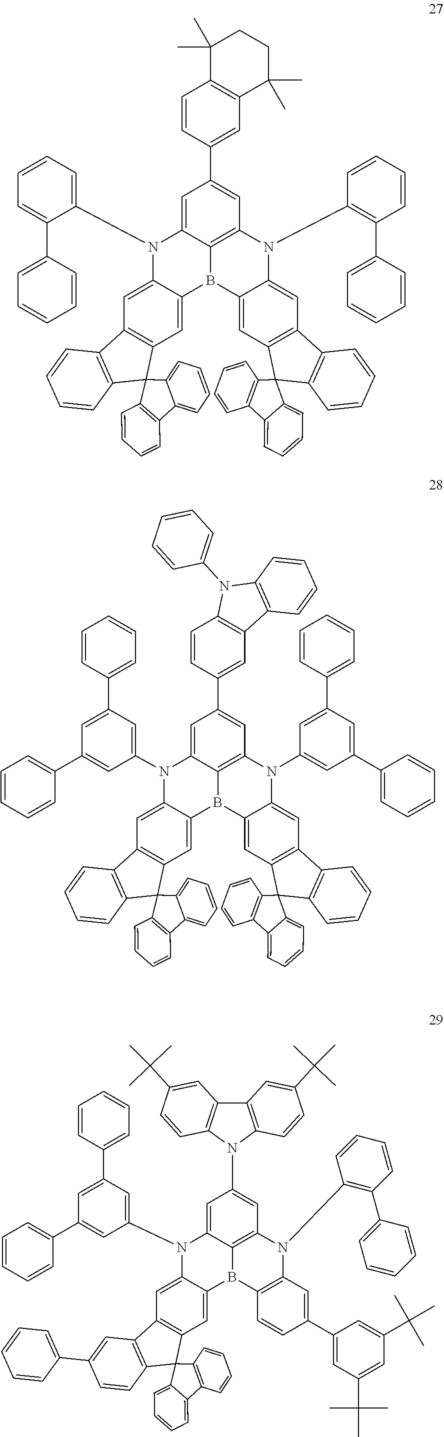

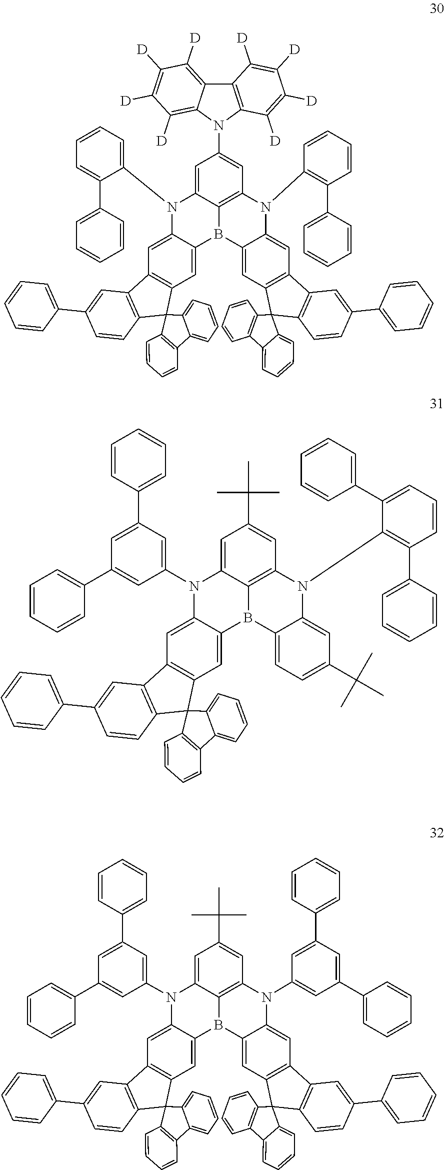

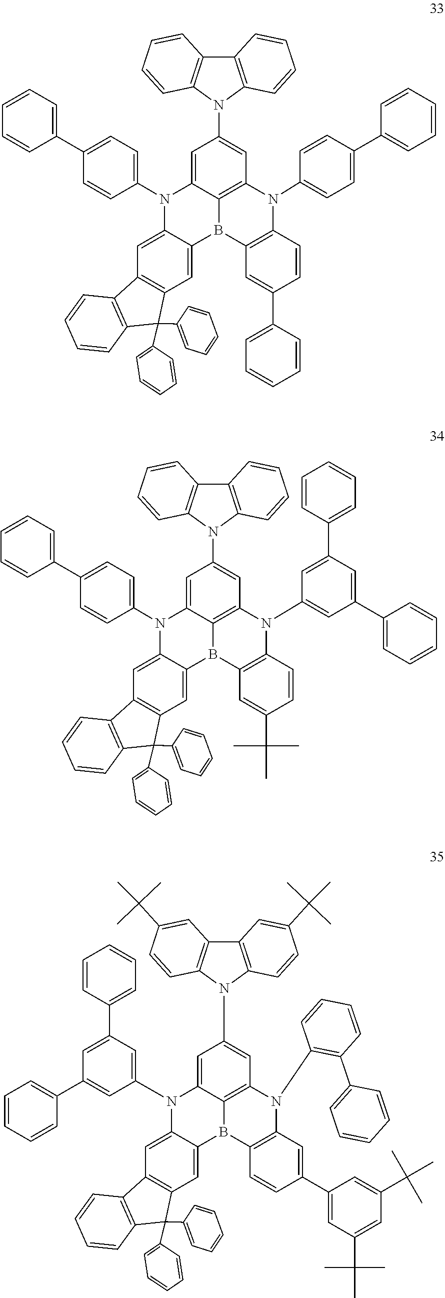 [SMILES: c1ccc(-c2ccc(N3c4ccc(-c5ccccc5)cc4B4c5cc6c(cc5N(c5ccc(-c7ccccc7)cc5)c5cc(-n7c8ccccc8c8ccccc87)cc3c54)-c3ccccc3C6(c3ccccc3)c3ccccc3)cc2)cc1 ; CC(C)(C)c1ccc2c(c1)B1c3cc4c(cc3N(c3ccc(-c5ccccc5)cc3)c3cc(-n5c6ccccc6c6ccccc65)cc(c31)N2c1cc(-c2ccccc2)cc(-c2ccccc2)c1)-c1ccccc1C4(c1ccccc1)c1ccccc1 ; CC(C)(C)c1cc(-c2ccc3c(c2)N(c2ccccc2-c2ccccc2)c2cc(-n4c5ccc(C(C)(C)C)cc5c5cc(C(C)(C)C)ccc54)cc4c2B3c2cc3c(cc2N4c2cc(-c4ccccc4)cc(-c4ccccc4)c2)-c2ccccc2C3(c2ccccc2)c2ccccc2)cc(C(C)(C)C)c1]

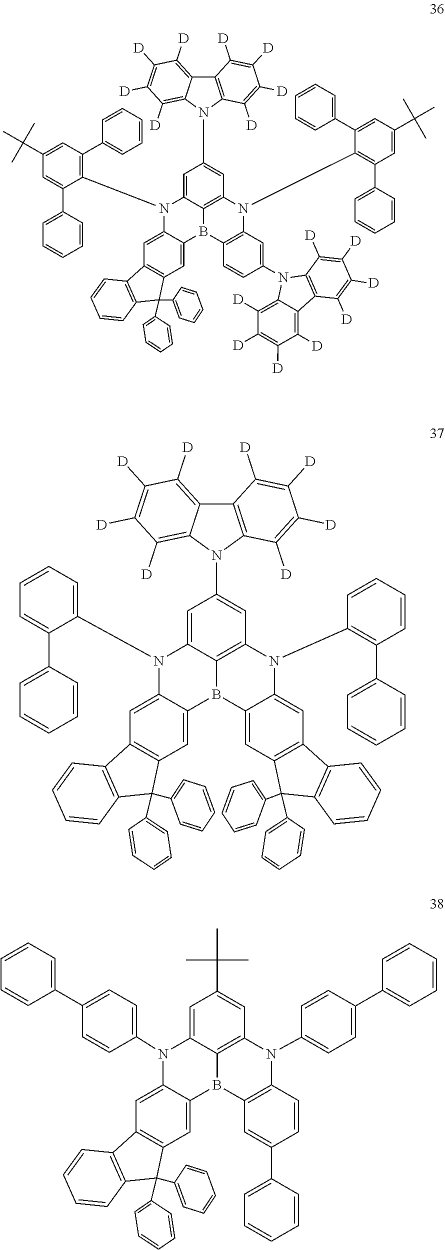

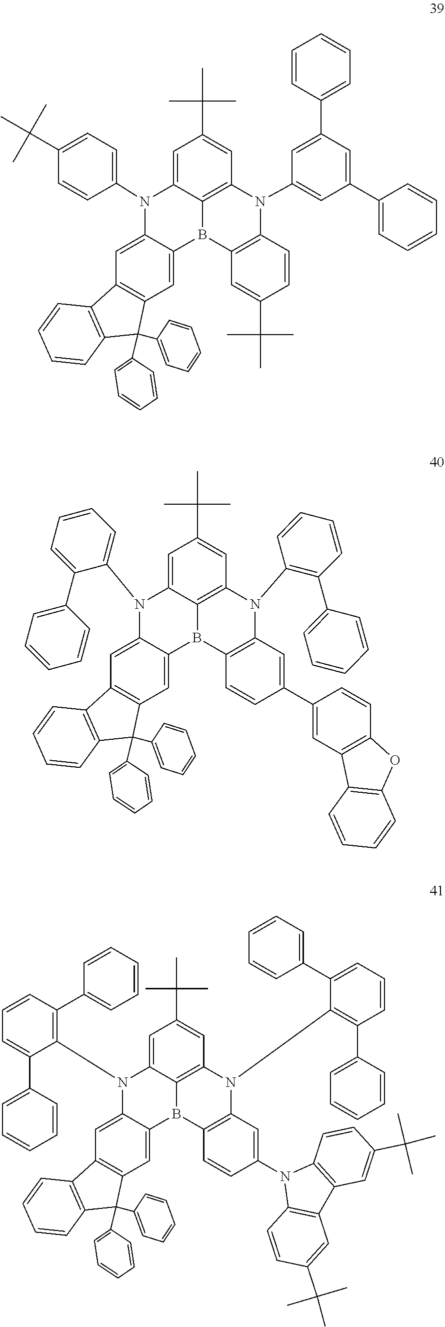 [SMILES: CC(C)(C)c1ccc(N2c3cc4c(cc3B3c5cc(C(C)(C)C)ccc5N(c5cc(-c6ccccc6)cc(-c6ccccc6)c5)c5cc(C(C)(C)C)cc2c53)C(c2ccccc2)(c2ccccc2)c2ccccc2-4)cc1 ; CC(C)(C)c1cc2c3c(c1)N(c1ccccc1-c1ccccc1)c1cc4c(cc1B3c1ccc(-c3ccc5oc6ccccc6c5c3)cc1N2c1ccccc1-c1ccccc1)C(c1ccccc1)(c1ccccc1)c1ccccc1-4 ; CC(C)(C)c1cc2c3c(c1)N(c1c(-c4ccccc4)cccc1-c1ccccc1)c1cc4c(cc1B3c1ccc(-n3c5ccc(C(C)(C)C)cc5c5cc(C(C)(C)C)ccc53)cc1N2c1c(-c2ccccc2)cccc1-c1ccccc1)C(c1ccccc1)(c1ccccc1)c1ccccc1-4]

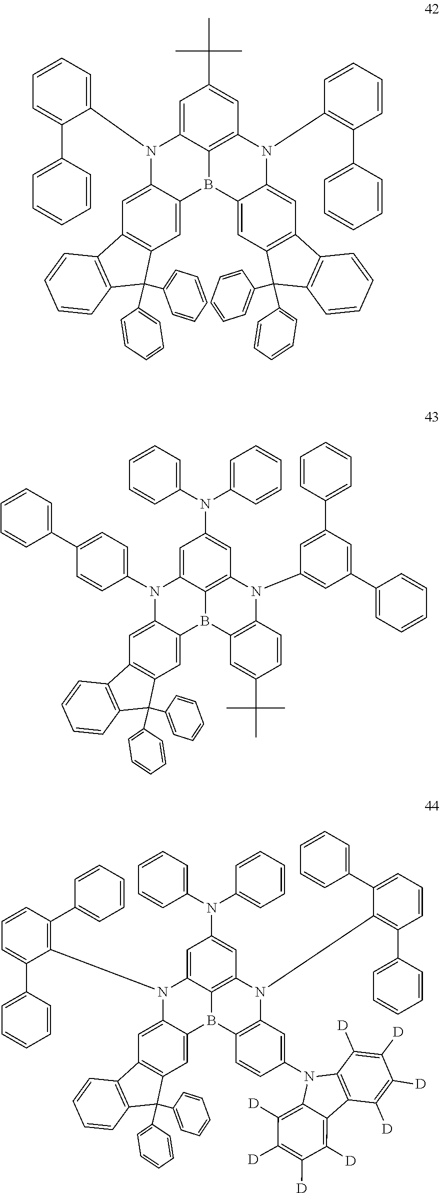

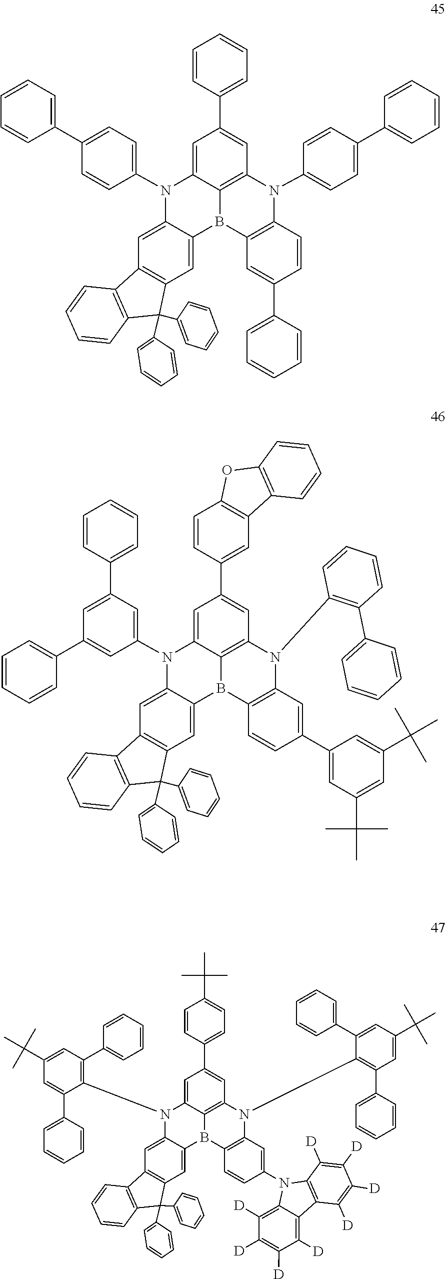

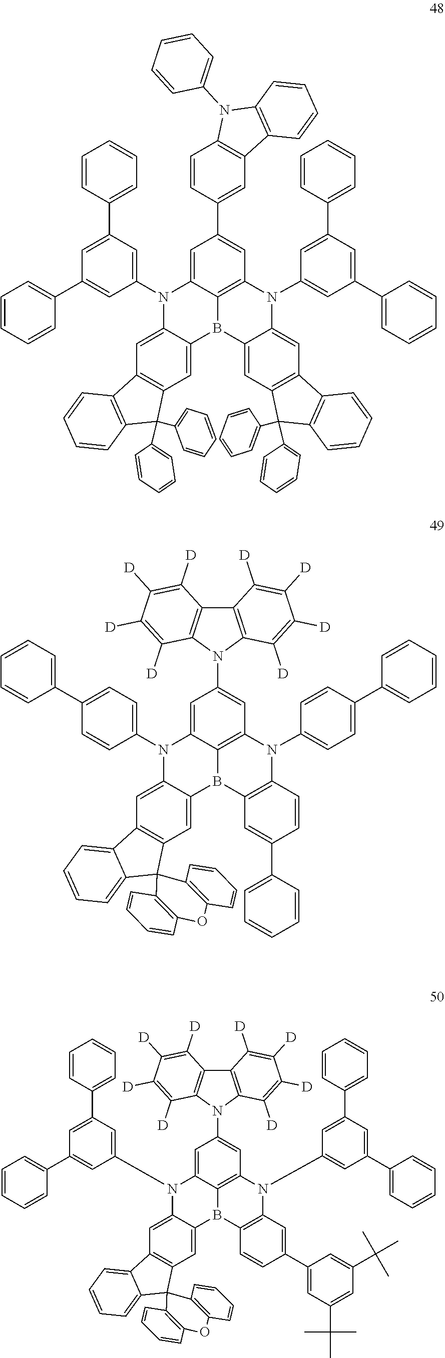

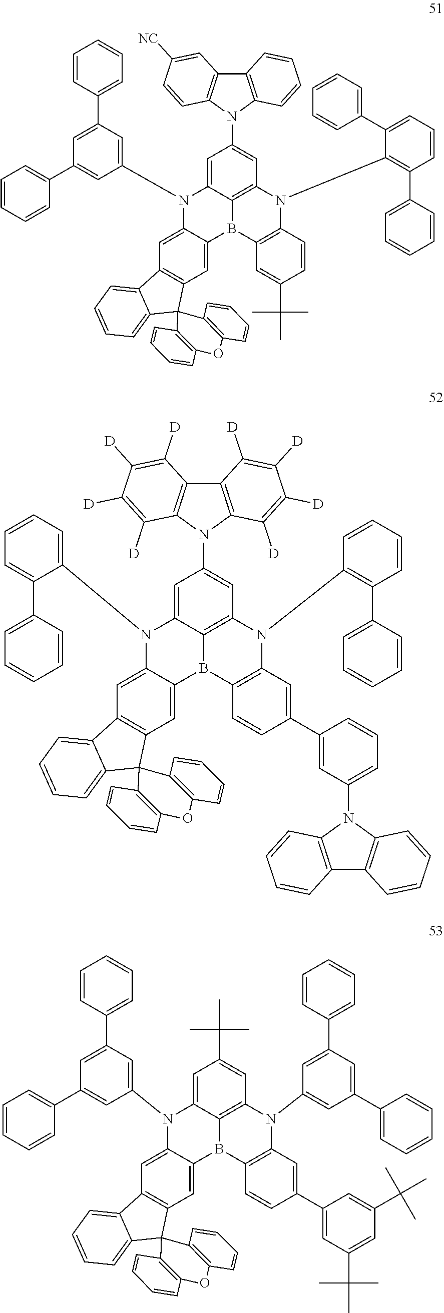

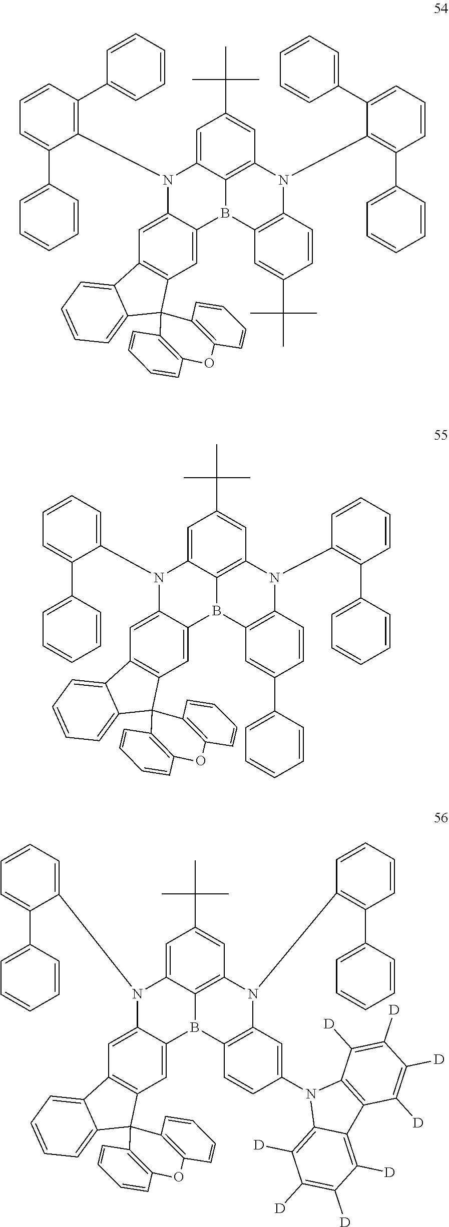 [SMILES: CC(C)(C)c1ccc2c(c1)B1c3cc4c(cc3N(c3c(-c5ccccc5)cccc3-c3ccccc3)c3cc(C(C)(C)C)cc(c31)N2c1c(-c2ccccc2)cccc1-c1ccccc1)-c1ccccc1C41c2ccccc2Oc2ccccc21 ; CC(C)(C)c1cc2c3c(c1)N(c1ccccc1-c1ccccc1)c1cc4c(cc1B3c1cc(-c3ccccc3)ccc1N2c1ccccc1-c1ccccc1)C1(c2ccccc2Oc2ccccc21)c1ccccc1-4 ; [2H]c1c([2H])c([2H])c2c(c1[2H])c1c([2H])c([2H])c([2H])c([2H])c1n2-c1ccc2c(c1)N(c1ccccc1-c1ccccc1)c1cc(C(C)(C)C)cc3c1B2c1cc2c(cc1N3c1ccccc1-c1ccccc1)-c1ccccc1C21c2ccccc2Oc2ccccc21]

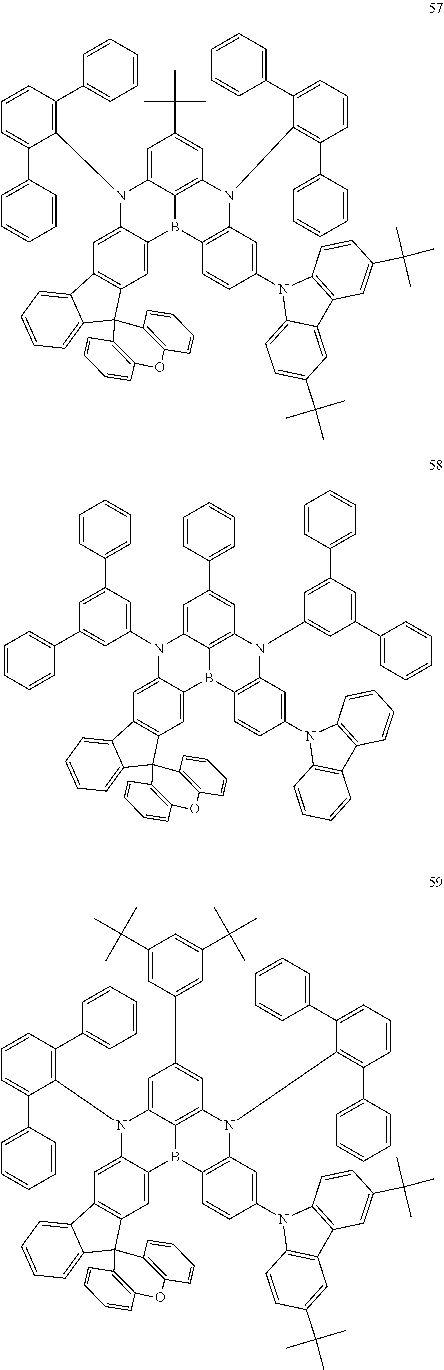

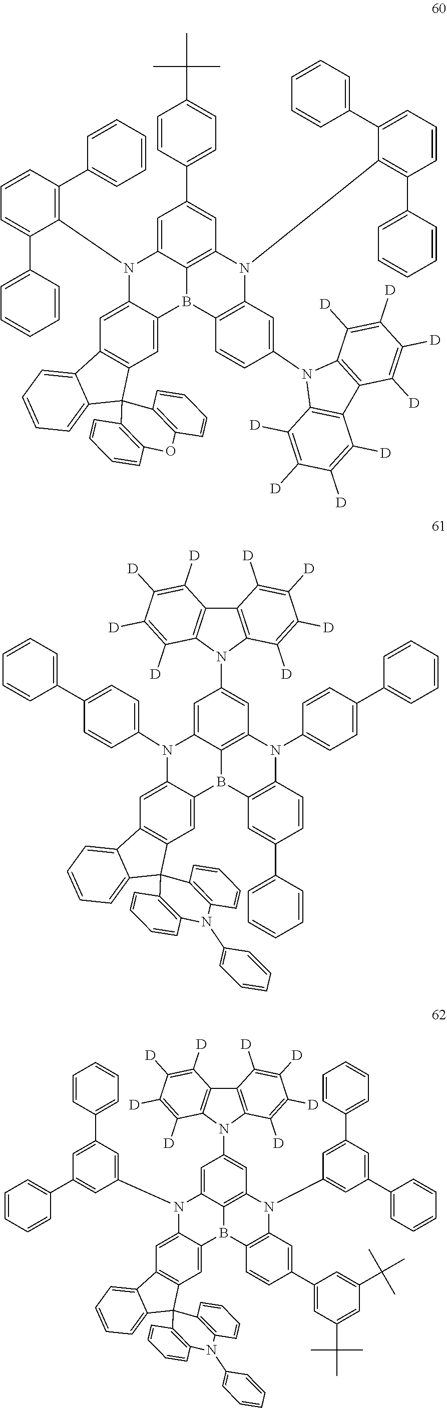

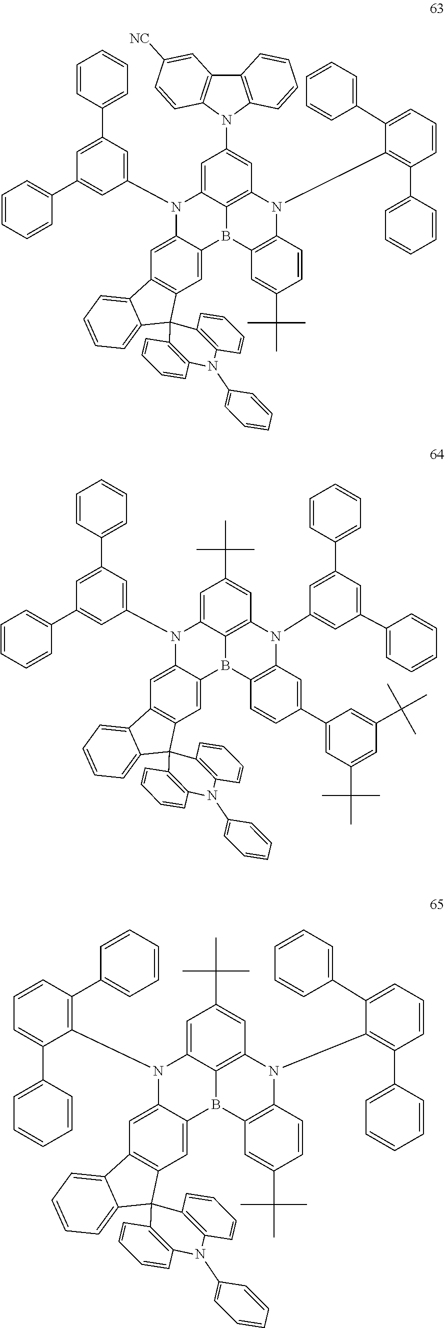

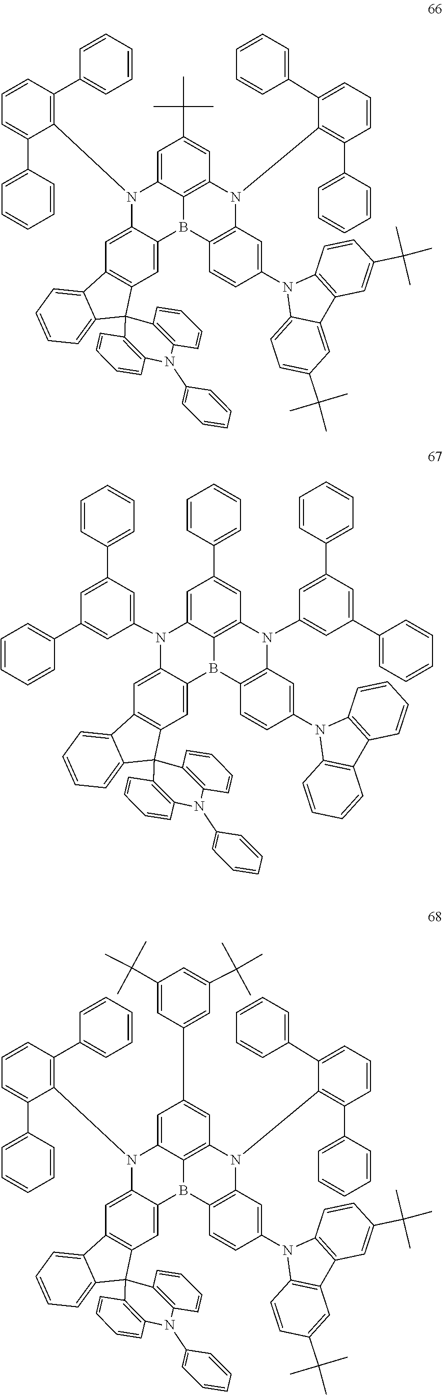

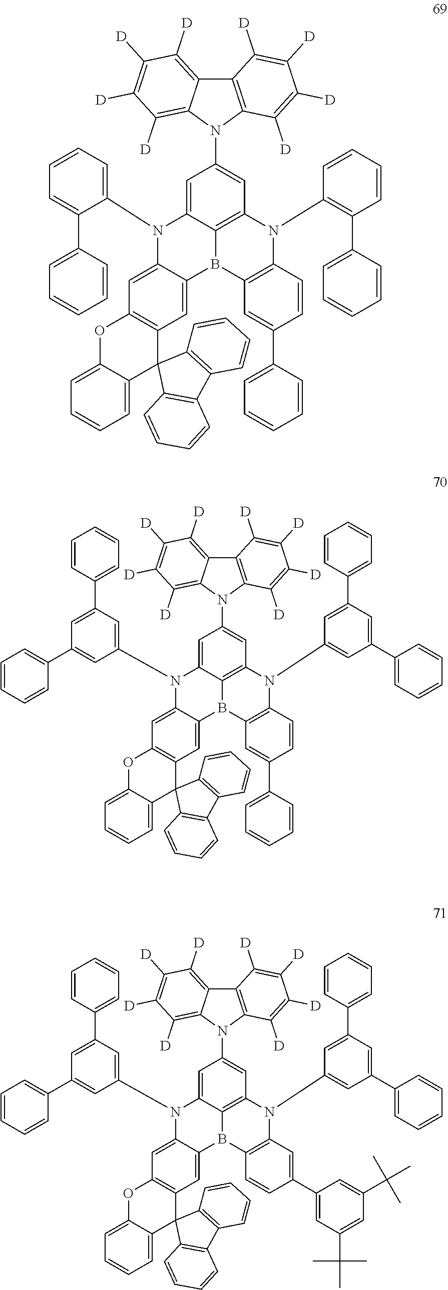

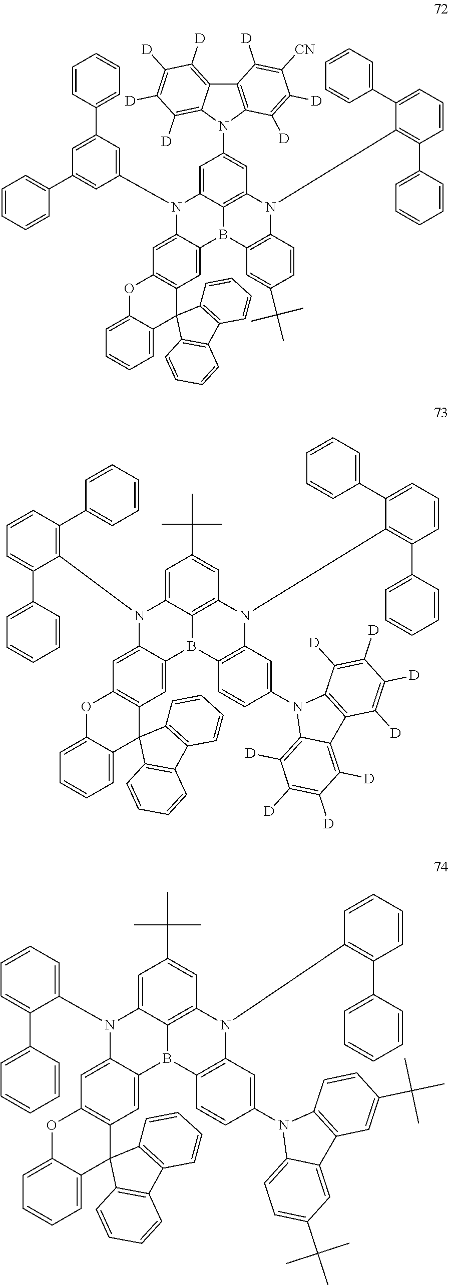

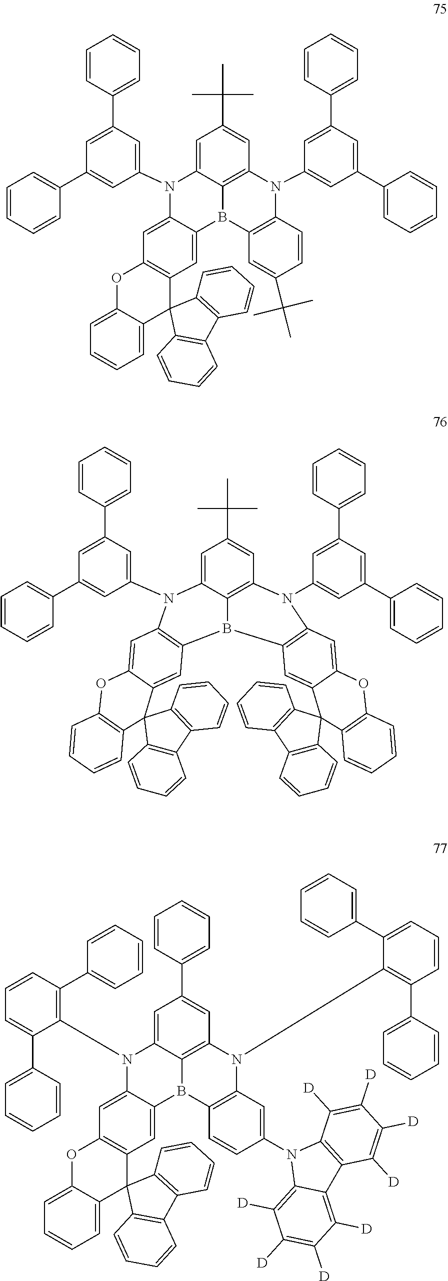

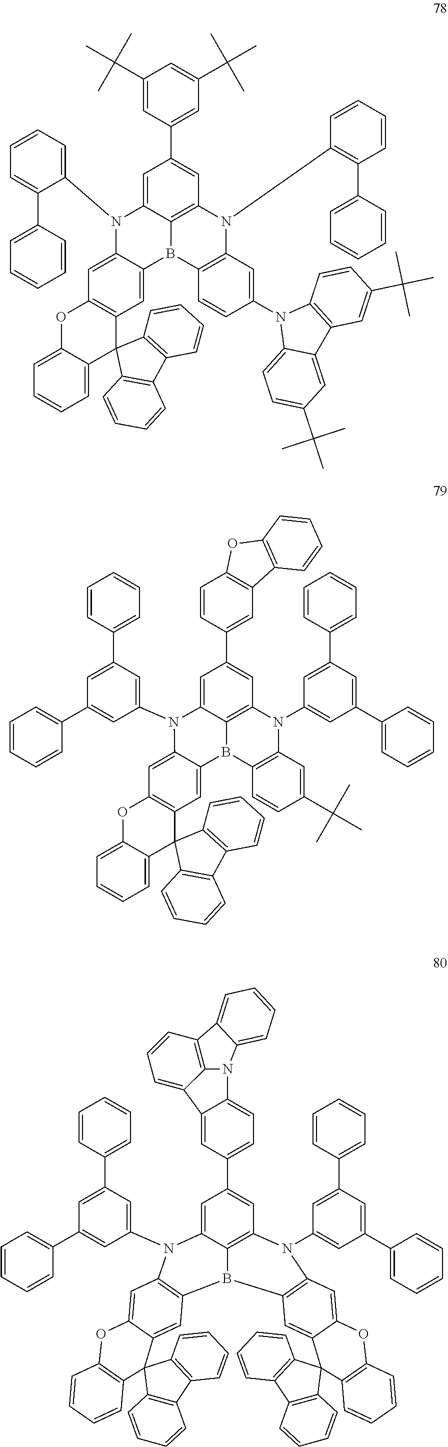

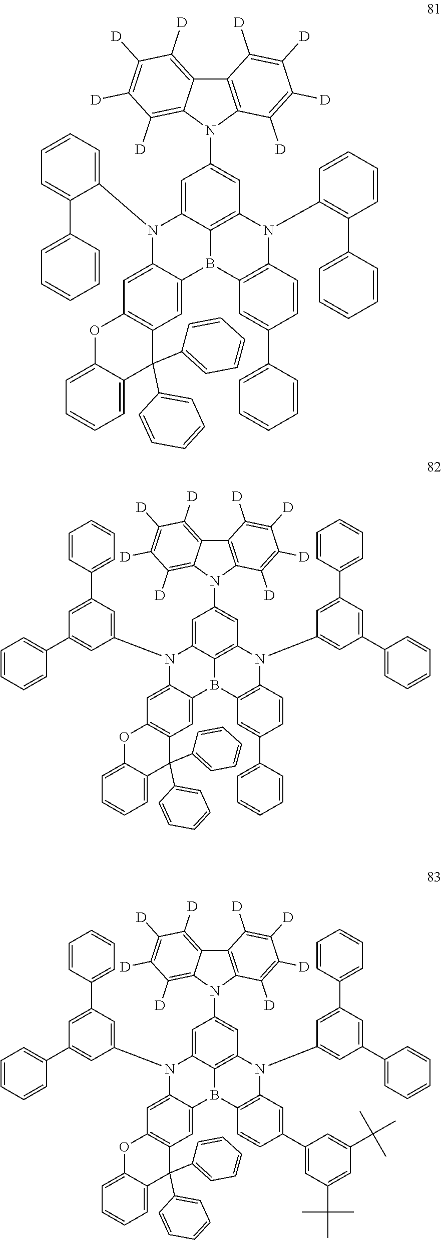

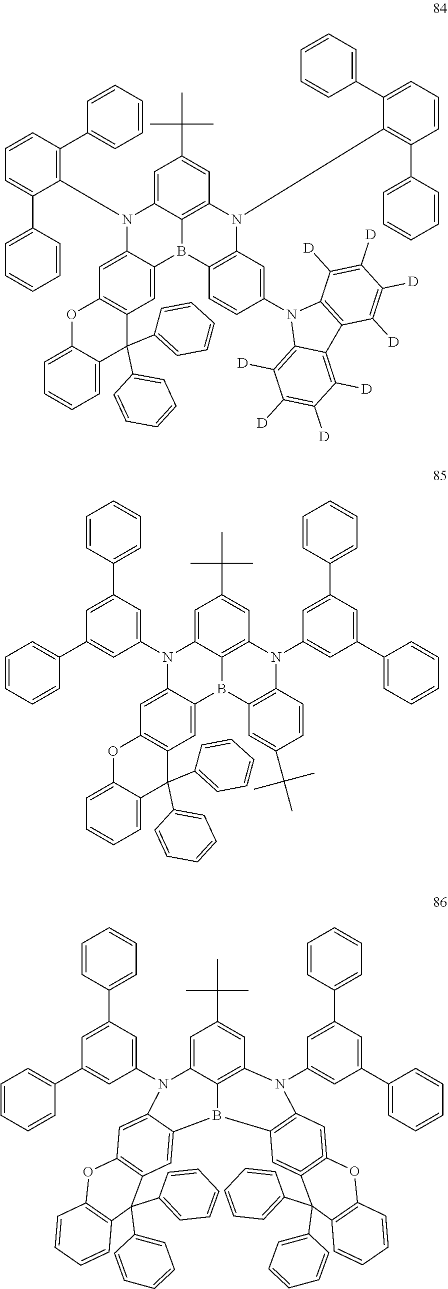

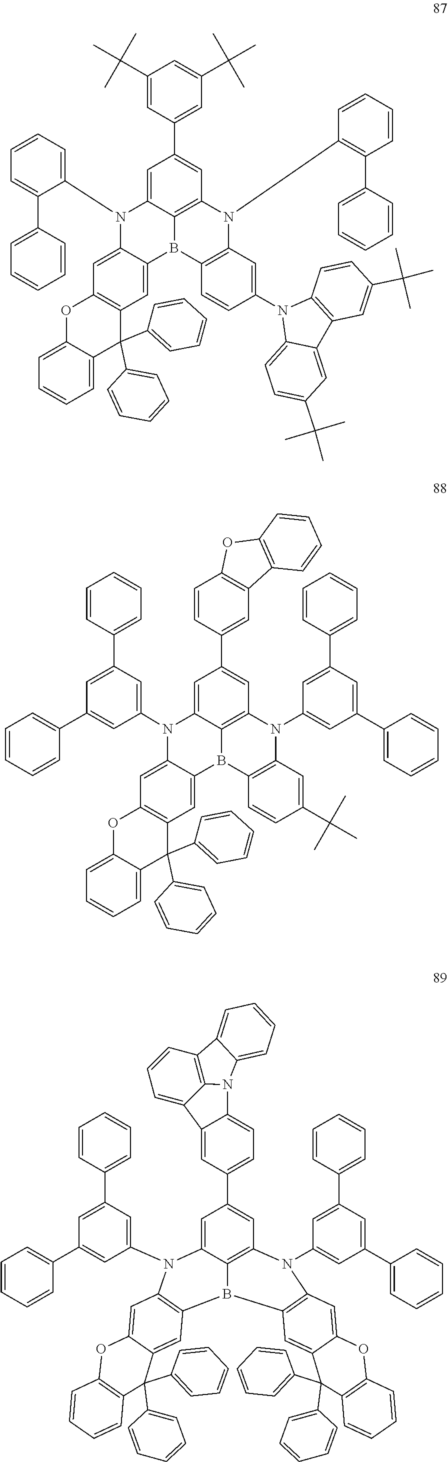

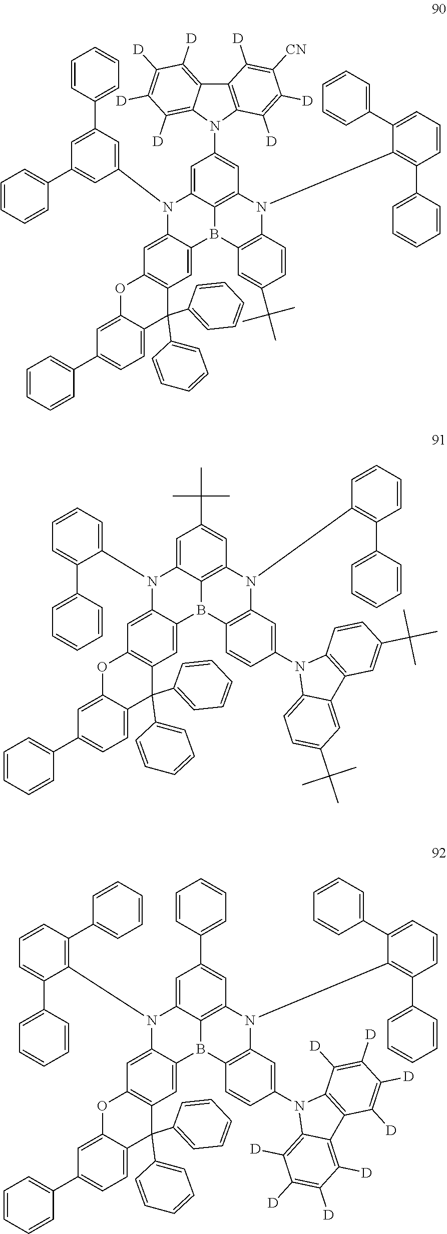

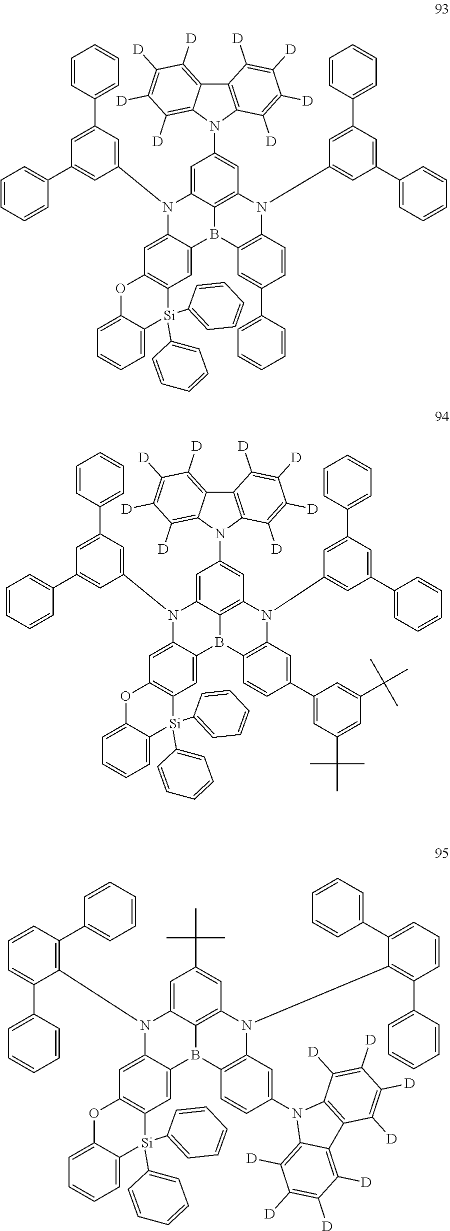

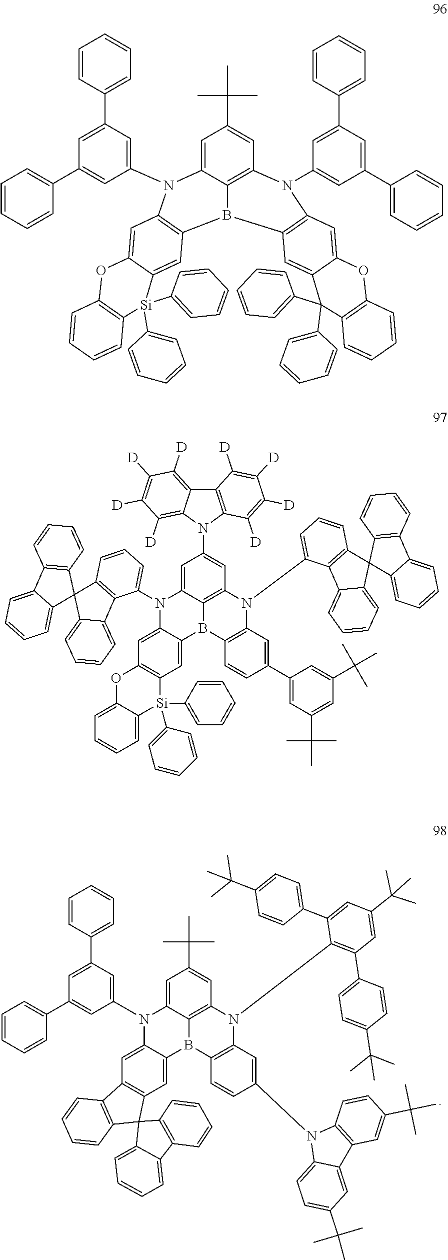

In Compound Group 1, D represents a deuterium atom.

The fused polycyclic compound represented by Formula 1 according to an embodiment includes a structure in which the first moiety is fused at the fused ring core, and thereby high luminous efficiency and long service life may be achieved.

The fused polycyclic compound may have a structure in which the first to third aromatic rings are fused by one boron atom and the first and second nitrogen atoms, and may include a structure in which the first moiety is fused at the first aromatic ring. The first moiety may include the first to third benzene ring linked to the first atom, and the first atom and the first benzene ring of the first moiety may each be linked to the first aromatic ring of the fused ring core. The first atom may be linked at a para-position to the first nitrogen atom with respect to the first aromatic ring. The first benzene ring may be directly bonded to the first aromatic ring or may be linked to the first aromatic ring via the second atom. When the first benzene ring of the first moiety is linked at a para-position to the boron atom, or when the first benzene ring is linked to the first aromatic ring via the second atom, the second atom may be linked at a para-position to the boron atom. The fused polycyclic compound having such a structure may effectively maintain a trigonal planar structure of the boron atom through the steric hindrance effect due to the first moiety. The boron atom may have electron deficiency characteristics by an empty p-orbital, thereby form a bond with other nucleophiles, and thus be changed into a tetrahedral structure, which may cause deterioration of the device. According to embodiments, the fused polycyclic compound represented by Formula 1 may have a structure in which the first moiety is fused at the fused ring core, and may thereby effectively protect the empty p-orbital of the boron atom, and may thus prevent deterioration due to the structural change.

The fused polycyclic compound may have an improvement in luminous efficiency and service life characteristics because intermolecular interaction may be suppressed by the introduction of the first moiety, thereby suppressing the formation of aggregation, excimer, or exciplex. The fused polycyclic compound represented by Formula 1 includes a structure in which the first moiety is fused at the fused ring core, thereby increasing intermolecular distance, and thus the fused polycyclic compound has an effect of reducing exciton quenching, such as Dexter energy transfer, triplet-triplet annihilation (TTA), or triplet-polaron quenching (TPQ). Dexter energy transfer, TTA, and TPQ are phenomena, in which a triplet exciton moves between molecules, and may increase when intermolecular distance is short, and may become a factor that increases a quenching phenomenon due to the increase of triplet concentration. According to embodiments, the fused polycyclic compound has an increase in the distance between adjacent molecules due to the large steric hindrance structure to thereby suppress Dexter energy transfer, TTA, and TPQ, and may thus suppress the deterioration of service life due to the increase of triplet concentration. Therefore, when the fused polycyclic compound is applied to the emission layer EML of the light emitting device ED, luminous efficiency may be increased, and the device service life may also be improved.

When the fused polycyclic compound includes the first moiety, the rigidity of the molecule increases, so that structural change in the excited state and ground state is small, and thus Stokes shift and FWHM may be significantly reduced, and accordingly, blue emission with high color purity may be achieved. Thus, when the fused polycyclic compound according to embodiments is introduced as a delayed fluorescence dopant of the emission layer, luminous efficiency and service life characteristics may not only be improved, but the color purity may also be improved.

The fused polycyclic compound may be included in the emission layer EML. The fused polycyclic compound may be included as a dopant material in the emission layer EML. The fused polycyclic compound may be a thermally activated delayed fluorescence material. The fused polycyclic compound may be used as a thermally activated delayed fluorescence dopant. For example, in the light emitting device ED, the emission layer EML may include, as a thermally activated delayed fluorescence dopant, at least one fused polycyclic compound selected from Compound Group 1 as described above. However, a use of the fused polycyclic compound according to embodiments is not limited thereto.

In an embodiment, the emission layer EML may include multiple compounds. The emission layer EML may include the fused polycyclic compound represented by Formula 1, i.e., the first compound, and may further include at least one of a second compound represented by Formula H-1, a third compound represented by Formula H-2, or a fourth compound represented by Formula D-1.

In an embodiment, the emission layer EML may include a second compound represented by Formula H-1. In an embodiment, the second compound may be used as a hole transporting host material of the emission layer EML.

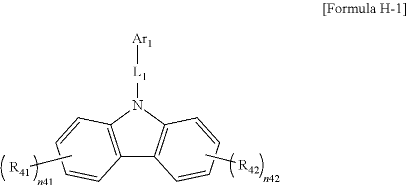

In Formula H-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but embodiments are not limited thereto.

In Formula H-1, Ar₁ may be a substituted or unsubstituted aryl group having 6 to 30 ring-forming carbon atoms, or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula H-1, R₄₁ and R₄₂ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, a substituted or unsubstituted heteroaryl group having 2 to 60 ring-forming carbon atoms, or may be bonded to an adjacent group to form a ring. For example, R₄₁ and R₄₂ may each independently be a hydrogen atom or a deuterium atom.

In Formula H-1, n41 and n42 may each independently be an integer from 0 to 4. If n41 and n42 are each 0, the fused polycyclic compound may not be substituted with each of R₄₁ and R₄₂. A case where n41 and n42 are each 4 and R₄₁ groups and R₄₂ groups are each hydrogen atoms may be the same as the case where each of n41 and n42 is 0. When n41 and n42 are each 2 or more, multiple groups of each of R₄₁ and R₄₂ may each be the same, or at least one thereof may be different from the others.

In an embodiment, the second compound represented by Formula 2 may be a compound selected from Compound Group 2. The emission layer EML may include at least one compound selected from Compound Group 2 as a hole transporting host material.

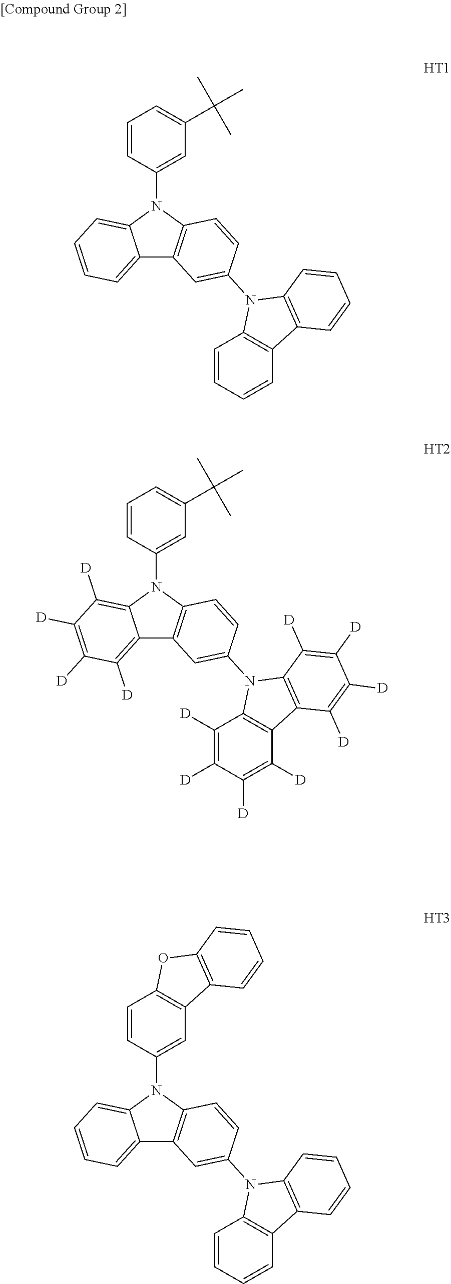 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

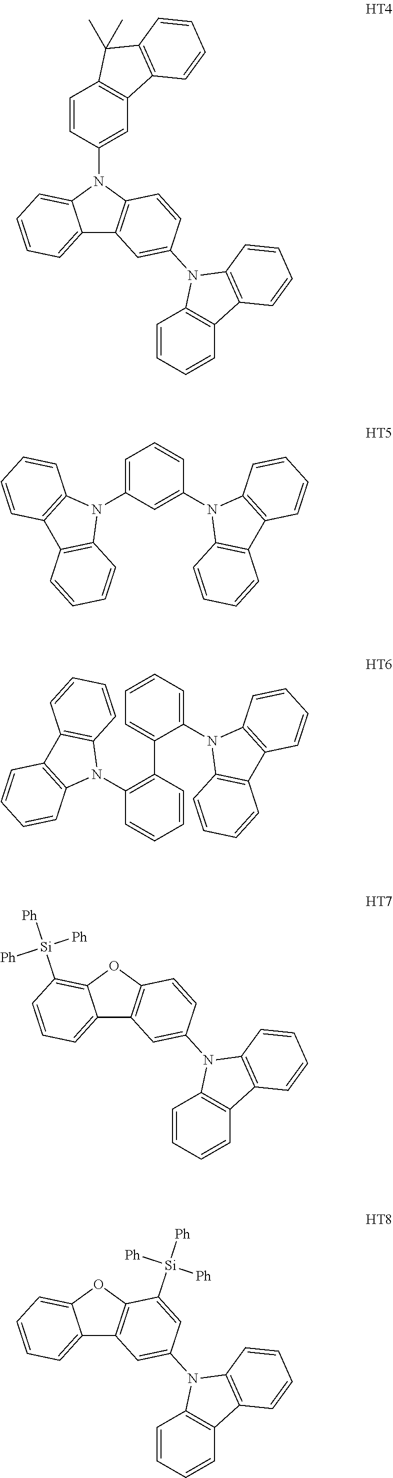 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

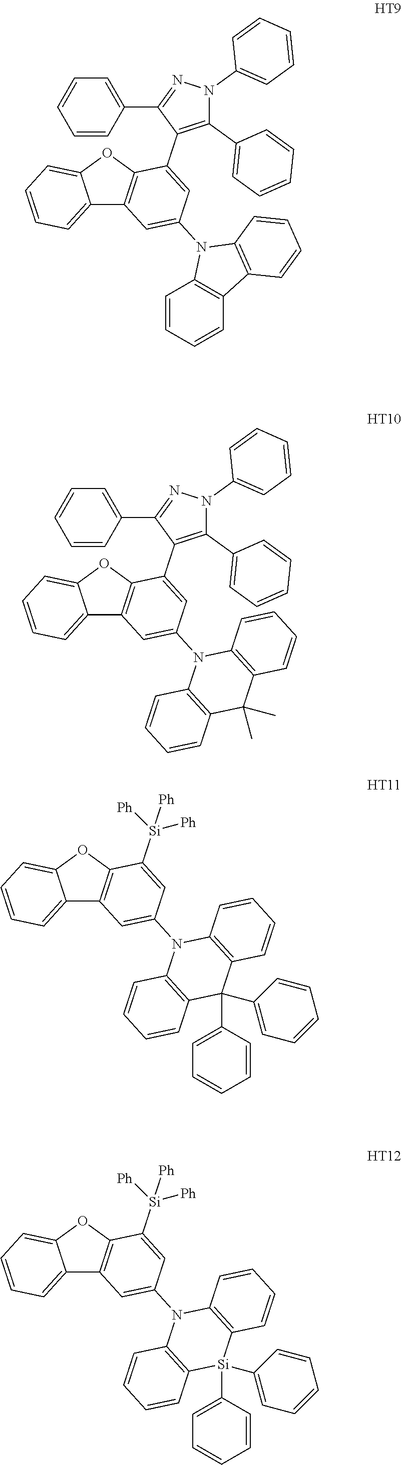 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

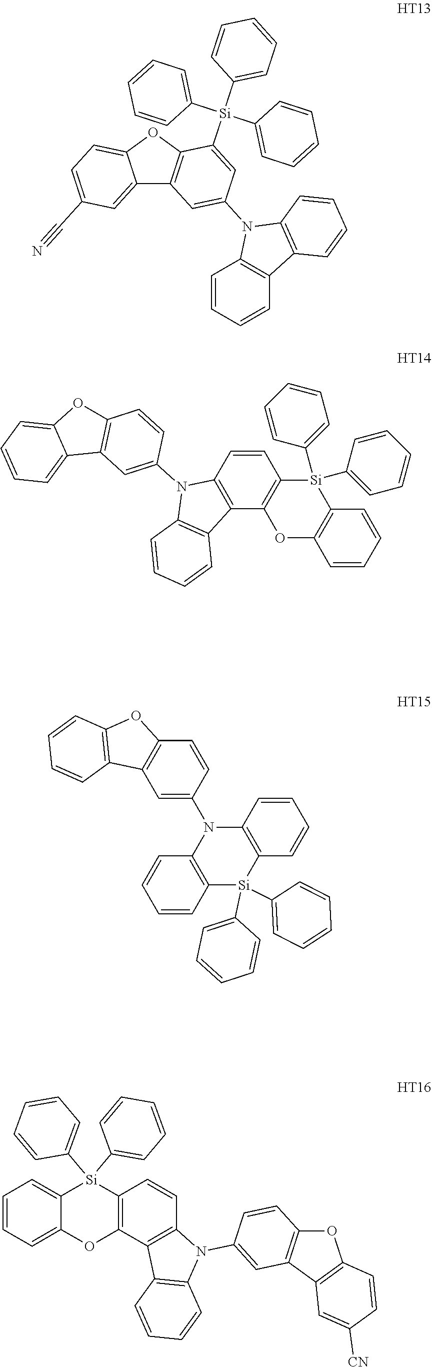 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

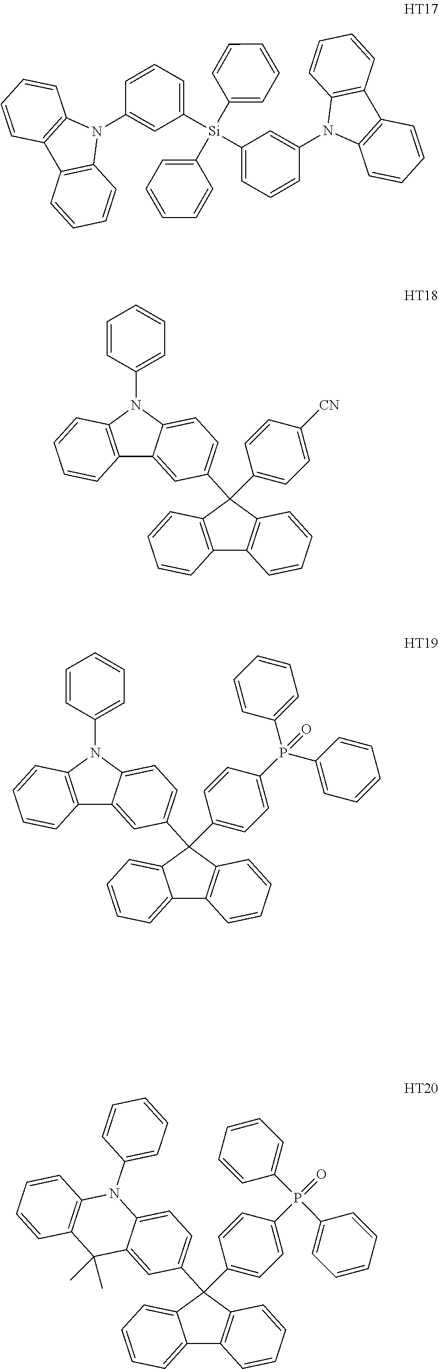 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

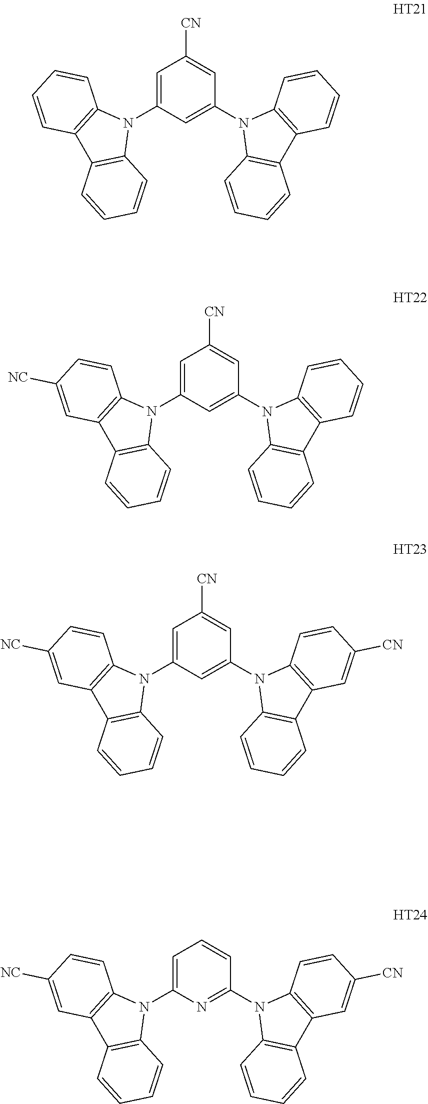 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

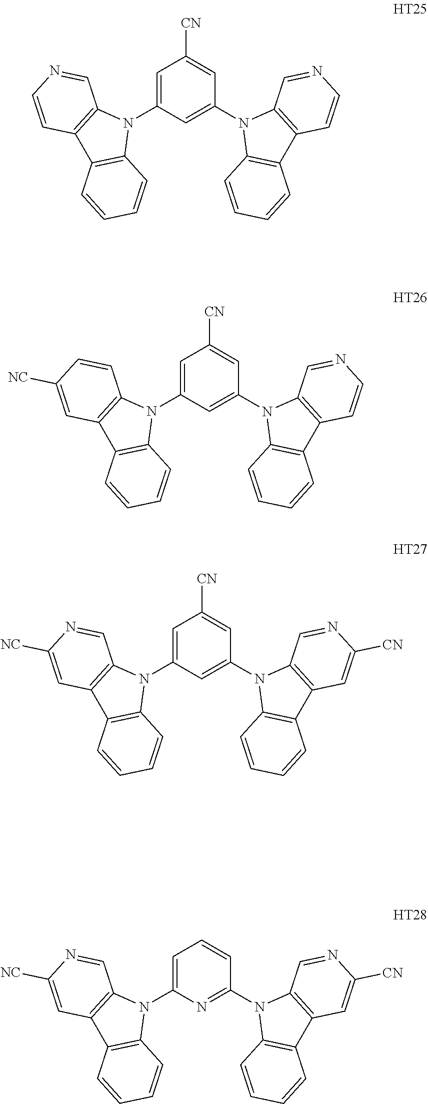 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

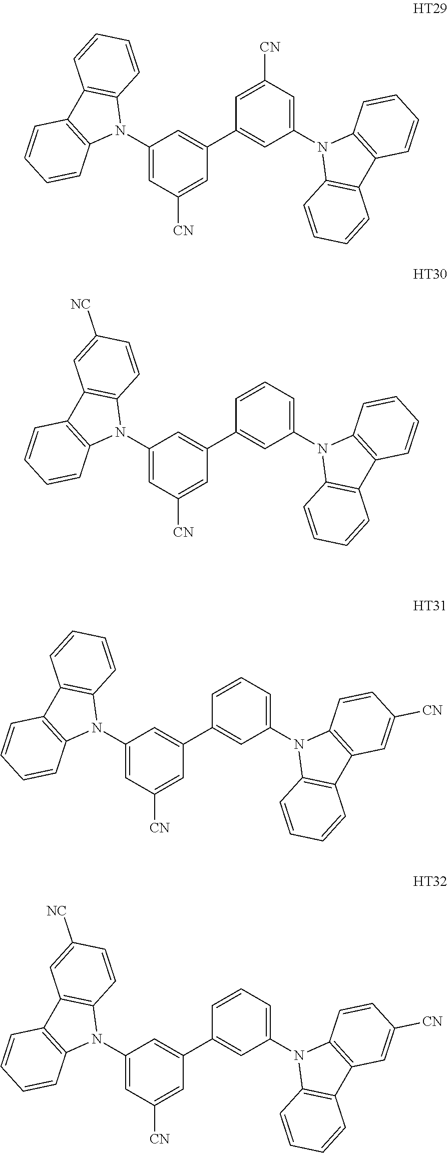 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

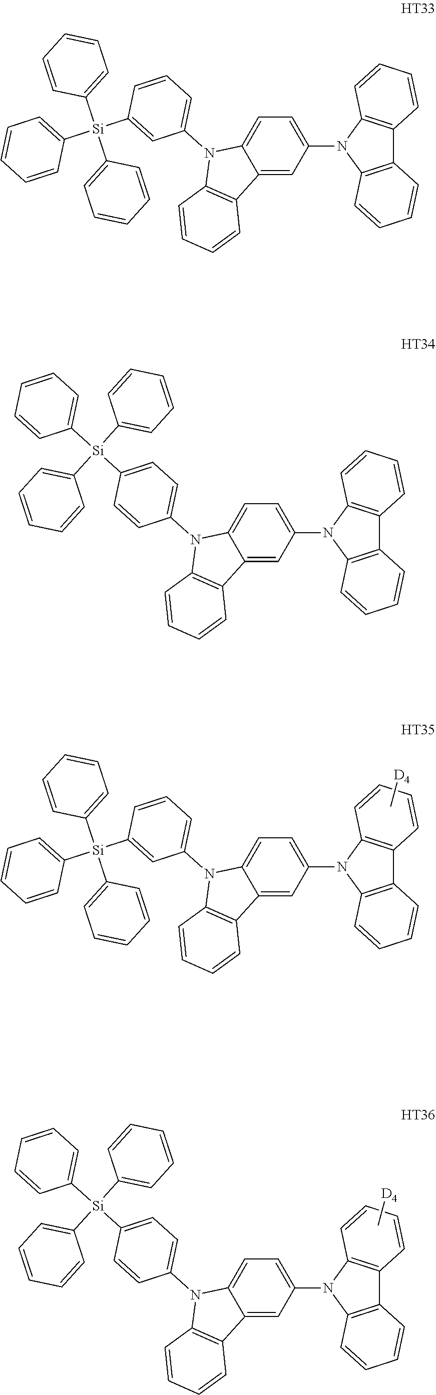

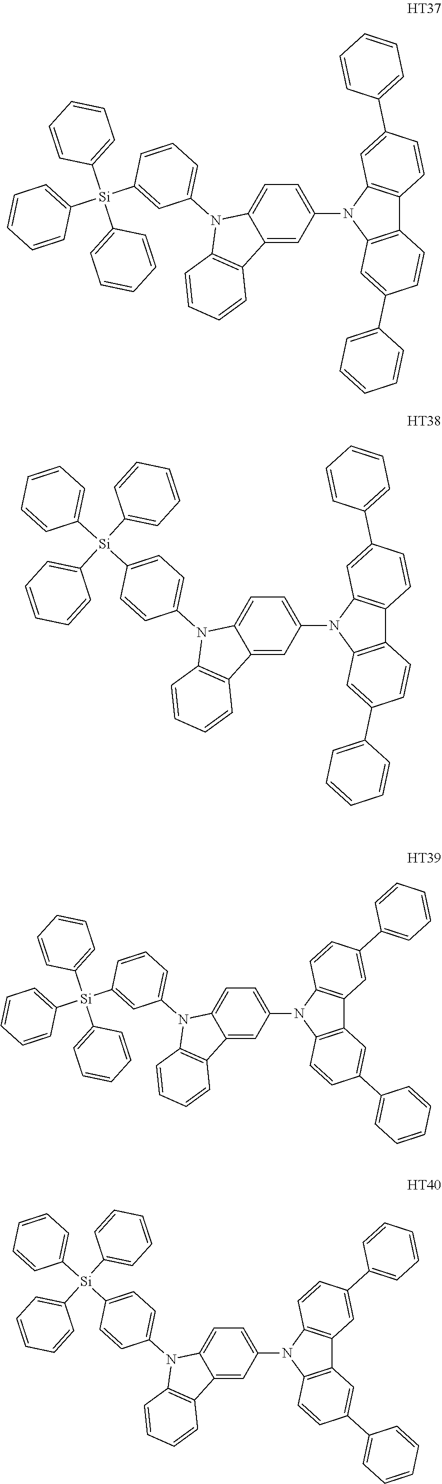 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

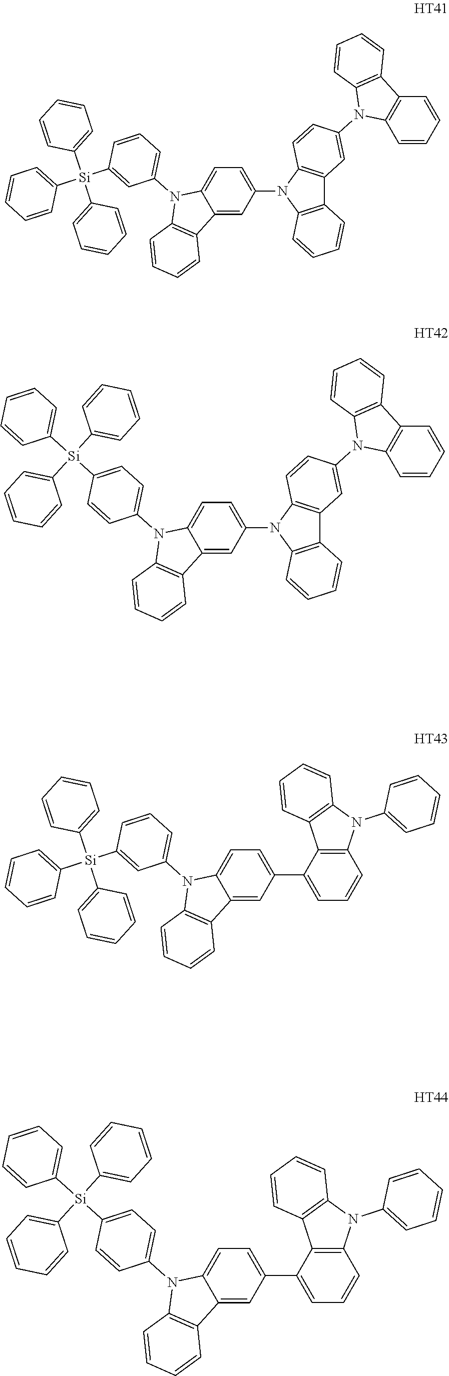 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

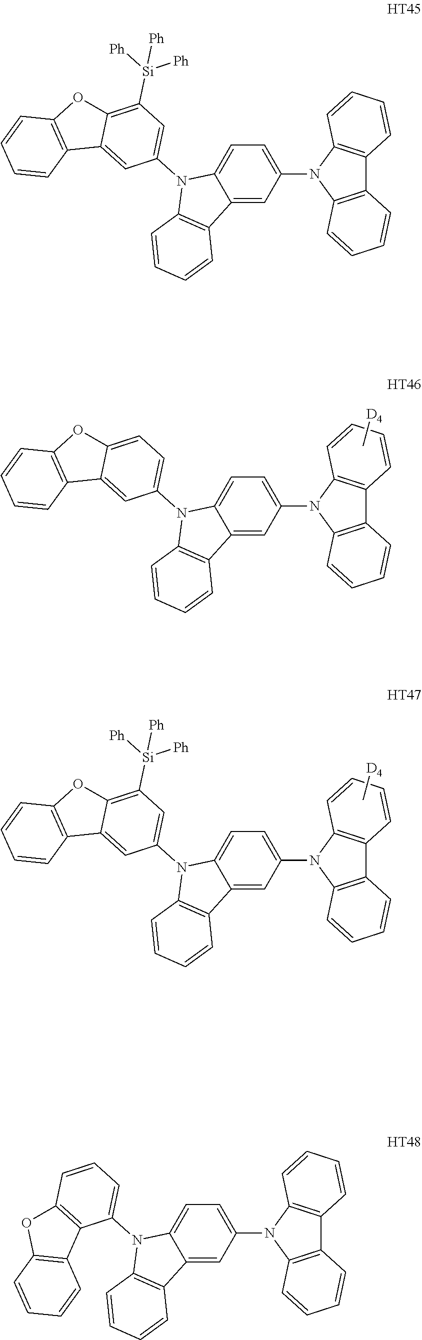

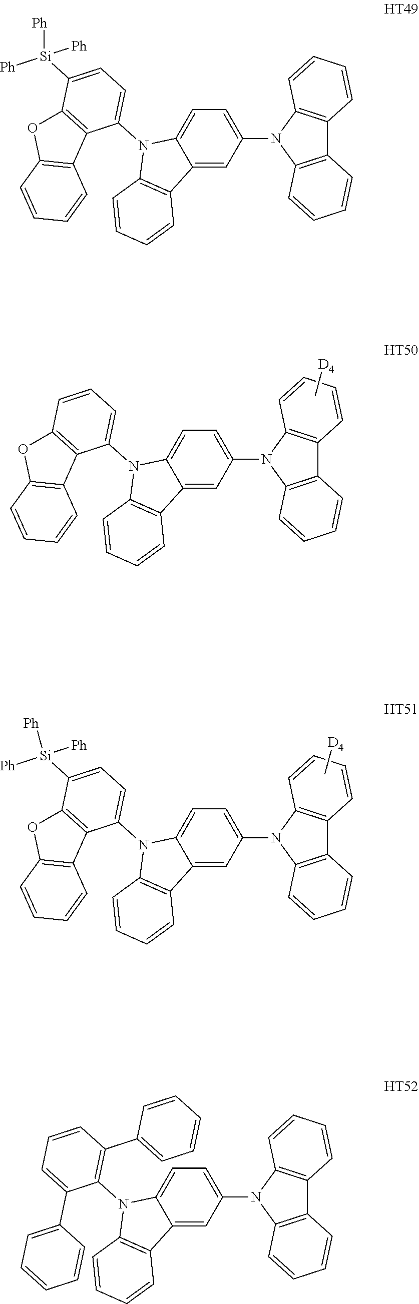

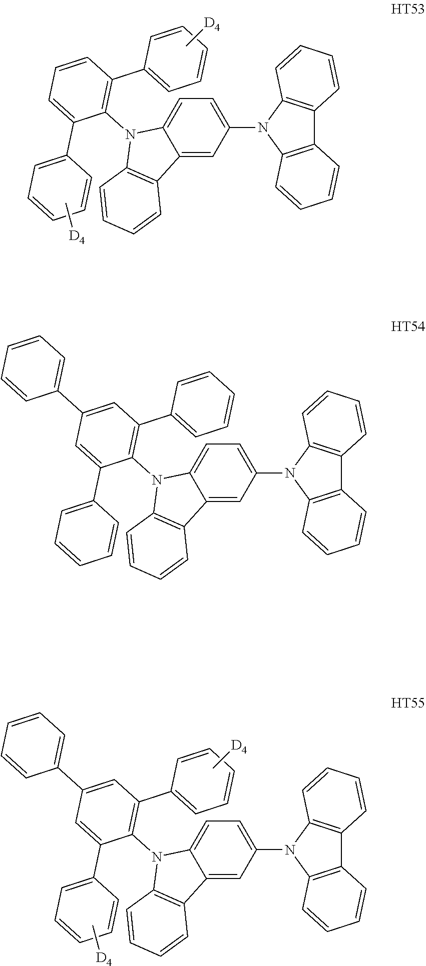

In Compound Group 2, D represents a deuterium atom, and Ph represents a substituted or unsubstituted phenyl group. For example, in Compound Group 2, Ph may be an unsubstituted phenyl group.

In an embodiment, the emission layer EML may include a third compound represented by Formula H-2. For example, the third compound may be used as an electron transport host material of the emission layer EML.

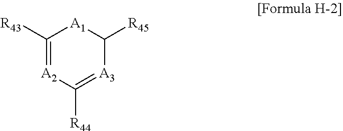

In Formula H-2, A₁ to A₃ may each independently be N or C(R₄₆), and at least one of A₁ to A₃ may be N.

In Formula H-2, R₄₃ to R₄₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, a substituted or unsubstituted heteroaryl group having 2 to 60 ring-forming carbon atoms, or may be bonded to an adjacent group to form a ring. For example, R₄₃ to R₄₆ may each independently be a substituted or unsubstituted phenyl group, a substituted or unsubstituted carbazole group, etc., but embodiments are not limited thereto.

In an embodiment, the third compound represented by Formula 3 may be a compound selected from Compound Group 3. The emission layer EML may include at least one compound selected from Compound Group 3 as an electron transporting host material.

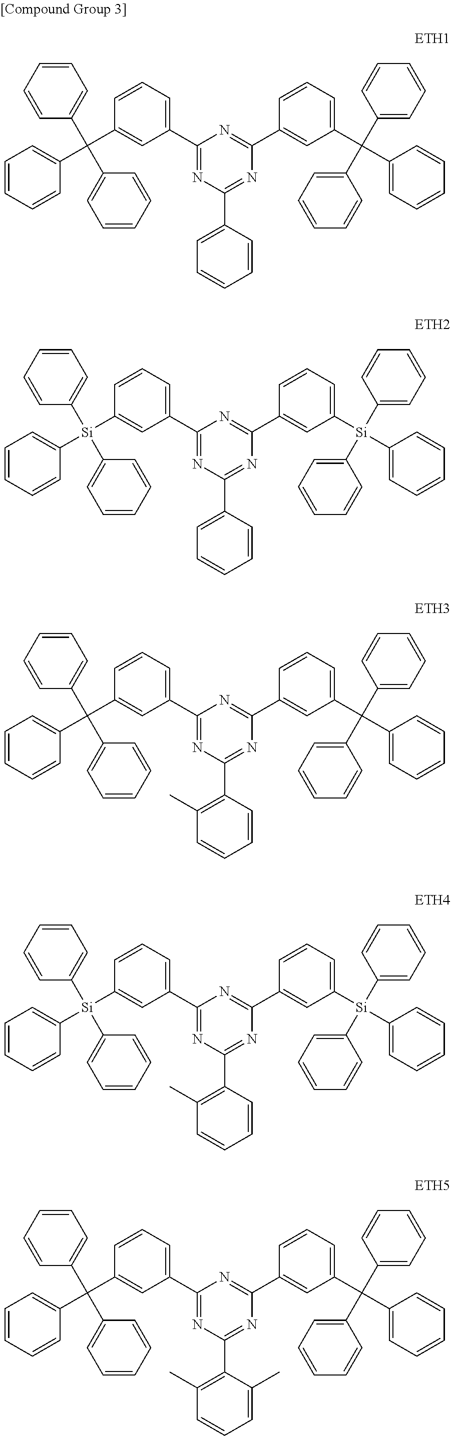

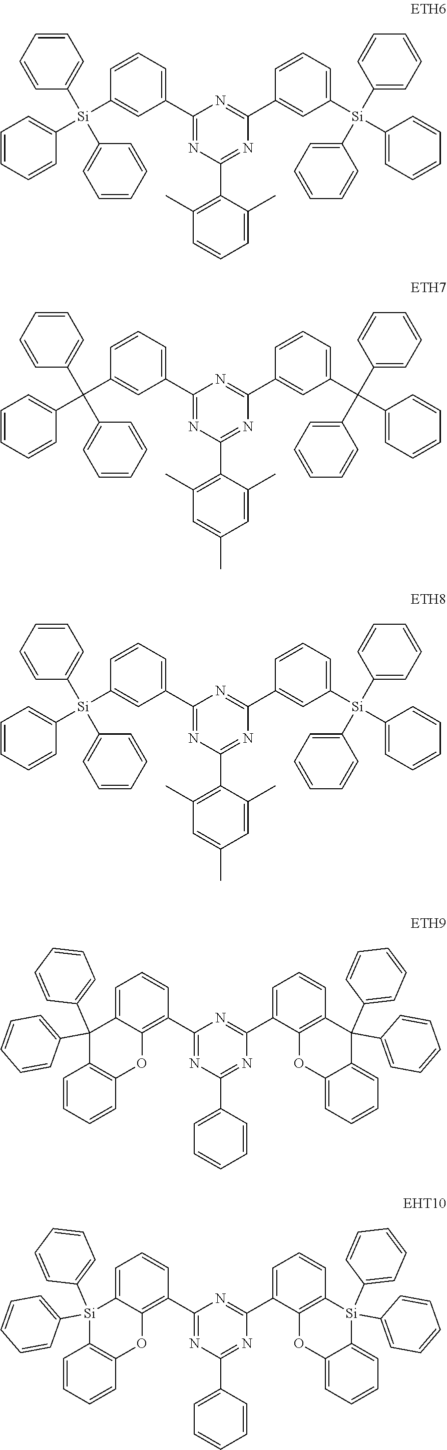

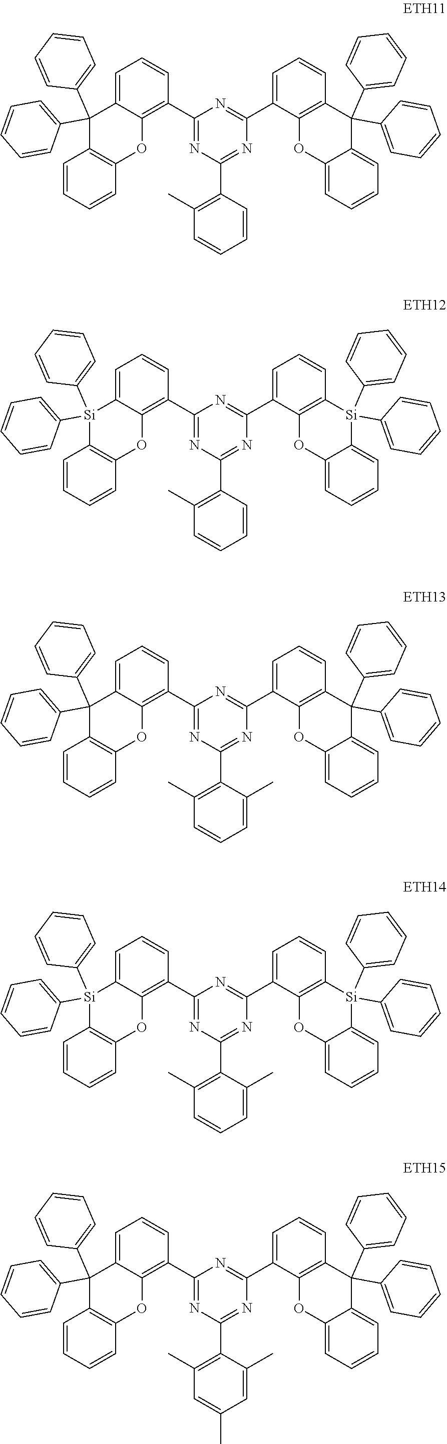

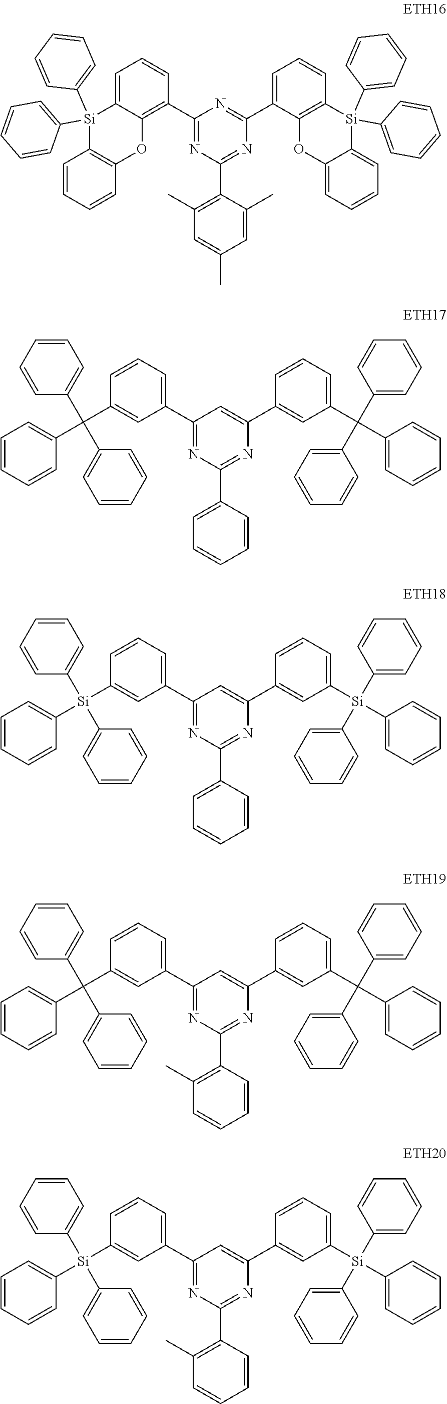

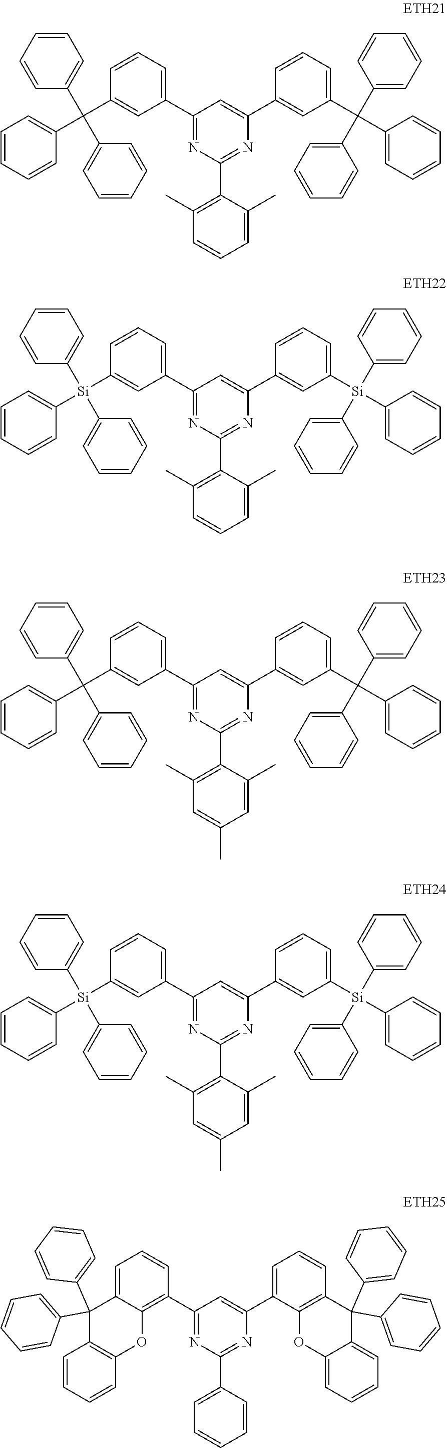

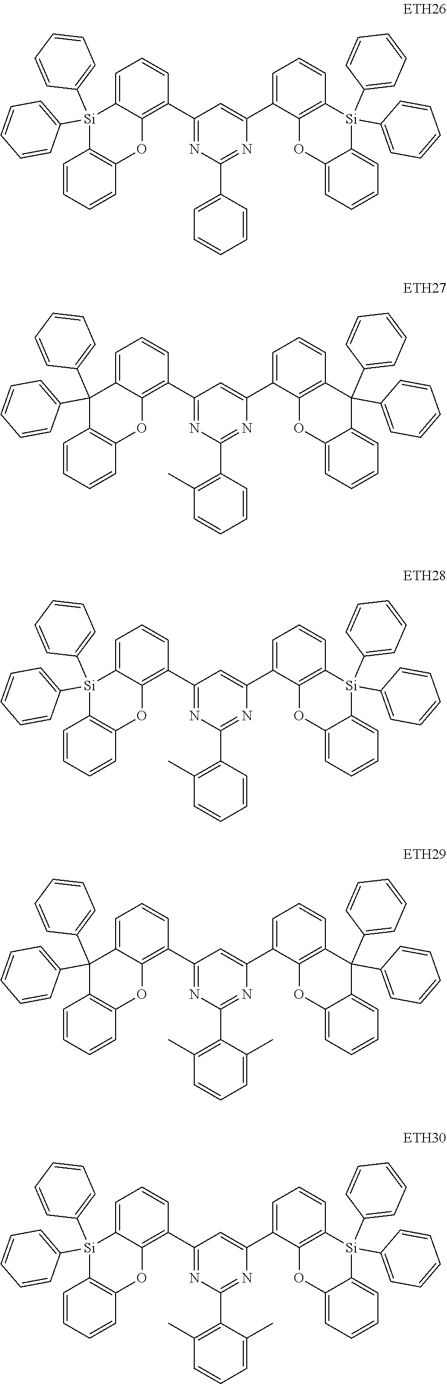

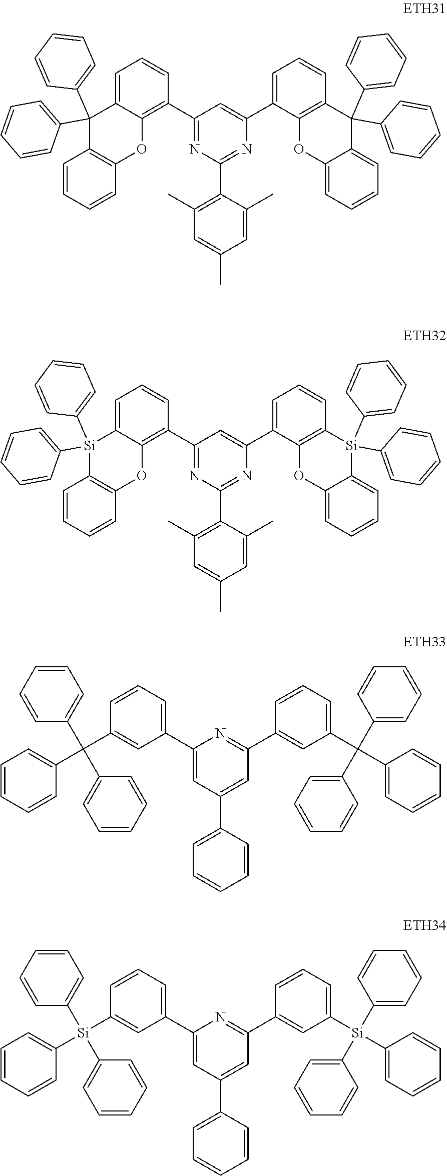 [SMILES: Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1 ; c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1]

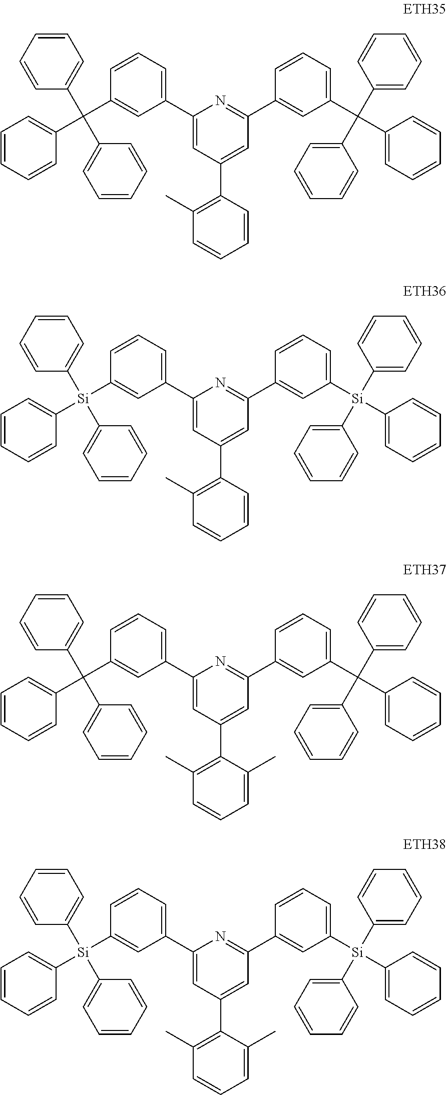 [SMILES: Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

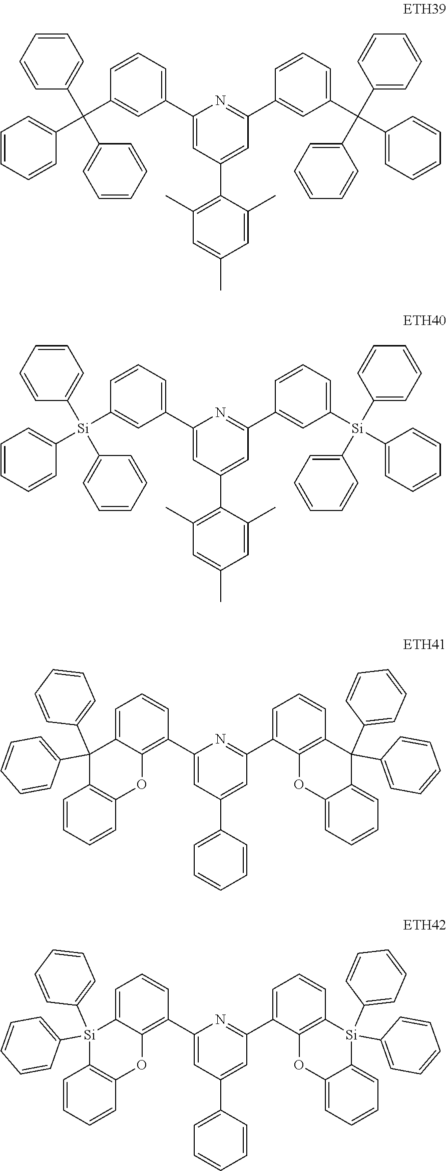 [SMILES: Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1 ; c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1]

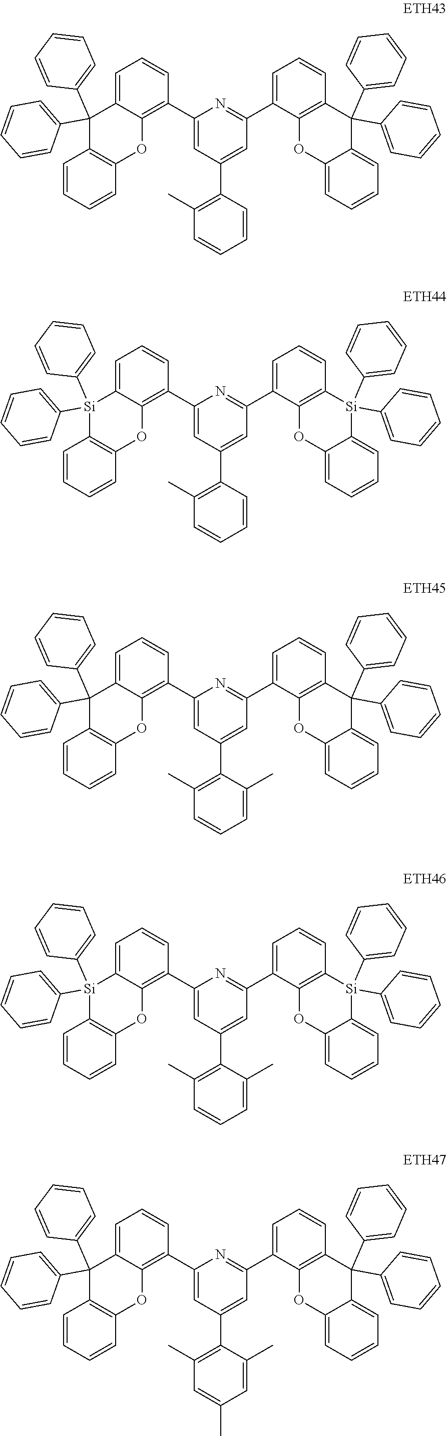

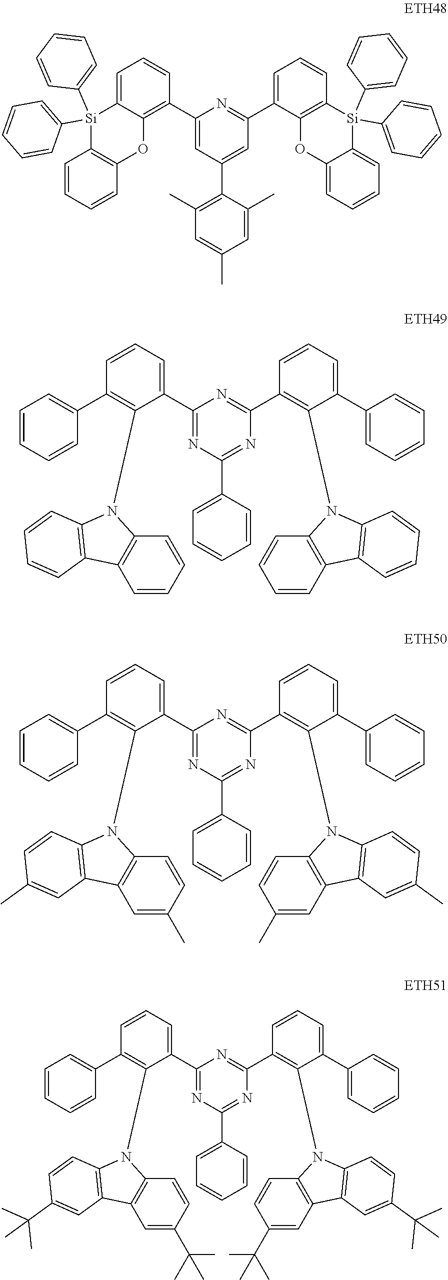

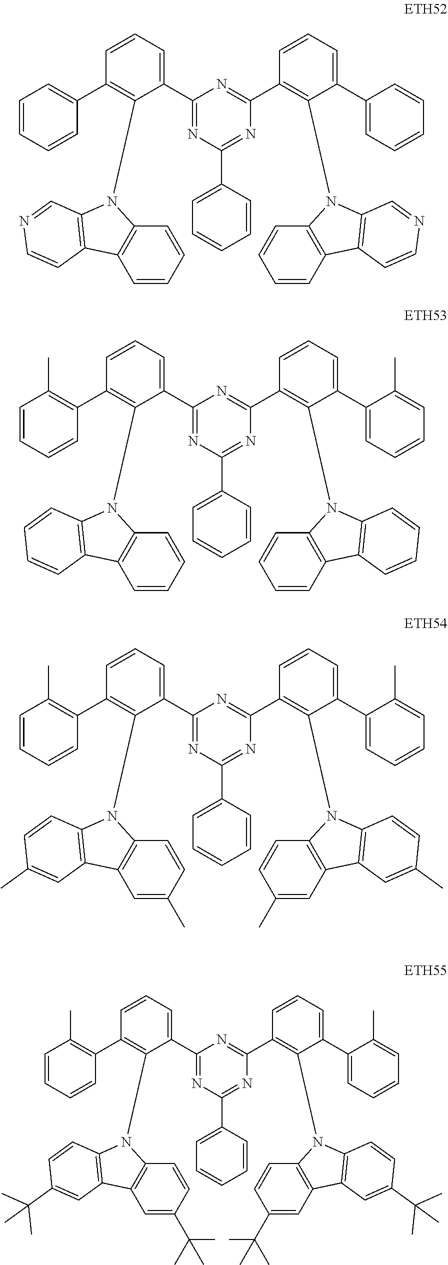

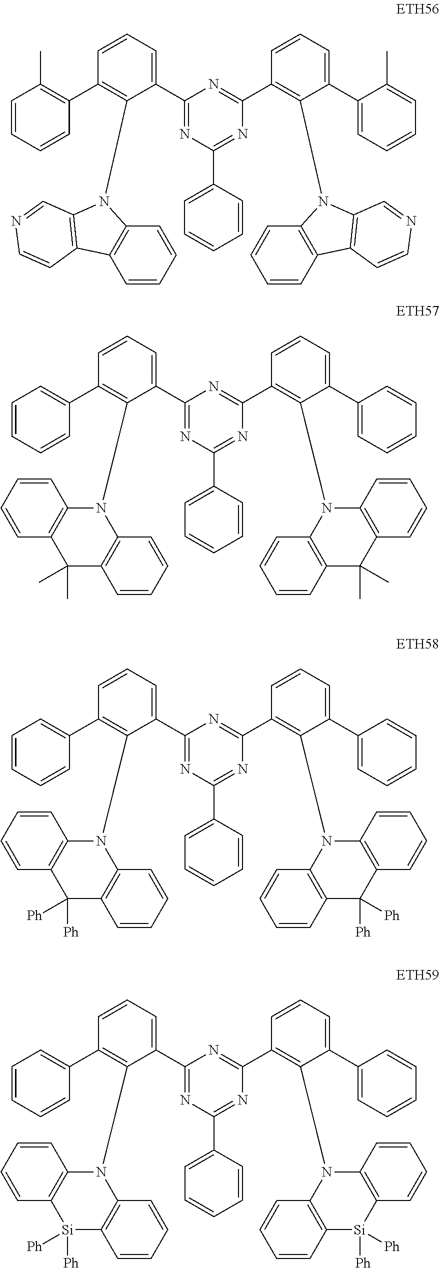

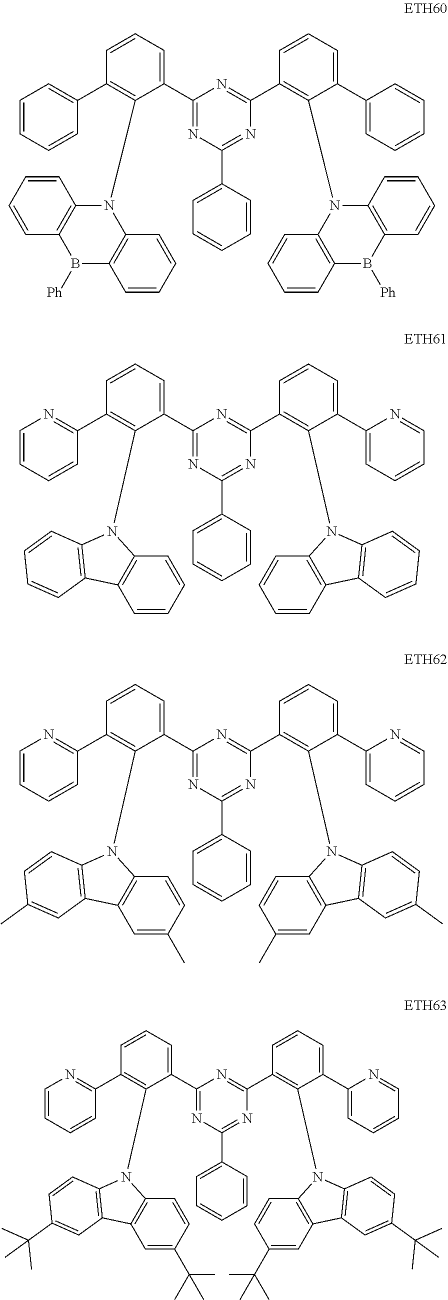

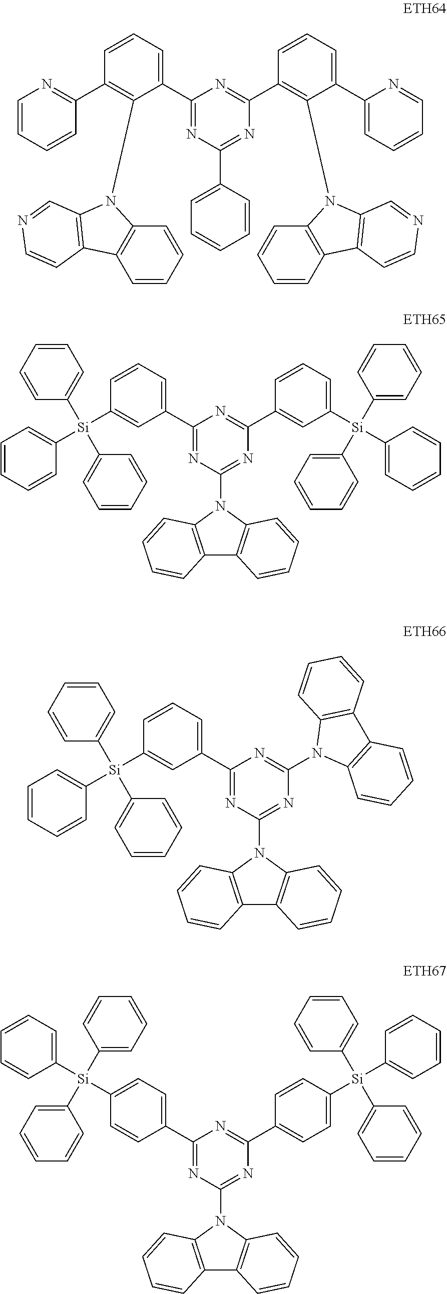 [SMILES: c1ccc(-c2nc(-c3cccc(-c4ccccn4)c3-n3c4ccccc4c4ccncc43)nc(-c3cccc(-c4ccccn4)c3-n3c4ccccc4c4ccncc43)n2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1]

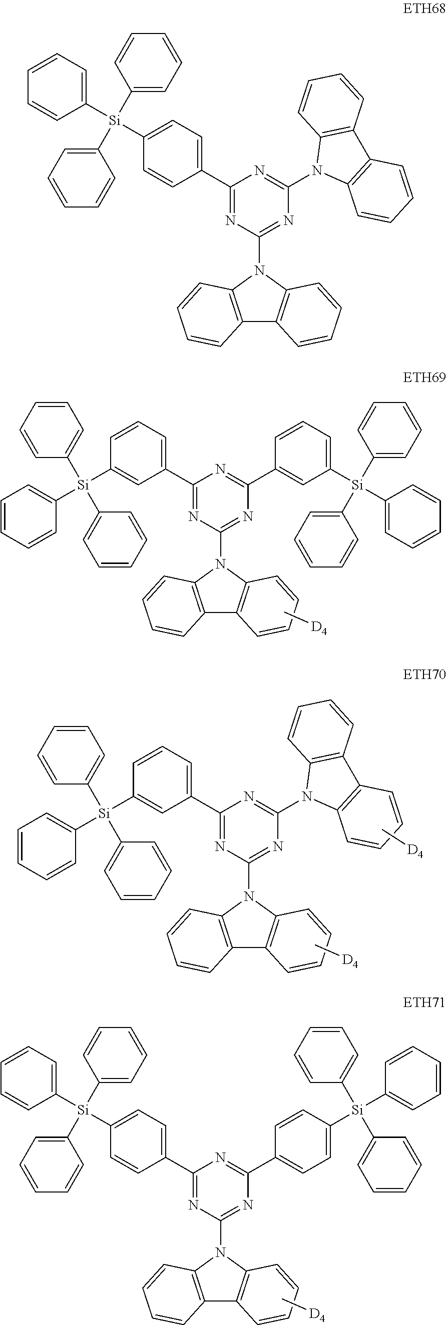

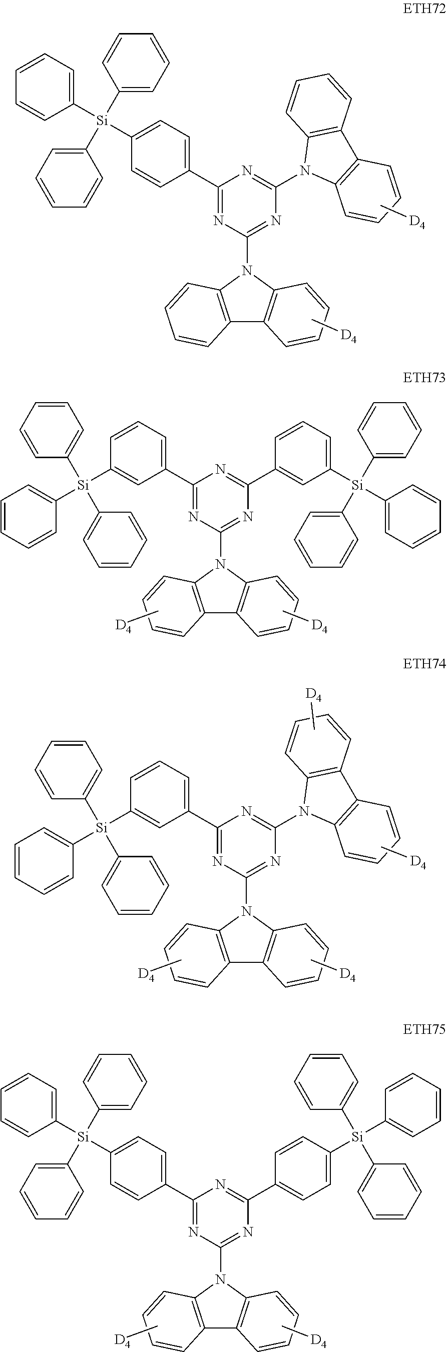

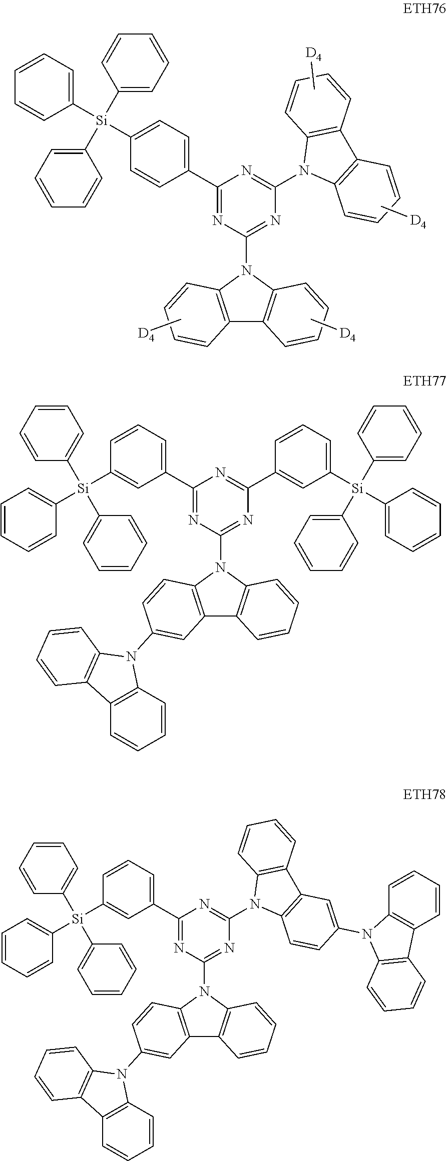

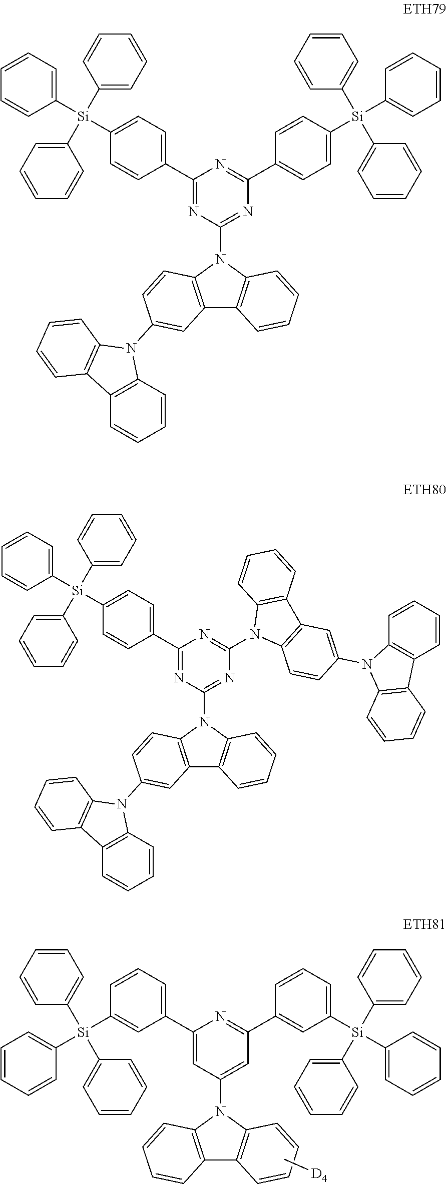

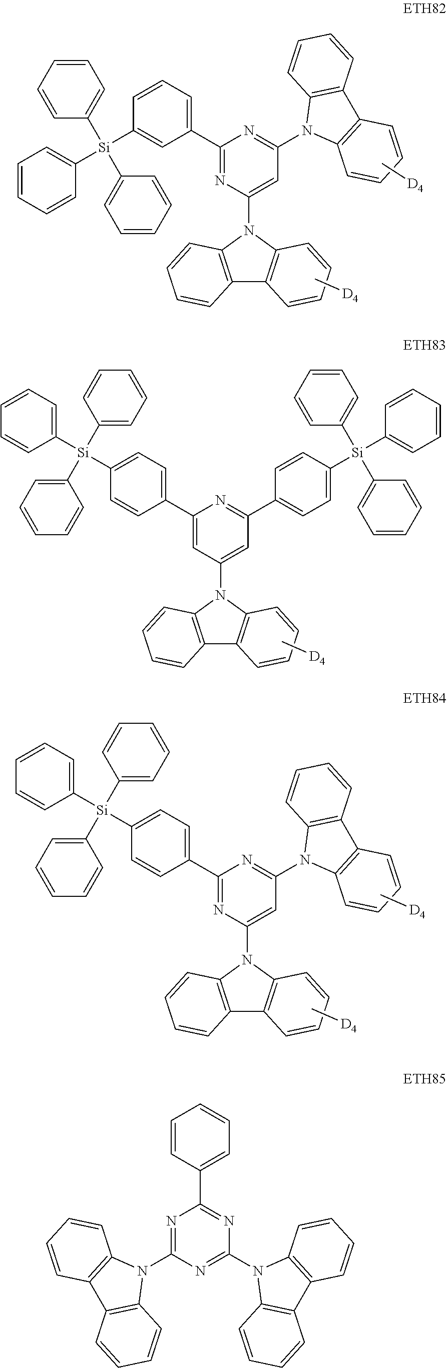

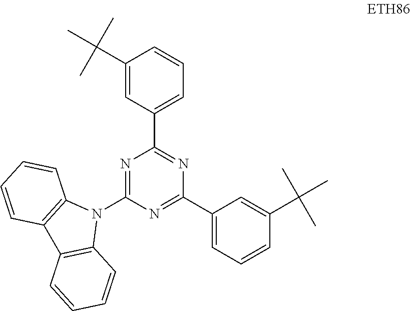 [SMILES: CC(C)(C)c1cccc(-c2nc(-c3cccc(C(C)(C)C)c3)nc(-n3c4ccccc4c4ccccc43)n2)c1]

In Compound Group 3, D represents a deuterium atom, and Ph represents an unsubstituted phenyl group.

The emission layer EML may include the second compound and the third compound, and the second compound and the third compound may form an exciplex. In the emission layer EML, an exciplex may be formed by the hole transport host and the electron transport host. A triplet energy of the exciplex formed by the hole transporting host and the electron transporting host may correspond to a difference between a lowest unoccupied molecular orbital (LUMO) energy level of the electron transporting host and a highest occupied molecular orbital (HOMO) energy level of the hole transporting host.

For example, an absolute value of the triplet energy (Ti) of the exciplex formed by the hole transporting host and the electron transporting host may be in a range of about 2.4 eV to about 3.0 eV. A triplet energy of the exciplex may be a value that is smaller than an energy gap of each host material. The exciplex may have a triplet energy equal to or less than about 3.0 eV that is an energy gap between the hole transporting host and the electron transporting host.

In an embodiment, the emission layer EML may include a fourth compound, in addition to the first compound to the third compound. The fourth compound may be used as a phosphorescent sensitizer of the emission layer EML. Energy may be transferred from the fourth compound to the first compound, thereby emitting light.

For example, the emission layer EML may include, as the fourth compound, an organometallic complex containing platinum (Pt) as a central metal atom and ligands linked to the central metal atom. The emission layer EML in the light emitting device ED may include, as the fourth compound, a compound represented by Formula D-1:

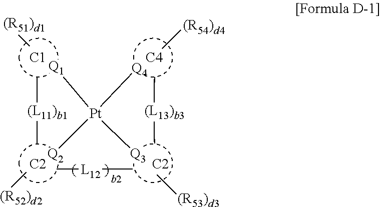

In Formula D-1, Q₁ to Q₄ may each independently be C or N.

In Formula D-1, C1 to C4 may each independently be a substituted or unsubstituted hydrocarbon ring having 5 to 30 ring-forming carbon atoms, or a substituted or unsubstituted heterocycle having 2 to 30 ring-forming carbon atoms.

In Formula D-1, L₁₁ to L₁₃ may each independently be a direct linkage, *—O—*, *—S—*,

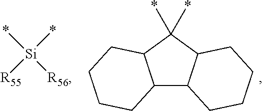

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, -* represents a bonding site to one of C1 to C4.

In Formula D-1, b1 to b3 may each independently be 0 or 1. If b1 is 0, C1 and C2 may not be linked to each other. If b2 is 0, C2 and C3 may not be linked to each other. If b3 is 0, C3 and C4 may not be linked to each other.

In Formula D-1, R₅₁ to R₅₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, a substituted or unsubstituted heteroaryl group having 2 to 60 ring-forming carbon atoms, or may be bonded to an adjacent group to form a ring. For example, R₅₁ to R₅₆ may each independently be a substituted or unsubstituted methyl group, or a substituted or unsubstituted t-butyl group.

In Formula D-1, d1 to d4 may each independently be an integer from 0 to 4. In Formula D-1, if d1 to d4 are each 0, the fourth compound may not be substituted with each of R₅₁ to R₅₄. A case where d1 to d4 are each 4 and R₅₁ groups, R₅₂ groups, R₅₃ groups, and R₅₄ groups are each hydrogen atoms may be the same as the case where d1 to d4 are each 0. When d1 to d4 are each 2 or more, multiple groups of each of R₅₁ to R₅₄ may each be the same, or at least one thereof may be different from the others.

In an embodiment, in Formula D-1, C1 to C4 may each independently be a substituted or unsubstituted hydrocarbon ring or a substituted or unsubstituted heterocycle represented by any one of C-1 to C-4:

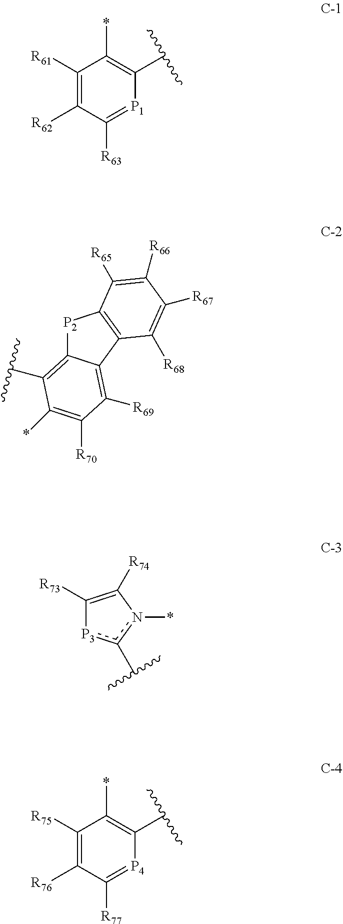

In C-1 to C-4, P₁ may be C—* or C(R₆₄), P₂ may be N—* or N(R₇₁), P₃ may be N—* or N(R₇₂), and P₄ may be C—* or C(R₇₈). In C-1 to C-4, R₆₁ to R₇₈ may each independently be a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring.

In C-1 to C-4,

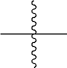

represents a bonding site to Pt that is a central metal atom, and -* represents a bonding site to a neighboring cyclic group (C1 to C4) or to a linker (L₁₁ to L₁₃).

The emission layer EML may include the first compound, which is a fused polycyclic compound, and at least one of the second to fourth compounds. For example, in an embodiment, the emission layer EML may include the first compound, the second compound, and the third compound. In the emission layer EML, the second compound and the third compound may form an exciplex, the energy may be transferred from the exciplex to the first compound, thereby emitting light.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound, thereby emitting light. In an embodiment, the fourth compound may be a sensitizer. The fourth compound included in the emission layer EML in the light emitting device ED may serve as a sensitizer to transfer energy from the host to the first compound that is a light emitting dopant. For example, when the fourth compound serves as an auxiliary dopant, the fourth compound may accelerate energy transfer to the first compound that is a light emitting dopant, thereby increasing the emission ratio of the first compound. Therefore, the emission layer EML including the first compound, the second compound, the third compound, and the fourth compound may have improved luminous efficiency. When energy transfer to the first compound is increased, an exciton formed in the emission layer EML may not accumulate inside the emission layer EML and may rapidly emit light, and thus deterioration of the emission layer EML may be reduced. Therefore, the service life of the light emitting device ED may increase.

The light emitting device ED may include all of the first compound, the second compound, the third compound, and the fourth compound, and the emission layer EML may include a combination of two host materials and two dopant materials. In the light emitting device ED, the emission layer EML may simultaneously include the second compound and the third compound, which are two different hosts, the first compound that emits a delayed fluorescence, and the fourth compound including an organometallic complex, thereby exhibiting excellent luminous efficiency characteristics.

In an embodiment, the fourth compound represented by Formula D-1 may be a compound selected from Compound Group 4. The emission layer EML may include at least one compound selected from Compound Group 4 as a sensitizer material.

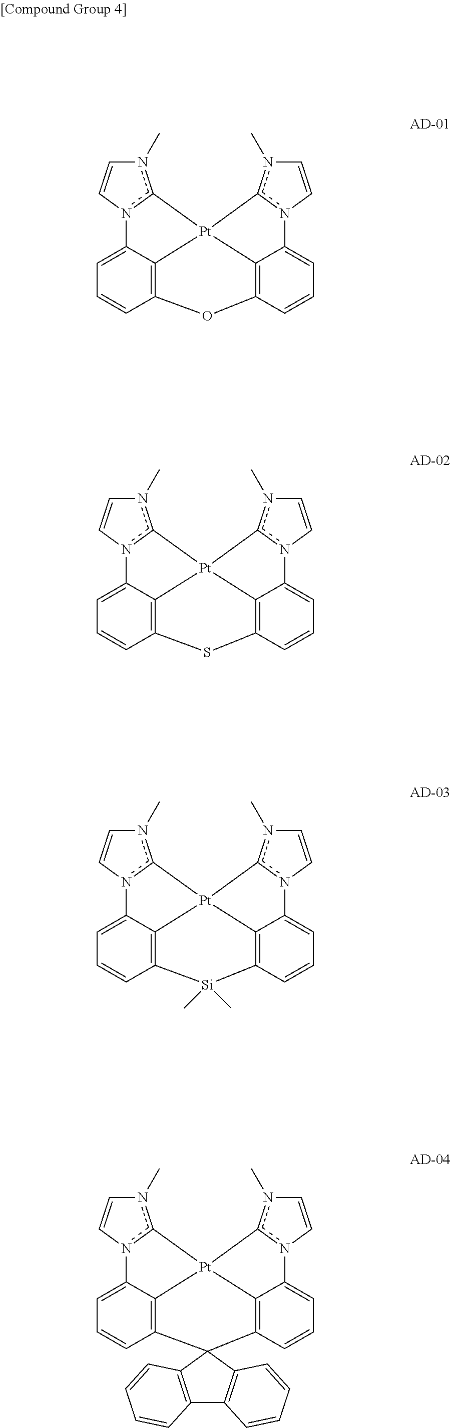

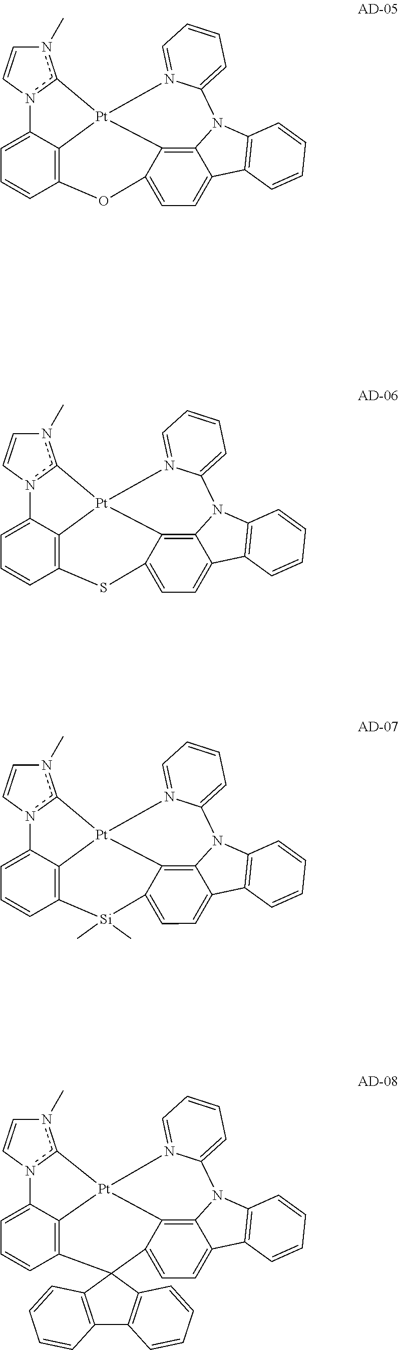

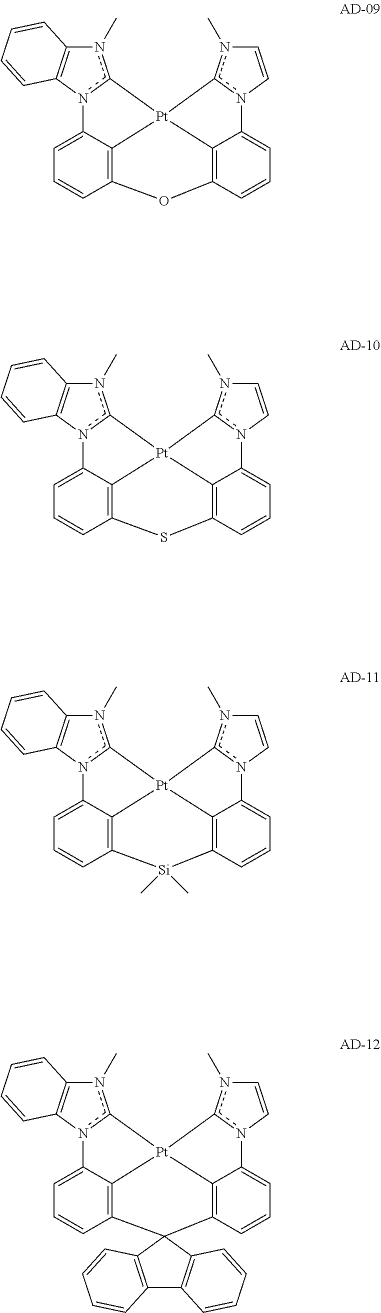

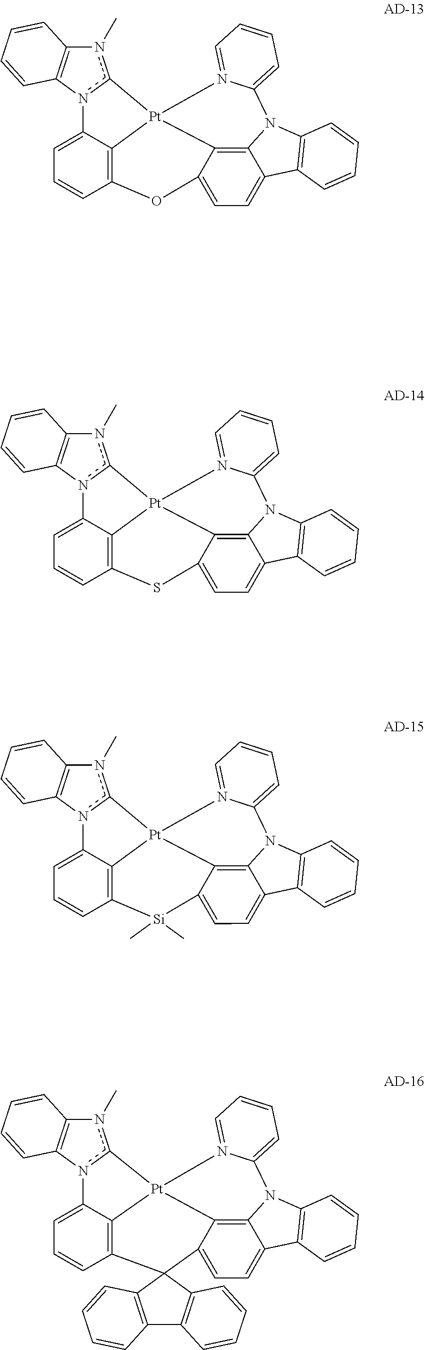

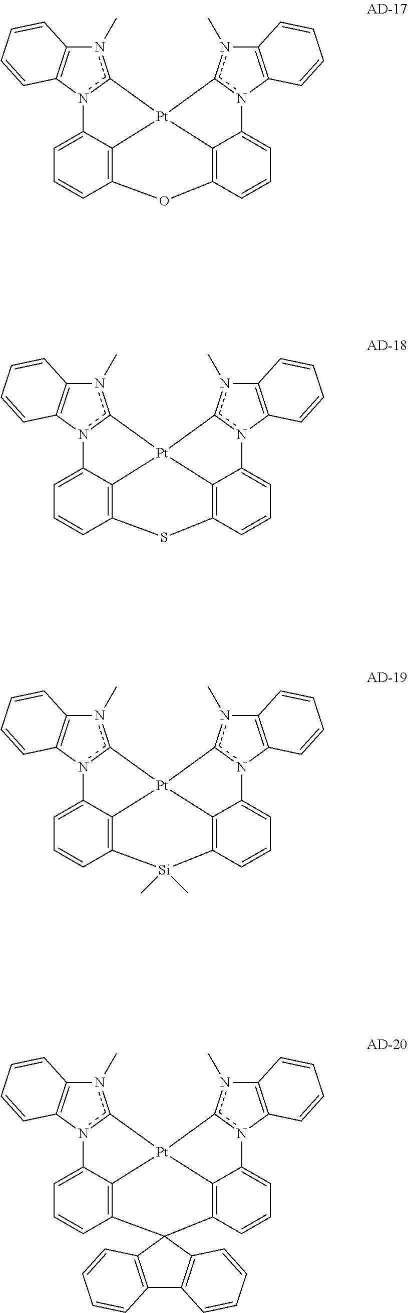

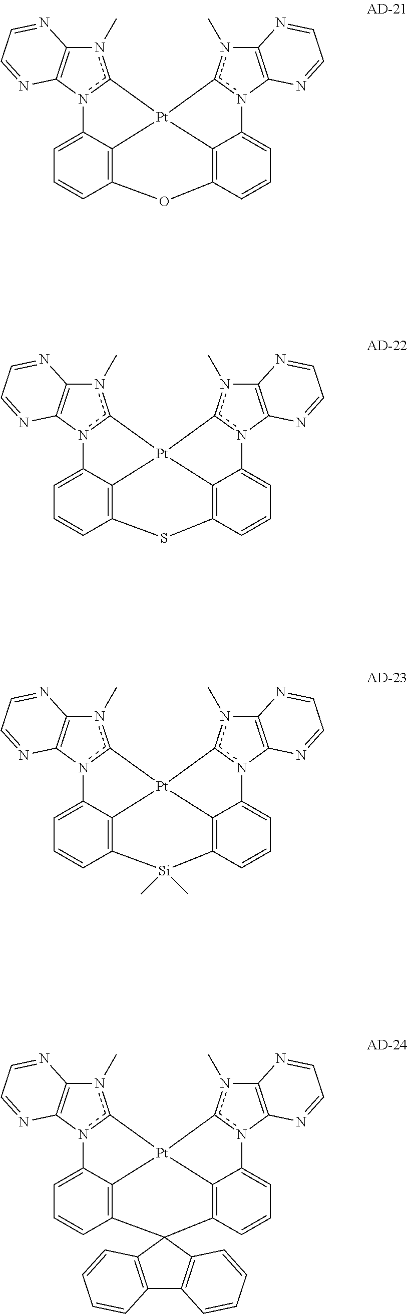

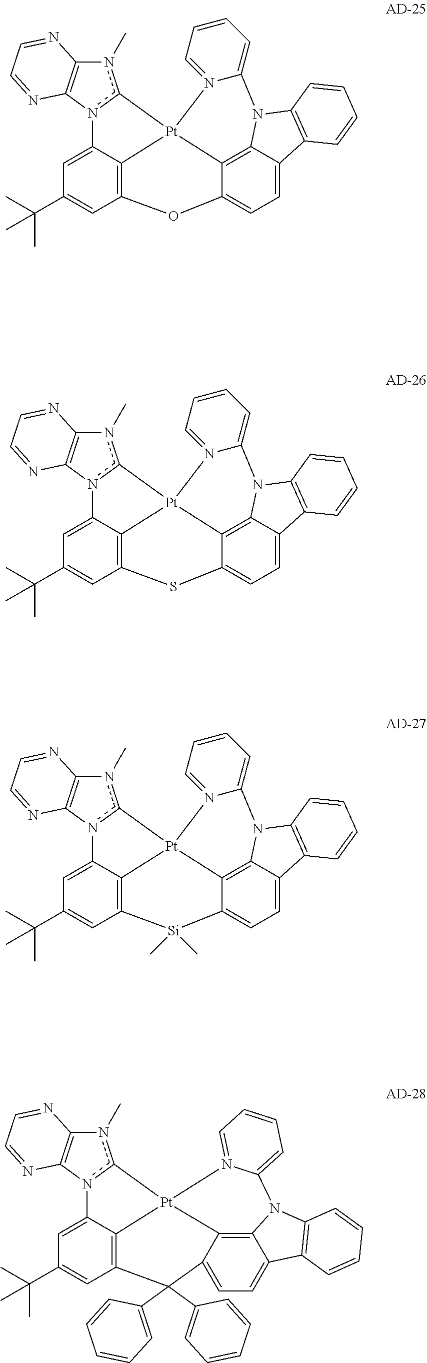

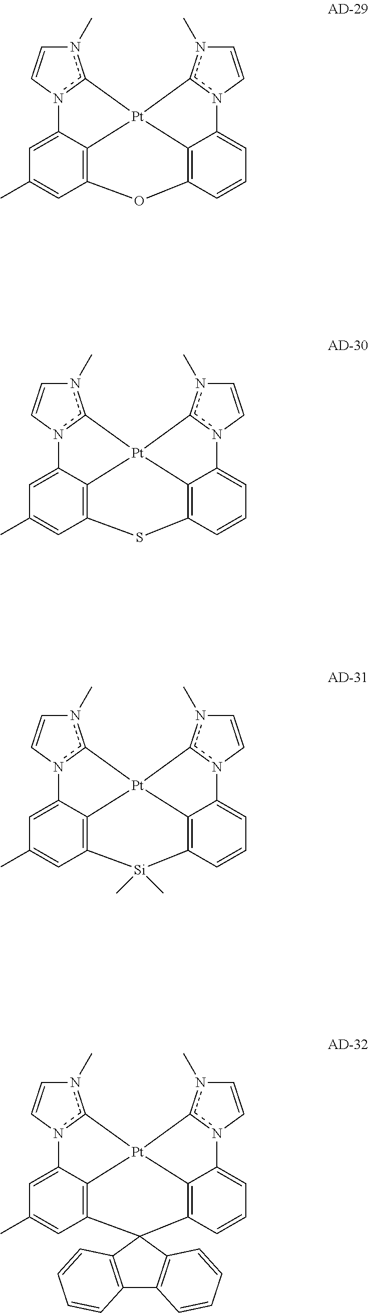

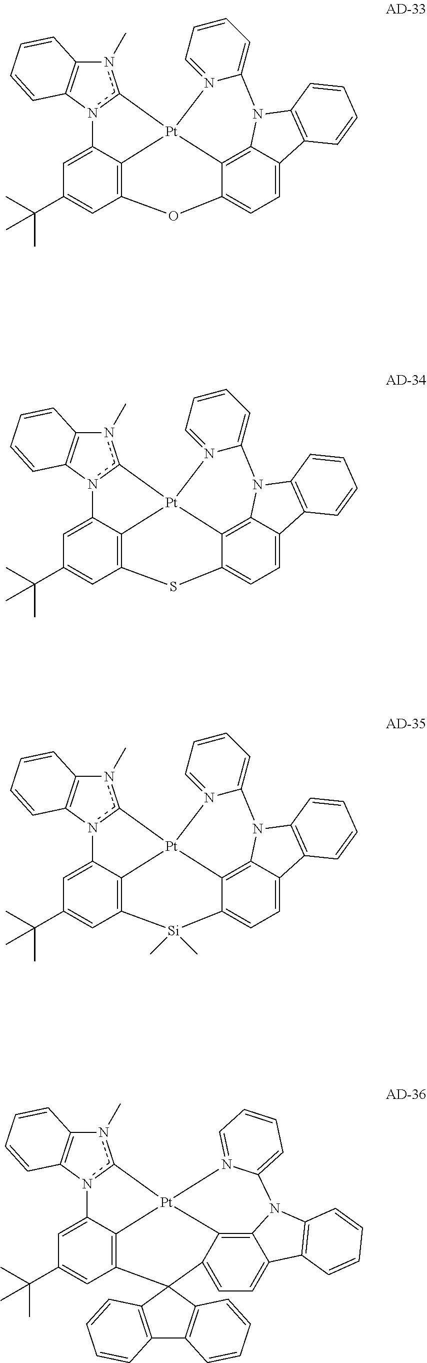

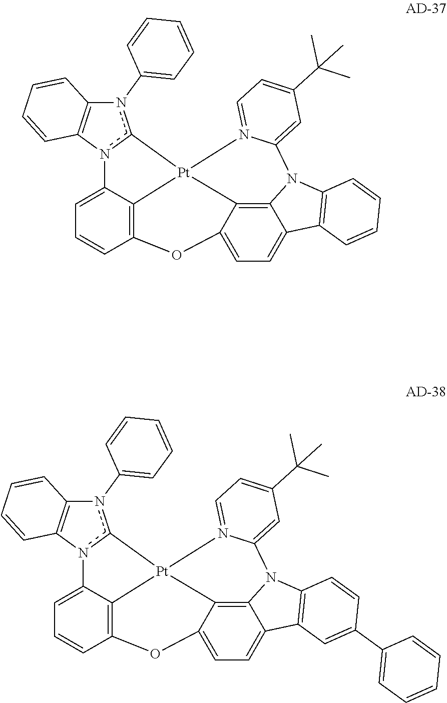

In an embodiment, the light emitting device ED may include multiple emission layers. The emission layers may be stacked and provided, and for example, the light emitting device ED including multiple emission layers may emit white light. The light emitting device including multiple emission layers may be a light emitting device having a tandem structure. In an embodiment, when the light emitting device ED includes multiple emission layers, at least one emission layer EML may include the first compound represented by Formula 1. In another embodiment, when the light emitting device ED includes multiple emission layers, at least one emission layer EML may include all of the first compound, the second compound, the third compound, and the fourth compound as described above.

When the emission layer EML in the light emitting device ED includes all of the first compound, the second compound, and the third compound, an amount of the first compound may be in a range of about 0.1 wt % to about 5 wt %, with respect to a total weight of the first compound, the second compound, and the third compound. However, embodiments are not limited thereto. When the amount of the first compound satisfies the above-described range, energy transfer from the second compound and the third compound to the first compound may increase, and thus the luminous efficiency and device service life may increase.

An amount of the second compound and the third compound in the emission layer EML may be a remainder of the weight of the emission layer EML, excluding the weight of the first compound. For example, a total amount of the second compound and the third compound in the emission layer EML may be in a range of about 60 wt % to about 95 wt %, with respect to a total weight of the first compound, the second compound, and the third compound.

In the total amount of the second compound and the third compound, a weight ratio of the second compound to the third compound may be in a range of about 3:7 to about 7:3.

When the amounts of the second compound and the third compound satisfy the above-described ratio, charge balance characteristics in the emission layer EML may be improved, and thus the luminous efficiency and device service life may increase. When the amounts of the second compound and the third compound deviate from the above-described ratio range, charge balance in the emission layer EML is not achieved, and thus the luminous efficiency may be reduced, and the device may readily deteriorate.

When the first compound, the second compound, and the third compound included in the emission layer EML satisfies the above-described ranges and ratios, excellent luminous efficiency and long service life may be achieved.

In the light emitting device ED, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In each of the light emitting device ED according to embodiments illustrated in FIGS. 3 to 6, the emission layer EML may further include a host of the related art and a dopant of the related art, in addition to the above-described host and dopant. For example, the emission layer EML may include a compound represented by Formula E-1. The compound represented by Formula E-1 may be used as a fluorescent host material.

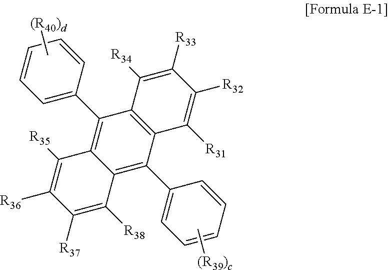

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. In Formula E-1, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

The compound represented by Formula E-1 may be any compound selected from Compound E1 to Compound E19:

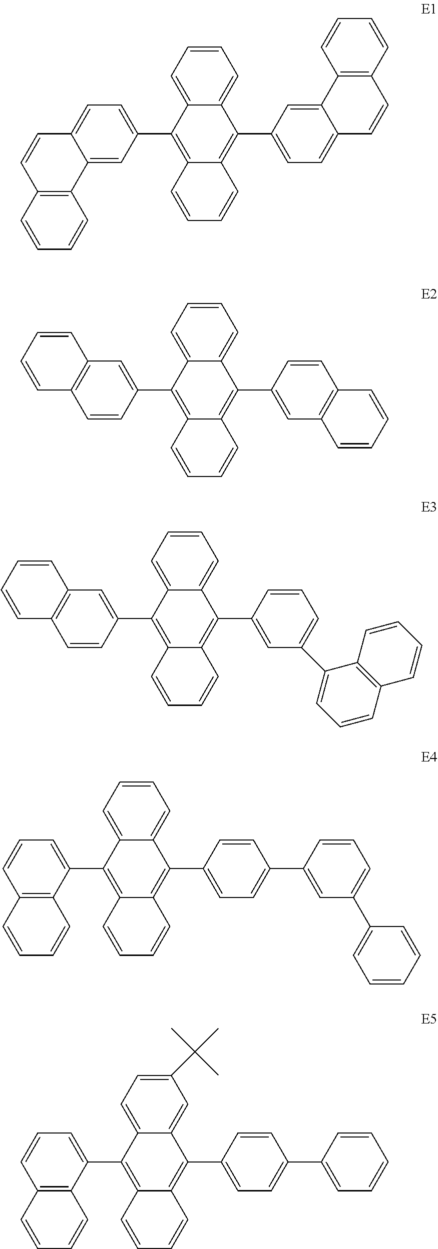

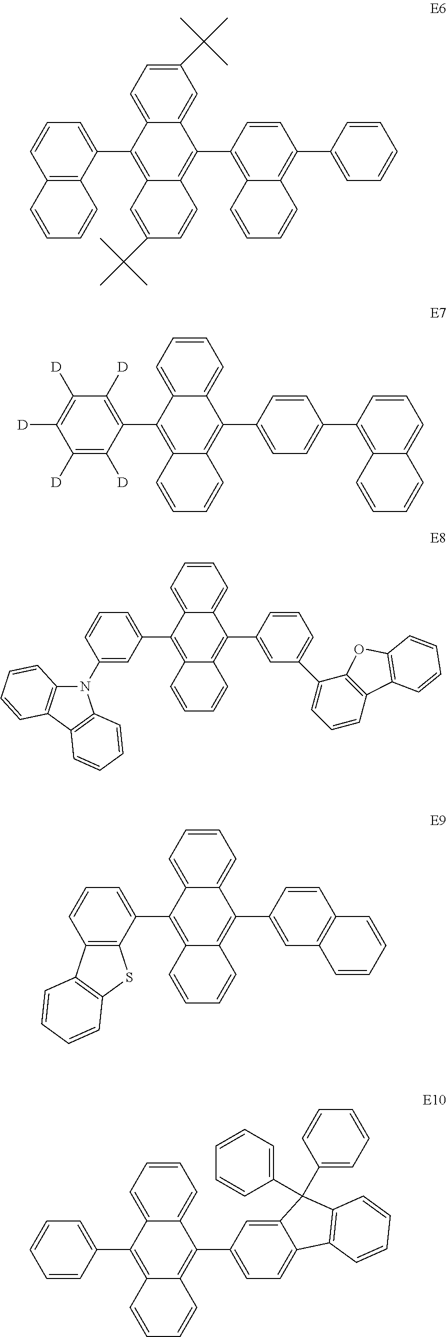

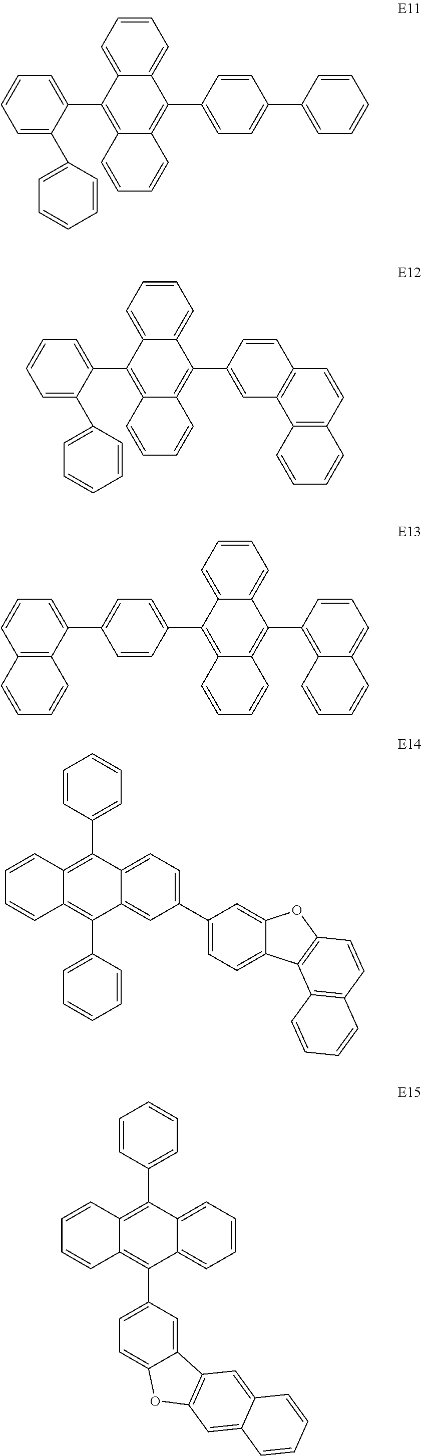

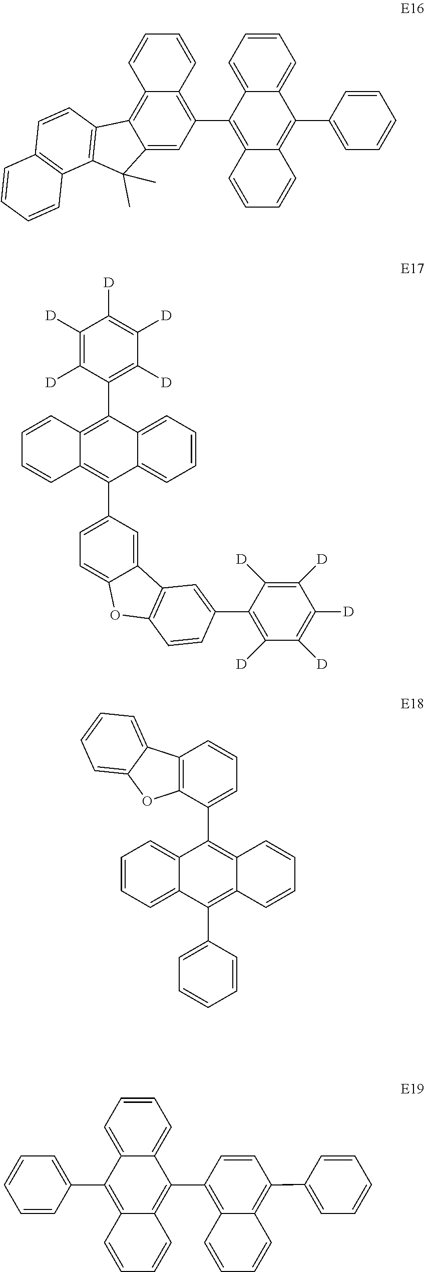

In an embodiment, the emission layer EML may include a compound represented by Formula E-2a or Formula E-2b. The compound represented by Formula E-2a or Formula E-2b may be used as a phosphorescent host material.

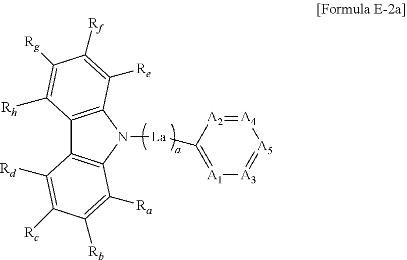

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or more, multiple Lₐ groups may each independently be a substituted or unsubstituted arylene group having 6 to 30 ring-forming carbon atoms, or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. For example, Rₐ to Rᵢ may be bonded to an adjacent group to form a hydrocarbon ring or a heterocycle containing N, O, S, etc. as a ring-forming atom.

In Formula E-2a, two or three of A₁ to A₅ may each be N, and the remainder of A₁ to A₅ may each independently be C(Rᵢ).

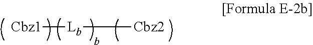

In Formula E-2b, Cbz1 and Cbz2 may each independently be an unsubstituted carbazole group, or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and when b is 2 or more, multiple L_{b} groups may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

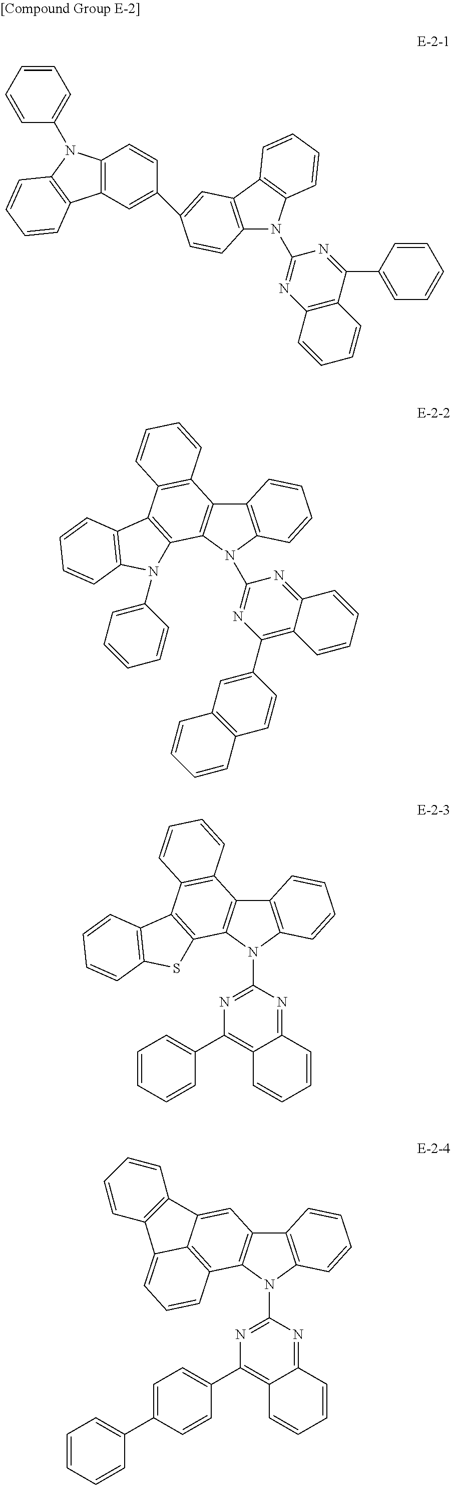

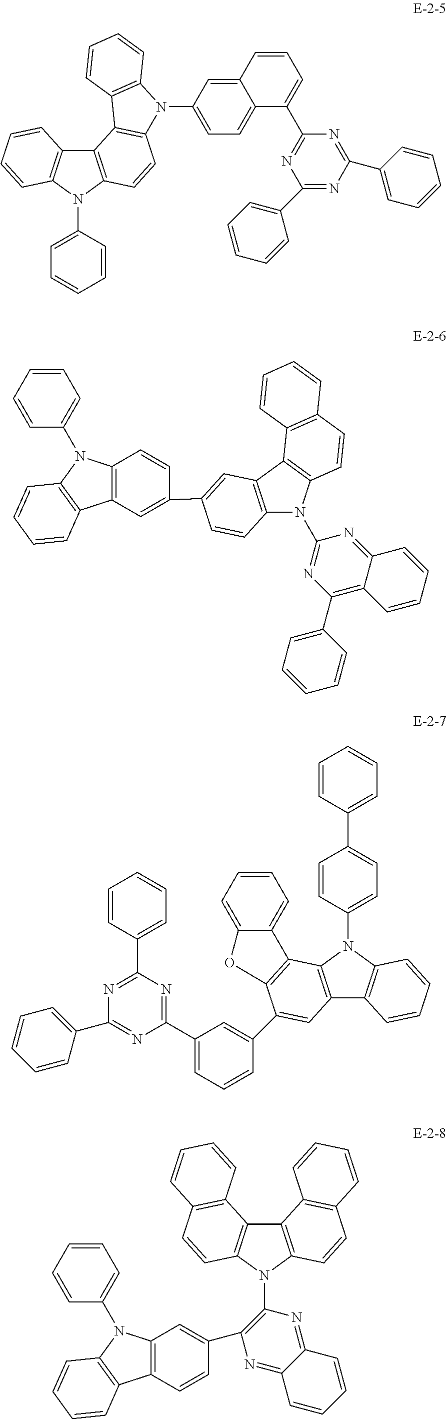 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

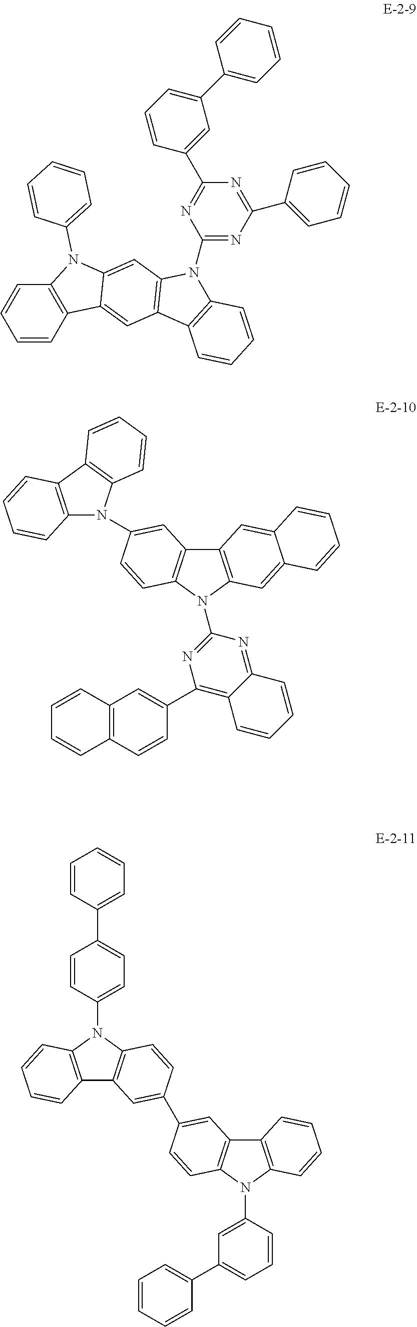 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

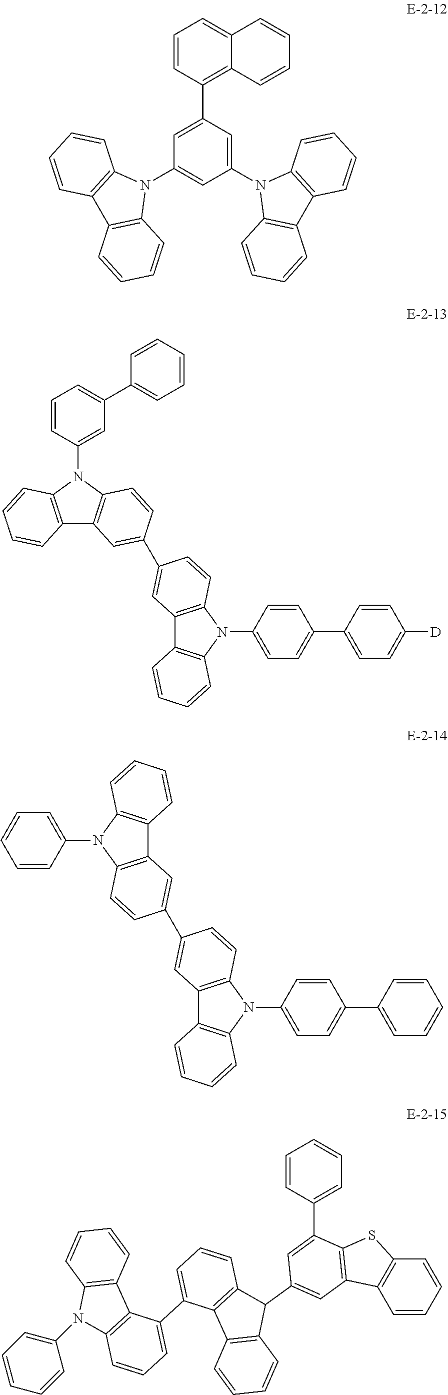 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(C3c4ccccc4-c4c(-c5cccc6c5c5ccccc5n6-c5ccccc5)cccc43)cc3c2sc2ccccc23)cc1]

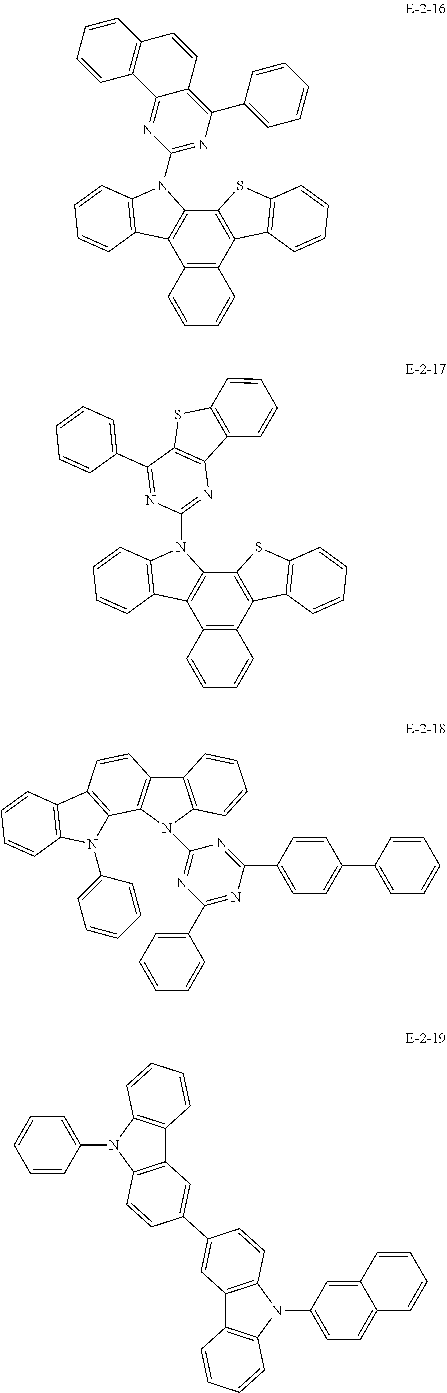 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1]

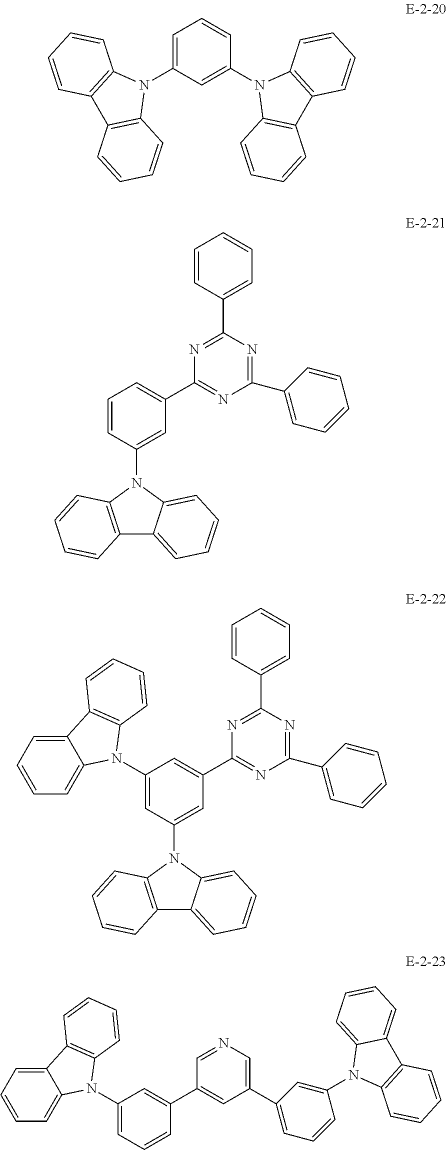 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

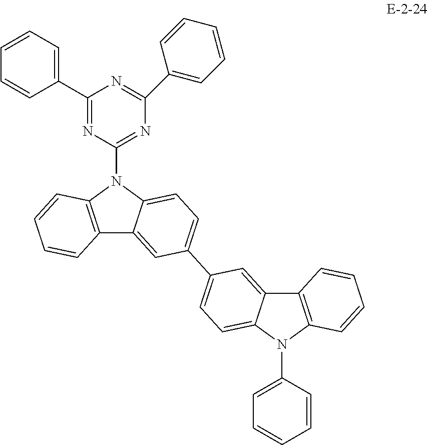 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as a host material.

The emission layer EML may include a compound represented by Formula M-a. The compound represented by Formula M-a may be used as a phosphorescent dopant material.

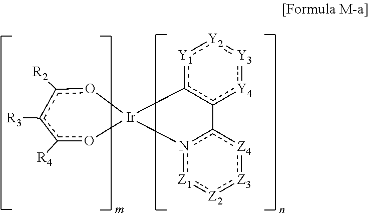

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be used as a phosphorescent dopant.

The compound represented by Formula M-a may be any compound selected from Compound M-al to Compound M-a25. However, Compounds M-al to M-a25 are only examples, and the compound represented by Formula M-a is not limited to Compounds M-al to M-a25.

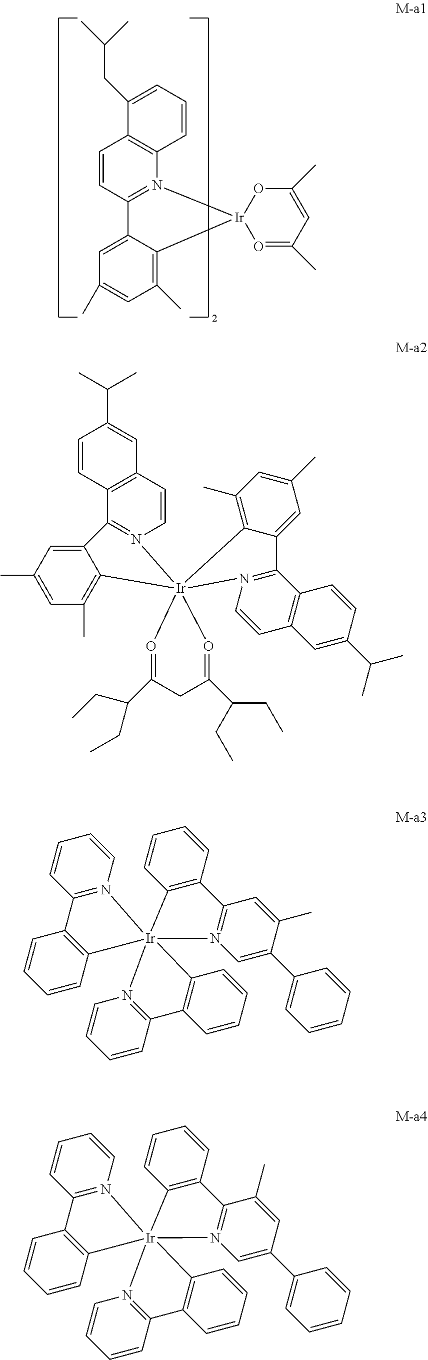

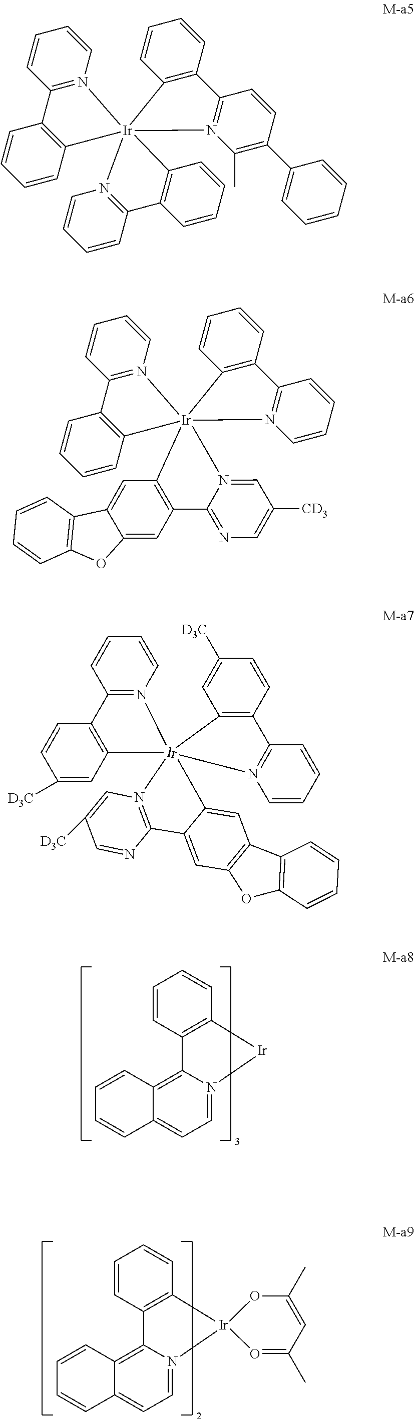

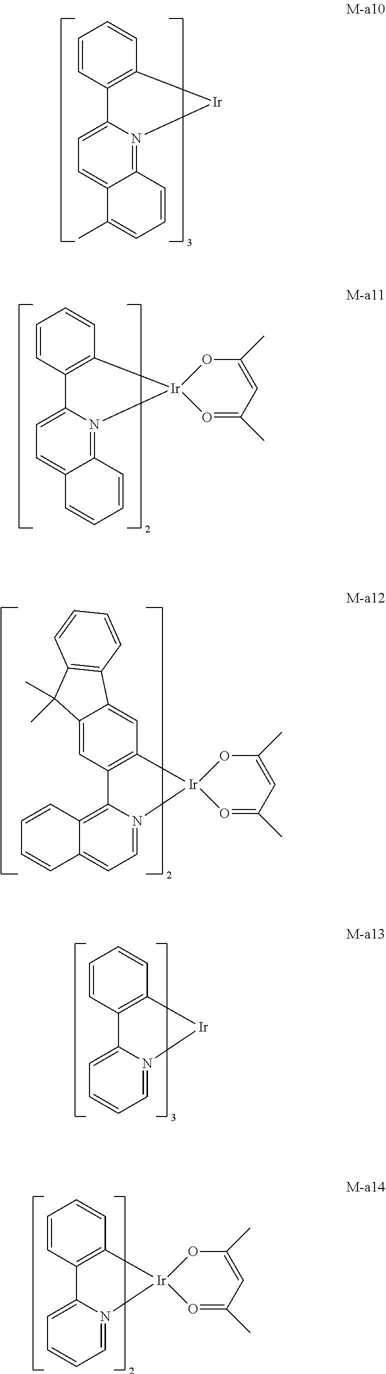

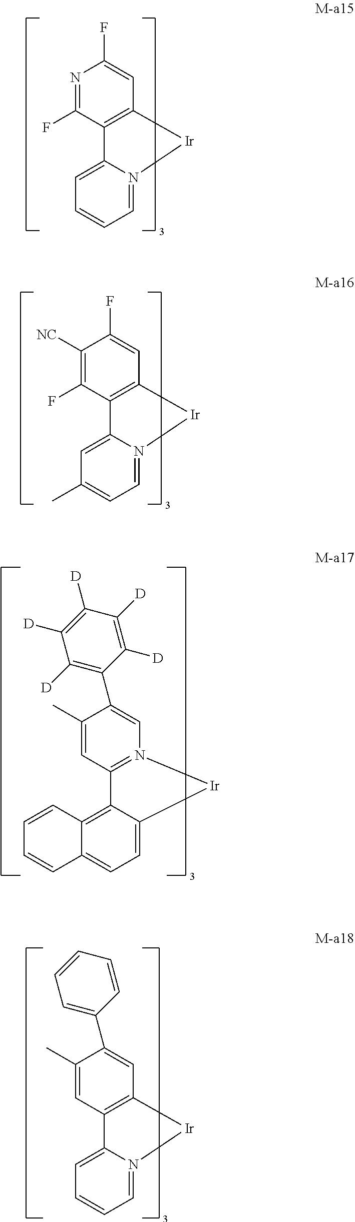

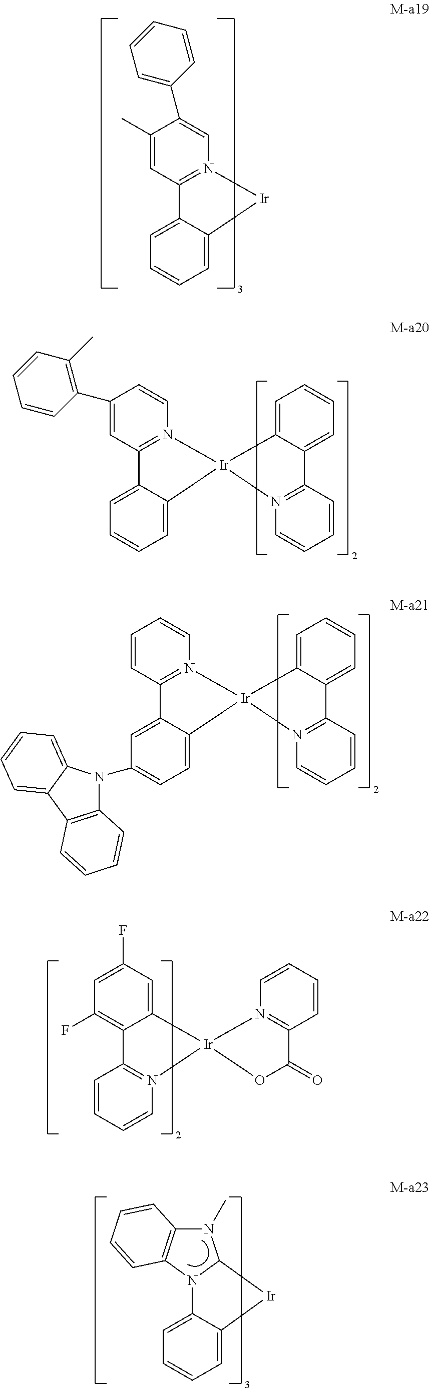

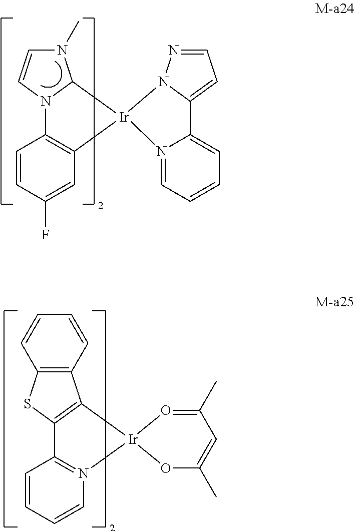

The emission layer EML may include a compound represented by one of Formula F-a to Formula F-c. The compound represented by one of Formula F-a to Formula F-c may be used as a fluorescence dopant material.

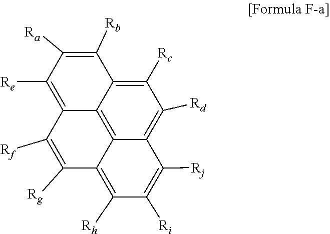

In Formula F-a, two of Rₐ to Rⱼ may each independently be substituted with a group represented by *—NAr₁Ar₂. The remainder of Rₐ to Rⱼ which are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In the group represented by *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

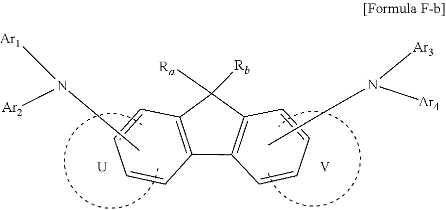

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. In Formula F-b, Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms. In an embodiment, in Formula F-b, least one of Ar₁ to Ar₄ may be a heteroaryl group containing O or S as a ring-forming atom.

In Formula F-b, the number of rings represented by U and V may each independently be 0 or 1. In Formula F-b, when the number of U or V is 1, a fused ring may be present at a portion indicated by U or V, and when the number of U or V is 0, a fused ring may not be present at a portion indicated by U or V. When the number of U is 0 and the number of V is 1, or when the number of U is 1 and the number of V is 0, a fused ring having a fluorene core of Formula F-b may be a cyclic compound having four rings. When the number of U and V is each 0, a fused ring having a fluorene core of Formula F-b may be a cyclic compound having three rings. When the number of U and V is each 1, a fused ring having a fluorene core of Formula F-b may be a cyclic compound having five rings.

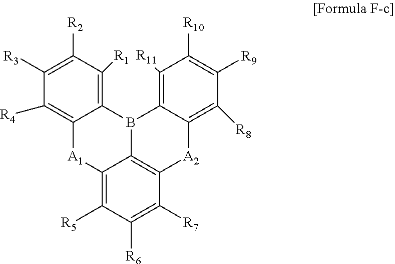

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring.

In Formula F-c, A₁ and A₂ may each independently be bonded to substituents of an adjacent ring to form a condensed ring. For example, when A₁ and A₂ are each independently N(Rₘ), A₁ may be bonded to R₄ or R₅ to form a ring. For example, A₂ may be bonded to R₇ or R₈ to form a ring.

In an embodiment, the emission layer EML may further include, as a dopant material of the related art, styryl derivatives (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and the derivatives thereof (e.g., 2,5,8,11-tetra-t-butylperylene (TBP)), pyrene and the derivatives thereof (e.g., 1,1-dipyrene, 1,4-dipyrenylbenzene, 1,4-bis(N,N-diphenylamino)pyrene), etc.

The emission layer EML may further include a phosphorescence dopant material of the related art. For example, a metal complex containing iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments are not limited thereto.

In embodiments, the emission layer EML may include a quantum dot. The quantum dot may be selected from a Group II-VI compound, a Group III-VI compound, a Group I-III-VI compound, a Group III-V compound, a Group III-II-V compound, a Group IV-VI compound, a Group IV element, a Group IV compound, or any combination thereof.

The Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof; or any combination thereof.

The Group III-VI compound may include: a binary compound such as In₂S₃ or In₂Se₃; a ternary compound such as InGaS₃ or InGaSe₃; or any combination thereof.

The Group I-III-VI compound may include: a ternary compound selected from the group consisting of AgInS, AgInS₂, CuInS, CuInS₂, AgGaS₂, CuGaS₂ CuGaO₂, AgGaO₂, AgAlO₂, and a mixture thereof; a quaternary compound such as AgInGaS₂ or CuInGaS₂; or any combination thereof.

The Group III-V compound may include: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; or any combination thereof. In an embodiment, the Group III-V compound may further include a Group II metal. For example, InZnP, etc. may be selected as a Group III-II-V compound.

The Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; or any combination thereof. The Group IV element may be Si, Ge, or a mixture thereof. The Group IV compound may include a binary compound selected from the group consisting of SiC, SiGe, or a mixture thereof.

A binary compound, a ternary compound, or a quaternary compound may be present in a particle at a uniform concentration distribution, or may be present in a particle at a partially different concentration distribution. In an embodiment, the quantum dot may have a core/shell structure in which one quantum dot surrounds another quantum dot. A quantum dot having a core/shell structure may have a concentration gradient in which the concentration of a material that is present in the shell decreases toward the core.

In embodiments, the quantum dot may have the above-described core/shell structure including a core containing nanocrystals and a shell surrounding the core. The shell of the quantum dot may serve as a protection layer to prevent the chemical deformation of the core to maintain semiconductor properties, and/or may serve as a charging layer to impart electrophoresis properties to the quantum dot. The shell may be a single layer or a multilayer. Examples of the shell of the quantum dot may include a metal oxide, a non-metal oxide, a semiconductor compound, or any combination thereof.

For example, the metal oxide or the non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound such as MgAl₂O₄, CoFe₂O₄, NiFe₂O₄, or CoMn₂O₄; or any combination thereof. However, embodiments are not limited thereto.

Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. When the quantum dot has a FWHM of an emission wavelength spectrum in any of the above ranges, color purity or color reproducibility may be improved. Light emitted through a quantum dot may be emitted in all directions, so that a wide viewing angle may be improved.

The form of the quantum dot is not limited, as long as it is any form that is used in the related art. For example, the quantum dot may have a spherical shape, a pyramidal shape, a multi-arm shape, or a cubic shape, or the quantum dot may be in the form of nanoparticles, nanotubes, nanowires, nanofibers, nanoplate particles, etc.

A quantum dot may control the color of emitted light according to a particle size thereof. Accordingly, the quantum dot may have various light emission colors such as green, red, etc.

In the light emitting device ED according to embodiments illustrated in FIGS. 3 to 6, the electron transport region ETR is provided on the emission layer EML. The electron transport region ETR may include at least one of a hole blocking layer HBL, an electron transport layer ETL, or an electron injection layer EIL, but embodiments are not limited thereto.

The electron transport region ETR may be a layer formed of a single material, a layer formed of different materials, or a structure including multiple layers formed of different materials.

For example, the electron transport region ETR may have a single layer structure of an electron injection layer EIL or an electron transport layer ETL, or may have a single layer structure formed of an electron injection material and an electron transport material. In other embodiments, the electron transport region ETR may have a single layer structure formed of different materials, or may have a structure in which an electron transport layer ETL/electron injection layer EIL, a hole blocking layer HBL/electron transport layer ETL/electron injection layer EIL are stacked in its respective stated order from the emission layer EML, but embodiments are not limited thereto. The electron transport region ETR may have a thickness, for example, in a range of about 1,000 Å to about 1,500 Å.

The electron transport region ETR may be formed by using various methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-1:

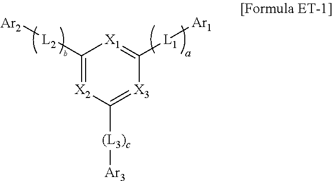

In Formula ET-1, at least one of X₁ to X₃ may each be N, and the remainder of X₁ to X₃ may each independently be C(Rₐ). In Formula ET-1, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-1, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula ET-1, when a to c are each 2 or more, multiple groups of each of L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), berylliumbis(benzoquinolin-10-olate (Bebq₂), 9,10-di(naphthalene-2-yl)anthracene (ADN), 1,3-Bis[3,5-di(pyridin-3-yl)phenyl]benzene (BmPyPhB), or a mixture thereof.

In an embodiment, the electron transport region ETR may include at least one compound selected from Compound ET1 to Compound ET36:

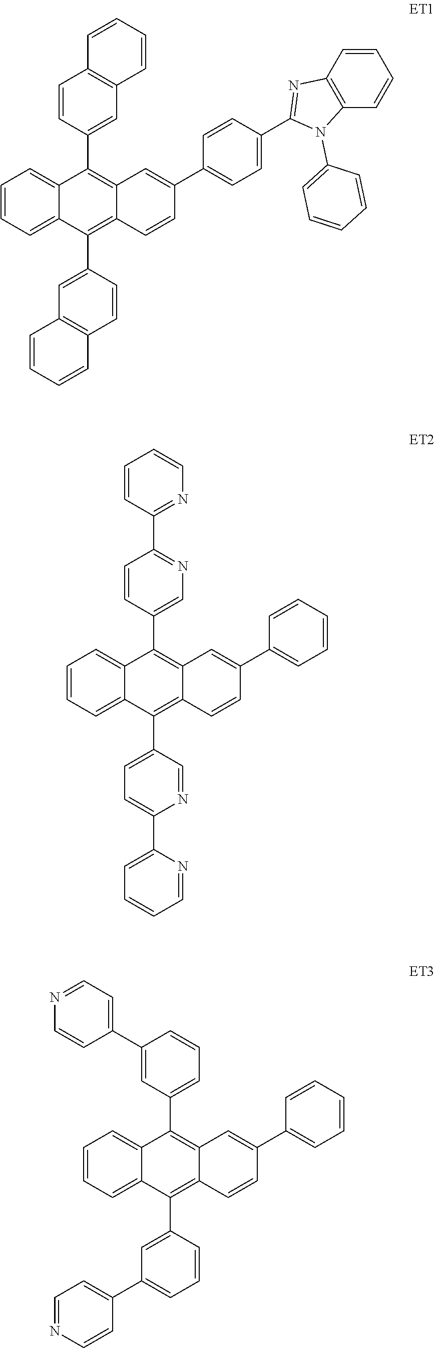 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

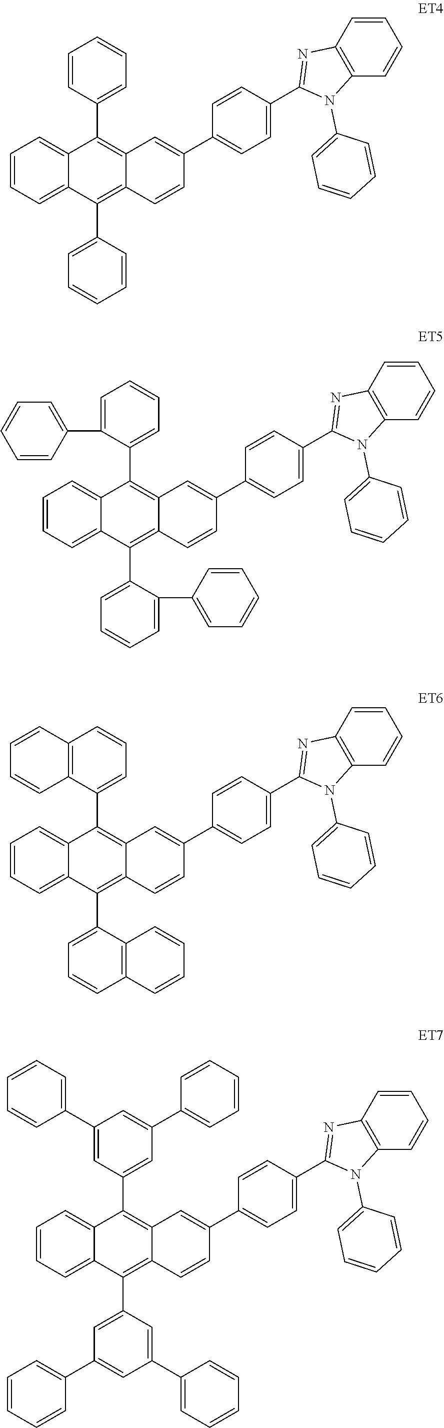 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

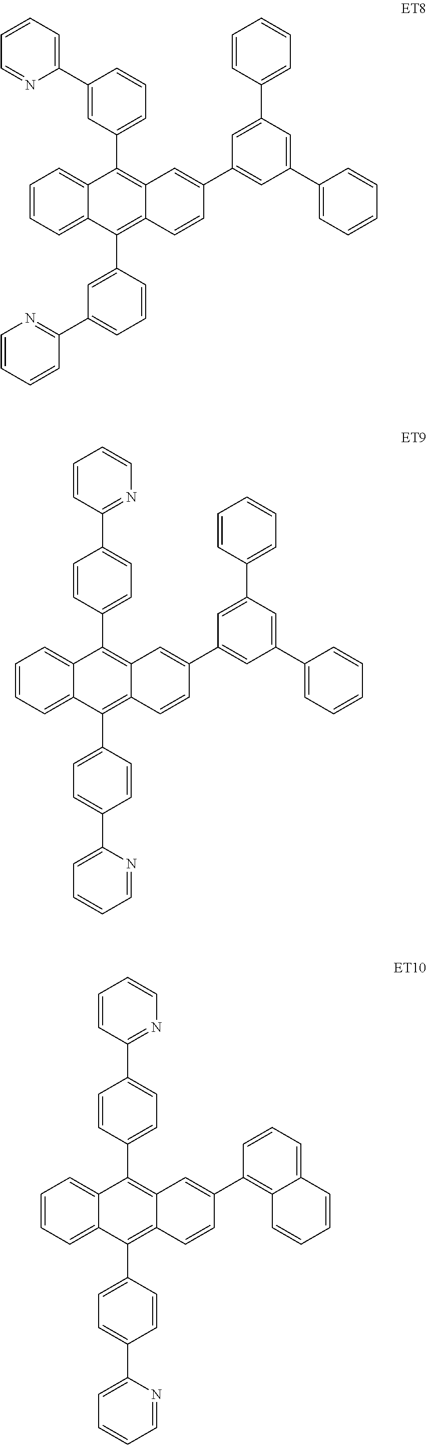 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

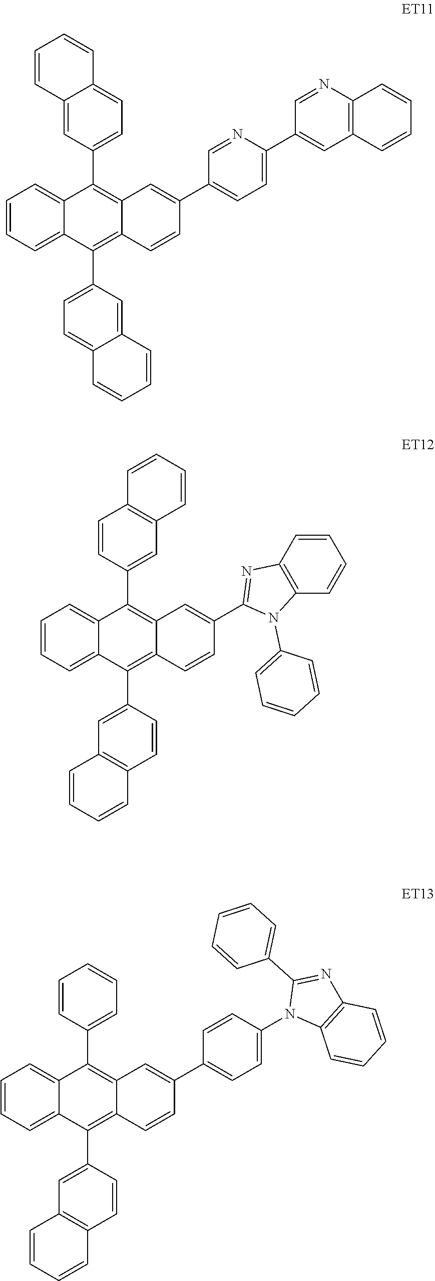 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

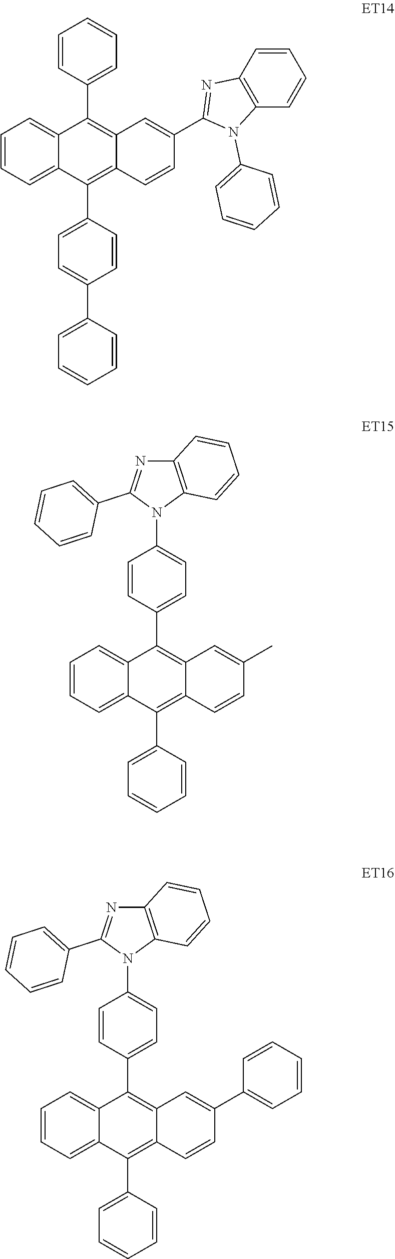 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

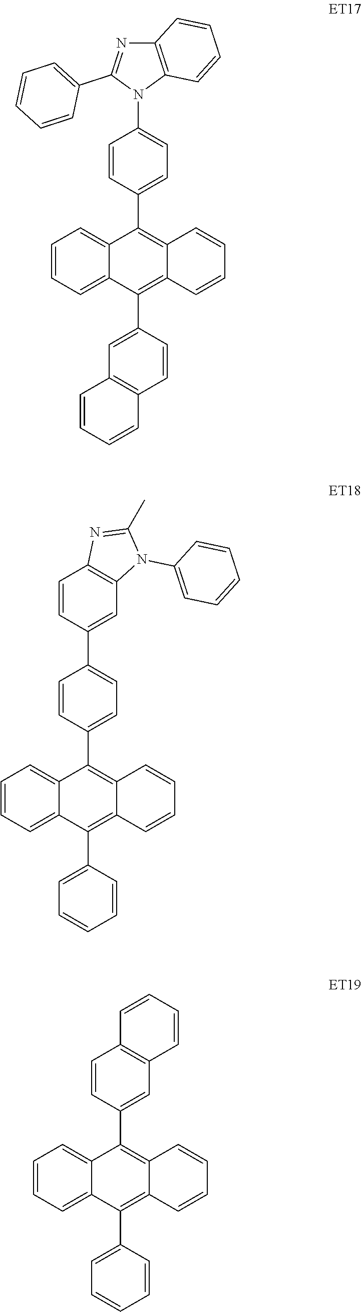

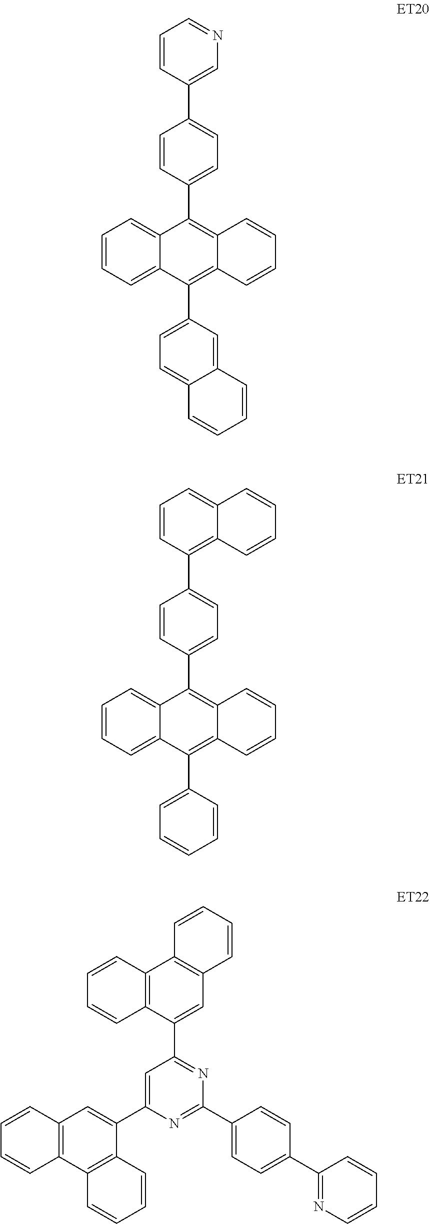

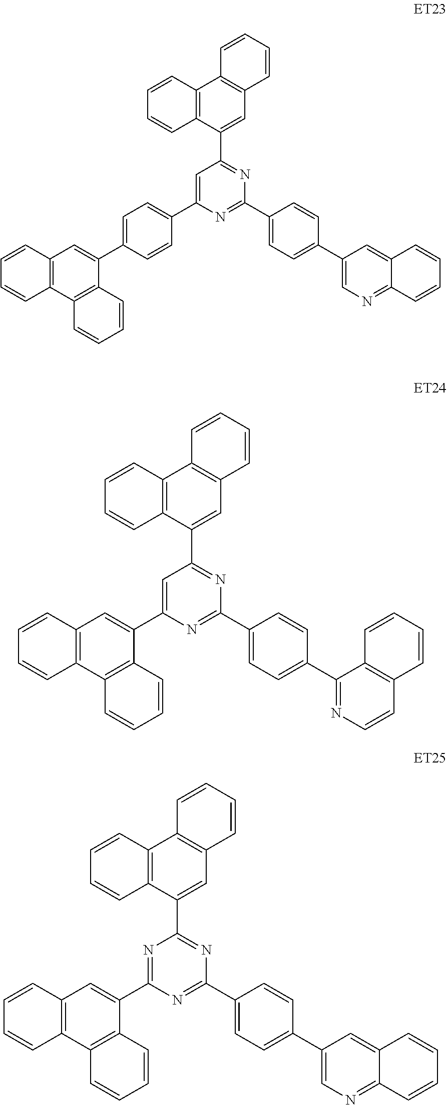 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

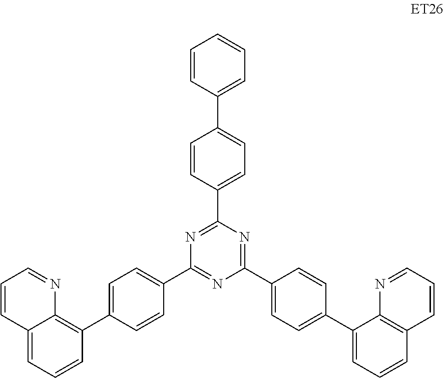 [SMILES: c1ccc(-c2ccc(-c3nc(-c4ccc(-c5cccc6cccnc56)cc4)nc(-c4ccc(-c5cccc6cccnc56)cc4)n3)cc2)cc1]

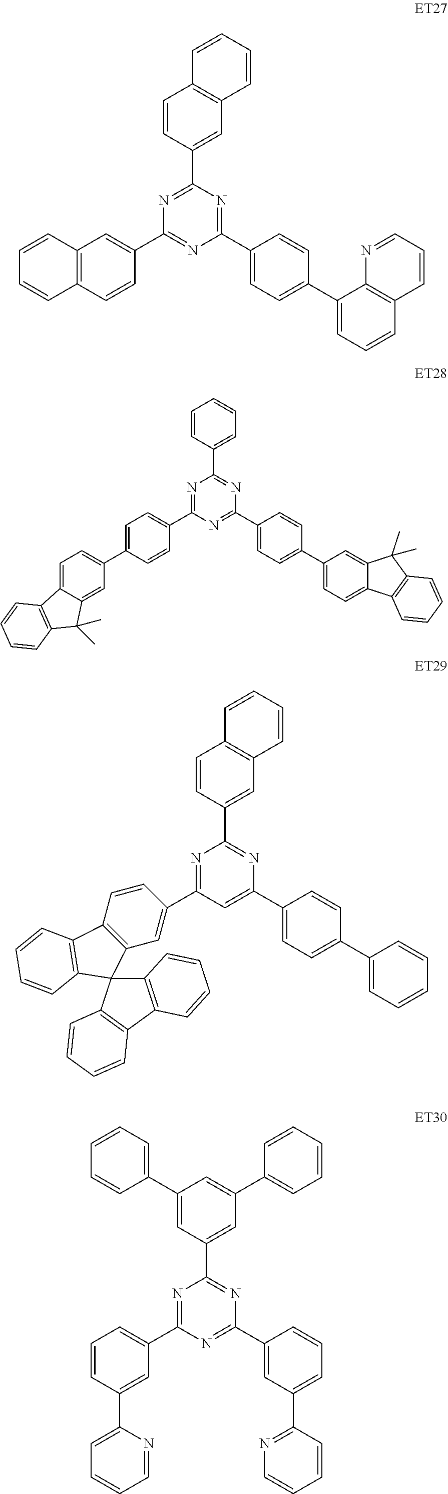 [SMILES: c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

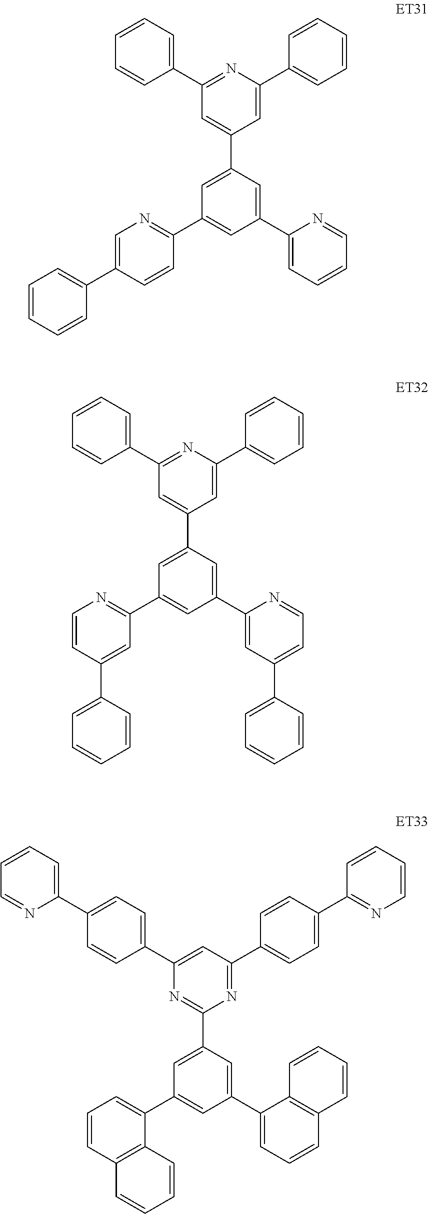 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

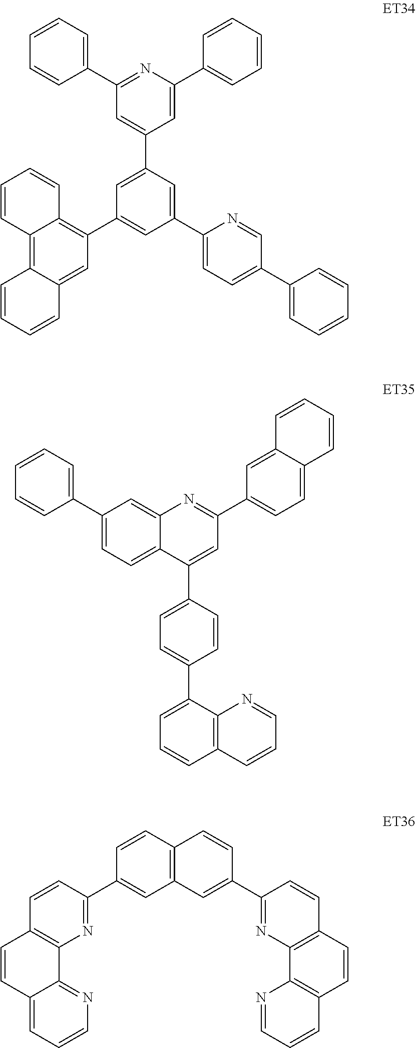 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

The electron transport region ETR may include: a metal halide such as LiF, NaCl, CsF, RbCl, RbI, CuI, or KI; a lanthanide metal such as Yb; or a co-deposited material of the metal halide and the lanthanide metal. For example, the electron transport region ETR may include KI:Yb, RbI:Yb, LiF:Yb, etc. as a co-deposited material. The electron transport region ETR may be formed of a metal oxide such as Li₂O or BaO, or 8-hydroxyl-lithium quinolate (Liq), etc., but embodiments are not limited thereto. The electron transport region ETR may also be formed of a mixture material of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but embodiments are not limited thereto.

The electron transport region ETR may include the above-described compounds of the electron transport region in at least one of an electron injection layer EIL, an electron transport layer ETL, or a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgAg). In another embodiment, the second electrode EL2 may have a multilayer structure including a reflective layer or a transflective layer formed of the above-described materials, and a transparent conductive layer formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, the resistance of the second electrode EL2 may decrease.

In an embodiment, the light emitting device ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL contains an inorganic material, the inorganic material may include an alkaline metal compound (for example, LiF), an alkaline earth metal compound (for example, MgF₂), SiON, SiNₓ, SiOy, etc.

For example, when the capping layer CPL contains an organic material, the organic material may include 2,2′-dimethyl-N,N′-di-[(1-naphthyl)-N,N′-diphenyl]-1,1′-biphenyl-4,4′-diamine (a-NPD), NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or may include an epoxy resin, or an acrylate such as a methacrylate. However, embodiments are not limited thereto, and the capping layer CPL may include at least one of Compounds P1 to P5:

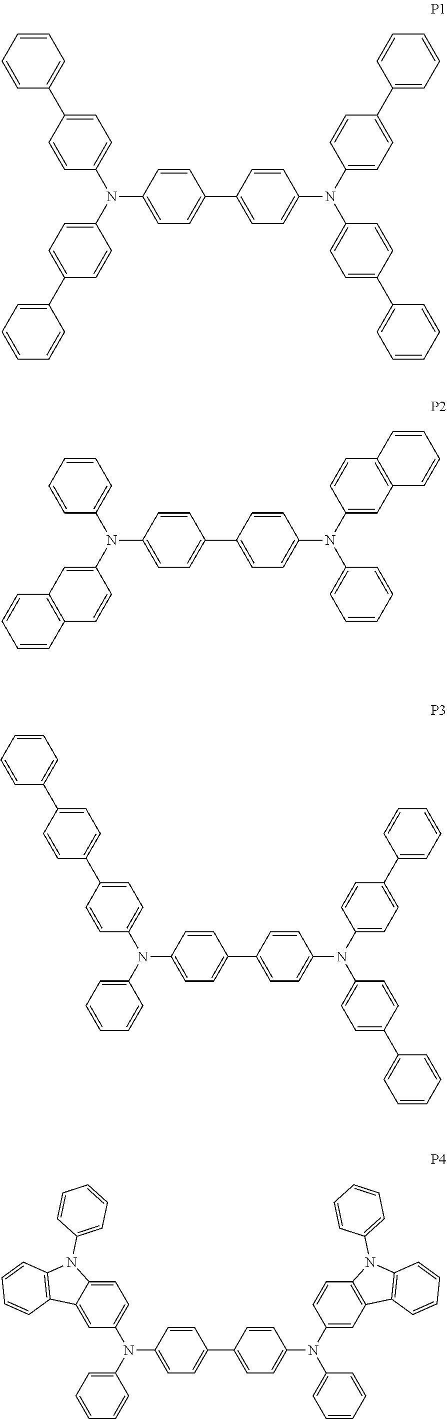 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

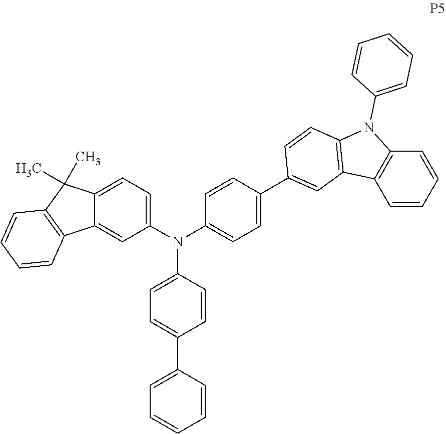 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, the refractive index of the capping layer CPL may be equal to or greater than about 1.6 with respect to light in a wavelength range of about 550 nm to about 660 nm.

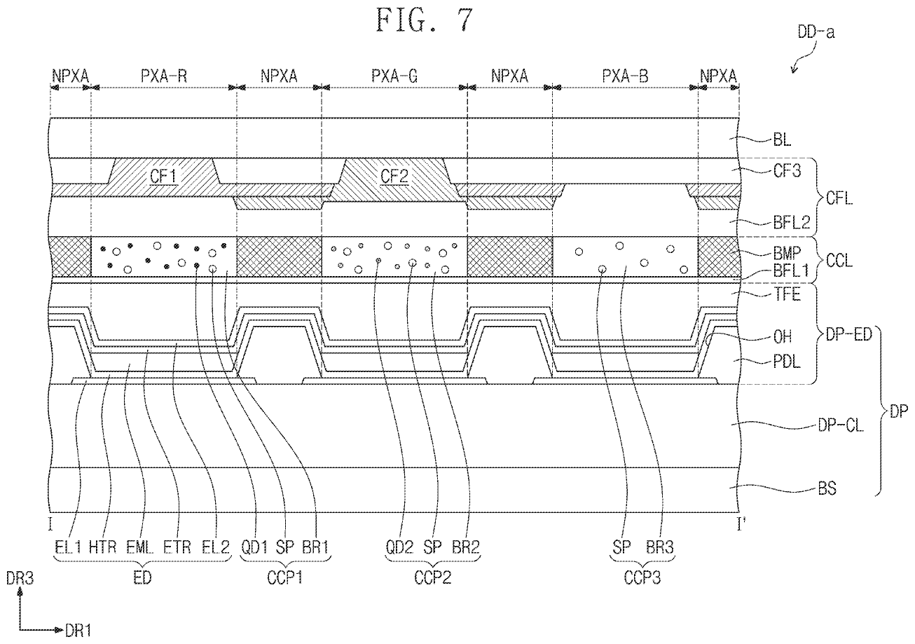

FIGS. 7 to 10 are each a schematic cross-sectional view of a display apparatus according to embodiments. Hereinafter, in describing the display apparatuses according to embodiments with reference to FIGS. 7 to 10, the features which have been described above with respect to FIGS. 1 to 6 will not be explained again, and the differing features will be described.

Referring to FIG. 7, a display apparatus DD-a according to an embodiment may include a display panel DP including a display apparatus layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and the display device layer DP-ED, and the display device layer DP-ED may include a light emitting device ED.

The light emitting device ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting device ED shown in FIG. 7 may be the same as a structure of a light emitting device according to one of FIGS. 3 to 6 as described herein.

The emission layer EML of the light emitting device ED included in the display apparatus DD-a according to an embodiment may include the above-described fused polycyclic compound according to embodiments.

Referring to FIG. 7, the emission layer EML may be disposed in an opening OH defined in a pixel defining film PDL. For example, the emission layer EML, which is separated by the pixel defining film PDL and provided corresponding to each of the light emitting regions PXA-R, PXA-G, and PXA-B, may each emit light in a same wavelength range. In the display apparatus DD-a, the emission layer EML may emit blue light. Although not shown in the drawings, in an embodiment, the emission layer EML may be provided as a common layer for all of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and may emit the resulting light. For example, the light control layer CCL may be a layer including a quantum dot or a layer including a phosphor.

The light control layer CCL may include light control parts CCP1, CCP2, and CCP3. The light control parts CCP1, CCP2, and CCP3 may be spaced apart from each other.

Referring to FIG. 7, divided patterns BMP may be disposed between the light control parts CCP1, CCP2, and CCP3, which are spaced apart from each other, but embodiments are not limited thereto. In FIG. 7, it is shown that the divided patterns BMP do not overlap the light control parts CCP1, CCP2, and CCP3, but at least a portion of the edges of the light control parts CCP1, CCP2, and CCP3 may overlap the divided patterns BMP.

The light control layer CCL may include a first light control part CCP1 containing a first quantum dot QD1 which converts first color light provided from the light emitting device ED into second color light, a second light control part CCP2 containing a second quantum dot QD2 which converts the first color light into third color light, and a third light control part CCP3 which transmits the first color light.

In an embodiment, the first light control part CCP1 may provide red light that is the second color light, and the second light control part CCP2 may provide green light that is the third color light. The third light control part CCP3 may provide blue light by transmitting the blue light that is the first color light provided from the light emitting device ED. For example, the first quantum dot QD1 may be a red quantum dot, and the second quantum dot QD2 may be a green quantum dot. The quantum dots QD1 and QD2 may each be a quantum dot as described herein.

The light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include any quantum dot but may include the scatterer SP.

The scatterer SP may be an inorganic particle. For example, the scatterer SP may include at least one of TiO₂, ZnO, Al₂O₃, SiO₂, or hollow silica. The scatterer SP may include any one of TiO₂, ZnO, Al₂O₃, SiO₂, and hollow silica, or the scatterer SP may be a mixture of at least two materials selected from TiO₂, ZnO, Al₂O₃, SiO₂, and hollow silica.

The first light control part CCP1, the second light control part CCP2, and the third light control part CCP3 may each include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3. The base resins BR1, BR2, and BR3 are media in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may be disposed on the light control parts CCP1, CCP2, and CCP3 to block the light control parts CCP1, CCP2 and CCP3 from exposure to moisture/oxygen. The barrier layer BFL1 may cover the light control parts CCP1, CCP2, and CCP3. A barrier layer BFL2 may be provided between the light control parts CCP1, CCP2, and CCP3 and the color filter layer CFL.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. The barrier layers BFL1 and BFL2 may each independently further include an organic layer. The barrier layers BFL1 and BFL2 may each independently be formed of a single layer or of multiple layers.

In the display apparatus DD-a according to an embodiment, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include a light shielding part (not shown) and color filters CF1, CF2, and CF3. The color filter layer CFL may include a first filter CF1 that transmits the second color light, a second filter CF2 that transmits the third color light, and a third filter CF3 that transmits the first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye. However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated but may be provided as one filter.

The light shielding part (not shown) may be a black matrix. The light shielding part (not shown) may include an organic light shielding material or an inorganic light shielding material containing a black pigment or dye. The light shielding part (not shown) may prevent light leakage, and may separate boundaries between adjacent filters CF1, CF2, and CF3. In an embodiment, the light shielding part (not shown) may be formed of a blue filter.

The first to third filters CF1, CF2, and CF3 may be disposed to respectively correspond to the red light emitting region PXA-R, the green light emitting region PXA-G, and the blue light emitting region PXA-B.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

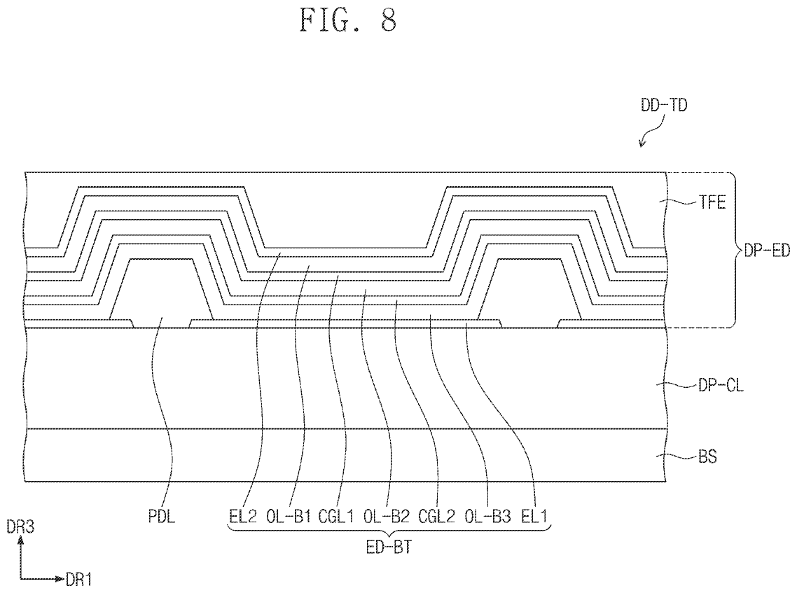

FIG. 8 is a schematic cross-sectional view illustrating a portion of the display apparatus DD-a according to an embodiment. In the display apparatus DD-TD according to an embodiment, the light emitting device ED-BT may include light emitting structures OL-B1, OL-B2, and OL-B3. The light emitting device ED-BT may include a first electrode EL1 and a second electrode EL2 which face each other, and the light emitting structures OL-B1, OL-B2, and OL-B3 stacked in a thickness direction between the first electrode EL1 and the second electrode EL2. The light emitting structures OL-B1, OL-B2, and OL-B3 may each include an emission layer EML (FIG. 7) and a hole transport region HTR and an electron transport region ETR disposed with the emission layer EML (FIG. 7) located therebetween.

For example, the light emitting device ED-BT included in the display apparatus DD-TD may be a light emitting device having a tandem structure and including multiple emission layers.

In an embodiment illustrated in FIG. 8, light emitted from each of the light emitting structures OL-B1, OL-B2, and OL-B3 may be blue light. However, embodiments are not limited thereto, and the light emitted from each of the light emitting structures OL-B1, OL-B2, and OL-B3 may have wavelength ranges that are different from each other. For example, the light emitting device ED-BT including the light emitting structures OL-B1, OL-B2, and OL-B3 which emit light having wavelength ranges that are different from each other may emit white light.

Charge generation layers CGL1 and CGL2 may be disposed between neighboring light emitting structures OL-B1, OL-B2, and OL-B3. Charge generation layers CGL1 and CGL2 may each independently include a p-type charge generation layer and/or an n-type charge generation layer.

At least one among the light emitting structures OL-B1, OL-B2, and OL-B3 included in the display apparatus DD-TD may include the above-described fused polycyclic compound according to an embodiment. For example, at least one of the emission layers included in the light emitting device ED-BT may include the fused polycyclic compound.

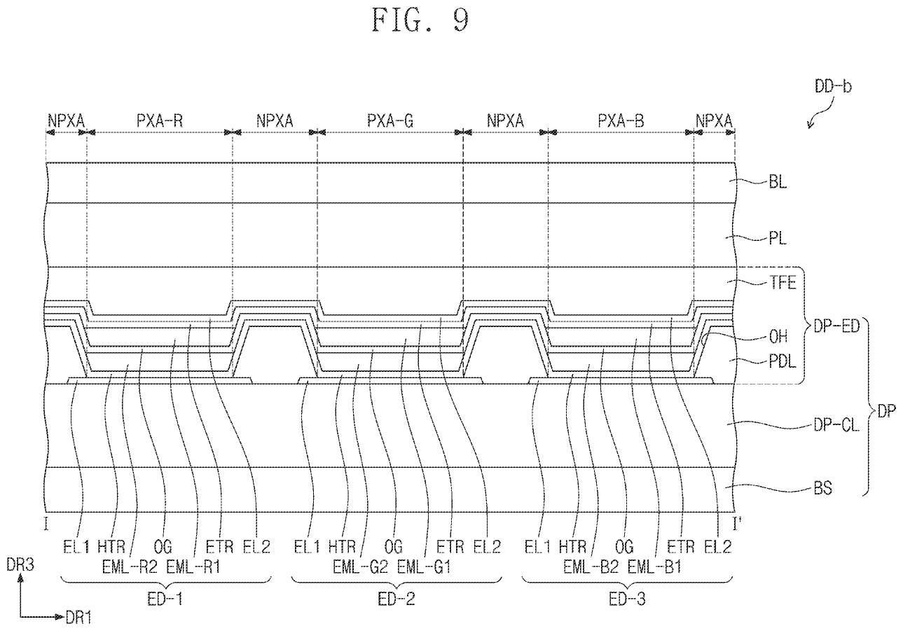

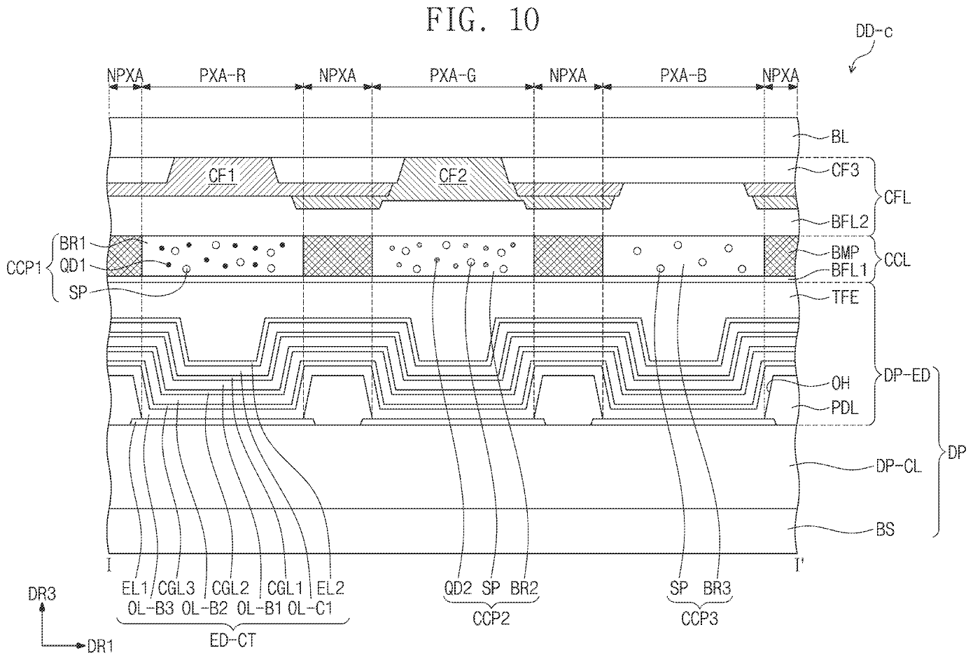

FIG. 9 is a schematic cross-sectional view illustrating a display apparatus DD-b according to an embodiment. FIG. 10 is a schematic cross-sectional view illustrating a display apparatus DD-c according to an embodiment.

Referring to FIG. 9, the display apparatus DD-b according to an embodiment may include light emitting devices ED-1, ED-2, and ED-3 which may each include two emission layers that are stacked. In comparison to the display apparatus DD illustrated in FIG. 2, the embodiment illustrated in FIG. 9 is different at least in that the first to third light emitting devices ED-1, ED-2, and ED-3 each include two emission layers that are stacked in a thickness direction. In each of the first to third light emitting devices ED-1, ED-2, and ED-3, the two emission layers may emit light in a same wavelength region.

The first light emitting device ED-1 may include a first red emission layer EML-R1 and a second red emission layer EML-R2. The second light emitting device ED-2 may include a first green emission layer EML-G1 and a second green emission layer EML-G2. The third light emitting device ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generation layer. For example, the emission auxiliary part OG may include an electron transport region, a charge generation layer, and a hole transport region that are which may be stacked in that order. The emission auxiliary part OG may be provided as a common layer for all of the first to third light emitting devices ED-1, ED-2, and ED-3. However, embodiments are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may each be disposed between the electron transport region ETR and the emission auxiliary part OG. The second red emission layer EML-R2, the second green emission layer EML-G2, and the second blue emission layer EML-B2 may each be disposed between the emission auxiliary part OG and the hole transport region HTR.

For example, the first light emitting device ED-1 may include the first electrode EL1, the hole transport region HTR, the second red emission layer EML-R2, the emission auxiliary part OG, the first red emission layer EML-R1, the electron transport region ETR, and the second electrode EL2 that are stacked in that order. The second light emitting device ED-2 may include the first electrode EL1, the hole transport region HTR, the second green emission layer EML-G2, the emission auxiliary part OG, the first green emission layer EML-G1, the electron transport region ETR, and the second electrode EL2 that are stacked in that order. The third light emitting device ED-3 may include the first electrode EL1, the hole transport region HTR, the second blue emission layer EML-B2, the emission auxiliary part OG, the first blue emission layer EML-B1, the electron transport region ETR, and the second electrode EL2 that are stacked in that order.

An optical auxiliary layer PL may be disposed on the display device layer DP-ED. The optical auxiliary layer PL may include a polarizing layer. The optical auxiliary layer PL may be disposed on the display panel DP and may control light reflected at the display panel DP from an external light. Although not shown in the drawings, in an embodiment, the optical auxiliary layer PL may be omitted from the display apparatus DD-b.

At least one emission layer included in the display apparatus DD-b illustrated in FIG. 9 may include the above-described fused polycyclic compound according to an embodiment. For example, in an embodiment, at least one of the first blue emission layer EML-B1 or the second blue emission layer may include the fused polycyclic compound according to an embodiment.

In contrast to FIGS. 8 and 9, FIG. 10 illustrates a display apparatus DD-c that is different at least in that it includes four light emitting structures OL-B1, OL-B2, OL-B3, and OL-C1. A light emitting device ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may be disposed between the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may each emit light in different wavelength regions.

The charge generation layers CGL1, CGL2, and CGL3 which are disposed between adjacent light emitting structures OL-B1, OL-B2, OL-B3, and OL-C1 may each independently include a p-type charge generation layer and/or an n-type charge generation layer.

In the display apparatus DD-c, at least one of the light emitting structures OL-B1, OL-B2, OL-B3, and OL-C1 may include the fused polycyclic compound according to embodiments. For example, in an embodiment, at least one of the first to third light emitting structures OL-B1, OL-B2, and OL-B3 may include the above-described fused polycyclic compound.

Hereinafter, a fused polycyclic compound according to an embodiment and a light emitting device according to an embodiment will be described in detail with reference to the Examples and the Comparative Examples. The Examples described below are only provided as illustrations to assist in understanding the disclosure, and the scope thereof is not limited thereto.

### Examples

1. Synthesis of Fused Polycyclic Compound

A synthesis method of the fused polycyclic compound according to an embodiment will be explained in detail with reference to the synthesis methods of Compounds 8, 14, 32, 42, 97, and 98. The synthesis methods of the fused polycyclic compounds explained below are provided only as examples, and the synthesis method of the fused polycyclic compound according to an embodiment is not limited to the Examples below.

(1) Synthesis of Compound 8

Compound 8 according to an example may be synthesized, for example, by the reaction below:

(Synthesis of Intermediate 8-1)

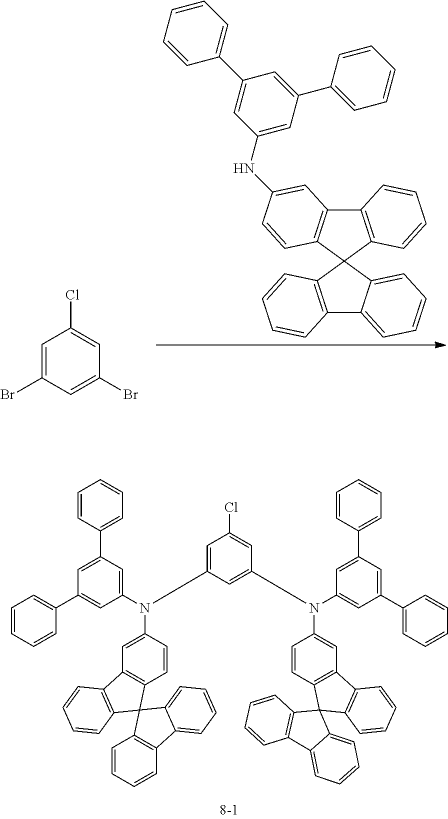 [SMILES: Clc1cc(Br)cc(Br)c1 ; c1ccc(-c2cc(Nc3ccc4c(c3)-c3ccccc3C43c4ccccc4-c4ccccc43)cc(-c3ccccc3)c2)cc1 ; Clc1cc(N(c2cc(-c3ccccc3)cc(-c3ccccc3)c2)c2ccc3c(c2)-c2ccccc2C32c3ccccc3-c3ccccc32)cc(N(c2cc(-c3ccccc3)cc(-c3ccccc3)c2)c2ccc3c(c2)-c2ccccc2C32c3ccccc3-c3ccccc32)c1]

1,3-dibromo-5-chlorobenzene (1 eq), N-([1,1′:3′,1″-terphenyl]-5′-yl)-9,9′-spirobi[fluoren]-3-amine (2 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 100° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using methylene chloride and n-hexane to obtain Intermediate 8-1. (yield: 81%)

(Synthesis of Intermediate 8-2)

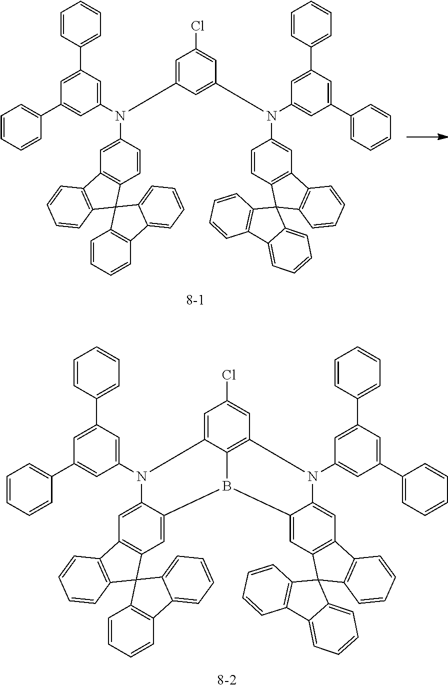 [SMILES: Clc1cc(N(c2cc(-c3ccccc3)cc(-c3ccccc3)c2)c2ccc3c(c2)-c2ccccc2C32c3ccccc3-c3ccccc32)cc(N(c2cc(-c3ccccc3)cc(-c3ccccc3)c2)c2ccc3c(c2)-c2ccccc2C32c3ccccc3-c3ccccc32)c1 ; Clc1cc2c3c(c1)N(c1cc(-c4ccccc4)cc(-c4ccccc4)c1)c1cc4c(cc1B3c1cc3c(cc1N2c1cc(-c2ccccc2)cc(-c2ccccc2)c1)-c1ccccc1C31c2ccccc2-c2ccccc21)C1(c2ccccc2-c2ccccc21)c1ccccc1-4]

Intermediate 8-1 (1 eq) was dissolved in ortho dichlorobenezene, the mixture was cooled to about 0° C., and BBr₃ (3 eq) was slowly injected thereto in a nitrogen atmosphere. After dropping was completed, the temperature was elevated to 180° C., and the mixture was stirred for 24 hours. After cooling, the reaction was terminated by dropping triethylamine slowly in the flask containing the reactant, and ethyl alcohol was added to the reactant, and extracted and filtered to obtain solids. The obtained solids were purified by column chromatography using methylene chloride and n-hexane, and were subjected to recrystallization using toluene and acetone to obtain Intermediate 8-2. (yield: 11%)

(Synthesis of Compound 8)

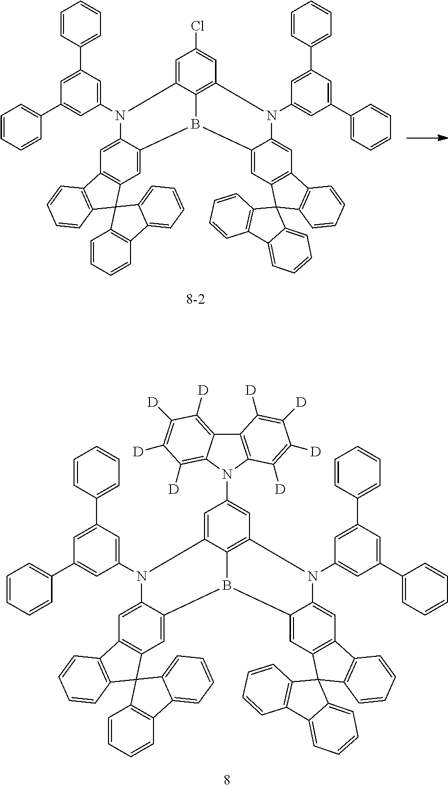 [SMILES: Clc1cc2c3c(c1)N(c1cc(-c4ccccc4)cc(-c4ccccc4)c1)c1cc4c(cc1B3c1cc3c(cc1N2c1cc(-c2ccccc2)cc(-c2ccccc2)c1)-c1ccccc1C31c2ccccc2-c2ccccc21)C1(c2ccccc2-c2ccccc21)c1ccccc1-4 ; [2H]c1c([2H])c([2H])c2c(c1[2H])c1c([2H])c([2H])c([2H])c([2H])c1n2-c1cc2c3c(c1)N(c1cc(-c4ccccc4)cc(-c4ccccc4)c1)c1cc4c(cc1B3c1cc3c(cc1N2c1cc(-c2ccccc2)cc(-c2ccccc2)c1)-c1ccccc1C31c2ccccc2-c2ccccc21)C1(c2ccccc2-c2ccccc21)c1ccccc1-4]

Intermediate 8-2 (1 eq), carbazole-D8 (1.2 eq), tris(dibenzylideneacetone)dipalladium(0) (0.05 eq), tri-tert-butylphosphine (0.1 eq), and sodium tert-butoxide (3 eq) were dissolved in o-xylene, and the resultant mixture was stirred at about 140° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using methylene chloride and n-hexane to obtain Compound 8. (yield: 53%)

(2) Synthesis of Compound 14

Compound 14 according to an example may be synthesized by, for example, the reaction below:

(Synthesis of Intermediate 14-1)

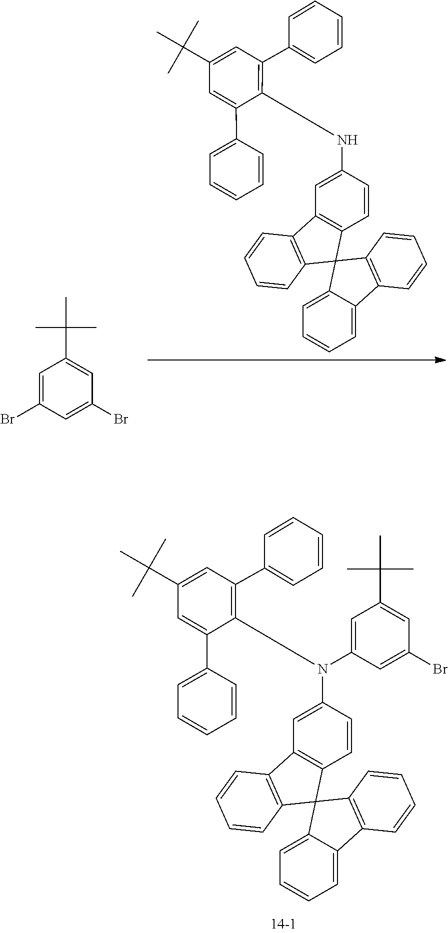 [SMILES: CC(C)(C)c1cc(Br)cc(Br)c1 ; CC(C)(C)c1cc(-c2ccccc2)c(Nc2ccc3c(c2)-c2ccccc2C32c3ccccc3-c3ccccc32)c(-c2ccccc2)c1 ; CC(C)(C)c1cc(Br)cc(N(c2ccc3c(c2)-c2ccccc2C32c3ccccc3-c3ccccc32)c2c(-c3ccccc3)cc(C(C)(C)C)cc2-c2ccccc2)c1]

1,3-dibromo-5-(tert-butyl)benzene (1 eq), N-(5′-(tert-butyl)-[1,1′:3′,1″-terphenyl]-2′-yl)-9,9′-spirobi[fluoren]-3-amine (1 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 100° C. for about 5 hours. After cooling, the mixture was washed three times with ethyl acetate and water, and separated to obtain an organic layer. The obtained organic layer was dried over MgSO₄, and dried under reduced pressure. The resulting product was purified by column chromatography using methylene chloride and n-hexane to obtain Intermediate 14-1. (yield: 51%)

(Synthesis of Intermediate 14-2)

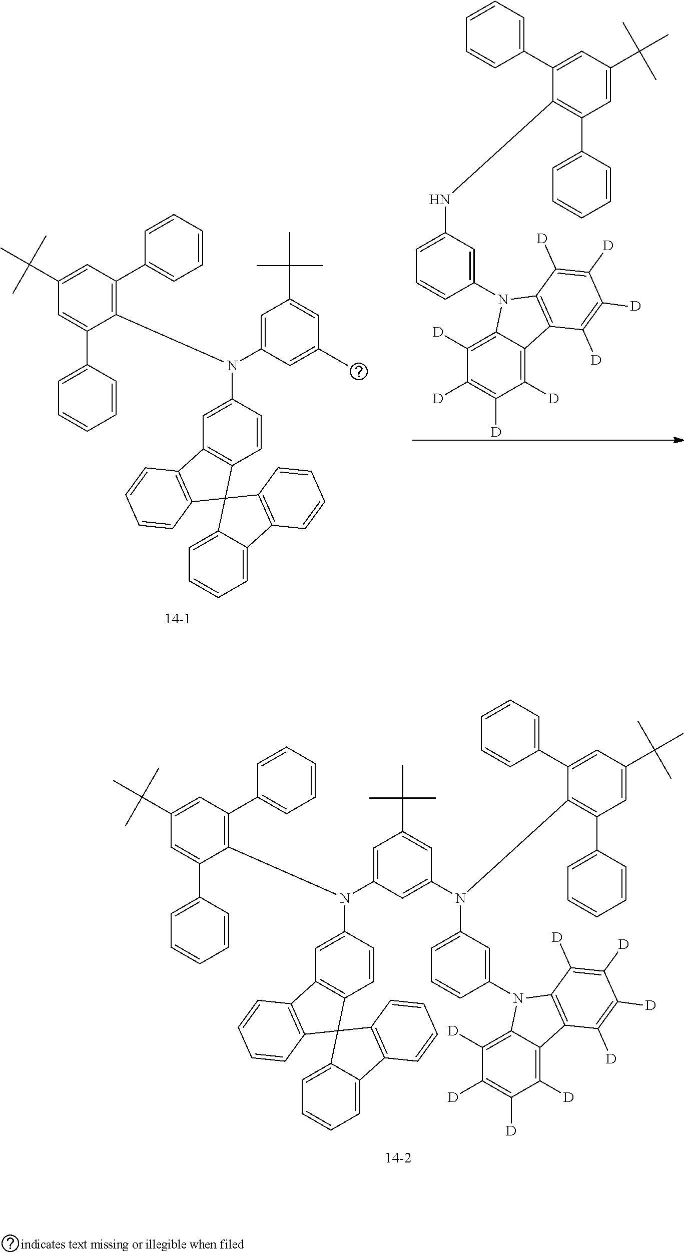 [SMILES: Cc1cc(N(c2ccc3c(c2)-c2ccccc2C32c3ccccc3-c3ccccc32)c2c(-c3ccccc3)cc(C(C)(C)C)cc2-c2ccccc2)cc(C(C)(C)C)c1 ; [2H]c1c([2H])c([2H])c2c(c1[2H])c1c([2H])c([2H])c([2H])c([2H])c1n2-c1cccc(Nc2c(-c3ccccc3)cc(C(C)(C)C)cc2-c2ccccc2)c1 ; [2H]c1c([2H])c([2H])c2c(c1[2H])c1c([2H])c([2H])c([2H])c([2H])c1n2-c1cccc(N(c2cc(N(c3ccc4c(c3)-c3ccccc3C43c4ccccc4-c4ccccc43)c3c(-c4ccccc4)cc(C(C)(C)C)cc3-c3ccccc3)cc(C(C)(C)C)c2)c2c(-c3ccccc3)cc(C(C)(C)C)cc2-c2ccccc2)c1]

Intermediate 14-1 (1 eq), N-(3-(9H-carbazol-9-yl-D8)phenyl)-5′-(tert-butyl)-[1,1′:3′,1″-terphenyl]-2′-amine (1.1 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 100° C. for about 6 hours. After cooling, the mixture was washed three times with ethyl acetate and water, and separated to obtain an organic layer. The obtained organic layer was dried over MgSO₄, and dried under reduced pressure. The resulting product was purified by column chromatography using methylene chloride and n-hexane to obtain Intermediate 14-2. (yield: 74%)

(Synthesis of Compound 14)

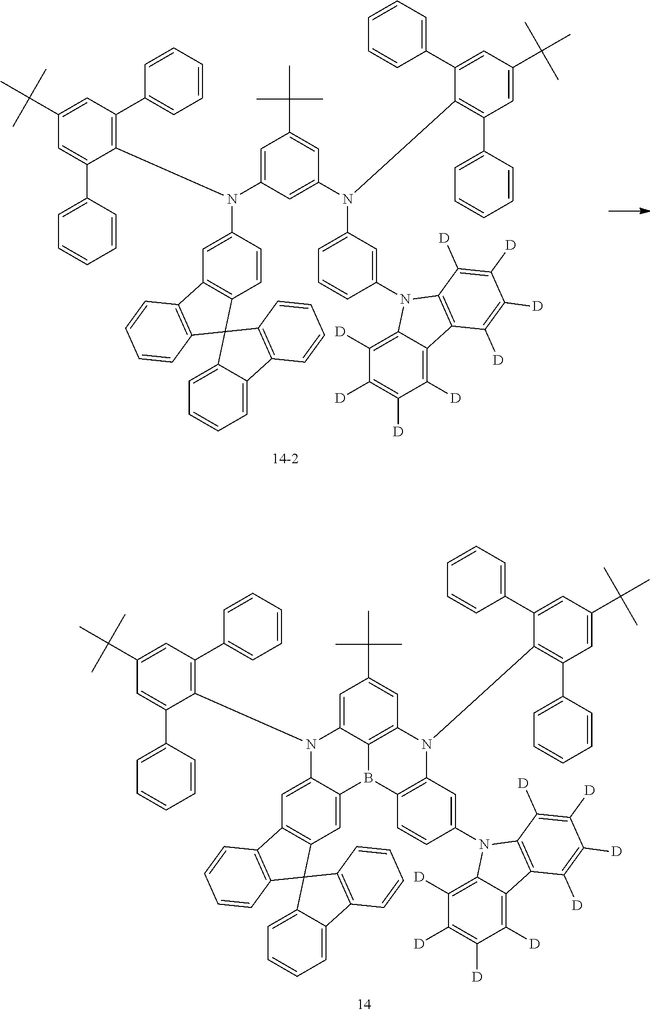

Intermediate 14-2 (1 eq) was dissolved in ortho dichlorobenezene, the mixture was cooled to about 0° C., and BBr₃ (2.5 eq) was slowly injected thereto in a nitrogen atmosphere. After dropping was completed, the temperature was elevated to 180° C., and the mixture was stirred for 24 hours. After cooling, the reaction was terminated by dropping triethylamine slowly in the flask containing the reactant, and ethyl alcohol was added to the reactant, and extracted and filtered to obtain solids. The obtained solids were purified by column chromatography using methylene chloride and n-hexane, and were subjected to recrystallization using toluene and acetone to obtain Compound 14. (yield: 18%)

(3) Synthesis of Compound 32

Compound 32 according to an example may be synthesized by, for example, the reaction below:

(Synthesis of Intermediate 32-1)

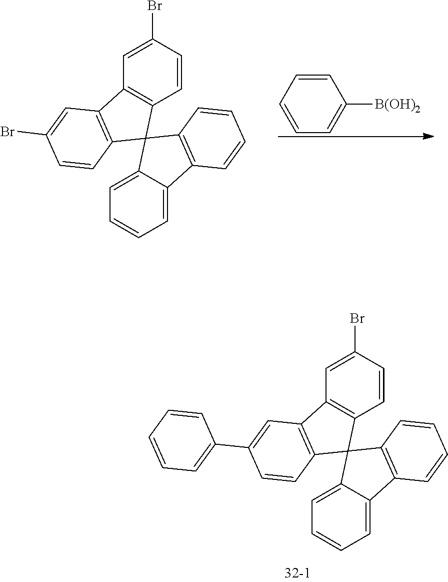 [SMILES: Brc1ccc2c(c1)-c1cc(Br)ccc1C21c2ccccc2-c2ccccc21 ; OB(O)c1ccccc1 ; Brc1ccc2c(c1)-c1cc(-c3ccccc3)ccc1C21c2ccccc2-c2ccccc21]

3,6-dibromo-9,9′-spirobi[fluorene] (1 eq), phenylboronic acid (1 eq), Pd(PPh₃)₄ (0.05 eq), and K₂CO₃ (3 eq) were dissolved in a mixed solution of water and THF (2:1), and the resultant mixture was stirred at about 80° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using methylene chloride and n-hexane to obtain Intermediate 32-1. (yield: 51%)

(Synthesis of Intermediate 32-2)

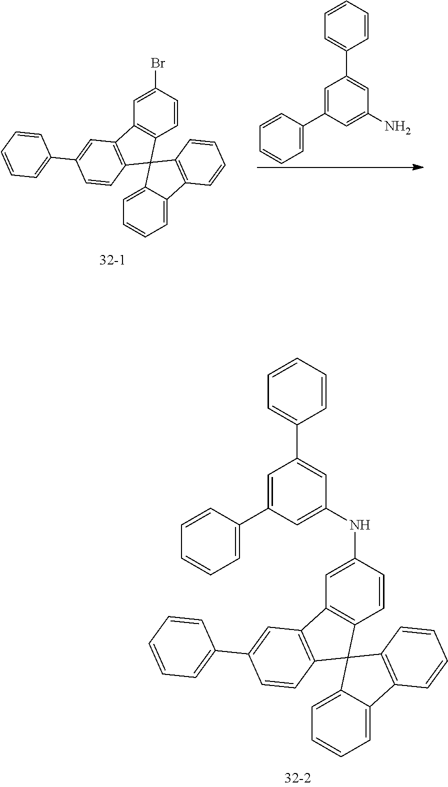

Intermediate 32-1 (1 eq), [1,1′:3′,1″-terphenyl]-5′-amine (1.1 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 100° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using methylene chloride and n-hexane to obtain Intermediate 32-2. (yield: 65%)

(Synthesis of Intermediate 32-3)

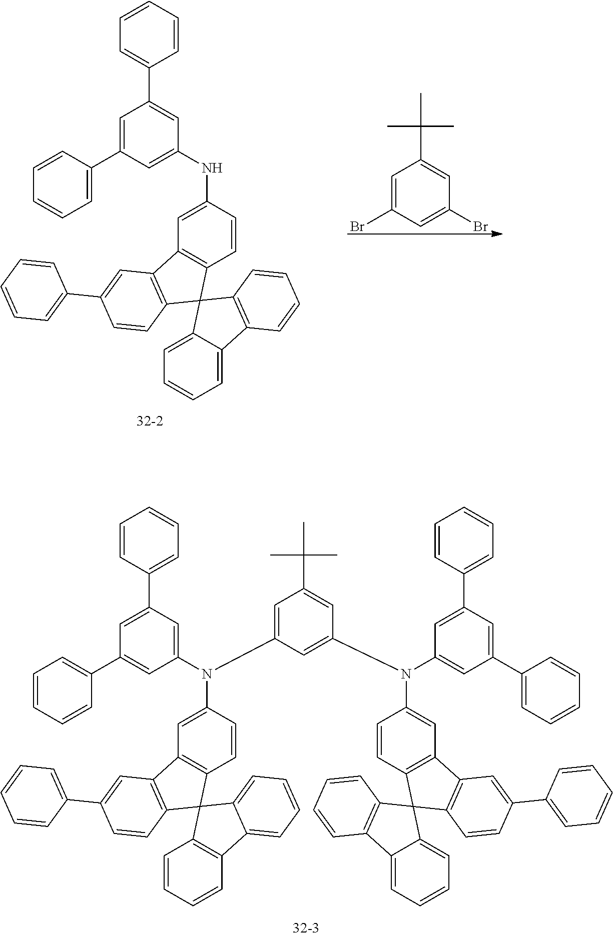 [SMILES: c1ccc(-c2cc(Nc3ccc4c(c3)-c3cc(-c5ccccc5)ccc3C43c4ccccc4-c4ccccc43)cc(-c3ccccc3)c2)cc1 ; CC(C)(C)c1cc(Br)cc(Br)c1 ; CC(C)(C)c1cc(N(c2cc(-c3ccccc3)cc(-c3ccccc3)c2)c2ccc3c(c2)-c2cc(-c4ccccc4)ccc2C32c3ccccc3-c3ccccc32)cc(N(c2cc(-c3ccccc3)cc(-c3ccccc3)c2)c2ccc3c(c2)-c2cc(-c4ccccc4)ccc2C32c3ccccc3-c3ccccc32)c1]

1,3-dibromo-5-(tert-butyl)benzene (1 eq), Intermediate 32-2 (2 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 100° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using methylene chloride and n-hexane to obtain Intermediate 32-3. (yield: 46%)

(Synthesis of Compound 32)

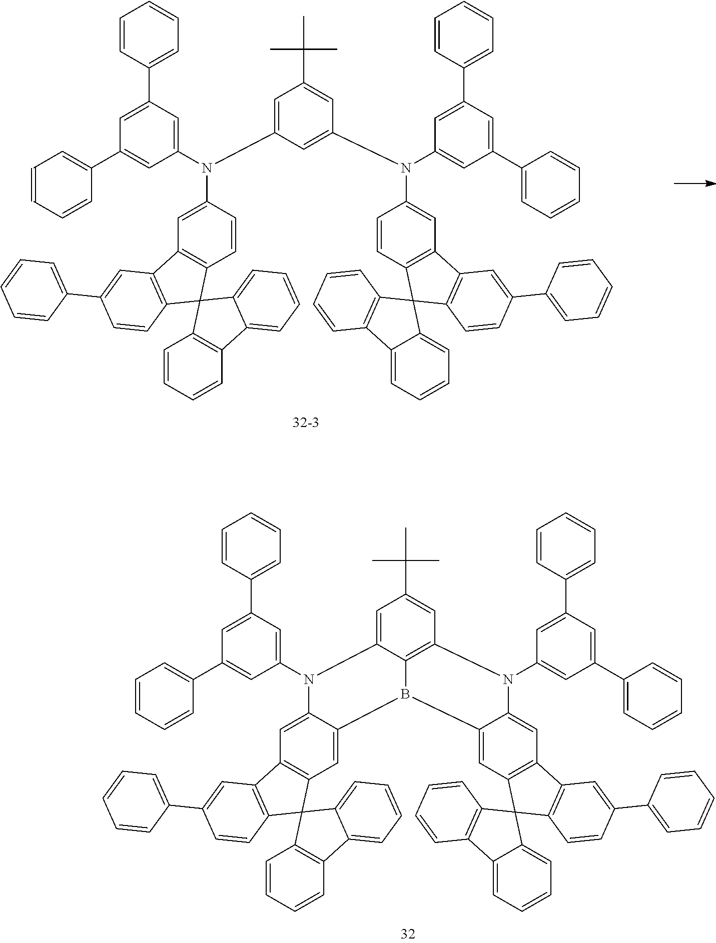 [SMILES: CC(C)(C)c1cc(N(c2cc(-c3ccccc3)cc(-c3ccccc3)c2)c2ccc3c(c2)-c2cc(-c4ccccc4)ccc2C32c3ccccc3-c3ccccc32)cc(N(c2cc(-c3ccccc3)cc(-c3ccccc3)c2)c2ccc3c(c2)-c2cc(-c4ccccc4)ccc2C32c3ccccc3-c3ccccc32)c1 ; CC(C)(C)c1cc2c3c(c1)N(c1cc(-c4ccccc4)cc(-c4ccccc4)c1)c1cc4c(cc1B3c1cc3c(cc1N2c1cc(-c2ccccc2)cc(-c2ccccc2)c1)-c1cc(-c2ccccc2)ccc1C31c2ccccc2-c2ccccc21)C1(c2ccccc2-c2ccccc21)c1ccc(-c2ccccc2)cc1-4]

Intermediate 32-3 (1 eq) was dissolved in ortho dichlorobenezene, the mixture was cooled to about 0° C., and BBr₃ (2 eq) was slowly injected thereto in a nitrogen atmosphere. After dropping was completed, the temperature was elevated to 180° C., and the mixture was stirred for 24 hours. After cooling, the reaction was terminated by dropping triethylamine slowly in the flask containing the reactant, and ethyl alcohol was added to the reactant, and extracted and filtered to obtain solids. The obtained solids were purified by column chromatography using methylene chloride and n-hexane, and were subjected to recrystallization using toluene and acetone to obtain Compound 32. (yield: 14%)

(4) Synthesis of Compound 42

Compound 42 according to an example may be synthesized by, for example, the reaction below:

(Synthesis of Intermediate 42-1)

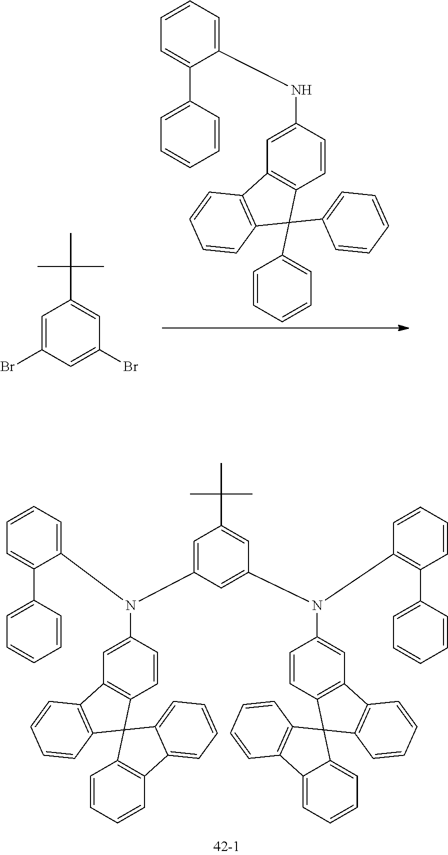

1,3-dibromo-5-(tert-butyl)benzene (l eq), N-([1,1′-biphenyl]-2-yl)-9,9-diphenyl-9H-fluoren-3-amine (1 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 100° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using methylene chloride and n-hexane to obtain Intermediate 42-1. (yield: 58%)

(Synthesis of Compound 42)

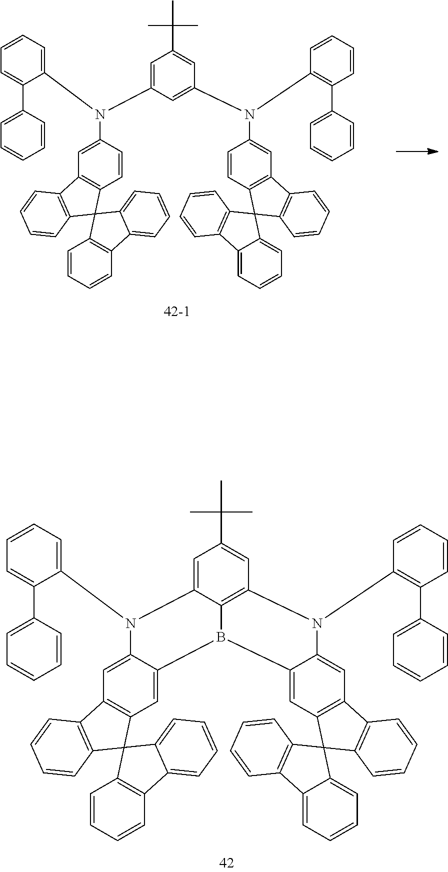 [SMILES: CC(C)(C)c1cc(N(c2ccc3c(c2)-c2ccccc2C32c3ccccc3-c3ccccc32)c2ccccc2-c2ccccc2)cc(N(c2ccc3c(c2)-c2ccccc2C32c3ccccc3-c3ccccc32)c2ccccc2-c2ccccc2)c1 ; CC(C)(C)c1cc2c3c(c1)N(c1ccccc1-c1ccccc1)c1cc4c(cc1B3c1cc3c(cc1N2c1ccccc1-c1ccccc1)-c1ccccc1C31c2ccccc2-c2ccccc21)C1(c2ccccc2-c2ccccc21)c1ccccc1-4]

Intermediate 42-1 (1 eq) was dissolved in ortho dichlorobenezene, the mixture was cooled to about 0° C., and BBr₃ (2.5 eq) was slowly injected thereto in a nitrogen atmosphere. After dropping was completed, the temperature was elevated to 180° C., and the mixture was stirred for 24 hours. After cooling, the reaction was terminated by dropping triethylamine slowly in the flask containing the reactant, and ethyl alcohol was added to the reactant, and extracted and filtered to obtain solids. The obtained solids were purified by column chromatography using methylene chloride and n-hexane, and were subjected to recrystallization using toluene and acetone to obtain Compound 42. (yield: 17%)

(5) Synthesis of Compound 97

Compound 97 according to an example may be synthesized, for example, by the reaction below:

(Synthesis of Intermediate 97-1)

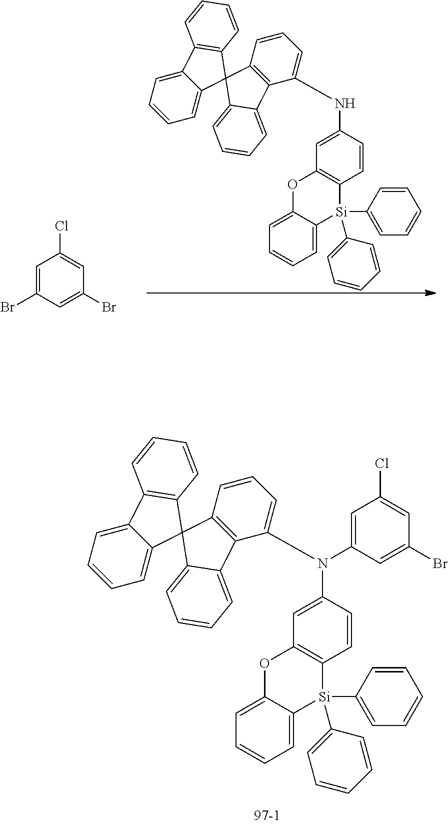 [SMILES: Clc1cc(Br)cc(Br)c1 ; c1ccc([Si]2(c3ccccc3)c3ccccc3Oc3cc(Nc4cccc5c4-c4ccccc4C54c5ccccc5-c5ccccc54)ccc32)cc1 ; Clc1cc(Br)cc(N(c2ccc3c(c2)Oc2ccccc2[Si]3(c2ccccc2)c2ccccc2)c2cccc3c2-c2ccccc2C32c3ccccc3-c3ccccc32)c1]

1,3-dibromo-5-chlorobenzene (1 eq), N-(9,9′-spirobi[fluoren]-4-yl)-10,10-diphenyl-10H-dibenzo[b,e][1,4]oxasilin-3-amine (1 eq), tris(dibenzylideneacetone)dipalladium(0) (0.05 eq), BINAP (0.1 eq), and sodium tert-butoxide (3 eq) were dissolved in toluene, and the resultant mixture was stirred at about 90° C. for about 10 hours. After cooling, the mixture was washed three times with ethyl acetate and water, and separated to obtain an organic layer. The obtained organic layer was dried over MgSO₄, and dried under reduced pressure. The resulting product was purified by column chromatography using methylene chloride and n-hexane to obtain Intermediate 97-1. (yield: 42%)

(Synthesis of Intermediate 97-2)

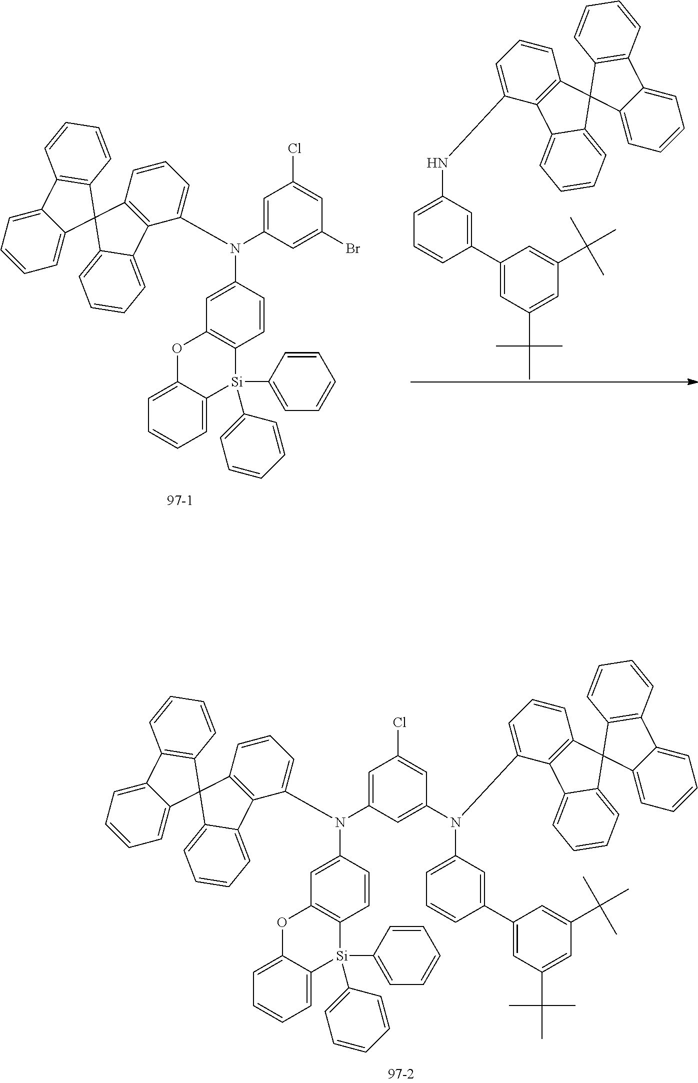 [SMILES: Clc1cc(Br)cc(N(c2ccc3c(c2)Oc2ccccc2[Si]3(c2ccccc2)c2ccccc2)c2cccc3c2-c2ccccc2C32c3ccccc3-c3ccccc32)c1 ; CC(C)(C)c1cc(-c2cccc(Nc3cccc4c3-c3ccccc3C43c4ccccc4-c4ccccc43)c2)cc(C(C)(C)C)c1 ; CC(C)(C)c1cc(-c2cccc(N(c3cc(Cl)cc(N(c4ccc5c(c4)Oc4ccccc4[Si]5(c4ccccc4)c4ccccc4)c4cccc5c4-c4ccccc4C54c5ccccc5-c5ccccc54)c3)c3cccc4c3-c3ccccc3C43c4ccccc4-c4ccccc43)c2)cc(C(C)(C)C)c1]

Intermediate 97-1 (1 eq), N-(3′,5′-di-tert-butyl-[1,1′-biphenyl]-3-yl)-9,9′-spirobi[fluoren]-4-amine (1 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using methylene chloride and n-hexane to obtain Intermediate 97-2. (yield: 67%)

(Synthesis of Intermediate 97-3)

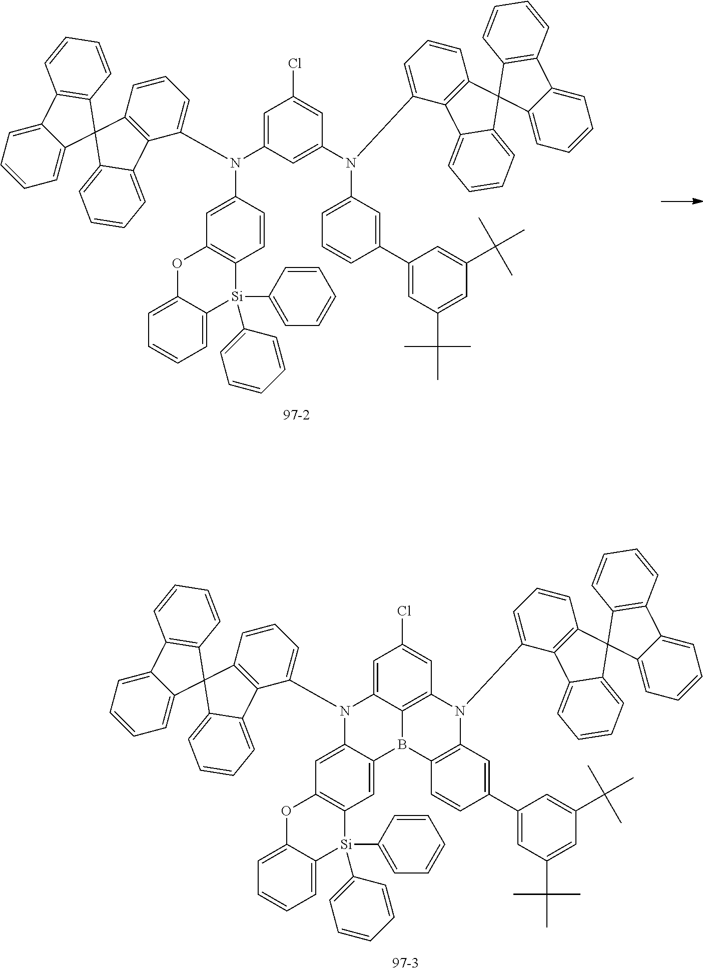 [SMILES: CC(C)(C)c1cc(-c2cccc(N(c3cc(Cl)cc(N(c4ccc5c(c4)Oc4ccccc4[Si]5(c4ccccc4)c4ccccc4)c4cccc5c4-c4ccccc4C54c5ccccc5-c5ccccc54)c3)c3cccc4c3-c3ccccc3C43c4ccccc4-c4ccccc43)c2)cc(C(C)(C)C)c1 ; CC(C)(C)c1cc(-c2ccc3c(c2)N(c2cccc4c2-c2ccccc2C42c4ccccc4-c4ccccc42)c2cc(Cl)cc4c2B3c2cc3c(cc2N4c2cccc4c2-c2ccccc2C42c4ccccc4-c4ccccc42)Oc2ccccc2[Si]3(c2ccccc2)c2ccccc2)cc(C(C)(C)C)c1]

Intermediate 97-2 (1 eq) was dissolved in ortho dichlorobenezene, the mixture was cooled to about 0° C., and BBr₃ (3 eq) was slowly injected thereto in a nitrogen atmosphere. After dropping was completed, the temperature was elevated to 180° C., and the mixture was stirred for 24 hours. After cooling, the reaction was terminated by dropping triethylamine slowly in the flask containing the reactant, and ethyl alcohol was added to the reactant, and extracted and filtered to obtain solids. The obtained solids were purified by column chromatography using methylene chloride and n-hexane, and were subjected to recrystallization using toluene and acetone to obtain Intermediate 97-3. (yield: 7%)

(Synthesis of Compound 97)

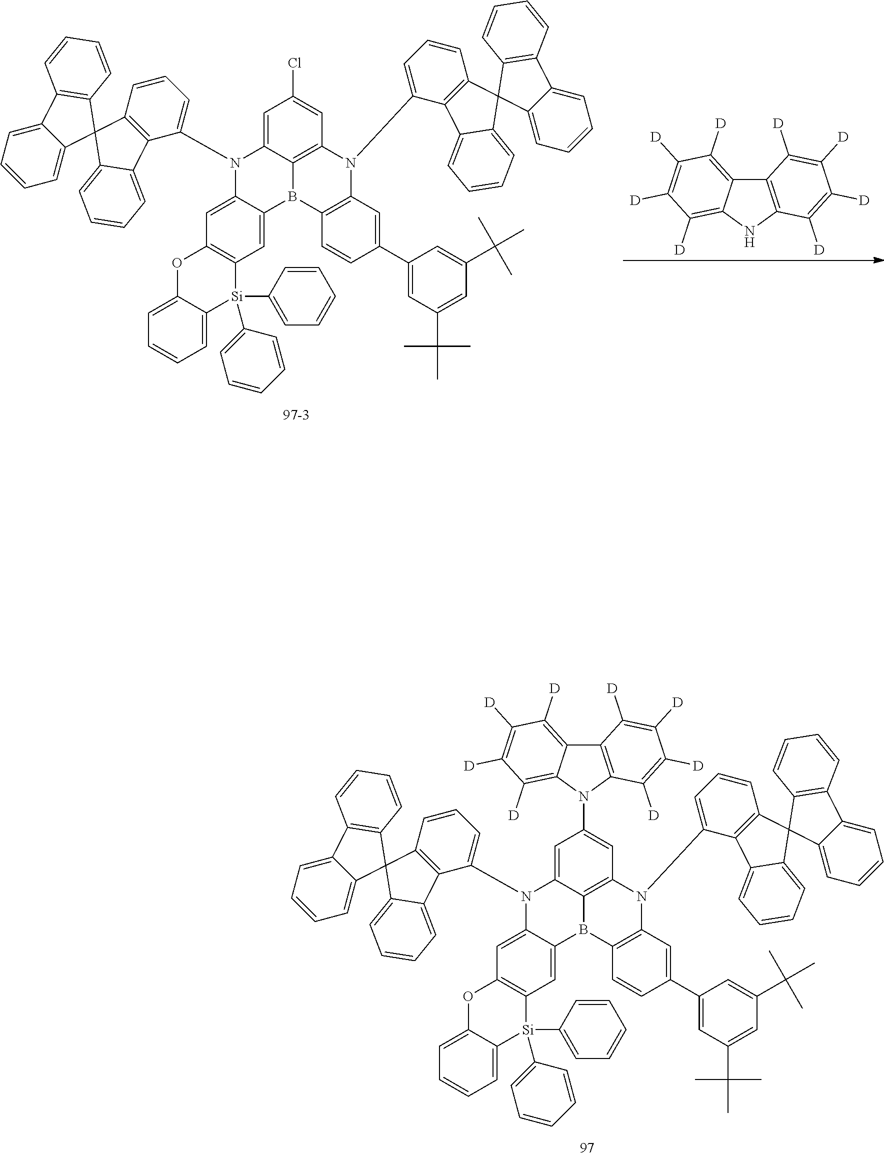

Intermediate 97-3 (1 eq), carbazole-D8 (2 eq), tris(dibenzylideneacetone)dipalladium(0) (0.05 eq), tri-tert-butylphosphine (0.1 eq), and sodium tert-butoxide (3 eq) were dissolved in o-xylene, and the resultant mixture was stirred at about 150° C. for about 24 hours. After cooling, the mixture was washed three times with ethyl acetate and water, and separated to obtain an organic layer. The obtained organic layer was dried over MgSO₄, and dried under reduced pressure. The resulting product was purified by column chromatography using methylene chloride and n-hexane to obtain Compound 97. (yield: 48%)

(6) Synthesis of Compound 98

Compound 98 according to an example may be synthesized, for example, by the reaction below:

(Synthesis of Intermediate 98-1)

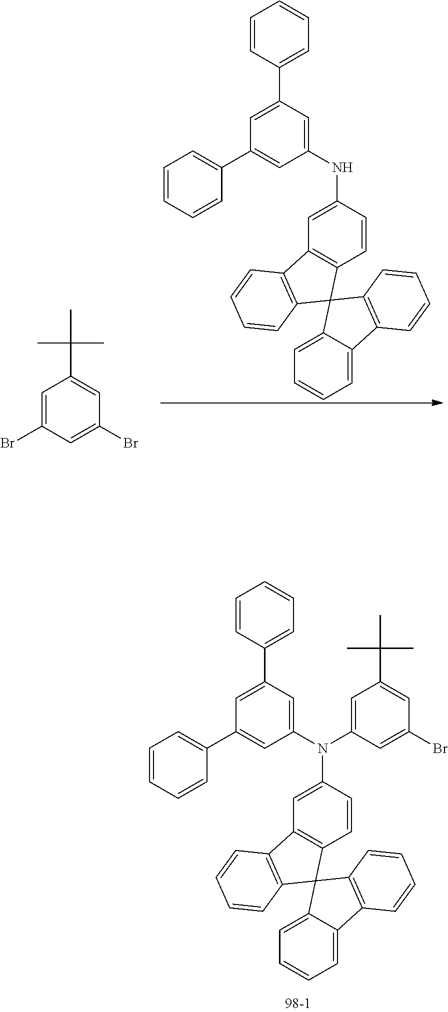 [SMILES: CC(C)(C)c1cc(Br)cc(Br)c1 ; c1ccc(-c2cc(Nc3ccc4c(c3)-c3ccccc3C43c4ccccc4-c4ccccc43)cc(-c3ccccc3)c2)cc1 ; CC(C)(C)c1cc(Br)cc(N(c2cc(-c3ccccc3)cc(-c3ccccc3)c2)c2ccc3c(c2)-c2ccccc2C32c3ccccc3-c3ccccc32)c1]

1,3-dibromo-5-(tert-butyl)benzene (1 eq), N-([1,1′:3′,1″-terphenyl]-5′-yl)-9,9′-spirobi[fluoren]-3-amine (1 eq), tris(dibenzylideneacetone)dipalladium(0) (0.05 eq), BINAP (0.1 eq), and sodium tert-butoxide (3 eq) were dissolved in toluene, and the resultant mixture was stirred at about 90° C. for about 12 hours. After cooling, the mixture was washed three times with ethyl acetate and water, and separated to obtain an organic layer. The obtained organic layer was dried over MgSO₄, and dried under reduced pressure. The resulting product was purified by column chromatography using methylene chloride and n-hexane to obtain Intermediate 98-1. (yield: 40%)

(Synthesis of Intermediate 98-2)

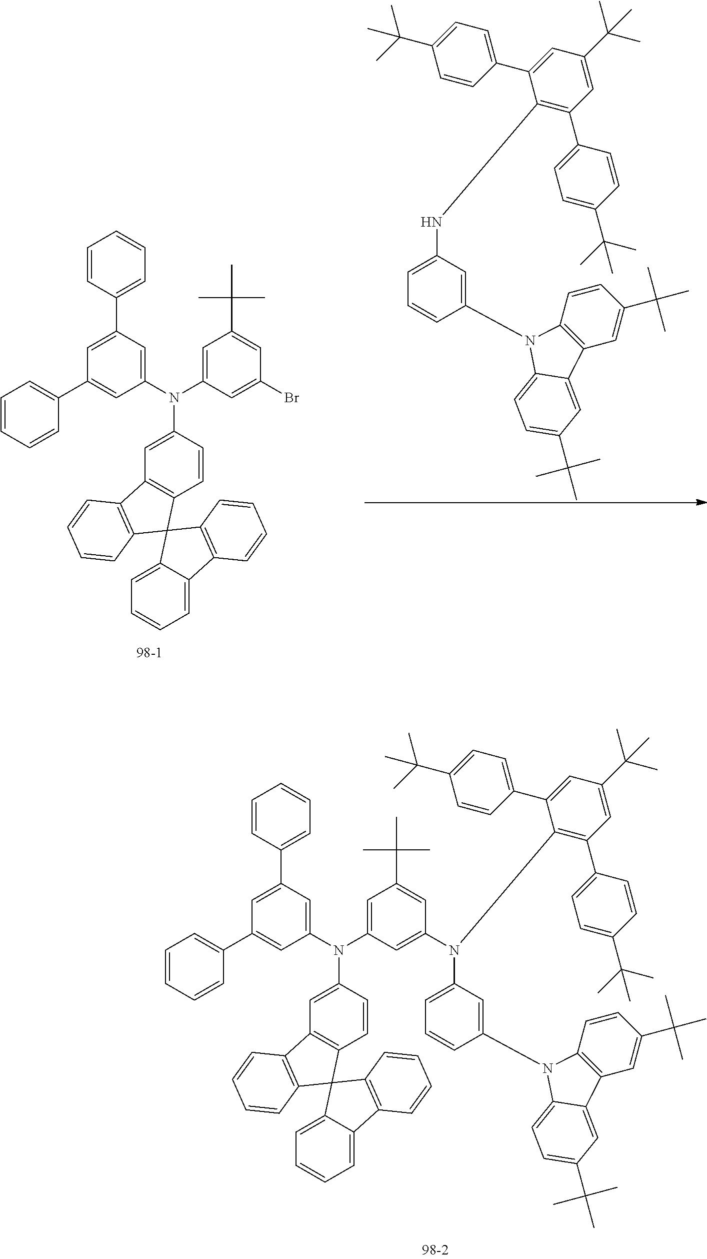 [SMILES: CC(C)(C)c1cc(Br)cc(N(c2cc(-c3ccccc3)cc(-c3ccccc3)c2)c2ccc3c(c2)-c2ccccc2C32c3ccccc3-c3ccccc32)c1 ; CC(C)(C)c1ccc(-c2cc(C(C)(C)C)cc(-c3ccc(C(C)(C)C)cc3)c2Nc2cccc(-n3c4ccc(C(C)(C)C)cc4c4cc(C(C)(C)C)ccc43)c2)cc1 ; CC(C)(C)c1ccc(-c2cc(C(C)(C)C)cc(-c3ccc(C(C)(C)C)cc3)c2N(c2cccc(-n3c4ccc(C(C)(C)C)cc4c4cc(C(C)(C)C)ccc43)c2)c2cc(N(c3cc(-c4ccccc4)cc(-c4ccccc4)c3)c3ccc4c(c3)-c3ccccc3C43c4ccccc4-c4ccccc43)cc(C(C)(C)C)c2)cc1]

Intermediate 98-1 (1 eq), 4,4″,5′-tri-tert-butyl-N-(3-(3,6-di-tert-butyl-9H-carbazol-9-yl)phenyl)-[11,1′:3′,1″-terphenyl]-2′-amine (1 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 24 hours. After cooling, the mixture was washed three times with ethyl acetate and water, and separated to obtain an organic layer. The obtained organic layer was dried over MgSO₄, and dried under reduced pressure. The resulting product was purified by column chromatography using methylene chloride and n-hexane to obtain Intermediate 98-2. (yield: 55%)

(Synthesis of Compound 98)

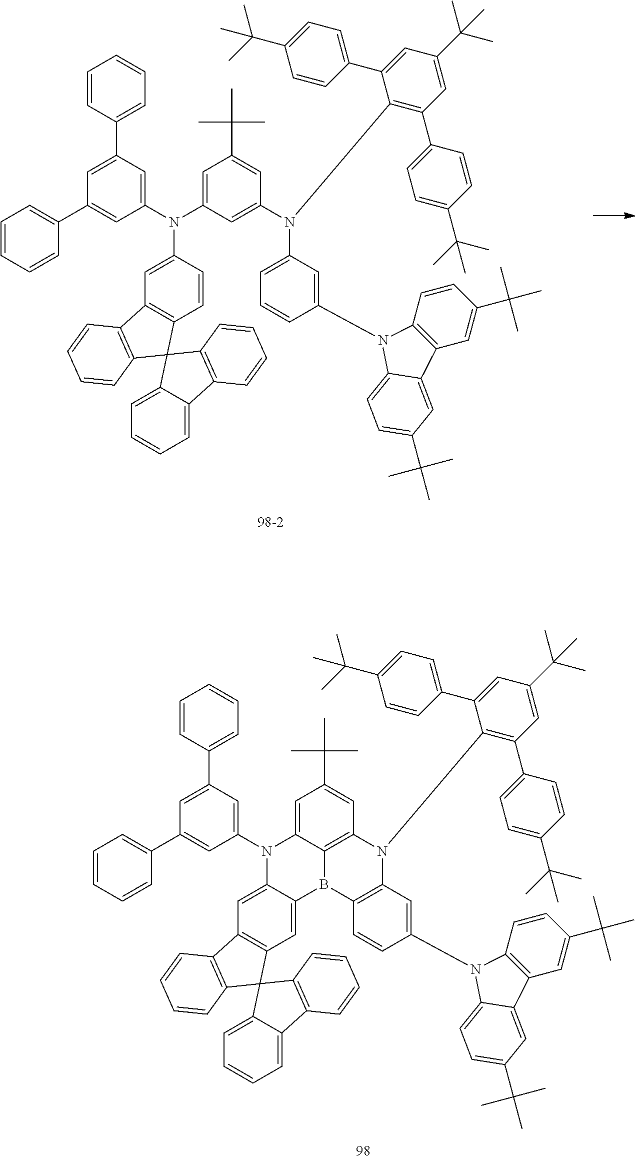 [SMILES: CC(C)(C)c1ccc(-c2cc(C(C)(C)C)cc(-c3ccc(C(C)(C)C)cc3)c2N(c2cccc(-n3c4ccc(C(C)(C)C)cc4c4cc(C(C)(C)C)ccc43)c2)c2cc(N(c3cc(-c4ccccc4)cc(-c4ccccc4)c3)c3ccc4c(c3)-c3ccccc3C43c4ccccc4-c4ccccc43)cc(C(C)(C)C)c2)cc1 ; CC(C)(C)c1ccc(-c2cc(C(C)(C)C)cc(-c3ccc(C(C)(C)C)cc3)c2N2c3cc(-n4c5ccc(C(C)(C)C)cc5c5cc(C(C)(C)C)ccc54)ccc3B3c4cc5c(cc4N(c4cc(-c6ccccc6)cc(-c6ccccc6)c4)c4cc(C(C)(C)C)cc2c43)-c2ccccc2C52c3ccccc3-c3ccccc32)cc1]

Intermediate 98-2 (1 eq) was dissolved in ortho dichlorobenezene, the mixture was cooled to about 0° C., and BBr₃ (2.5 eq) was slowly injected thereto in a nitrogen atmosphere. After dropping was completed, the temperature was elevated to 180° C., and the mixture was stirred for 24 hours. After cooling, the reaction was terminated by dropping triethylamine slowly in the flask containing the reactant, and ethyl alcohol was added to the reactant, and extracted and filtered to obtain solids. The obtained solids were purified by column chromatography using methylene chloride and n-hexane, and were subjected to recrystallization using toluene and acetone to obtain Compound 98. (yield: 14%)

¹H NMR and MS/FAB of the compounds synthesized in Examples (1) to (6) are shown in Table 1. The synthesis methods of other compounds may be readily recognized by those skilled in the art with reference to the above synthesis paths and raw materials.

TABLE 1

| | ¹H NMR chemical shift | MS-Cal | MS-Meas. |
|---|---|---|---|
| 8 | 8.87-8.84 (2H, s), 8.00-7.86 (6H, m), 7.62-7.56 (8H, m), 7.53- | 1374.501 | 1374.488 |
| | 7.44 (8H, m), 7.40-7.31 (16H, m), 7.27-7.23 (6H, m), 7.04-7.01 | | |
| | (2H, m), 6.92-6.81 (6H, m), 6.55-6.51 (2H, s) | | |
| 14 | 8.72-8.69 (1H, s), 8.63-8.57 (1H, d), 7.97-7.89 (3H, m), 7.60- | 1304.538 | 1304.529 |
| | 7.55 (8H, d), 7.50-7.31 (18H, m), 7.28-7.25 (3H, m), 7.22-7.17 | | |
| | (1H, d), 7.11-7.07 (4H, d), 6.44-6.41 (1H, s), 6.38-6.35 (1H, s), | | |
| | 6.15-6.10 (2H, s), 1.57-1.53 (18H, s), 1.50-1.45 (9H, s) | | |
| 32 | 8.79-8.75 (2H, s), 8.04-8.01 (6H, m), 7.75-7.63 (10H, m), 7.60- | 1409.560 | 1409.548 |
| | 7.55 (8H, d), 7.52-7.44 (8H, m), 7.40-7.32 (14H, m), 7.25-7.21 | | |
| | (6H, m), 6.92-6.81 (6H, s), 6.68-6.54 (2H, m), 6.31-6.27 (2H, s), | | |
| | 1.59-1.56 (9H, s) | | |
| 42 | 8.68-8.65 (2H, s), 7.94-7.89 (6H, m), 7.63-7.55 (4H, d), 7.51- | 1109.208 | 1109.194 |
| | 7.45 (4H, t), 7.40-7.35 (18H, m), 7.29-7.25 (6H, m), 7.16-7.12 | | |
| | (4H, d), 7.06-7.02 (2H, m), 6.80-6.72 (4H, t), 6.56-6.51 (2H, s), | | |
| | 1.50-1.45 (9H, s) | | |
| 97 | 8.94-8.88 (1H, d), 8.79-8.75 (1H, s), 7.98-7.92 (6H, m), 7.82- | 1530.799 | 1530.787 |
| | 7.78 (2H, s), 7.48-7.45 (1H, s), 7.42-7.38 (14H, d), 7.36-7.31 | | |
| | (13H, m), 7.31-7.25 (13H, m), 7.04-7.01 (1H, m), 6.91-6.86 (2H, | | |
| | s), 1.52-1.49 (18H, s) | | |
| 98 | 8.74-8.69 (1H, s), 8.64-8.59 (1H, d), 8.11-8.08 (2H, s), 8.04-7.99 | 1464.807 | 1464.802 |
| | (3H, m), 7.61-7.43 (16H, d), 7.40-7.32 (12H, m), 7.28-7.18 (4H, | | |
| | m), 7.12-7.07 (2H, d), 6.93-6.81 (3H, s), 6.45-6.41 (1H, s), 6.39- | | |
| | 6.35 (1H, s), 6.16-6.11 (2H, s), 1.57-1.42 (54H, m) | | |

2. Manufacture and Evaluation of Light Emitting Device Including Fused Polycyclic Compound

Examples of light emitting devices that include the fused polycyclic compound of an Example in an emission layer were manufactured as follows. Compounds 8, 14, 32, 42, 97, and 98, which are Example Compounds as described above, were used as dopant materials for the emission layers to manufacture the light emitting devices of Examples 1 to 12, respectively. Comparative Examples 1 to 6 correspond to the light emitting devices manufactured by using Comparative Example Compounds C1 to C3 as dopant materials for the emission layers, respectively.

[Example Compounds]

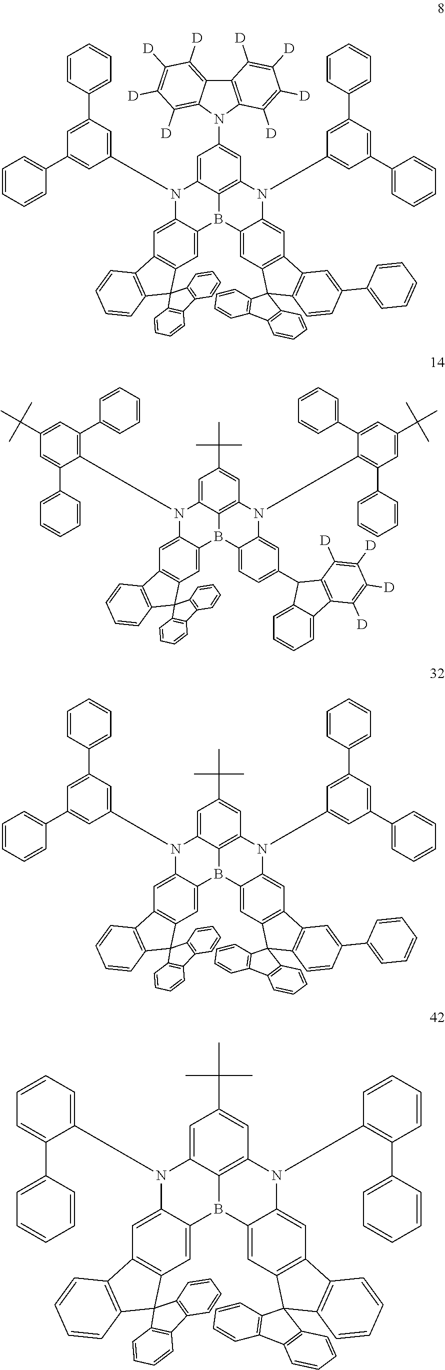

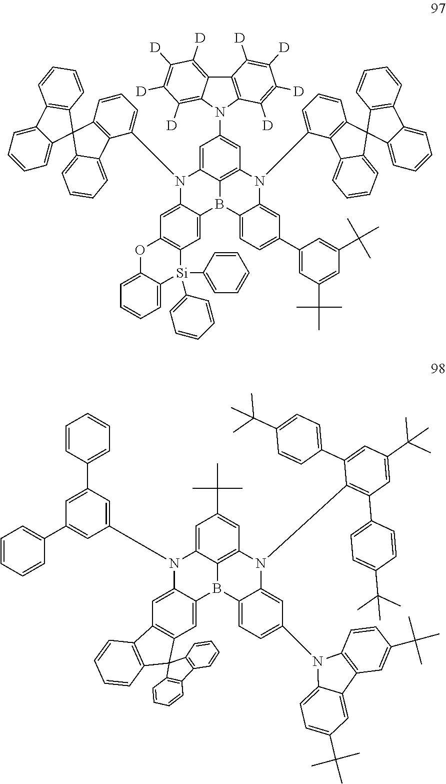 [SMILES: [2H]c1c([2H])c([2H])c2c(c1[2H])c1c([2H])c([2H])c([2H])c([2H])c1n2-c1cc2c3c(c1)N(CCc1cccc4c1-c1ccccc1C41c4ccccc4-c4ccccc41)c1cc4c(cc1B3c1ccc(-c3cc(C(C)(C)C)cc(C(C)(C)C)c3)cc1N2CCc1cccc2c1-c1ccccc1C21c2ccccc2-c2ccccc21)[Si](c1ccccc1)(c1ccccc1)c1ccccc1O4 ; CC(C)(C)c1ccc(-c2cc(C(C)(C)C)cc(-c3ccc(C(C)(C)C)cc3)c2N2c3cc(Cn4c5ccc(C(C)(C)C)cc5c5cc(C(C)(C)C)ccc54)ccc3B3c4cc5c(cc4N(CCc4cc(-c6ccccc6)cc(-c6ccccc6)c4)c4cc(C(C)(C)C)cc2c43)-c2ccccc2C52c3ccccc3-c3ccccc32)cc1]

[Comparative Example Compounds]

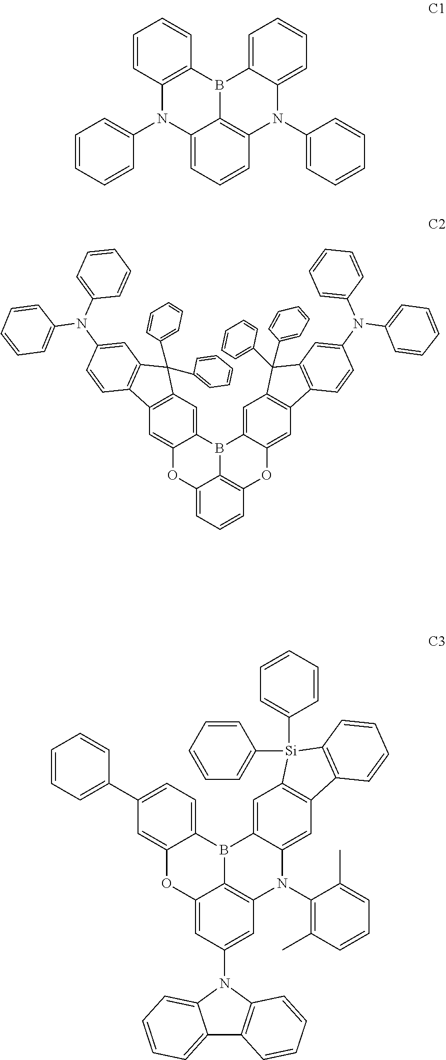 [SMILES: c1ccc(N2c3ccccc3B3c4ccccc4N(c4ccccc4)c4cccc2c43)cc1 ; c1ccc(N(c2ccccc2)c2ccc3c(c2)C(c2ccccc2)(c2ccccc2)c2cc4c(cc2-3)Oc2cccc3c2B4c2cc4c(cc2O3)-c2ccc(N(c3ccccc3)c3ccccc3)cc2C4(c2ccccc2)c2ccccc2)cc1 ; Cc1cccc(C)c1N1c2cc3c(cc2B2c4ccc(-c5ccccc5)cc4Oc4cc(-n5c6ccccc6c6ccccc65)cc1c42)[Si](c1ccccc1)(c1ccccc1)c1ccccc1-3]

(Manufacture of Light Emitting Device)

With respect to the light emitting devices of the Examples and the Comparative Examples, an ITO glass substrate was cut to a size of about 50 mm×50 mm×0.7 mm, washed by ultrasonic waves using isopropyl alcohol and distilled water for about 5 minutes, respectively, and irradiated with ultraviolet rays for about 30 minutes and cleansed by exposing to ozone, and installed on a vacuum deposition apparatus. NPD was used to form a hole injection layer having a thickness of about 300 Å, HT-1-1 was used to form a hole transport layer having a thickness of about 200 Å, and CzSi was used to form an emission auxiliary layer having about 100 Å. A host compound in which the second compound and the third compound according to an embodiment were mixed in an amount of about 1:1, the fourth compound, and an Example Compound or a Comparative Example Compound were co-deposited in a weight ratio of about 85:14:1 to form a 200 Å-thick emission layer, and TSPO1 was used to form a 200 Å-thick hole blocking layer. TPBI, an electron transporting compound, was used to form a 300 Å-thick electron transport layer, and LiF was used to form 10 Å-thick electron injection layer. Al was used to form a 3,000 Å-thick second electrode to form a LiF/Al electrode. Each layer was formed by a vacuum deposition method. HT1, HT2, and HT3 from Compound Group 2 as described above were used as the second compound. ETH85, ETH66, and ETH86 from Compound Group 3 as described above were used as the third compound. AD-37 and AD-38 from Compound Group 4 as described above were used as the fourth compound.

The compounds which were used for manufacturing the light emitting devices according to the Examples and the Comparative Examples are disclosed below. The materials below were used to manufacture the light emitting devices by subjecting commercial products to sublimation purification.

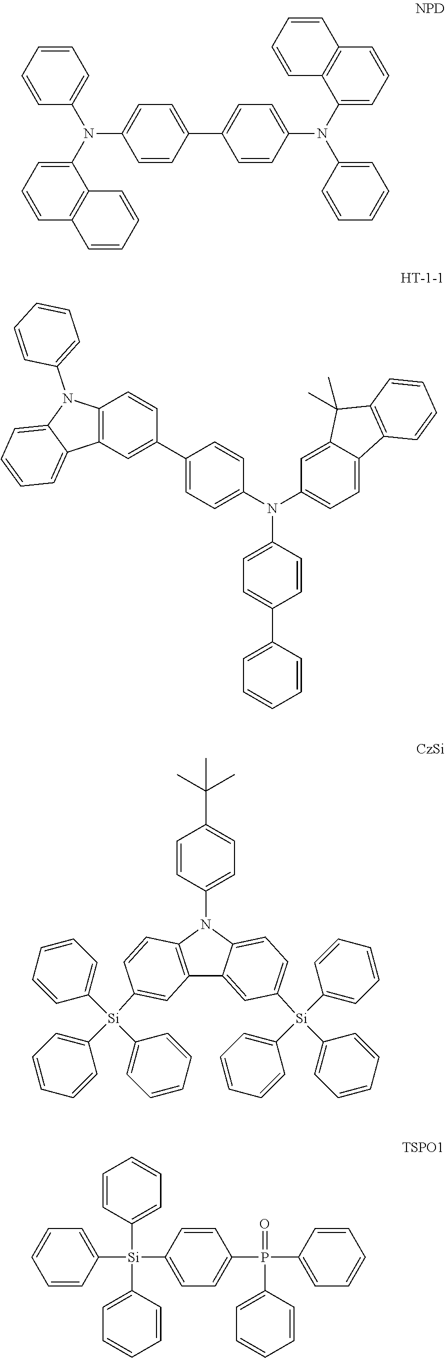 [SMILES: c1ccc(N(c2ccc(-c3ccc(N(c4ccccc4)c4cccc5ccccc45)cc3)cc2)c2cccc3ccccc23)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1 ; O=P(c1ccccc1)(c1ccccc1)c1ccc([Si](c2ccccc2)(c2ccccc2)c2ccccc2)cc1]

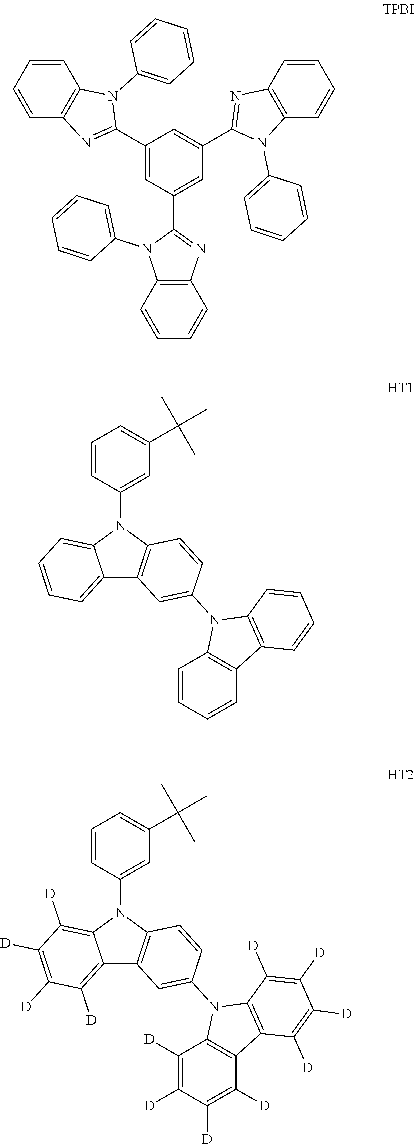 [SMILES: c1ccc(-n2c(-c3cc(-c4nc5ccccc5n4-c4ccccc4)cc(-c4nc5ccccc5n4-c4ccccc4)c3)nc3ccccc32)cc1 ; CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1]

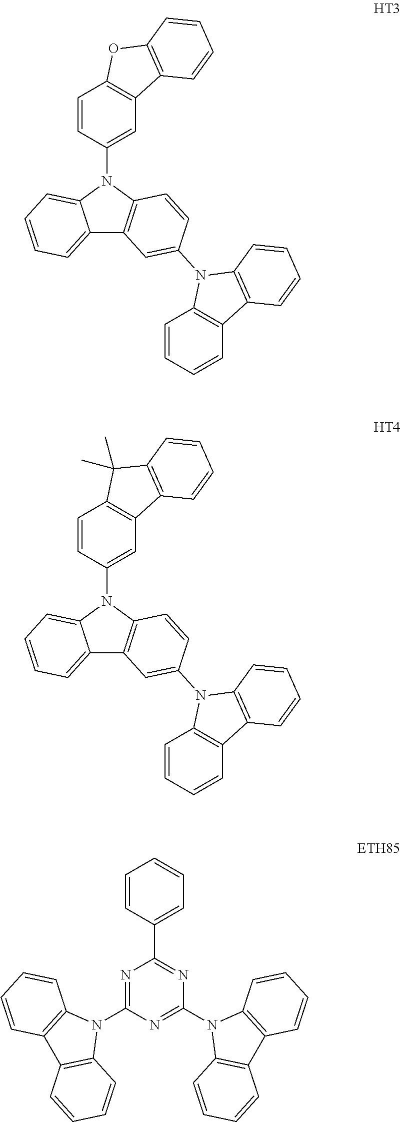 [SMILES: c1ccc2c(c1)oc1ccc(-n3c4ccccc4c4cc(-n5c6ccccc6c6ccccc65)ccc43)cc12 ; CC1(C)c2ccccc2-c2cc(-n3c4ccccc4c4cc(-n5c6ccccc6c6ccccc65)ccc43)ccc21 ; c1ccc(-c2nc(-n3c4ccccc4c4ccccc43)nc(-n3c4ccccc4c4ccccc43)n2)cc1]

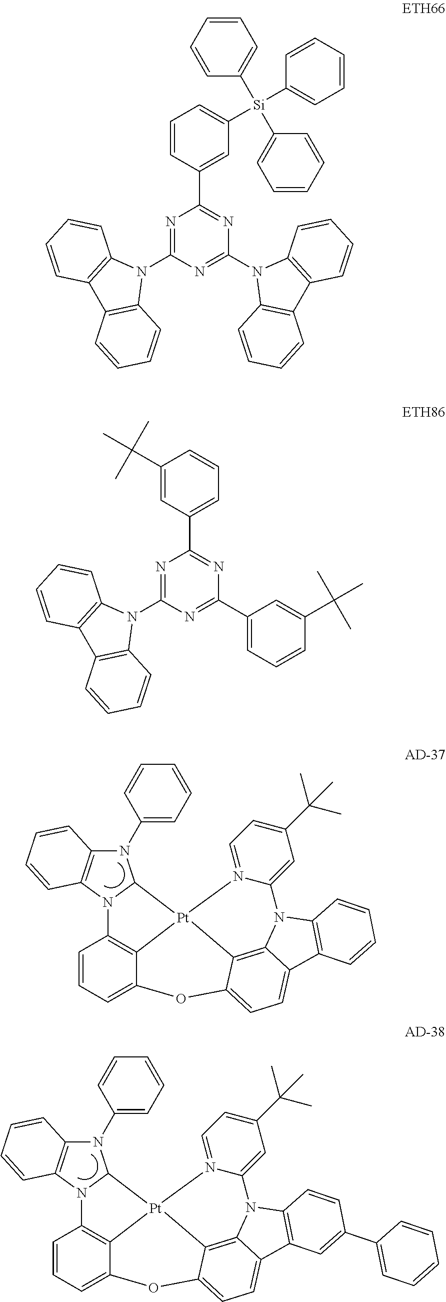

(Evaluation of Light Emitting Device Characteristics)

Device efficiency and device service life of the light emitting device manufactured with Example Compounds 8, 14, 32, 42, 97, and 98, and Comparative Example Compounds C1 to C3 as described above were evaluated. Evaluation results of the light emitting devices of Examples 1 to 12 and Comparative Examples 1 to 6 are listed in Table 2. In the characteristic evaluation results of Examples and Comparative Examples listed in Table 2, driving voltages and current densities were measured by using V7000 OLED IVL Test System (Polaronix). To evaluate the characteristics of the light emitting devices manufactured in Examples 1 to 12 and Comparative Examples 1 to 6, driving voltages and efficiencies (cd/A) at a current density of 10 mA/cm² were measured, and the relative device service life was set as a numerical value in which the deterioration time from an initial value to 50% brightness when the device was continuously operated at a current density of 10 mA/cm² was compared with Comparative Example 2, and the evaluation was conducted.

TABLE 2

| | Second | | | Driving | | Luminescence | Service |
|---|---|---|---|---|---|---|---|
| | compound/Third | Fourth | First | voltage | Efficiency | wavelength | life ratio |
| | compound | compound | compound | (V) | (cd/A) | (nm) | (T95) |
| Example 1 | HT2/ETH66 | AD-38 | Compound 8 | 4.5 | 26.2 | 459 | 5.7 |
| Example 2 | HT2/ETH66 | AD-38 | Compound 14 | 4.4 | 27.1 | 462 | 6.2 |
| Example 3 | HT2/ETH66 | AD-38 | Compound 32 | 4.3 | 26.6 | 461 | 5.5 |
| Example 4 | HT2/ETH66 | AD-38 | Compound 42 | 4.5 | 26.4 | 462 | 5.3 |
| Example 5 | HT2/ETH66 | AD-38 | Compound 97 | 4.5 | 25.4 | 463 | 5.2 |
| Example 6 | HT2/ETH66 | AD-38 | Compound 98 | 4.5 | 25.2 | 463 | 5.1 |
| Example 7 | HT3/ETH86 | AD-38 | Compound 32 | 4.4 | 25.8 | 461 | 6.2 |
| Example 8 | HT3/ETH86 | AD-38 | Compound 42 | 4.3 | 26.4 | 460 | 6.5 |
| Example 9 | HT1/ETH86 | AD-37 | Compound 8 | 4.6 | 25.2 | 460 | 6.1 |
| Example 10 | HT1/ETH86 | AD-37 | Compound 97 | 4.6 | 25.0 | 463 | 5.7 |
| Example 11 | HT4/ETH85 | AD-37 | Compound 14 | 4.4 | 25.4 | 460 | 5.6 |
| Example 12 | HT4/ETH85 | AD-37 | Compound 98 | 4.3 | 25.2 | 462 | 5.3 |
| Comparative | HT2/ETH66 | x | Comparative | 5.8 | 13.3 | 459 | 0.1 |
| Example 1 | | | Example | | | | |
| | | | Compound C1 | | | | |
| Comparative | HT2/ETH66 | AD-38 | Comparative | 5.6 | 14.7 | 464 | 1.0 |
| Example 2 | | | Example | | | | |
| | | | Compound C1 | | | | |
| Comparative | HT2/ETH66 | x | Comparative | 5.7 | 9.8 | 438 | 0.1 |
| Example 3 | | | Example | | | | |
| | | | Compound C2 | | | | |
| Comparative | HT2/ETH66 | AD-38 | Comparative | 5.8 | 17.2 | 463 | 1.3 |
| Example 4 | | | Example | | | | |
| | | | Compound C2 | | | | |
| Comparative | HT2/ETH66 | x | Comparative | 5.5 | 12.5 | 445 | 0.1 |
| Example 5 | | | Example | | | | |
| | | | Compound C3 | | | | |
| Comparative | HT2/ETH66 | AD-38 | Comparative | 5.4 | 18.3 | 464 | 2.2 |
| Example 6 | | | Example | | | | |
| | | | Compound C3 | | | | |

Referring to the results of Table 2, it may be confirmed that the light emitting devices according to the Examples in which the fused polycyclic compounds according to embodiments were used as a luminescent material exhibit lower driving voltage, and have improved luminous efficiency and service life characteristics as compared with the Comparative Examples. The Example Compounds include the fused ring core in which the first to third aromatic rings are fused via a boron atom and first and second nitrogen atoms and have a structure in which the first moiety is fused at the fused ring core, and thus may achieve high luminous efficiency and a long service life.

The Example Compounds include the fused ring core in which the first to third aromatic rings are fused via one boron atom and two nitrogen atoms, and include a structure in which the first moiety is fused at the first aromatic ring in the fused ring core. The first moiety may include the first to third benzene ring linked to the first atom, and each of the first atom and the first benzene ring of the first moiety may be linked to the first aromatic ring of the fused ring core. The first moiety may be fused at the first aromatic ring, so that the second benzene ring and the third benzene ring are adjacent to the boron atom. Accordingly, the Example Compounds may effectively protect the boron atom, thereby achieving high efficiency and a long service life. The Example Compounds may have increased luminous efficiency because intermolecular interaction may be suppressed by the introduction of the first moiety, thereby controlling the formation of aggregation, excimer, or exciplex. The Example Compounds may have a large steric hindrance structure due to the first moiety, so that the distance between adjacent molecules increases, thereby suppressing Dexter energy transfer, TTA, TPQ, etc. so that service life degradation caused by an increase in triplet concentration may be suppressed. The light emitting device according to an Example includes the fused polycyclic compound of an Example as a dopant of a thermally activated delayed fluorescence (TADF) light emitting device, and thus may achieve high device efficiency in a blue wavelength region, for example, a deep blue wavelength region.

Referring to Comparative Examples 1 and 2, it may be confirmed that Comparative Example Compound C1 includes a planar skeleton structure having two boron atoms at the center thereof, but does not include, in the planar skeleton structure, a first moiety according to embodiments, and thus when applied to the device, Comparative Example Compound C1 has higher driving voltage, and lower luminous efficiency and device service life than the Examples. It may be seen that Comparative Example 1 does not include a fourth compound according to embodiments in the emission layer, and thus exhibits relatively lower luminous efficiency than Comparative Example 2 and the Examples.

When Example 4 and Comparative Examples 3 and 4 are compared, it may be confirmed that Comparative Examples 3 and 4 have higher driving voltage and lower luminous efficiency and device service life than Example 4. Comparative Example Compound C2 included in Comparative Examples 3 and 4 includes a fused ring core in which three aromatic rings are fused around one boron atom, and includes a structure in which the first moiety is fused at the fused ring core. However, it may be confirmed that Comparative Example Compound C2 does not include a nitrogen atom as an atom constituting the fused ring core, and thus when applied to the light emitting device, Comparative Example Compound C2 has a decrease in the luminous efficiency and device service life as compared with the Examples. This is believed that when only an oxygen atom rather than a nitrogen atom is included as an atom constituting the fused ring core as in Comparative Example Compound C2, delayed fluorescence characteristics are not readily exhibited, and thus the luminous efficiency characteristics are reduced. It may be confirmed that unlike the Example Compounds, Comparative Example Compound C2 has an amine group substituted at the first benzene ring in a structure in which the second benzene ring and the third benzene ring of the first moiety are separated from each other, and thus when applied to the device, Comparative Example Compound C2 has a decrease in the luminous efficiency and service life of the device as compared with Examples. As in the fused polycyclic compound according to embodiments, when an amine group is not included as a substituent in the first benzene ring in a structure in which the first moiety is fused at a particular position of the fused ring core, and the second benzene ring and the third benzene ring of the first moiety are not linked, it may be expected to improve luminous efficiency and service life. It may be seen that Comparative Example 3 does not include the fourth compound according to embodiments in the emission layer, and thus exhibits relatively lower luminous efficiency than Comparative Example 4 and the Examples.

When Example 5 and Comparative Examples 5 and 6 are compared, it may be confirmed that Comparative Examples 5 and 6 have higher driving voltage and lower luminous efficiency and device service life than Example 5. Comparative Example Compound C3 includes a core in which three aromatic rings are fused around one boron atom, and includes a structure in which the first moiety is fused at the fused ring core. However, it may be confirmed that when Comparative Example Compound C3 has the first benzene ring of the fused ring core directly bonded to the first aromatic ring in a structure in which the first atom of the first moiety is a silicon atom, and thus when applied to the device, Comparative Example Compound C3 has a decrease in the luminous efficiency and service life of the device as compared with Examples. It may be seen that Comparative Example 5 does not include the fourth compound according to embodiment in the emission layer, and thus exhibits relatively lower luminous efficiency than Comparative Example 6 and Examples.

The light emitting device of an embodiment may exhibit improved device characteristics with high efficiency and a long service life.

The fused polycyclic compound of an embodiment may be included in the emission layer of the light emitting device to contribute to high efficiency and a long service life of the light emitting device.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting device comprising:
a first electrode;
a second electrode facing the first electrode; and
an emission layer disposed between the first electrode and the second electrode, wherein
the emission layer comprises a first compound represented by Formula 1: 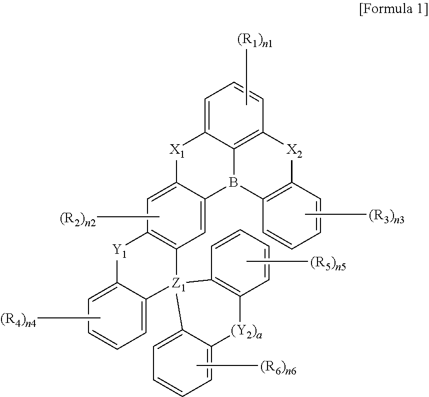
wherein in Formula 1,
X₁ and X₂ are each N(R₇),
Y₁ is a direct linkage or O,
Y₂ is a direct linkage, O, or N(R₈),
Z₁ is C or Si,
when Z₁ is Si, Y₁ is O,
R₁ to R₈ are each independently a hydrogen atom, a deuterium atom, a halogen atom, a substituted or unsubstituted amine group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or are bonded to an adjacent group to form a ring,
a is 0 or 1,
when a is 0, R₄ is not a substituted or unsubstituted amine group,
n1 is an integer from 0 to 3,
n2 is an integer from 0 to 2,
n3 and n4 are each independently an integer from 0 to 4,
n5 and n6 are each independently an integer from 0 to 5,
the sum of a and n5 is 5 or less, and
the sum of a and n6 is 5 or less.

2. The light emitting device of claim 1, wherein the first compound represented by Formula 1 is represented by one of Formula 2-1 to Formula 2-4: 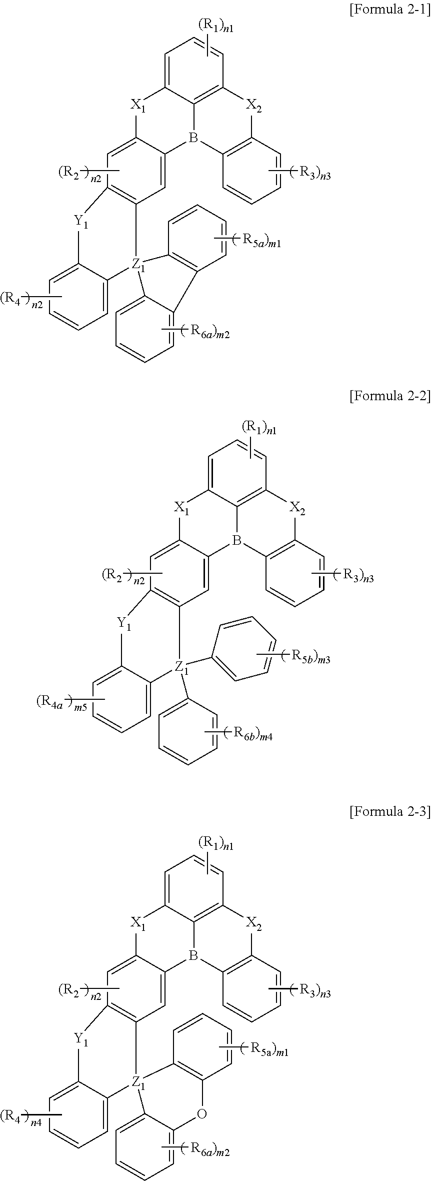 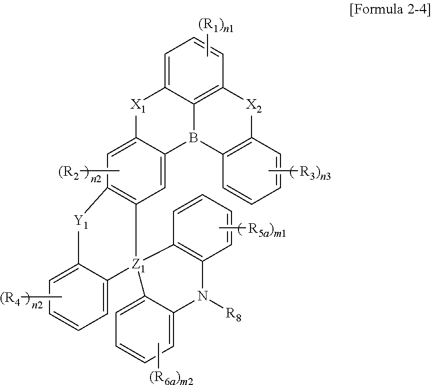
wherein in Formula 2-1 to Formula 2-4,
R₅ₐ, R₆ₐ, R_{5b}, and R_{6b} are each independently a hydrogen atom, a deuterium atom, a halogen atom, a substituted or unsubstituted amine group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
R₄ₐ is a hydrogen atom, a deuterium atom, a halogen atom, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
m1, m2, and m5 are each independently an integer from 0 to 4,
m3 and m4 are each independently an integer from 0 to 5, and
X₁, X₂, Y₁, Z₁, R₁ to R₄, and n1 to n4 are each the same as defined in Formula 1.

3. The light emitting device of claim 1, wherein the first compound represented by Formula 1 is represented by one of Formula 3-1 to Formula 3-3: 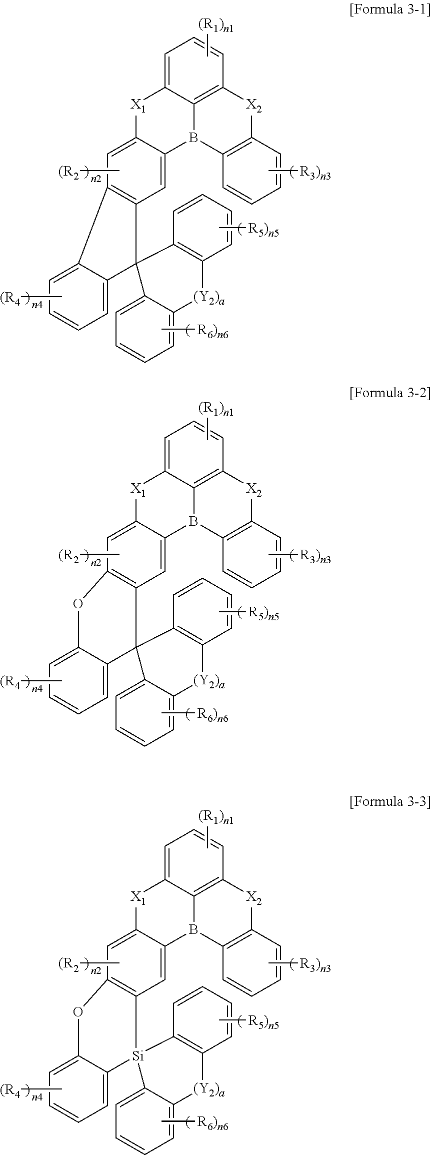
wherein in Formula 3-1 to Formula 3-3,
X₁, X₂, Y₂, a, R₁ to R₆, and n1 to n6 are each the same as defined in Formula 1.

4. The light emitting device of claim 1, wherein the first compound represented by Formula 1 is represented by one of Formula 4-1 to Formula 4-6: 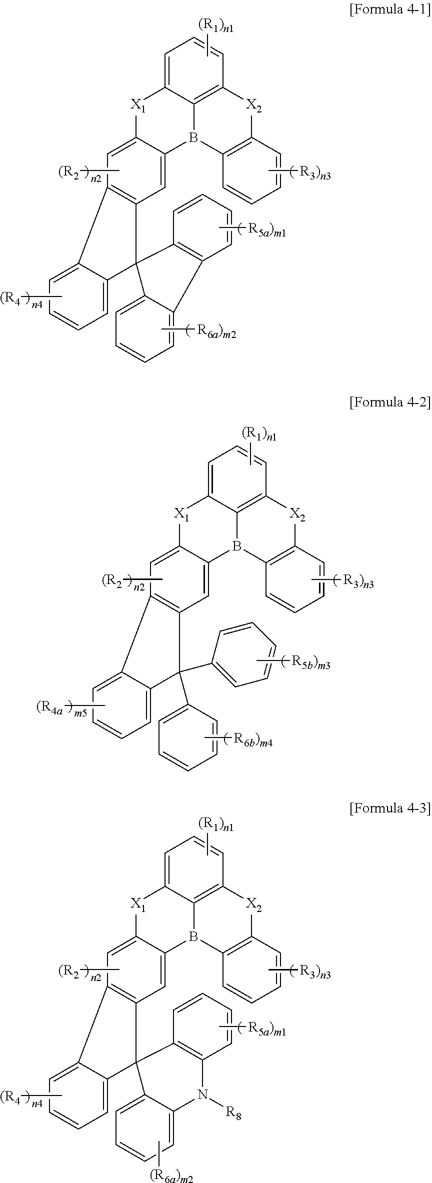 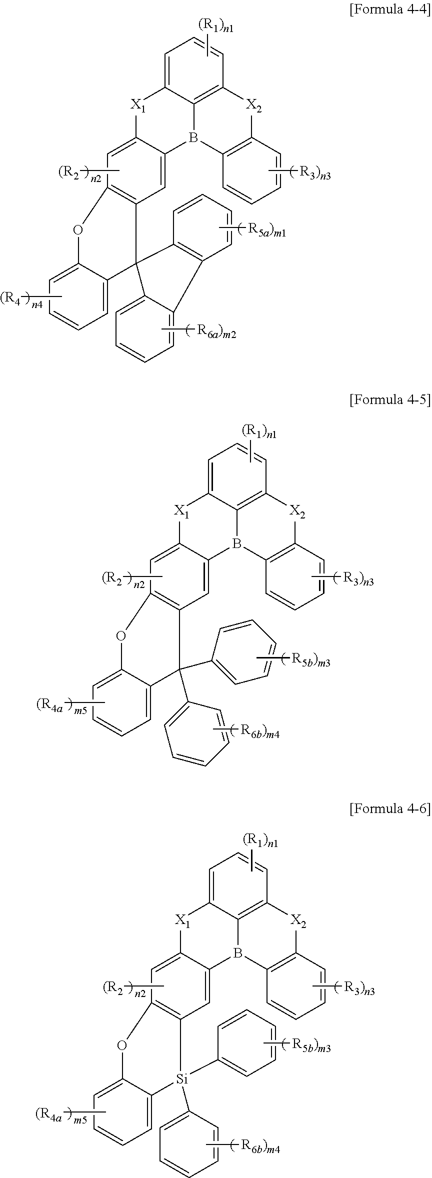
wherein in Formula 4-1 to Formula 4-6,
R₅ₐ, R₆ₐ, R_{5b}, and R_{6b} are each independently a hydrogen atom, a deuterium atom, a halogen atom, a substituted or unsubstituted amine group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
R₄ₐ is a hydrogen atom, a deuterium atom, a halogen atom, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
m1, m2, and m5 are each independently an integer from 0 to 4,
m3 and m4 are each independently an integer from 0 to 5, and
X₁, X₂, R₁ to R₄, and n1 to n4 are each the same as defined in Formula 1.

5. The light emitting device of claim 1, wherein the first compound represented by Formula 1 is represented by one of Formula 5-1 to Formula 5-3: 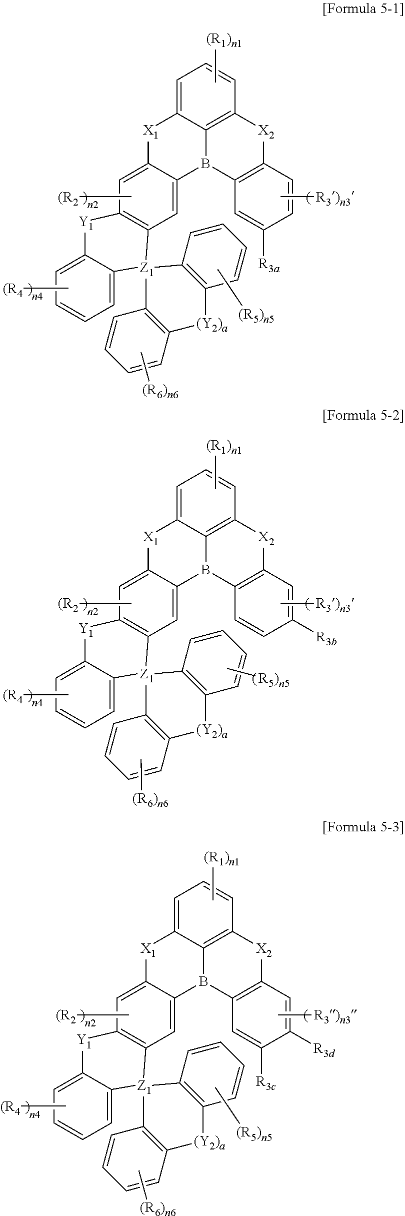
wherein in Formula 5-1 to Formula 5-3,
R₃ₐ and R_{3b} are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₃′ and R₃″ are each independently a hydrogen atom, a deuterium atom, a halogen atom, a substituted or unsubstituted amine group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
n3′ is an integer from 0 to 3,
n3″ is an integer from 0 to 2, and
R_{3c} and R_{3d} each represent a bonding position of a moiety represented by Formula 6, 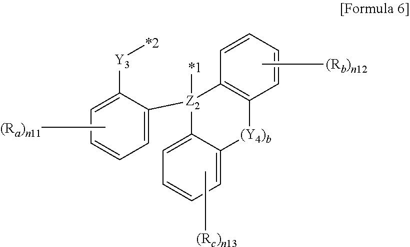
wherein in Formula 6,
-*1 is a bonding position to R_{3c} in Formula 5-3,
-*2 is a bonding position to R_{3d} in Formula 5-3,
Y₃ is a direct linkage or O,
Y₄ is a direct linkage, O, or N(R_{d}),
Z₂ is C or Si,
when Z₂ is Si, Y₃ is O,
Rₐ to R_{c} are each independently a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n11 to n13 are each independently an integer from 0 to 4,
b is 0 or 1,
when b is 0, Rₐ is not a substituted or unsubstituted amine group,
the sum of b and n12 is 5 or less,
the sum of b and n13 is 5 or less, and
in Formula 5-1 to Formula 5-3, X₁, X₂, Z₁, Y₁, Y₂, a, R₁, R₂, R₄ to R₆, n1, n2, and n4 to n6 are each the same as defined in Formula 1.

6. The light emitting device of claim 5, wherein in Formula 5-1 and Formula 5-2,
R₃ₐ and R_{3b} are each independently a substituted or unsubstituted alkyl group having 1 to 10 carbon atoms, or a group represented by one of Formula 7-1 to Formula 7-3: 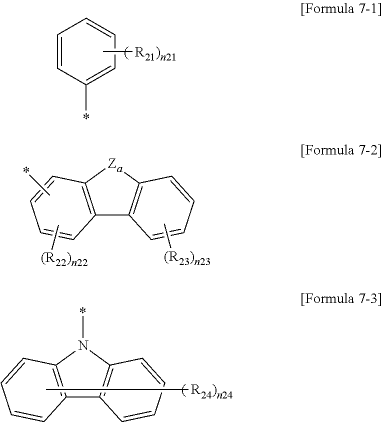
wherein in Formula 7-1 to Formula 7-3,
Zₐ is N(R₂₅) or O,
R₂₁ to R₂₅ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n21 is an integer from 0 to 5,
n22 is an integer from 0 to 3,
n23 is an integer from 0 to 4,
n24 is an integer from 0 to 8, and
-* is a bonding position to Formula 5-1 or Formula 5-2.

7. The light emitting device of claim 1, wherein the first compound represented by Formula 1 is represented by Formula 8: 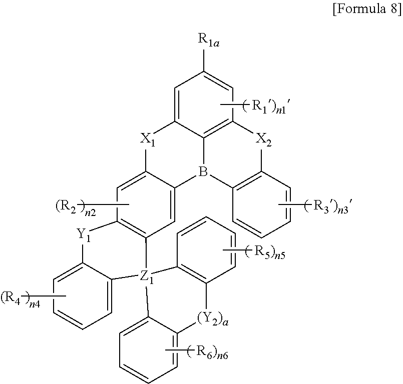
wherein in Formula 8,
R₁ₐ is a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₁′ is a hydrogen atom, a deuterium atom, a halogen atom, a substituted or unsubstituted amine group, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n1′ is an integer from 0 to 2, and
X₁, X₂, Z₁, Y₁, Y₂, a, R₂ to R₆, and n2 to n6 are each the same as defined in Formula 1.

8. The light emitting device of claim 1, wherein in Formula 1,
R₁ is a substituted or unsubstituted alkyl group having 1 to 10 carbon atoms, or a group represented by one of Formula 9-1 to Formula 9-6: 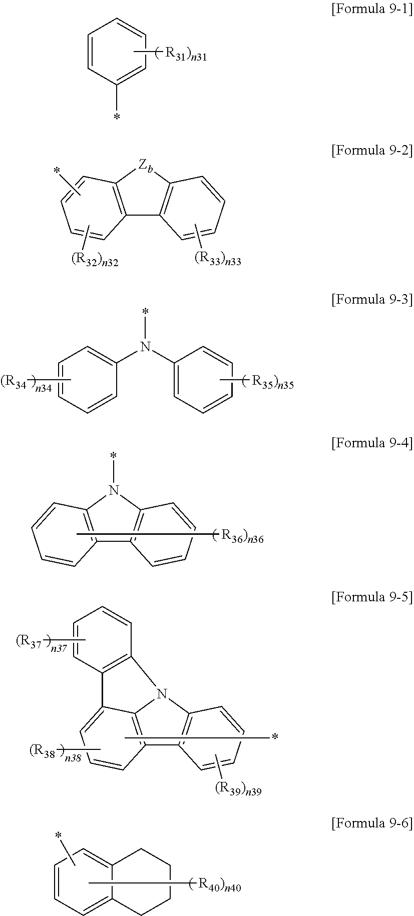
wherein in Formula 9-1 to Formula 9-6,
Z_{b} is N(R₄₁) or O,
R₃₁ to R₄₁ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n31 is an integer from 0 to 5,
n32 and n38 are each independently an integer from 0 to 3,
n33, n37 and n39 are each independently an integer from 0 to 4,
n34 and n35 are each independently an integer from 0 to 5,
the sum of n38 and n39 is 6 or less,
n36 is an integer from 0 to 8,
n40 is an integer from 0 to 11, and
-* is a bonding position to Formula 1.

9. The light emitting device of claim 1, wherein the first compound represented by Formula 1 comprises at least one compound selected from Compound Group 1:
[Compound Group 1] 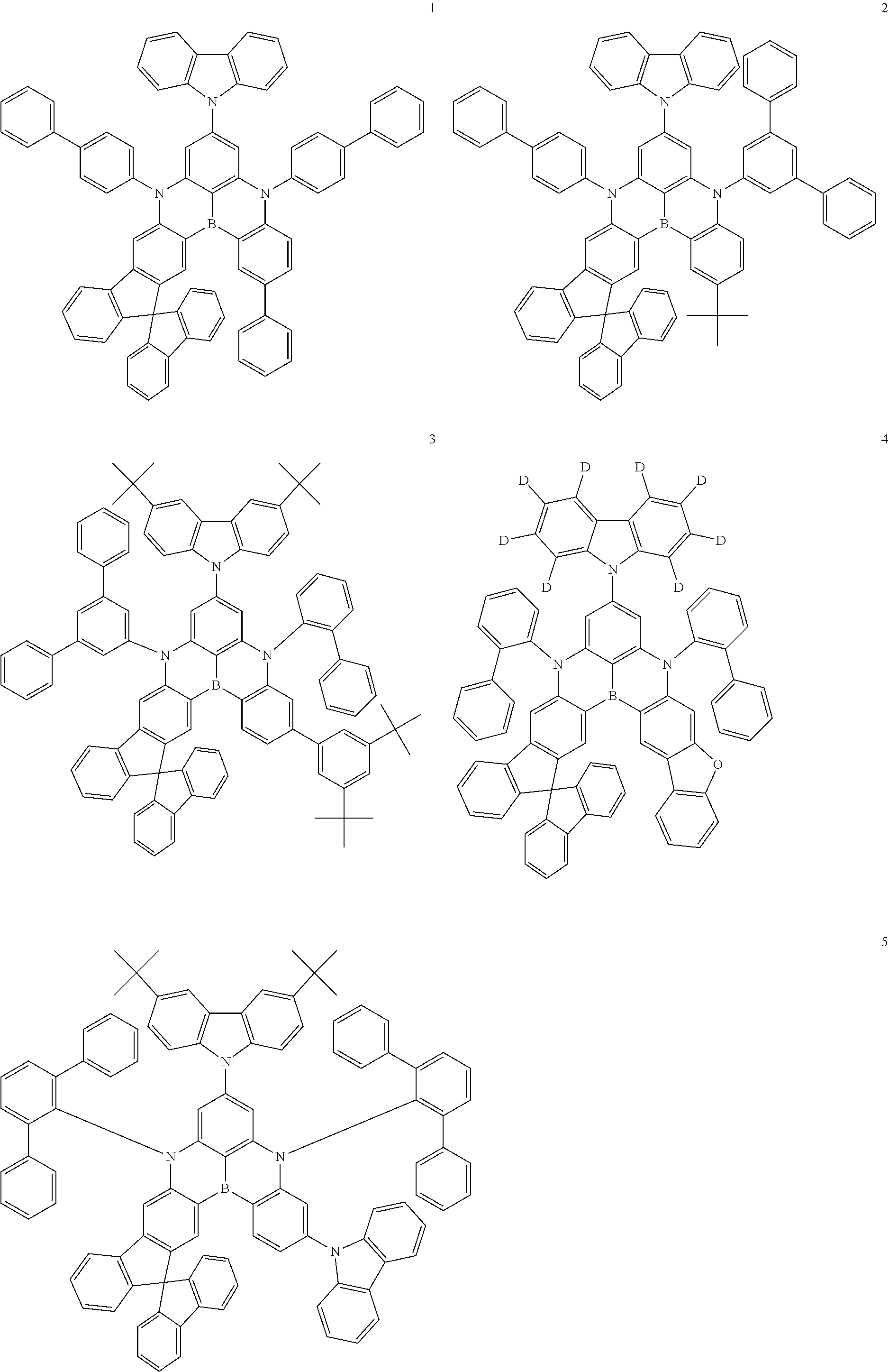 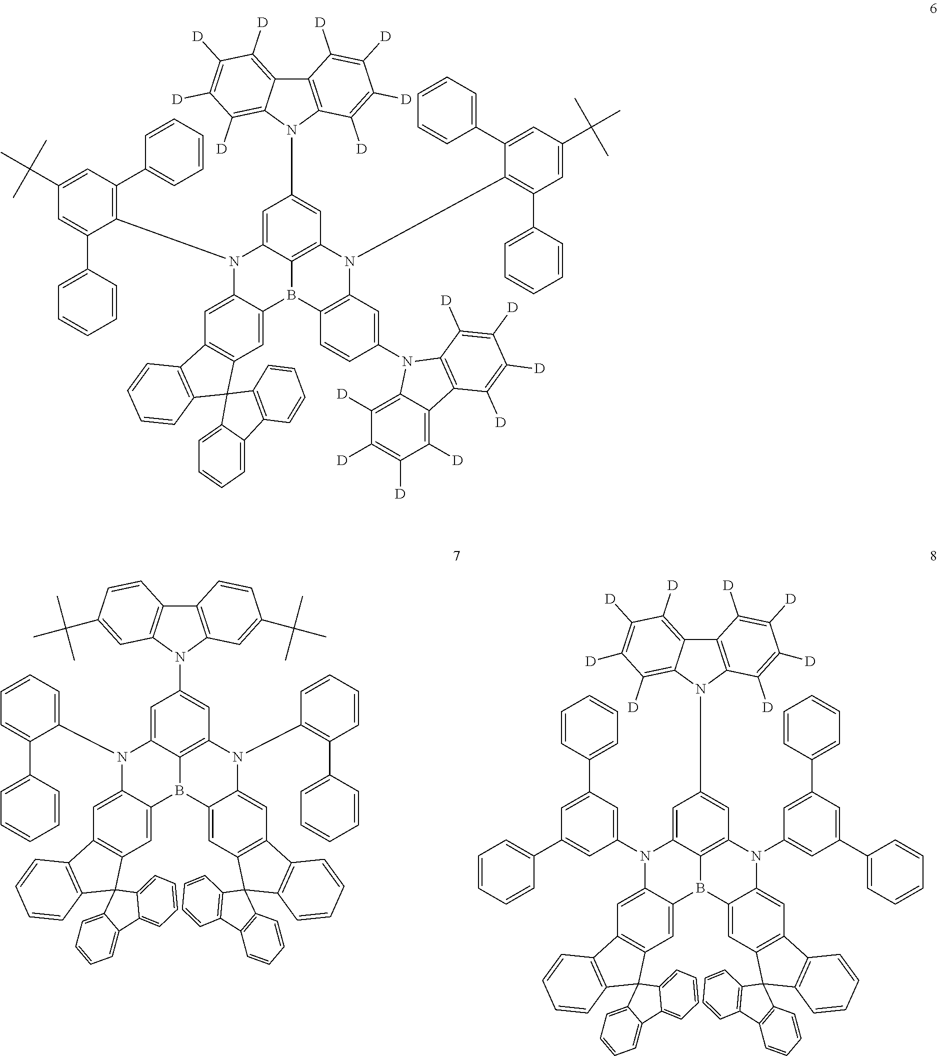 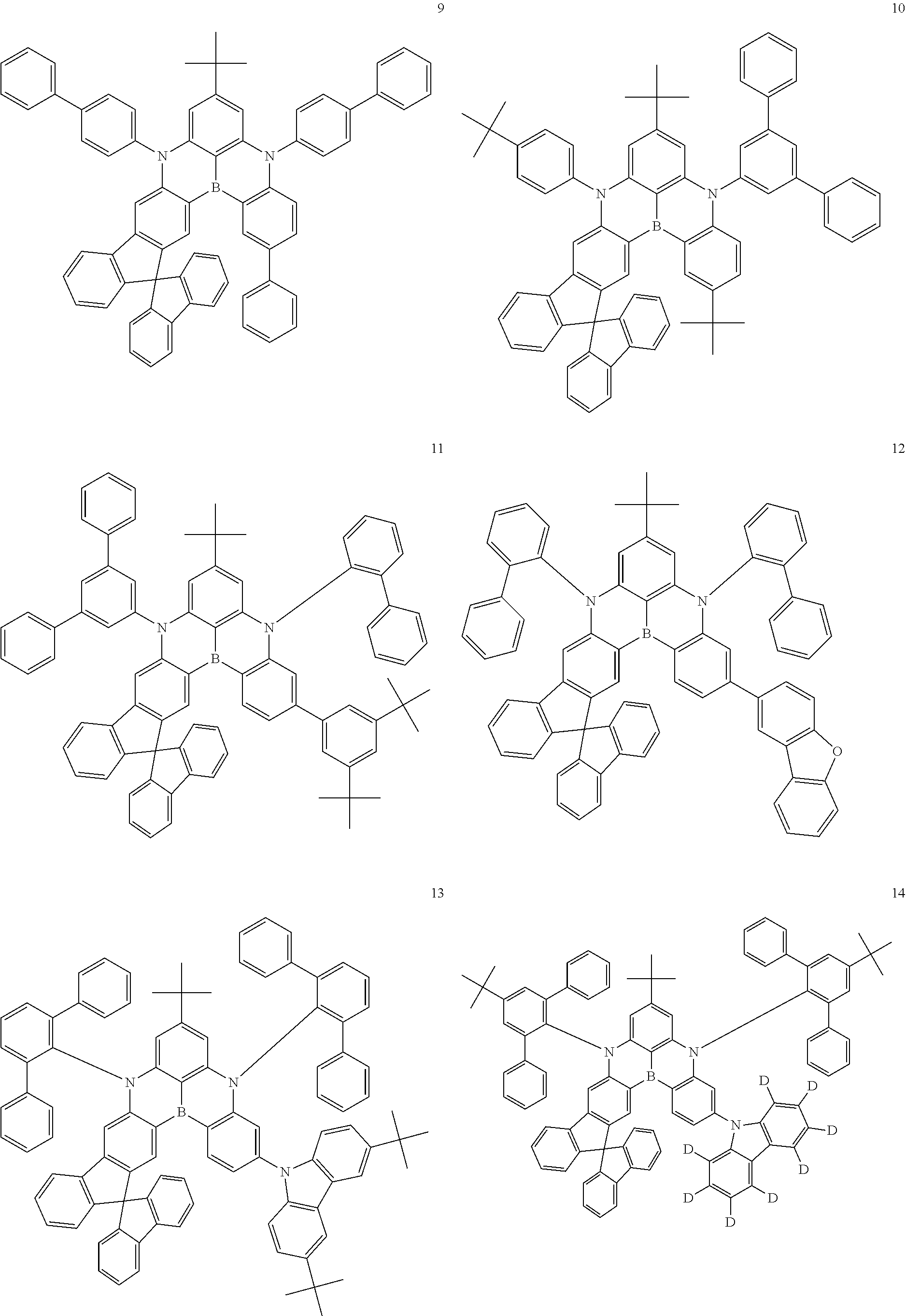 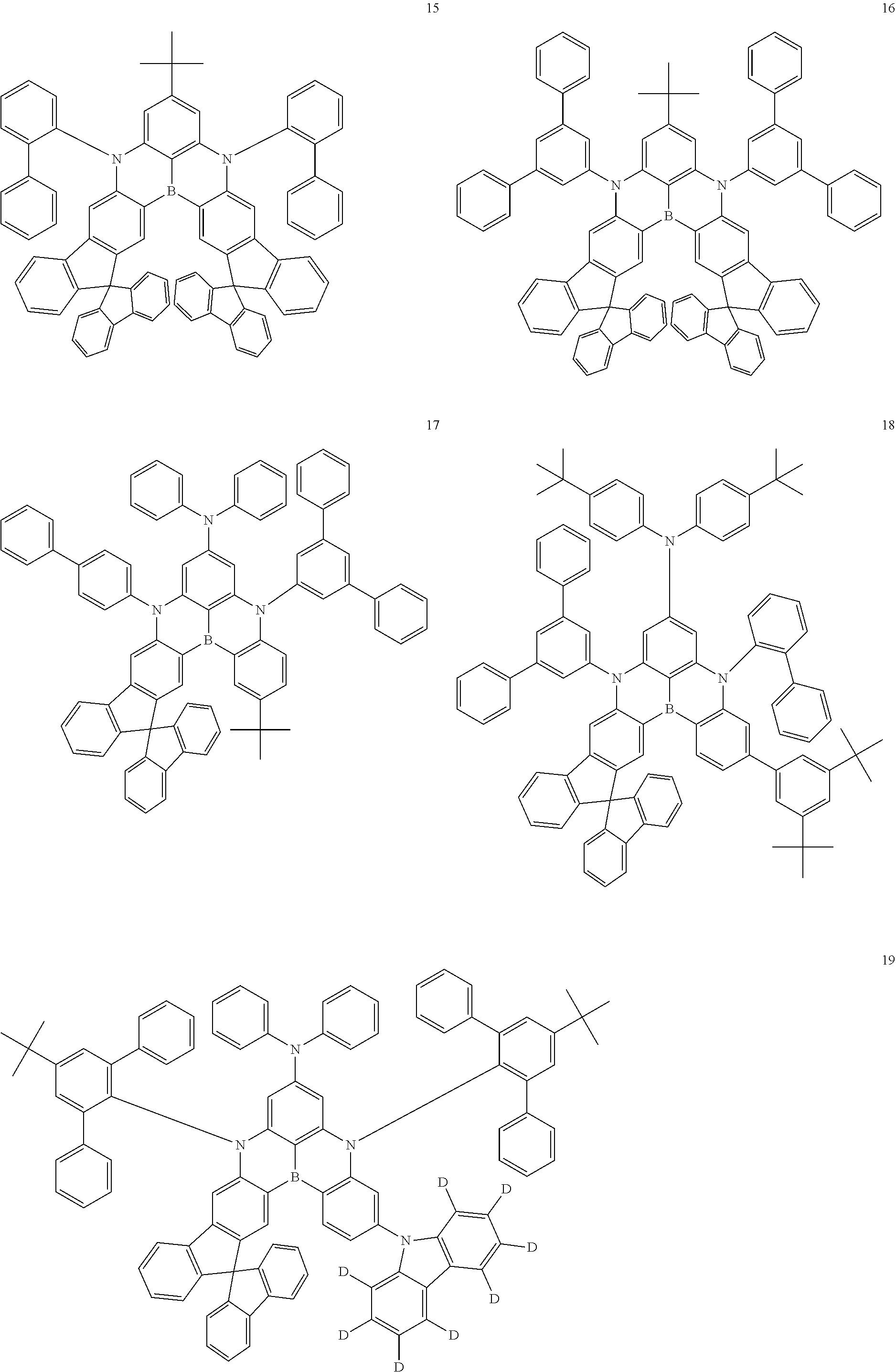 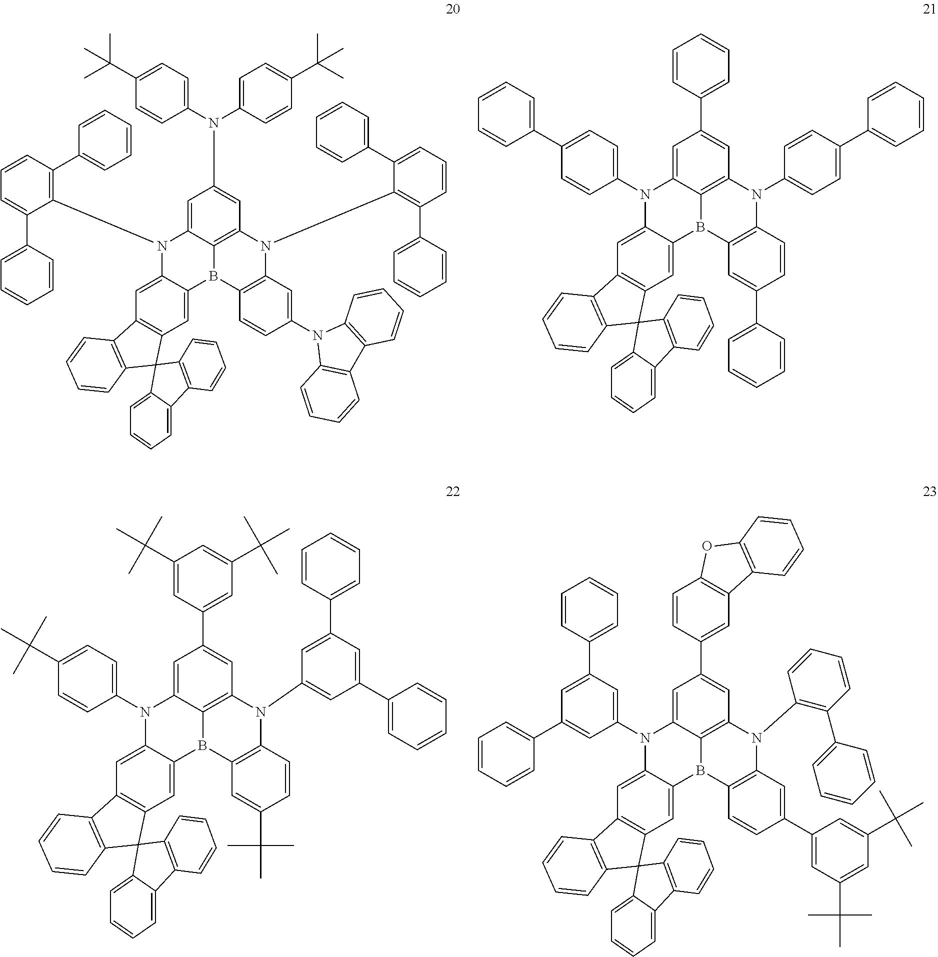 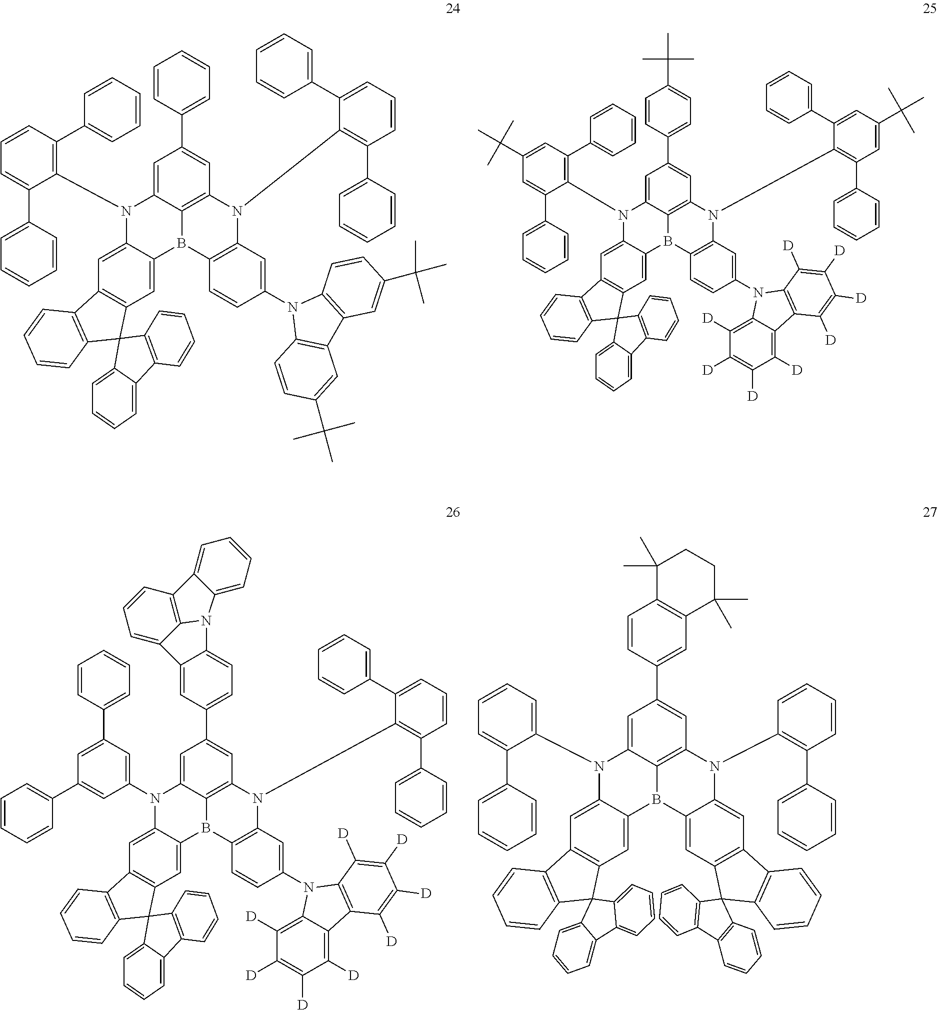 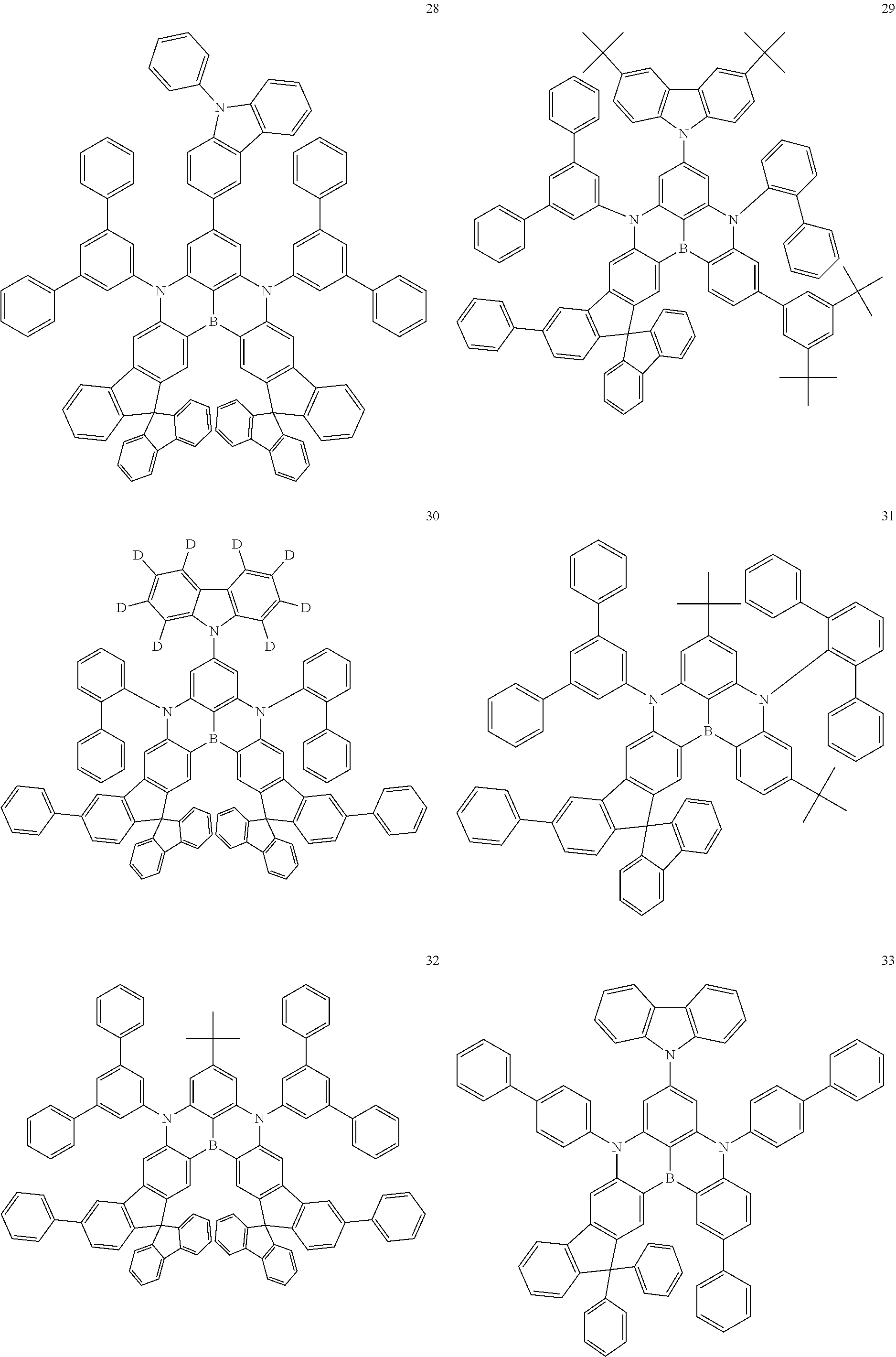 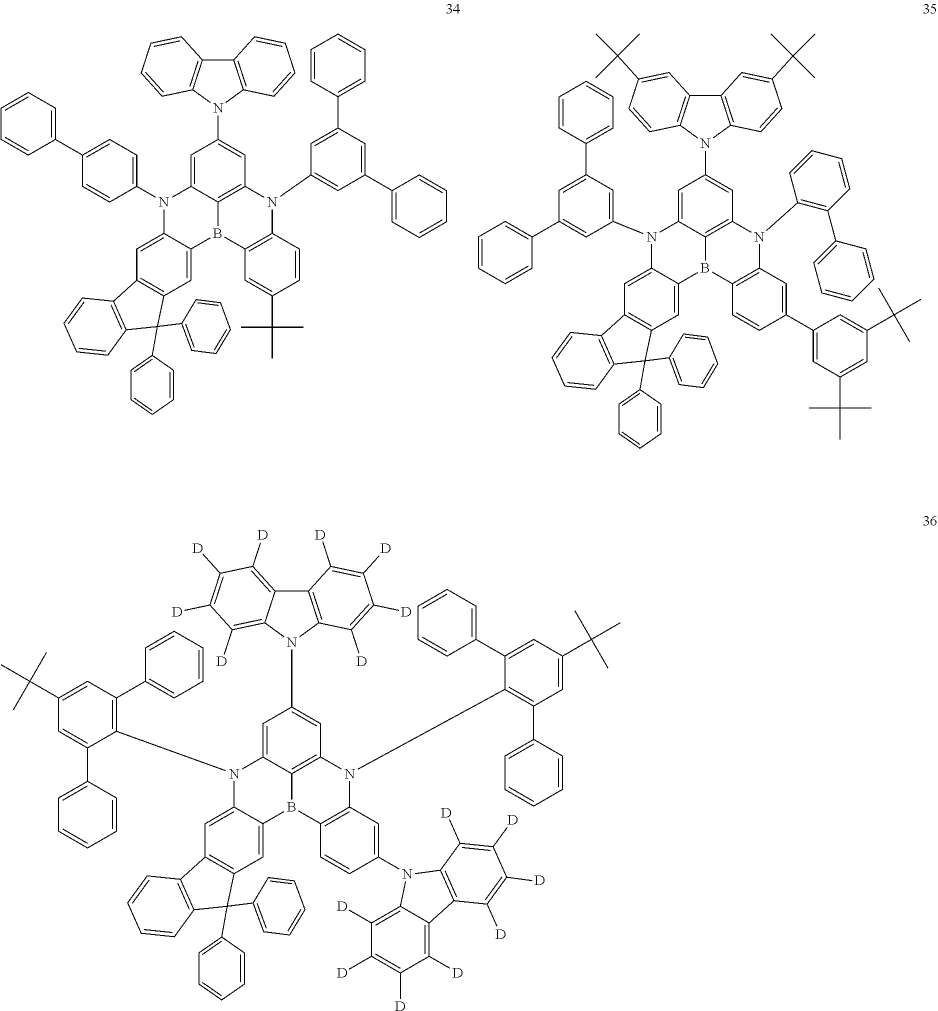 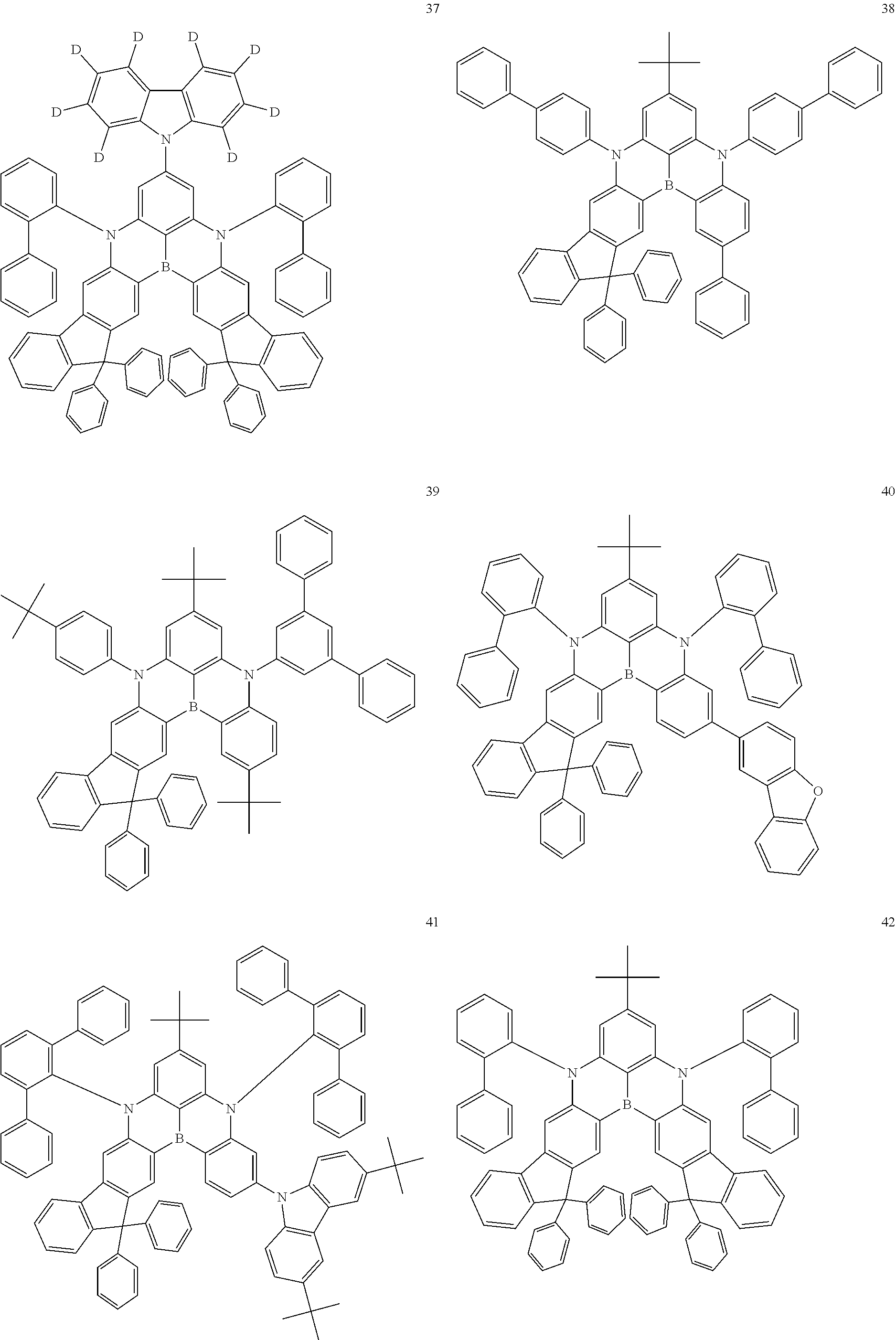 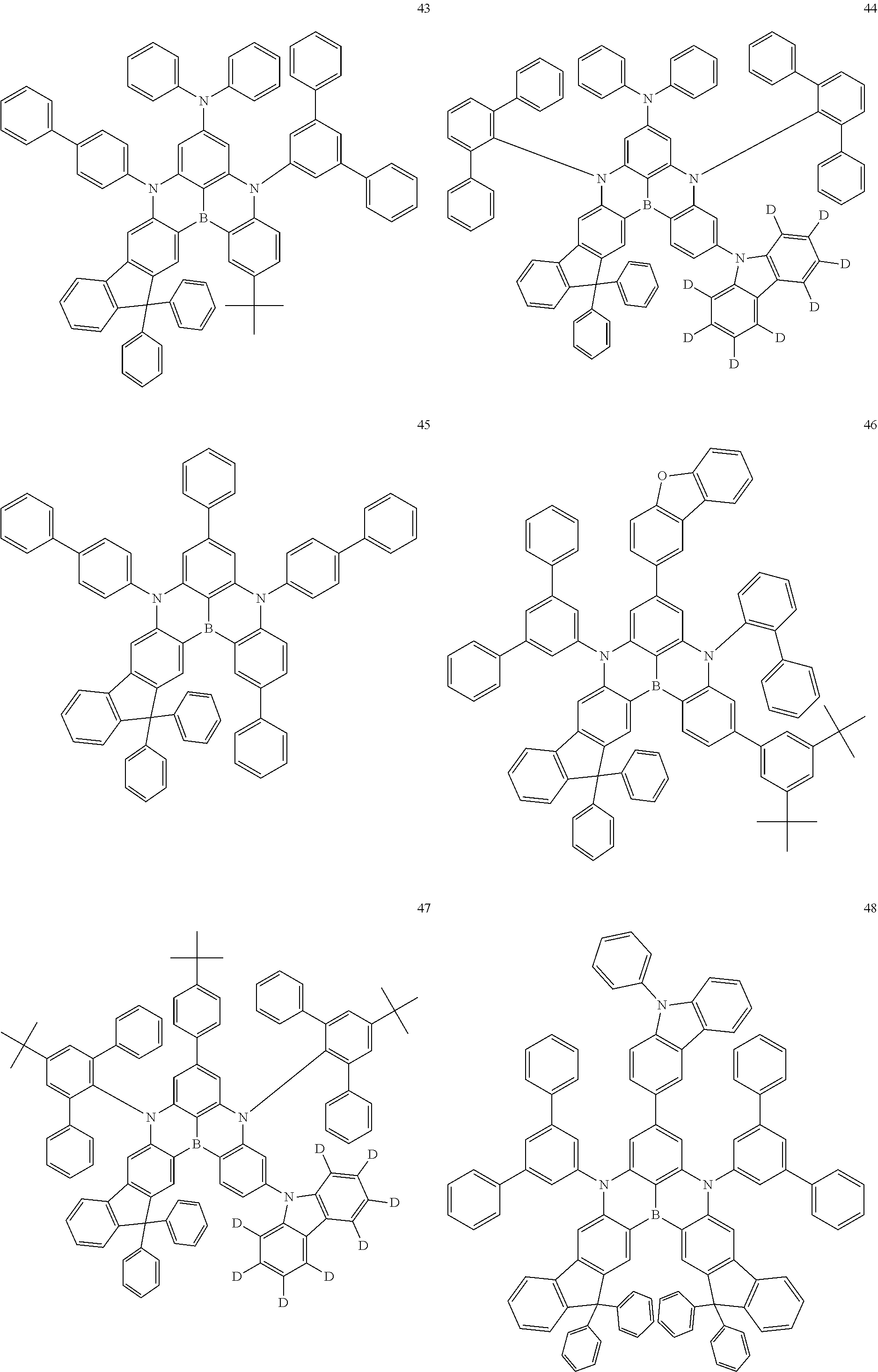 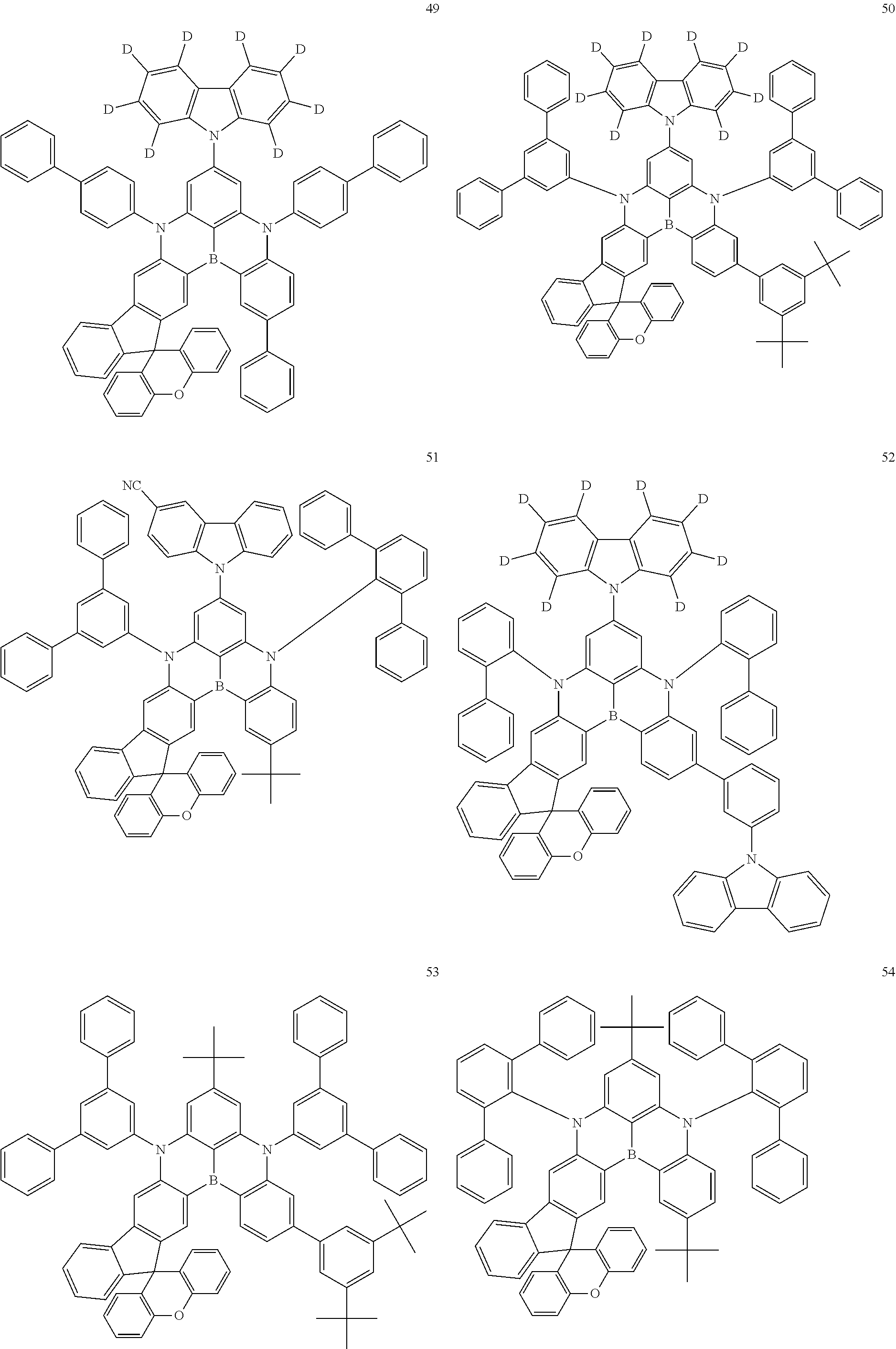 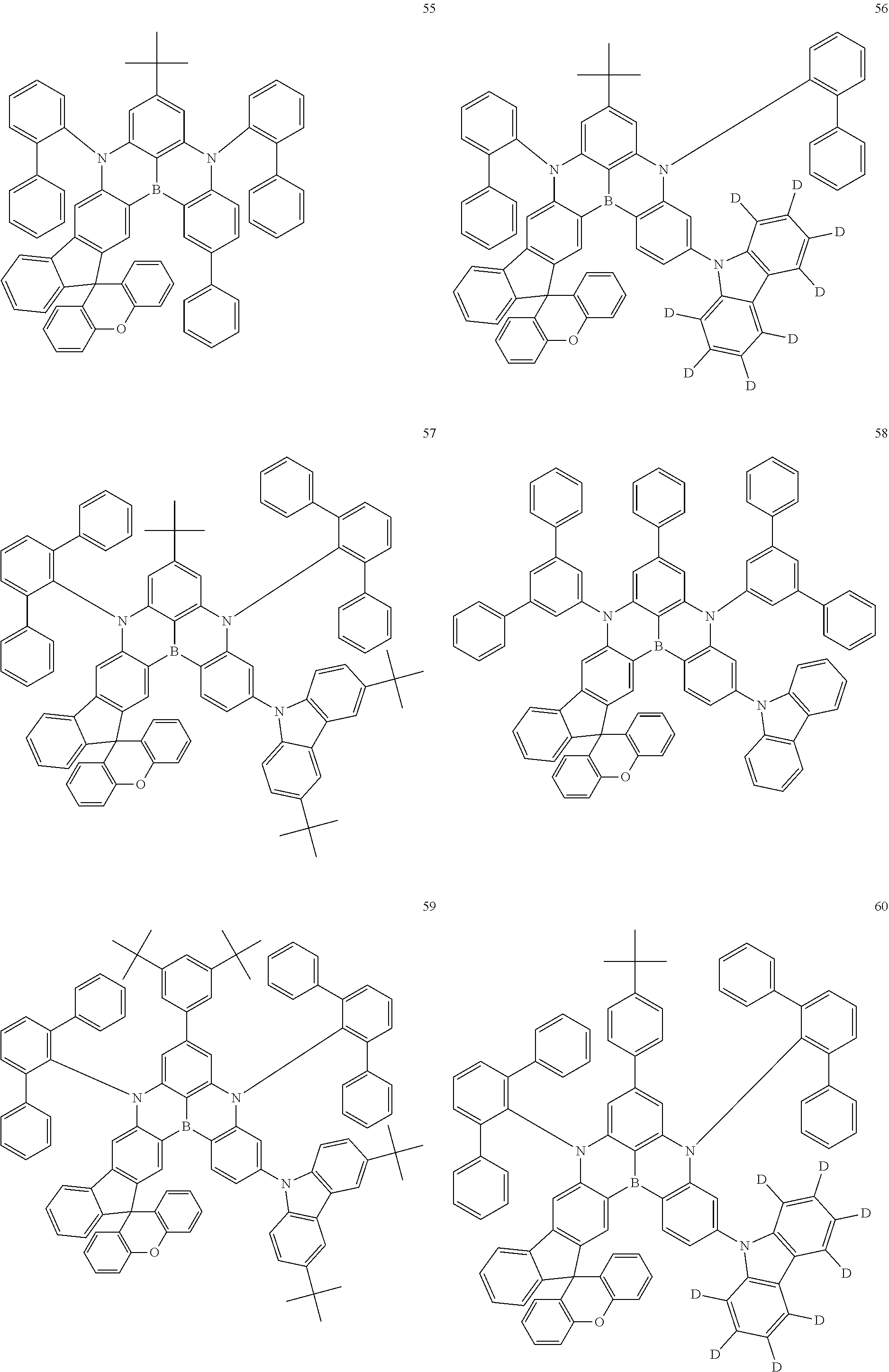 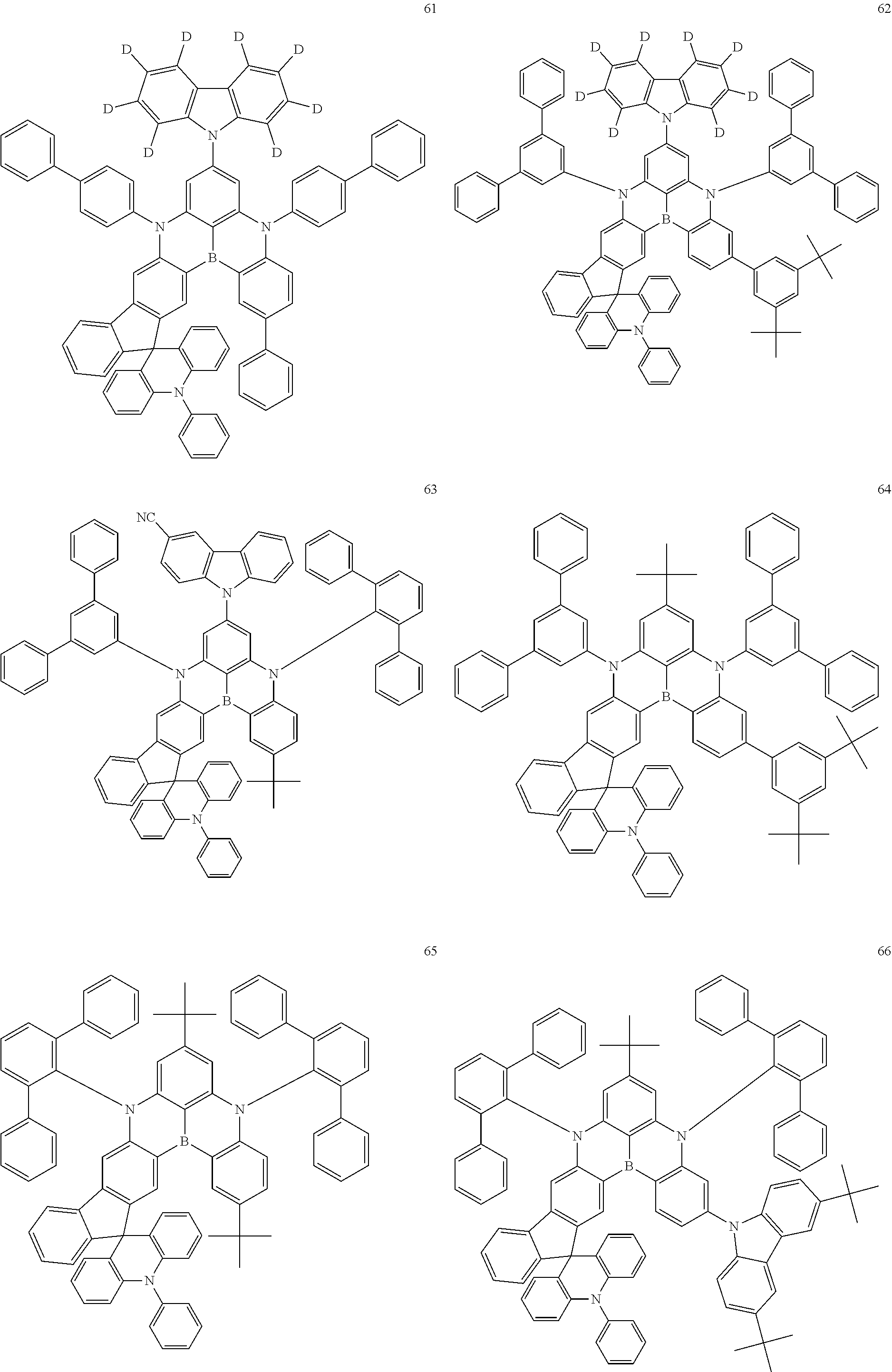 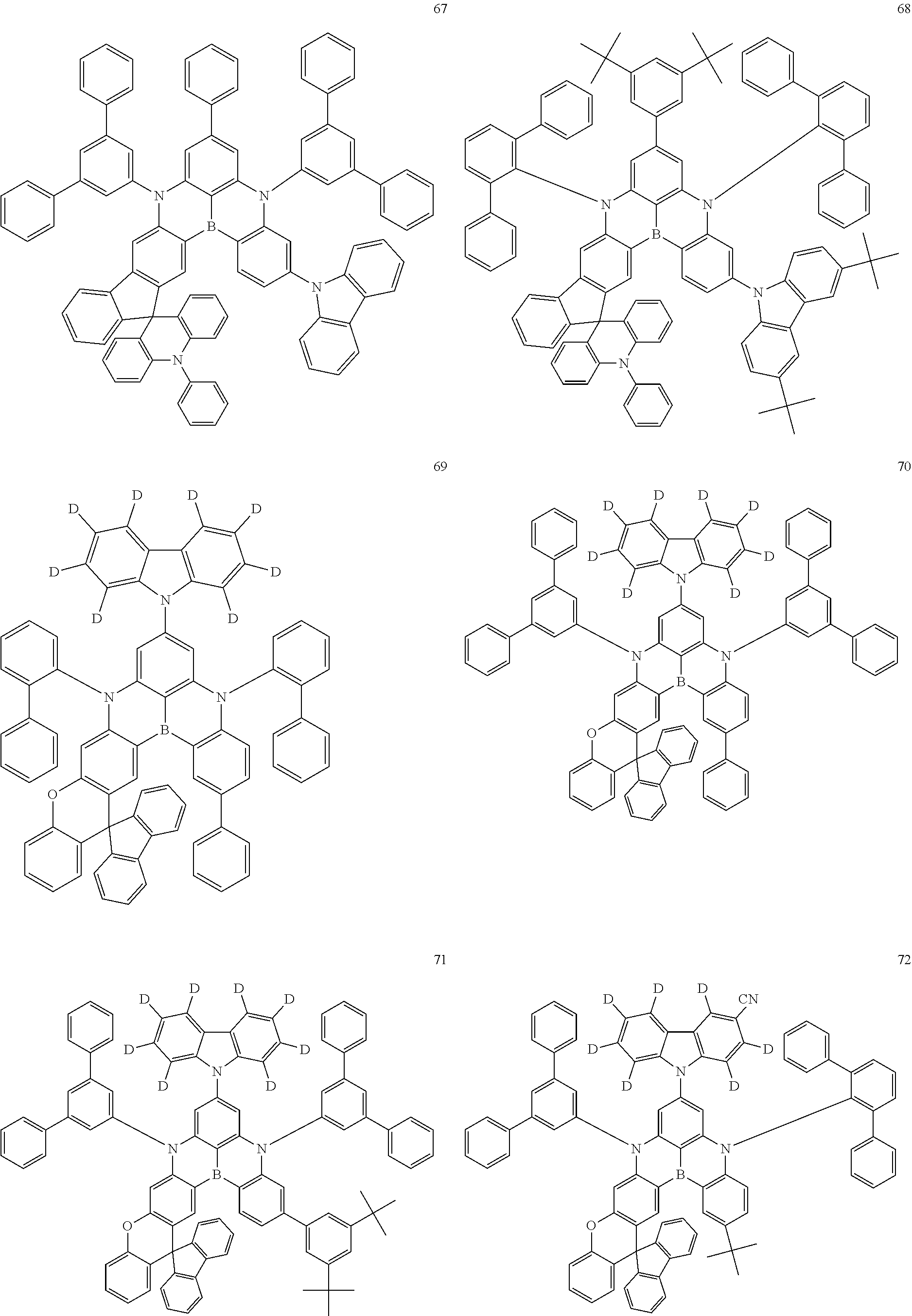 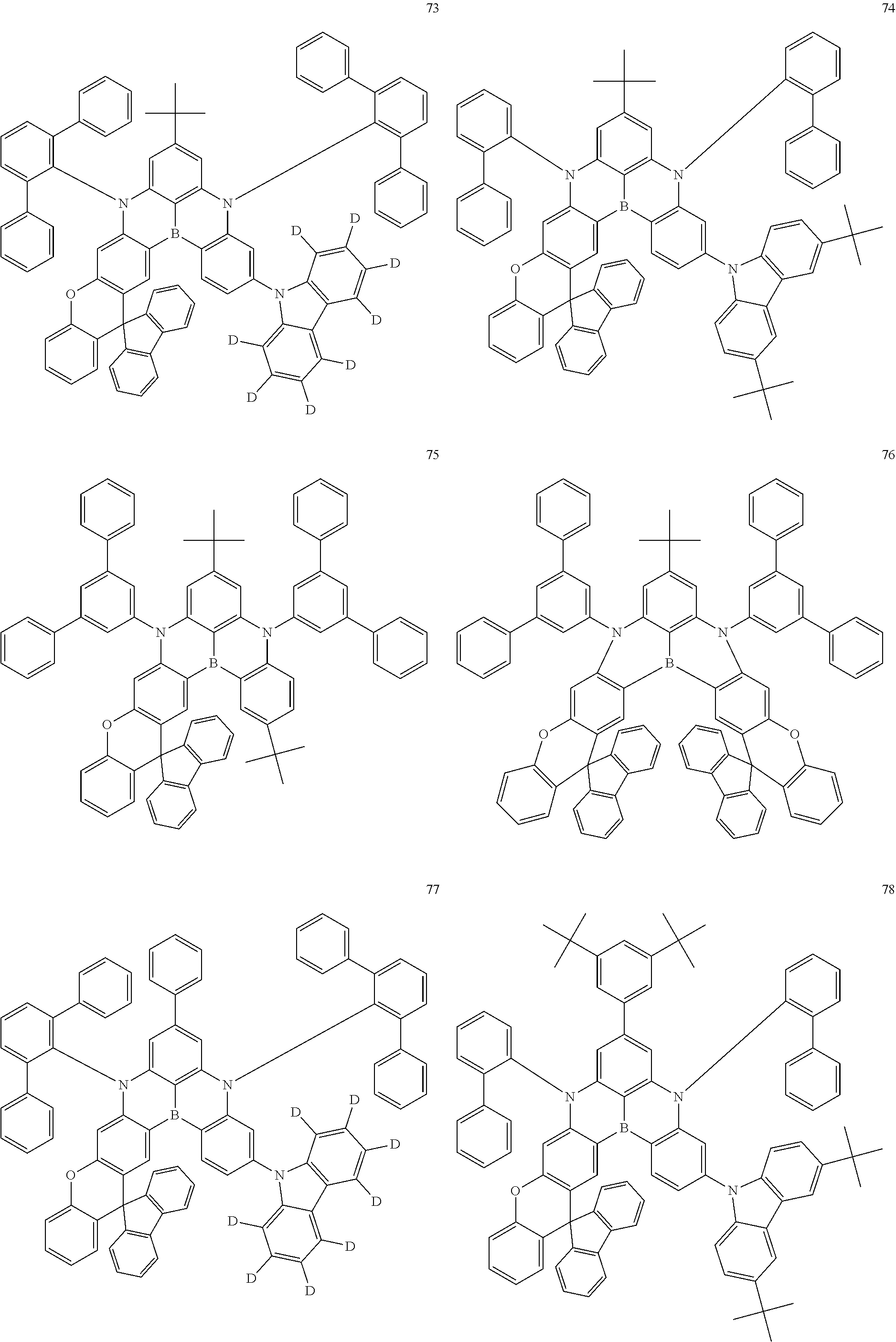 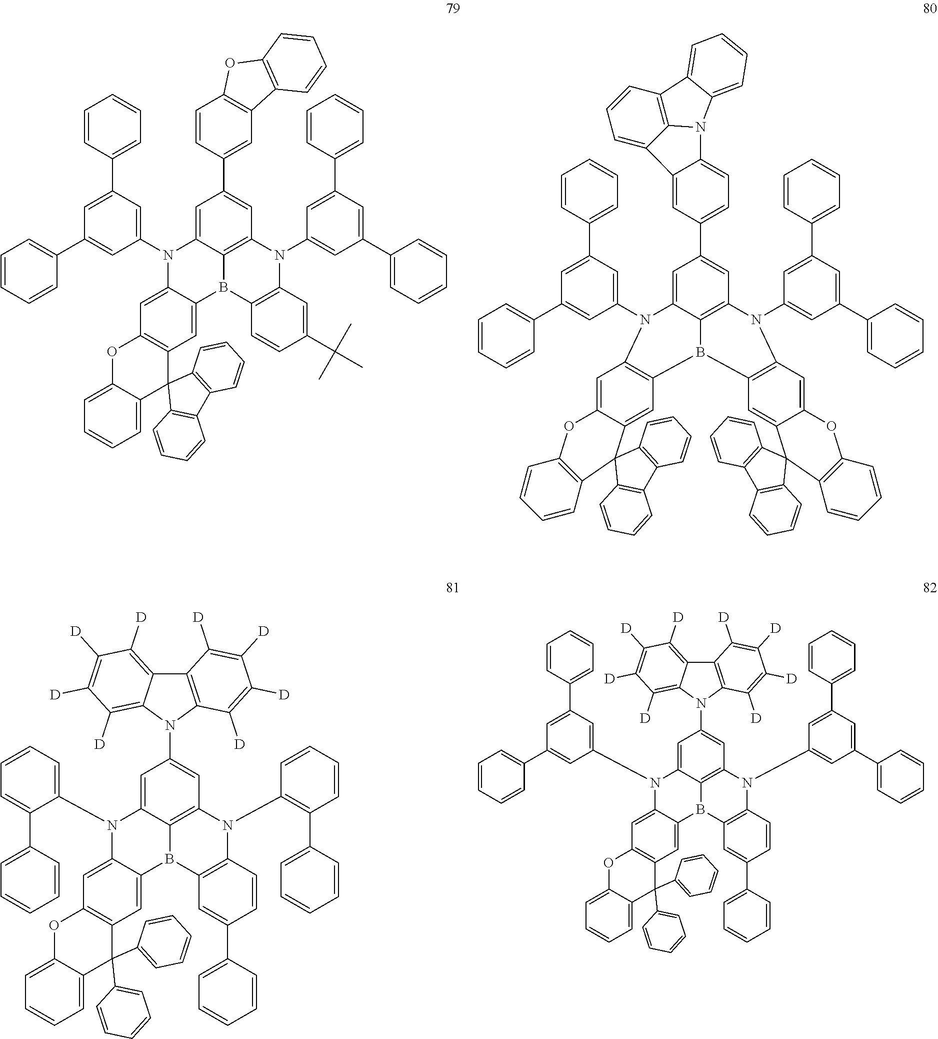 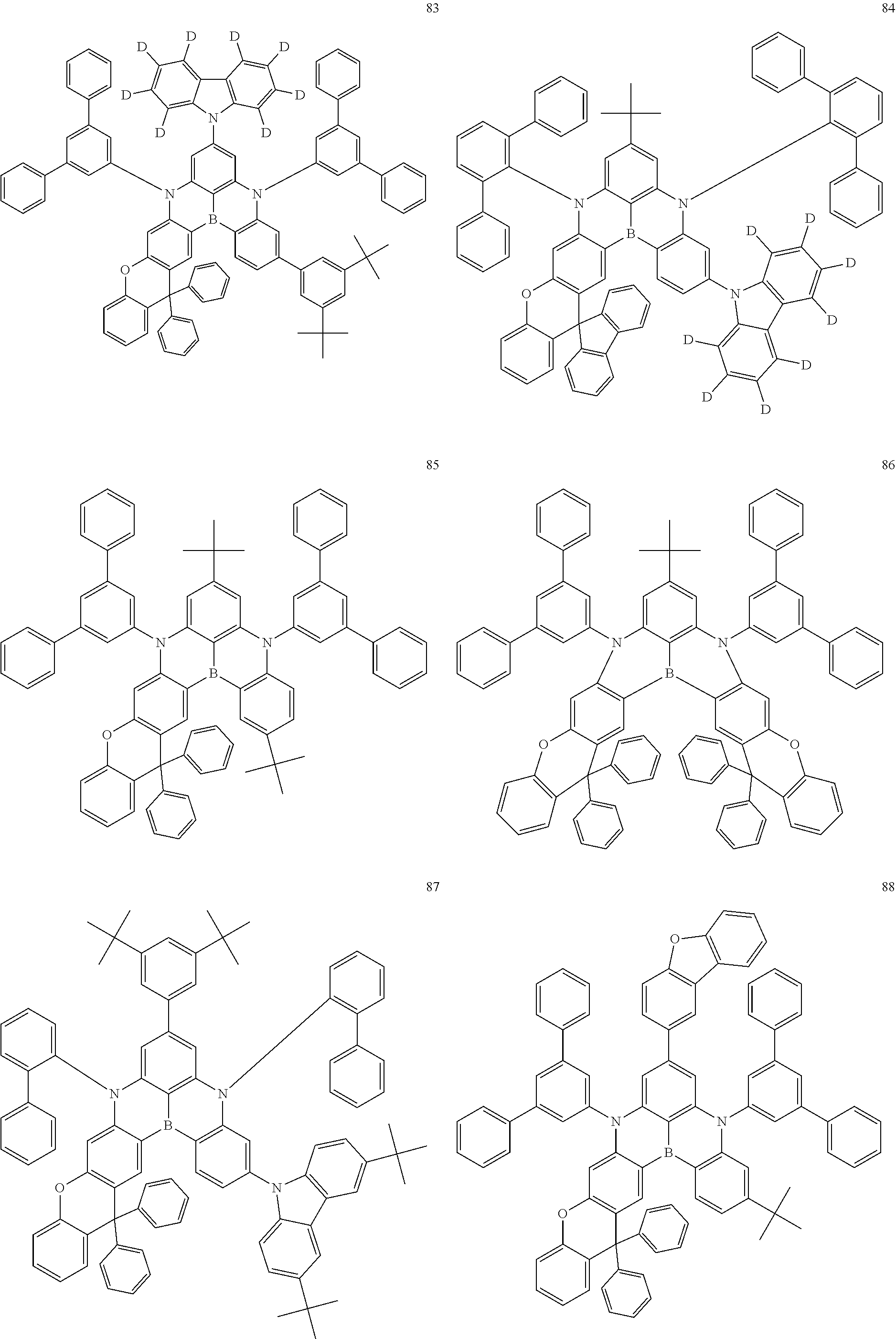 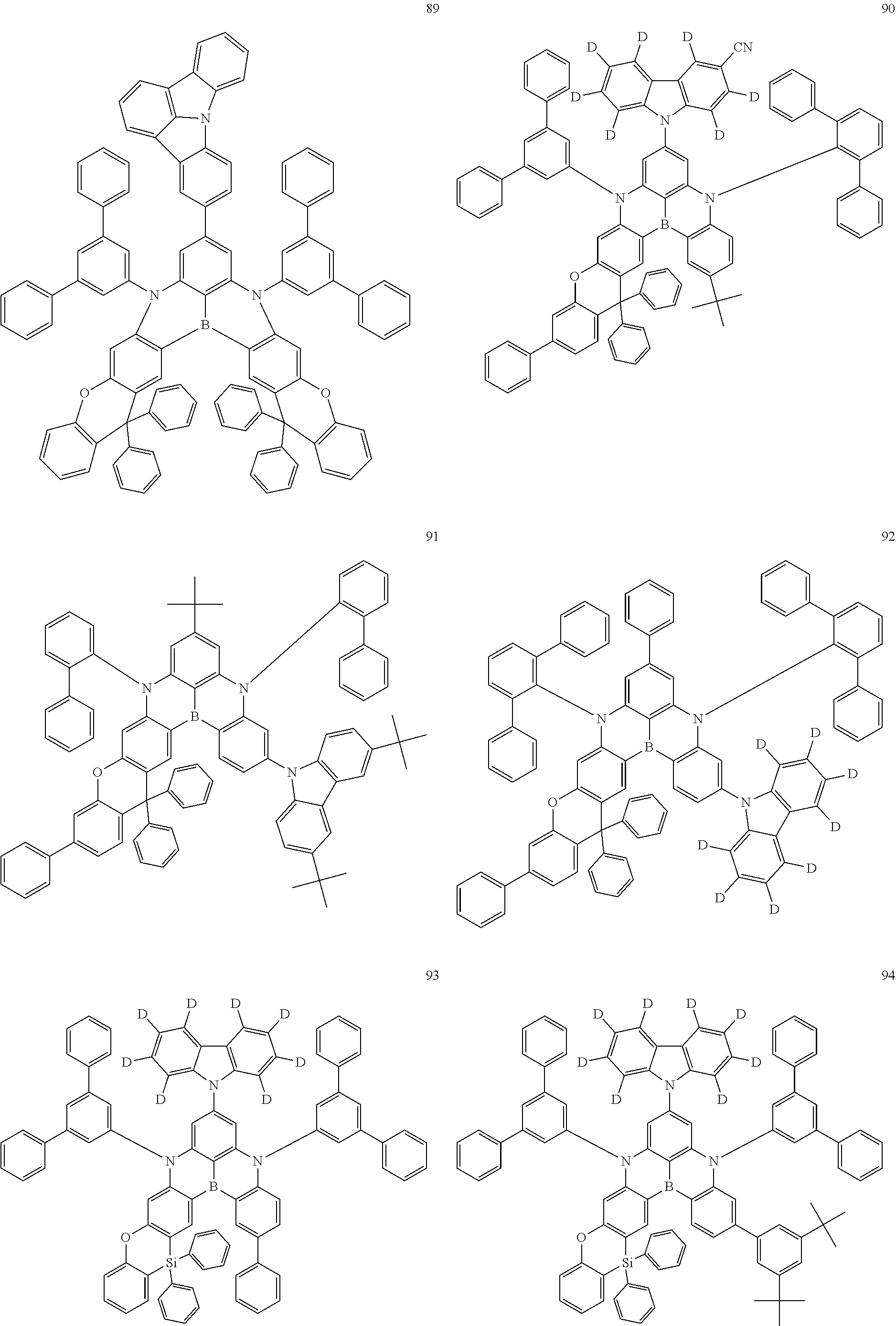 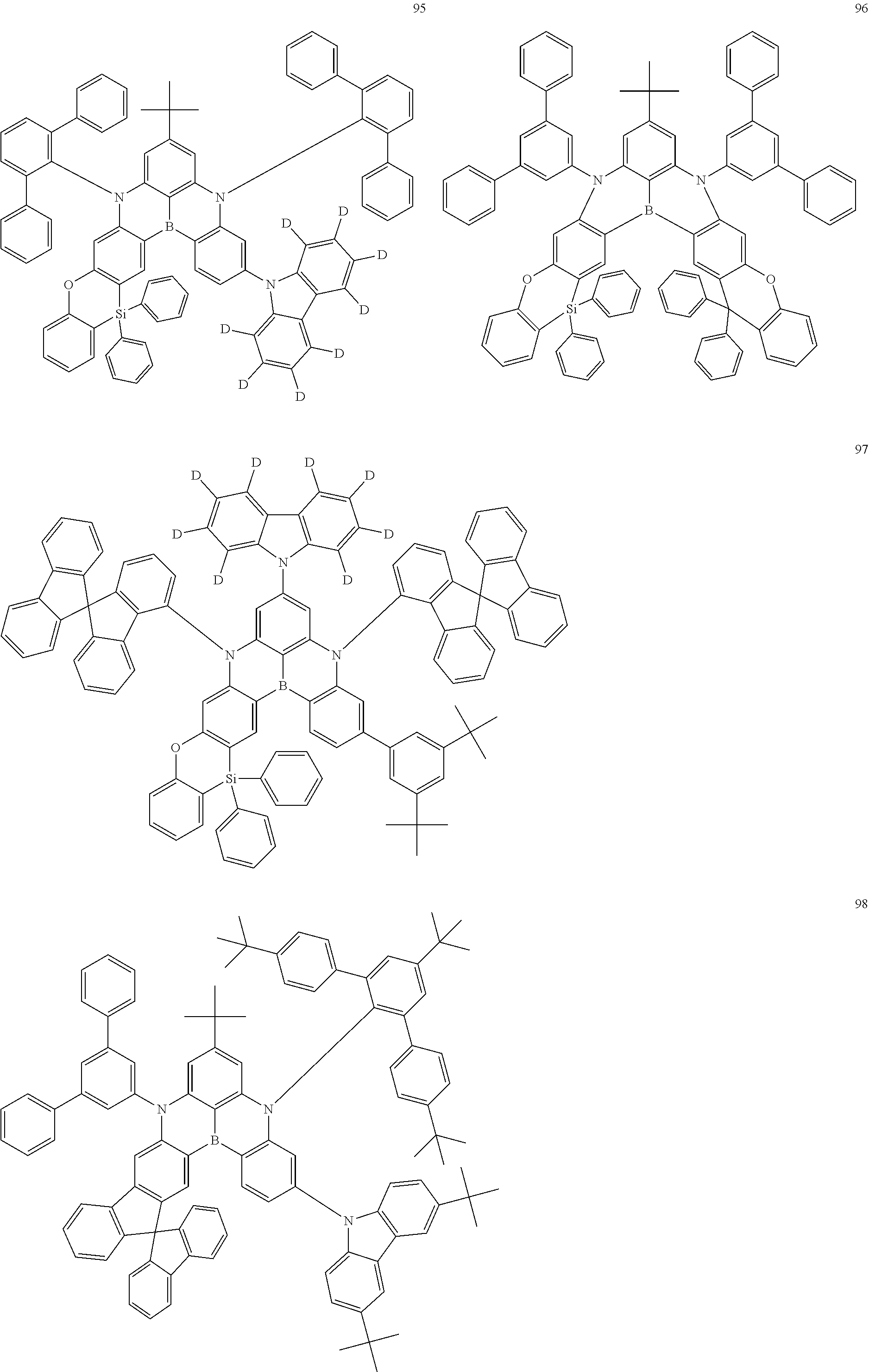
wherein in Compound Group 1,
D represents a deuterium atom.

10. The light emitting device of claim 1, wherein the emission layer further comprises a second compound represented by Formula H-1: 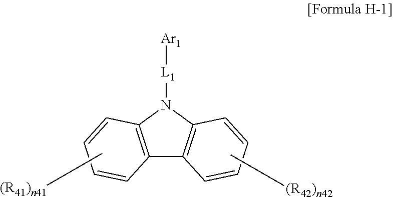
wherein in Formula H-1,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Ar₁ is a substituted or unsubstituted aryl group having 6 to 30 ring-forming carbon atoms, or a substituted or unsubstituted heteroaryl group having 2 to 30 ring-forming carbon atoms,
R₄₁ and R₄₂ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or are bonded to an adjacent group to form a ring, and
n41 and n42 are each independently an integer from 0 to 4.

11. The light emitting device of claim 1, wherein the emission layer further comprises a third compound represented by Formula H-2: 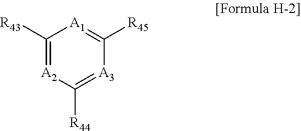
wherein in Formula H-2,
A₁ to A₃ are each independently N or C(R₄₆),
at least one of A₁ to A₃ is N, and
R₄₃ to R₄₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or are bonded to an adjacent group to form a ring.

12. The light emitting device of claim 1, wherein the emission layer further comprises a fourth compound represented by Formula D-1: 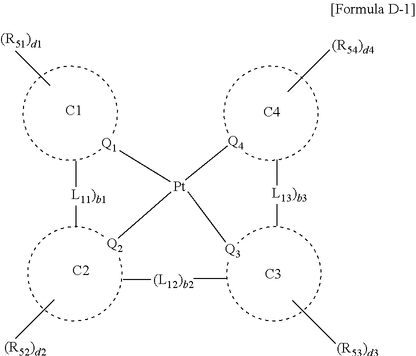
wherein in Formula D-1,
Q₁ to Q₄ are each independently C or N,
C1 to C4 are each independently a substituted or unsubstituted hydrocarbon ring having 5 to 30 ring-forming carbon atoms, or a substituted or unsubstituted heterocycle having 2 to 30 ring-forming carbon atoms,
L₁₁ to L₁₃ are each independently a direct linkage, *—θ-*, *—S—*, 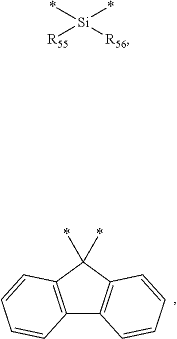
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b1 to b3 are each independently 0 or 1,
R₅₁ to R₅₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or are bonded to an adjacent group to form a ring, and
d1 to d4 are each independently an integer from 0 to 4.

13. A fused polycyclic compound represented by Formula 1: 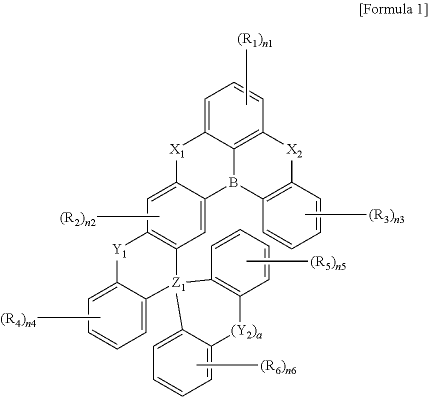
wherein in Formula 1,
X₁ and X₂ are each N(R₇),
Y₁ is a direct linkage or O,
Y₂ is a direct linkage, O, or N(R₈),
Z₁ is C or Si,
when Z₁ is Si, Y₁ is O,
R₁ to R₈ are each independently a hydrogen atom, a deuterium atom, a halogen atom, a substituted or unsubstituted amine group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or are bonded to an adjacent group to form a ring,
a is 0 or 1,
when a is 0, R₄ is not a substituted or unsubstituted amine group,
n1 is an integer from 0 to 3,
n2 is an integer from 0 to 2,
n3 and n4 are each independently an integer from 0 to 4,
n5 and n6 are each independently an integer from 0 to 5,
the sum of a and n5 is 5 or less, and
the sum of a and n6 is 5 or less.

14. The fused polycyclic compound of claim 13, wherein the fused polycyclic compound represented by Formula 1 is represented by one of Formula 2-1 to Formula 2-4: 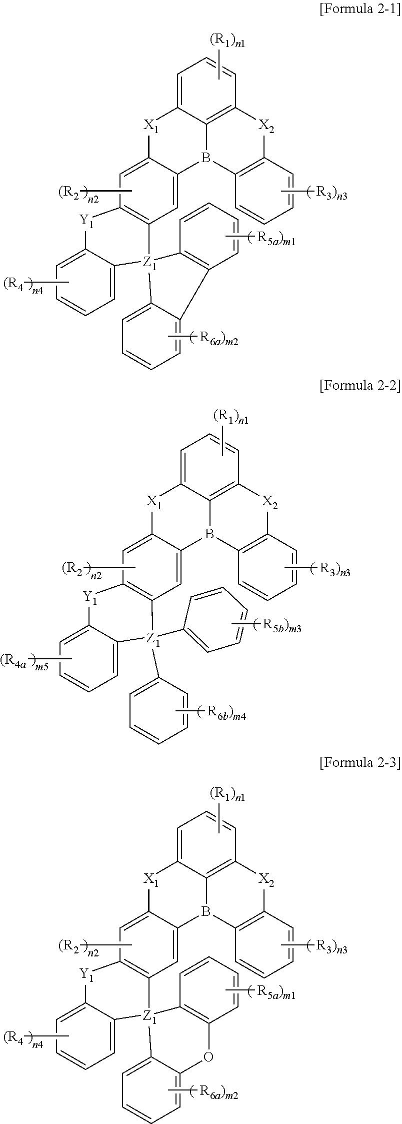 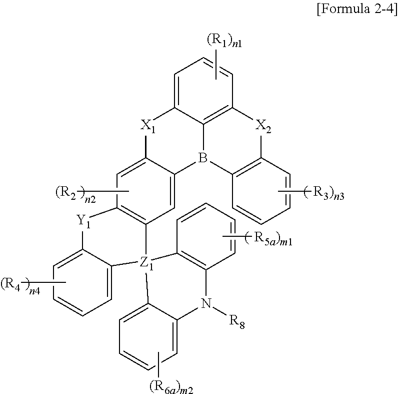
wherein in Formula 2-1 to Formula 2-4,
R₅ₐ, R₆ₐ, R_{5b}, and R_{6b} are each independently a hydrogen atom, a deuterium atom, a halogen atom, a substituted or unsubstituted amine group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
R₄ₐ is a hydrogen atom, a deuterium atom, a halogen atom, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
m1, m2, and m5 are each independently an integer from 0 to 4,
m3 and m4 are each independently an integer from 0 to 5, and
X₁, X₂, Y₁, Z₁, R₁ to R₄, and n1 to n4 are each the same as defined in Formula 1.

15. The fused polycyclic compound of claim 13, wherein the fused polycyclic compound represented by Formula 1 is represented by one of Formula 3-1 to Formula 3-3: 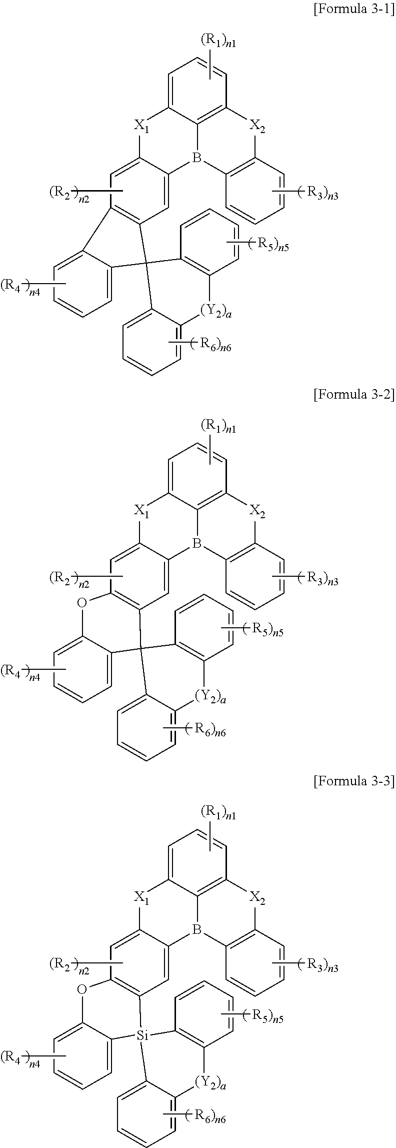
wherein in Formula 3-1 to Formula 3-3,
X₁, X₂, Y₂, a, R₁ to R₆, and n1 to n6 are each the same as defined in Formula 1.

16. The fused polycyclic compound of claim 13, wherein the fused polycyclic compound represented by Formula 1 is represented by one of Formula 4-1 to Formula 4-6: 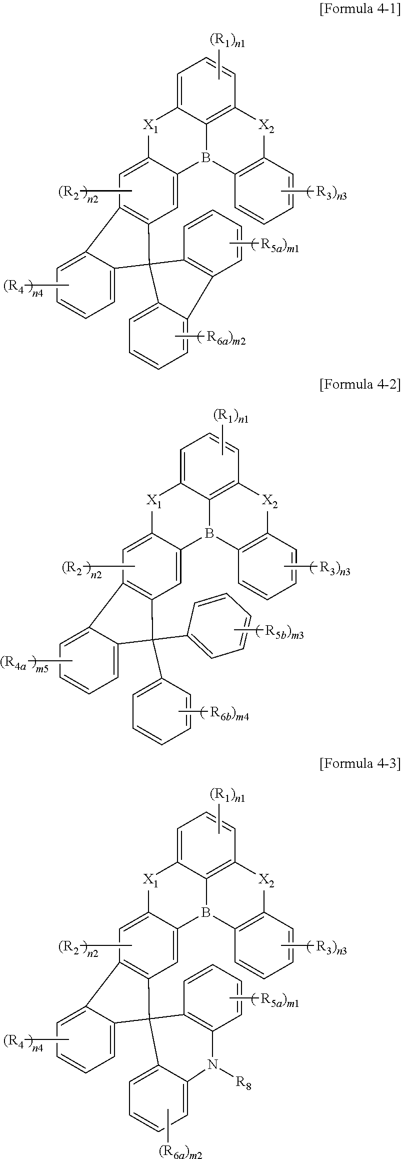 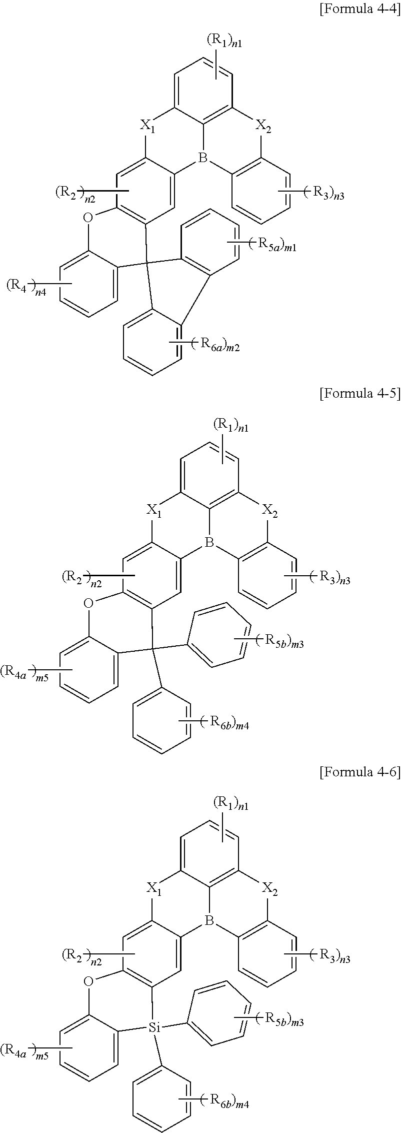
wherein in Formula 4-1 to Formula 4-6,
R₅ₐ, R₆ₐ, R_{5b}, and R_{6b} are each independently a hydrogen atom, a deuterium atom, a halogen atom, a substituted or unsubstituted amine group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
R₄ₐ is a hydrogen atom, a deuterium atom, a halogen atom, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
m1, m2, and m5 are each independently an integer from 0 to 4,
m3 and m4 are each independently an integer from 0 to 5, and
X₁, X₂, R₁ to R₄, and n1 to n4 are each the same as defined in Formula 1.

17. The fused polycyclic compound of claim 13, wherein the fused polycyclic compound represented by Formula 1 is represented by one of Formula 5-1 to Formula 5-3: 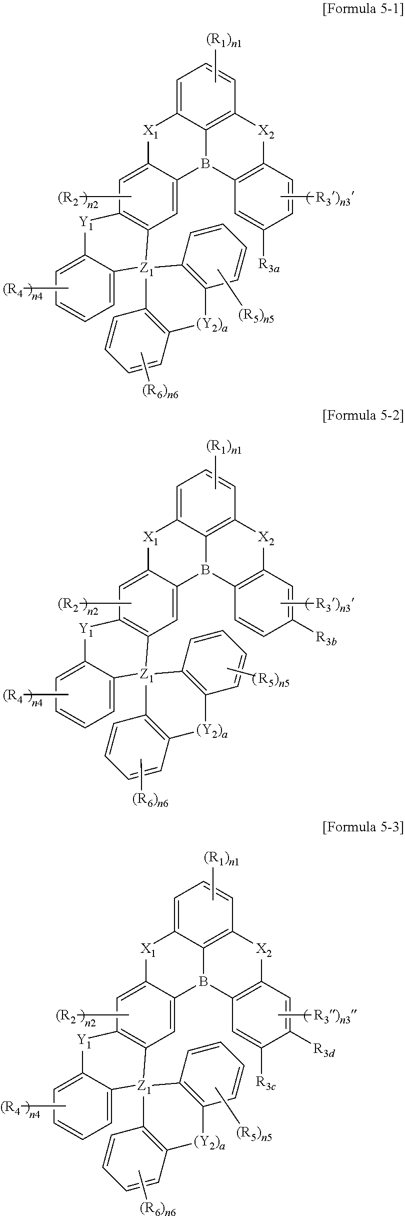
wherein in Formula 5-1 to Formula 5-3,
R₃ₐ to R_{3b} are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₃′ and R₃″ are each independently a hydrogen atom, a deuterium atom, a halogen atom, a substituted or unsubstituted amine group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
n3′ is an integer from 0 to 3,
n3″ is an integer from 0 to 2, and
R_{3c} and R_{3d} each represent a bonding position of a moiety represented by Formula 6, 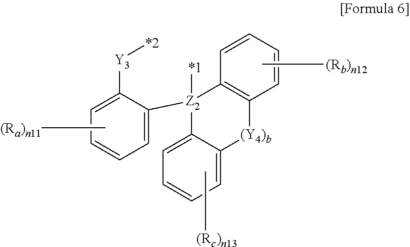
wherein in Formula 6,
-*1 is a bonding position to R_{3c} in Formula 5-3,
-*2 is a bonding position to R_{3d} in Formula 5-3,
Y₃ is a direct linkage or O,
Y₄ is a direct linkage, O, or N(R_{d}),
Z₂ is C or Si,
when Z₂ is Si, Y₃ is O,
Rₐ to R_{c} are each independently a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n11 to n13 are each independently an integer from 0 to 4,
b is 0 or 1,
when b is 0, Rₐ is not a substituted or unsubstituted amine group,
the sum of b and n12 is 5 or less,
the sum of b and n13 is 5 or less, and
in Formula 5-1 to Formula 5-3, X₁, X₂, Z₁, Y₁, Y₂, a, R₁, R₂, R₄ to R₆, n1, n2, and n4 to n6 are each the same as defined in Formula 1.

18. The fused polycyclic compound of claim 17, wherein in Formula 5-1 and Formula 5-2,
R₃ₐ and R_{3b} are each independently a substituted or unsubstituted alkyl group having 1 to 10 carbon atoms, or a group represented by one of Formula 7-1 to Formula 7-3: 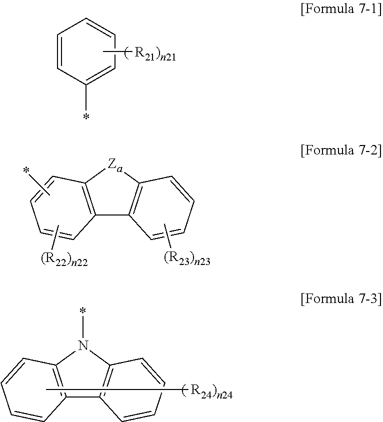
wherein in Formula 7-1 to Formula 7-3,
Zₐ is N(R₂₅) or O,
R₂₁ to R₂₅ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n21 is an integer from 0 to 5,
n22 is an integer from 0 to 3,
n23 is an integer from 0 to 4,
n24 is an integer from 0 to 8, and
-* is a bonding position to Formula 5-1 or Formula 5-2.

19. The fused polycyclic compound of claim 13, wherein the first compound represented by Formula 1 is represented by Formula 8: 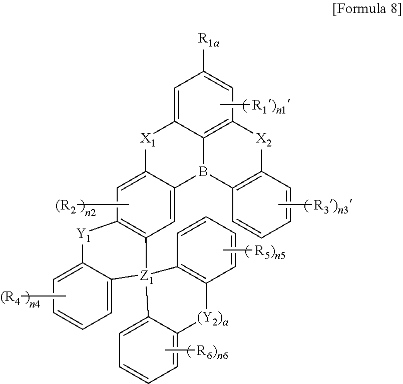
wherein in Formula 8,
R₁ₐ is a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, R₁′ is a hydrogen atom, a deuterium atom, a halogen atom, a substituted or unsubstituted amine group, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n1′ is an integer from 0 to 2, and
X₁, X₂, Z₁, Y₁, Y₂, a, R₂ to R₆, and n2 to n6 are each the same as defined in Formula 1.

20. The fused polycyclic compound of claim 13, wherein in Formula 1,
R₁ is a substituted or unsubstituted alkyl group having 1 to 10 carbon atoms, or a group represented by one of Formula 9-1 to Formula 9-6: 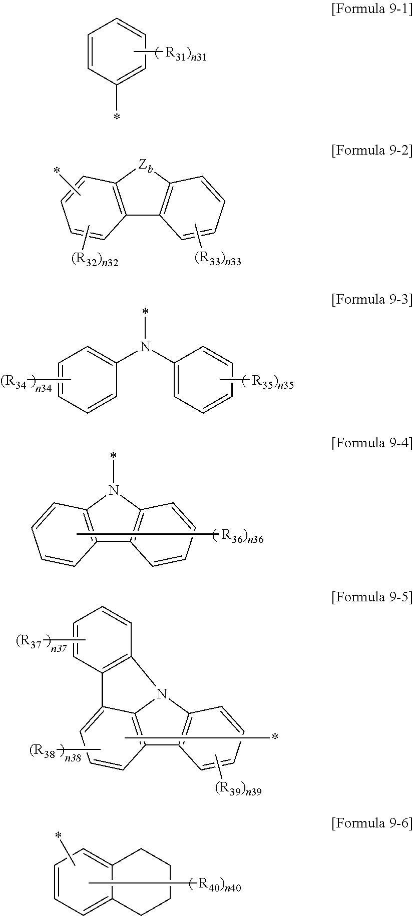
wherein in Formula 9-1 to Formula 9-6,
Z_{b} is N(R₄₁) or O,
R₃₁ to R₄₁ are each independently a hydrogen atom, a deuterium atom, a halogen atom a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n31 is an integer from 0 to 5,
n32 and n38 are each independently an integer from 0 to 3,
n33, n37 and n39 are each independently an integer from 0 to 4,
n34 and n35 are each independently an integer from 0 to 5,
the sum of n38 and n39 is 6 or less,
n36 is an integer from 0 to 8,
n40 is an integer from 0 to 11, and
-* is a bonding position to Formula 1.

21. The fused polycyclic compound of claim 13, wherein the fused polycyclic compound represented by Formula 1 is selected from Compound Group 1:
[Compound Group 1] 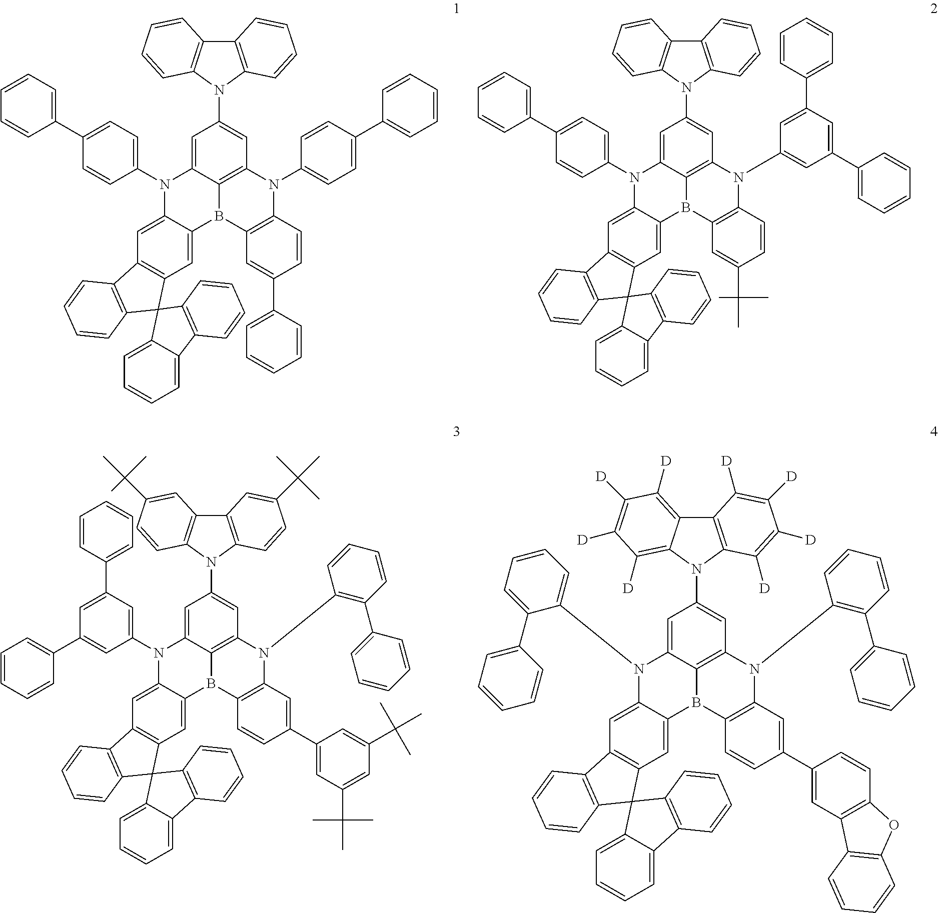 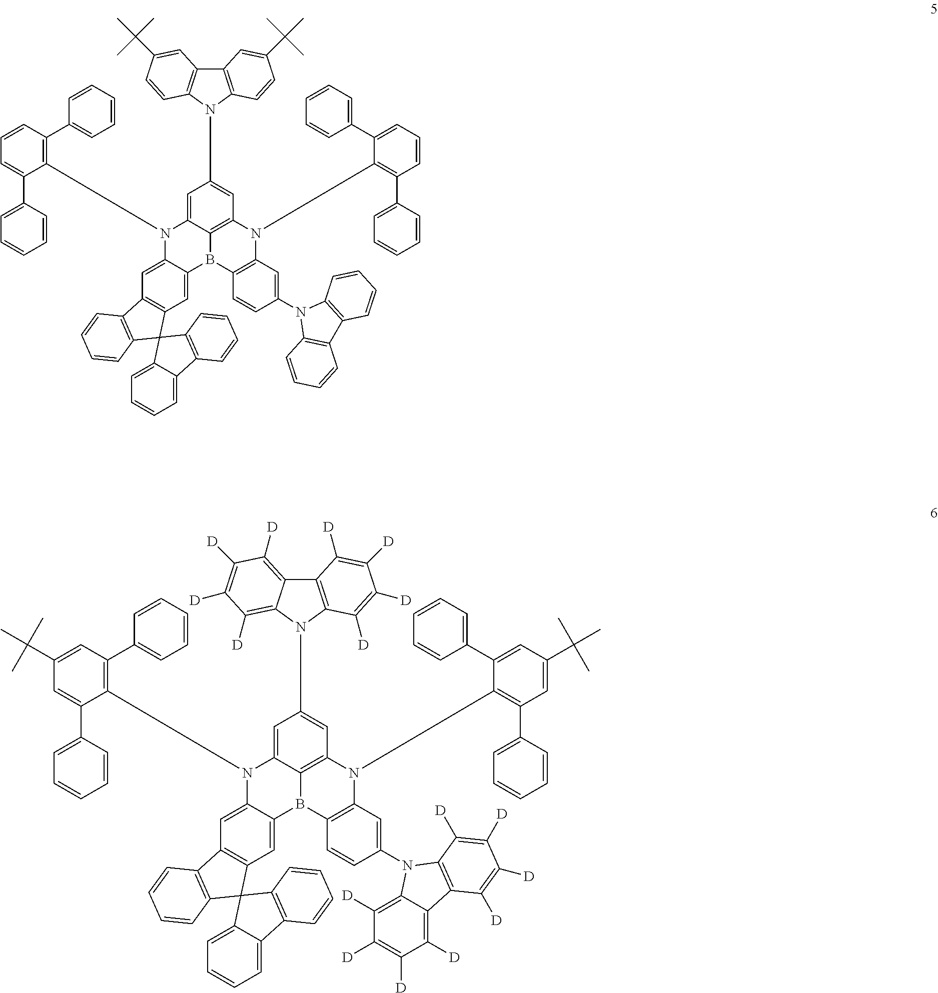 [SMILES: CC(C)(C)c1ccc2c(c1)c1cc(C(C)(C)C)ccc1n2-c1cc2c3c(c1)N(c1c(-c4ccccc4)cccc1-c1ccccc1)c1cc4c(cc1B3c1ccc(-n3c5ccccc5c5ccccc53)cc1N2c1c(-c2ccccc2)cccc1-c1ccccc1)C1(c2ccccc2-c2ccccc21)c1ccccc1-4 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-n3c4c([2H])c([2H])c([2H])c([2H])c4c4c([2H])c([2H])c([2H])c([2H])c43)cc3c1B2c1cc2c(cc1N3c1c(-c3ccccc3)cc(C(C)(C)C)cc1-c1ccccc1)-c1ccccc1C21c2ccccc2-c2ccccc21] 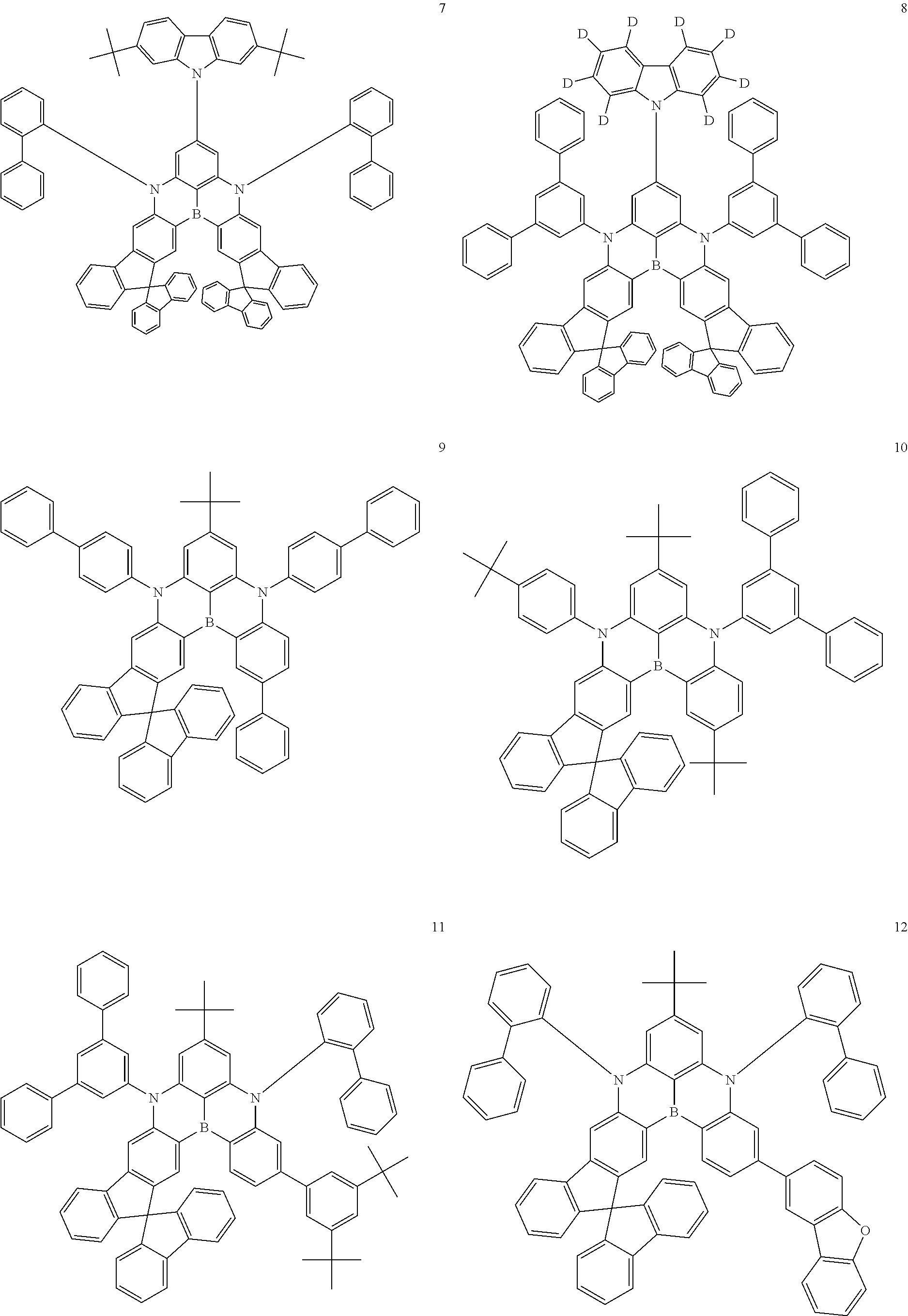 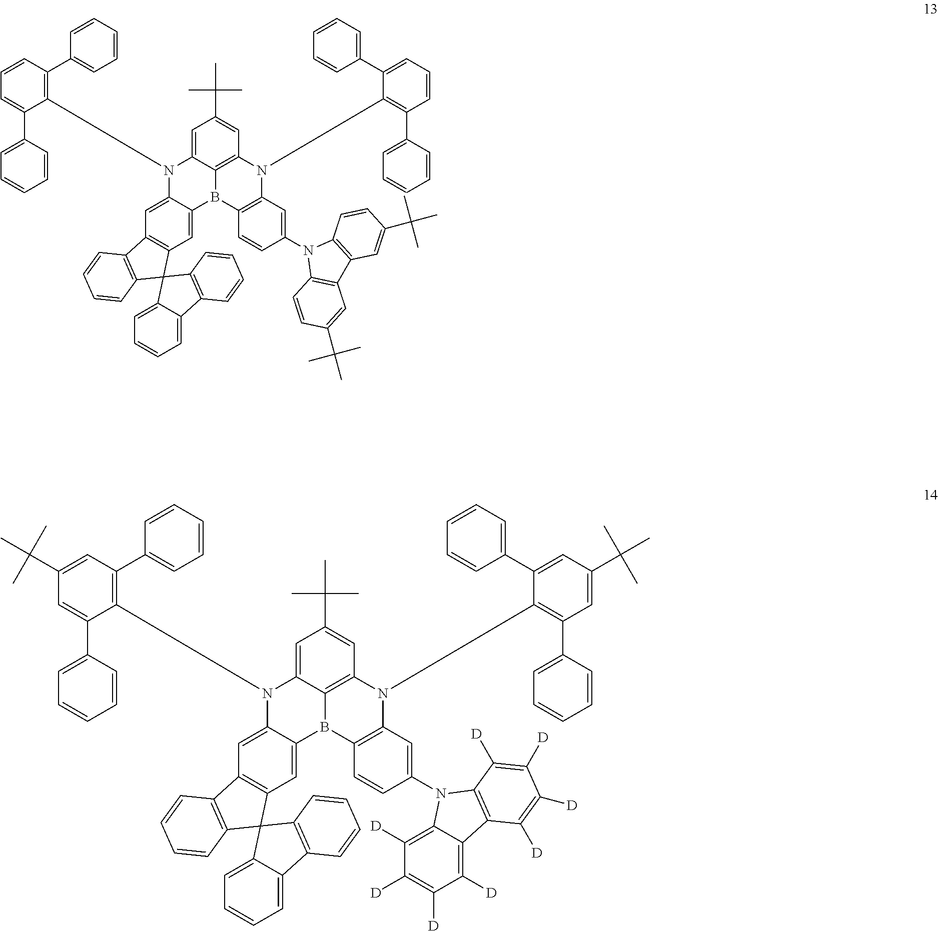 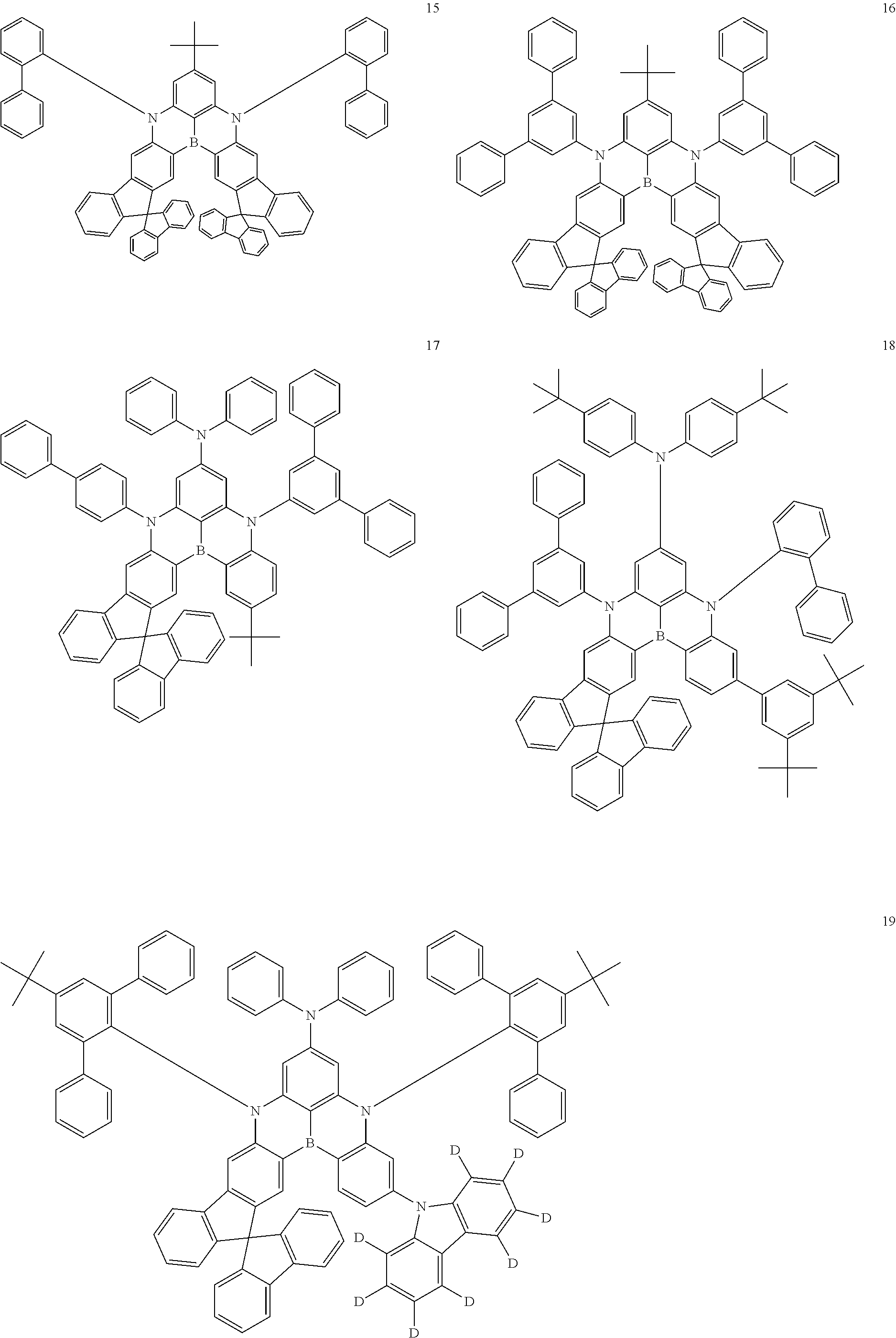 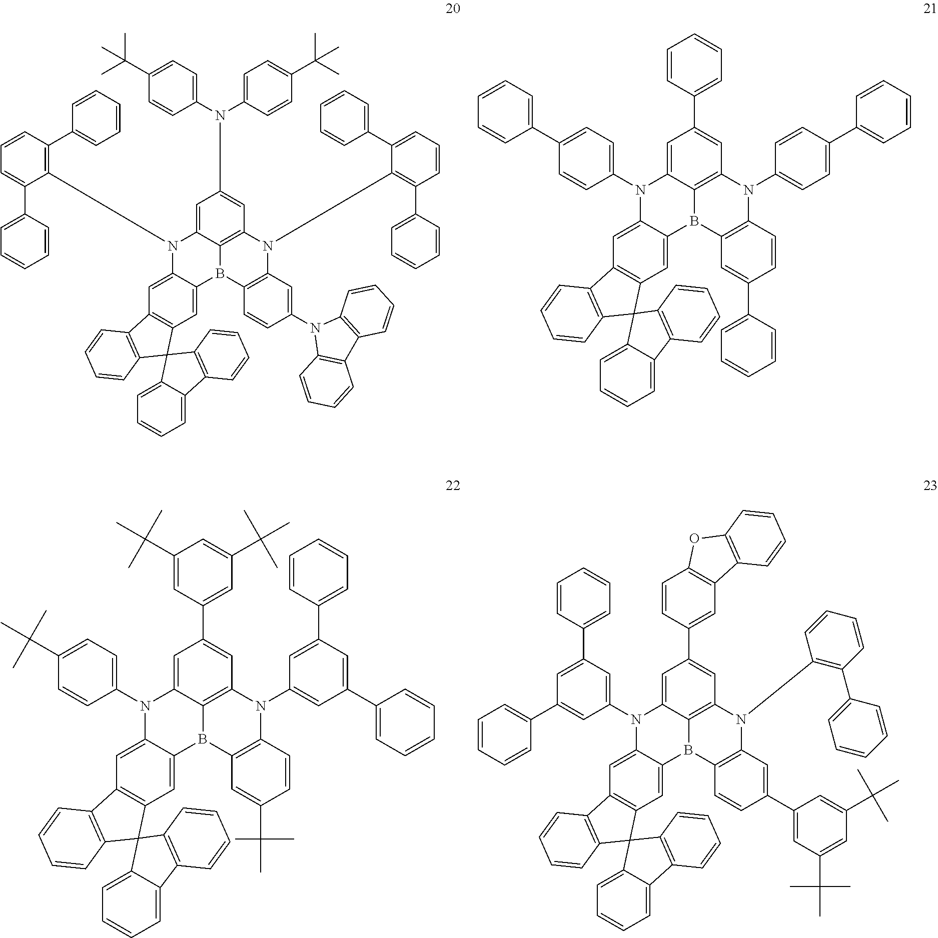 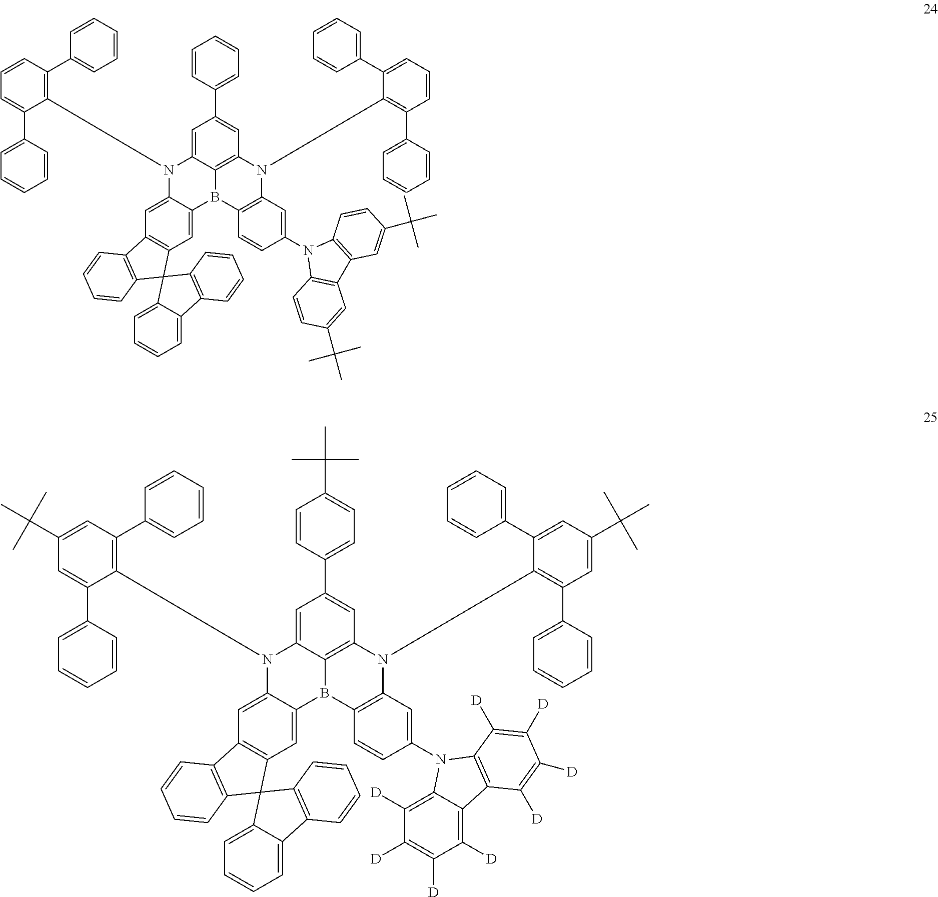 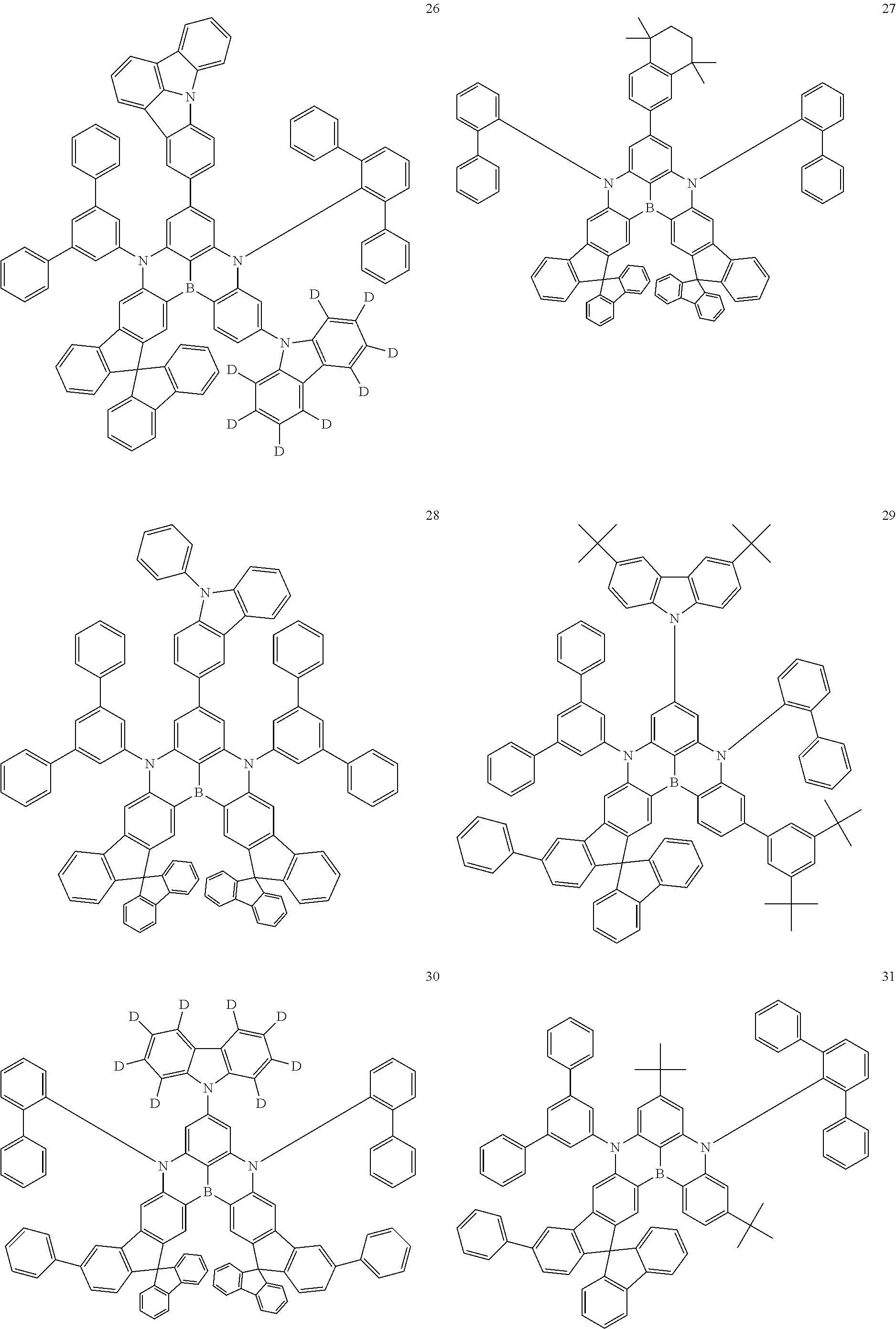 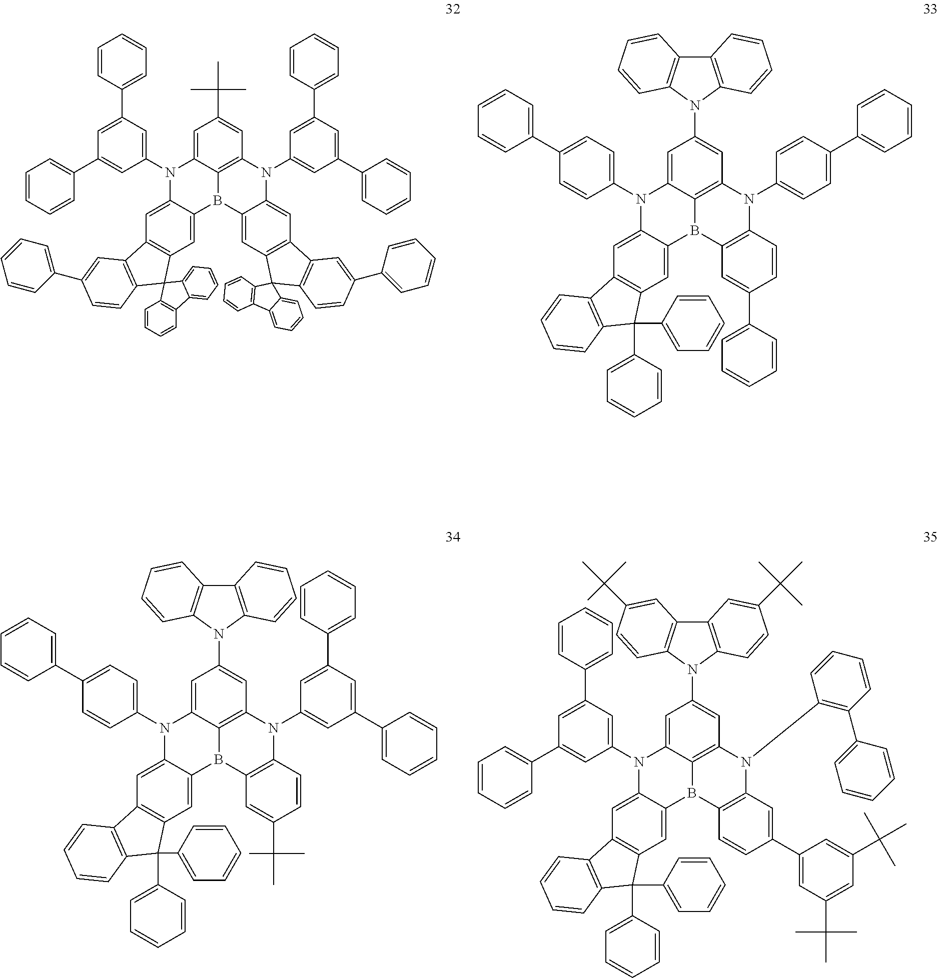 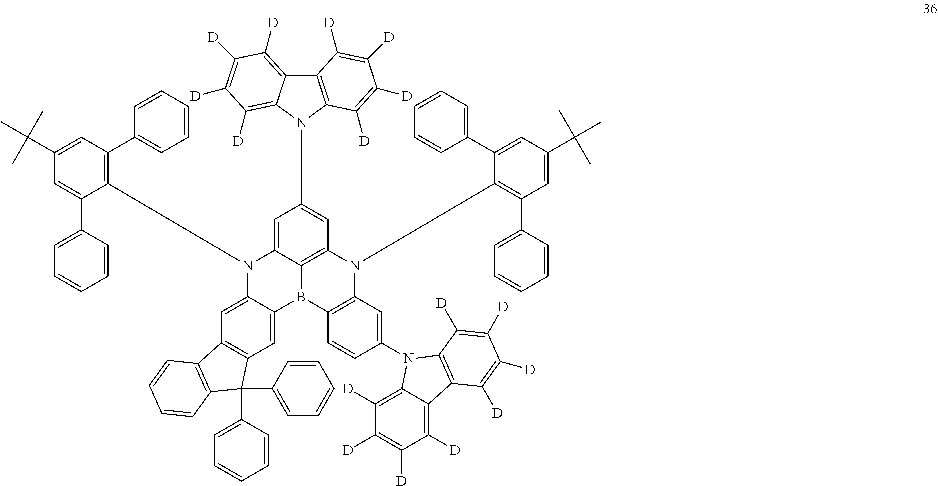 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-n3c4c([2H])c([2H])c([2H])c([2H])c4c4c([2H])c([2H])c([2H])c([2H])c43)cc3c1B2c1cc2c(cc1N3c1c(-c3ccccc3)cc(C(C)(C)C)cc1-c1ccccc1)-c1ccccc1C2(c1ccccc1)c1ccccc1] 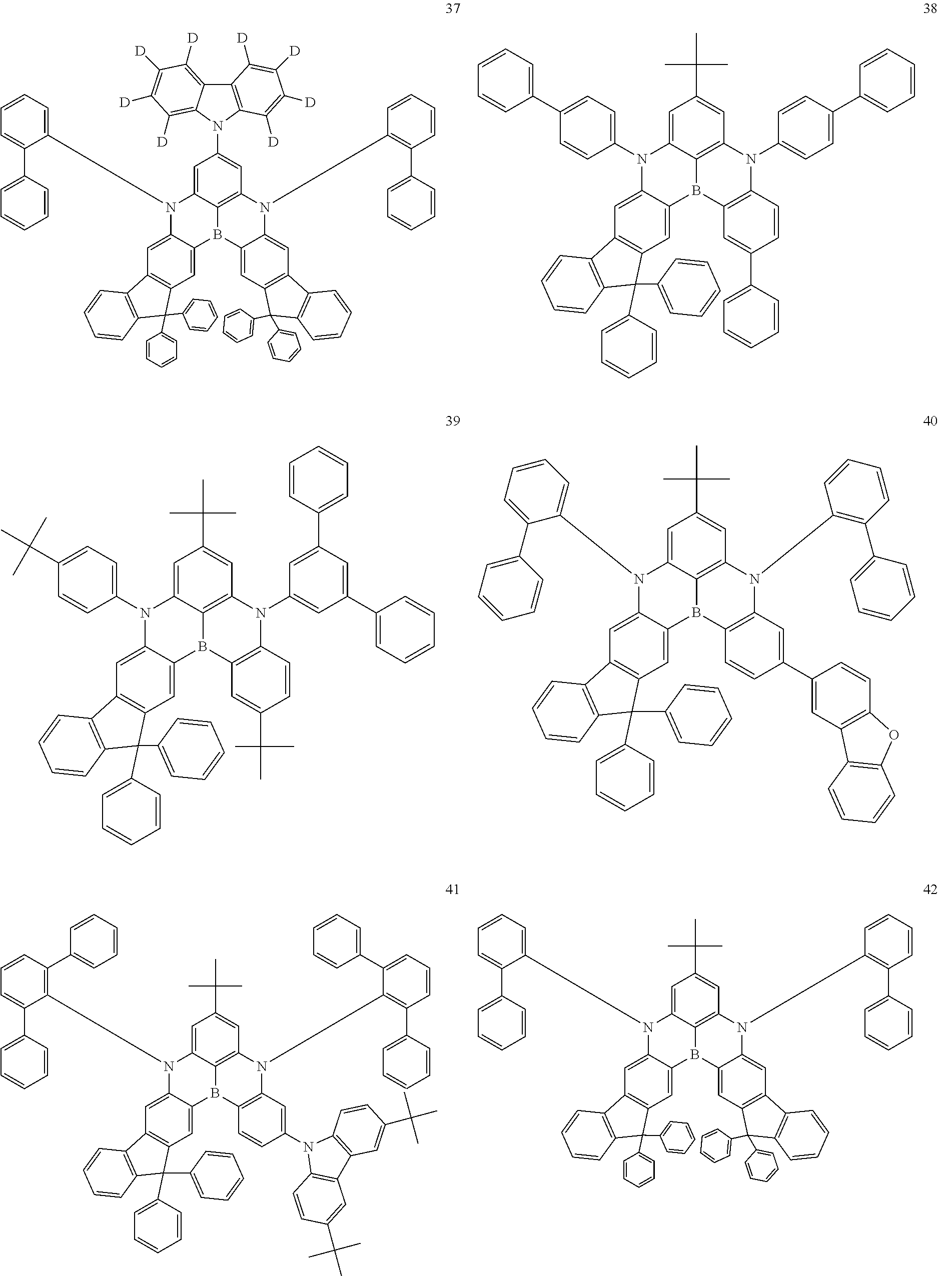 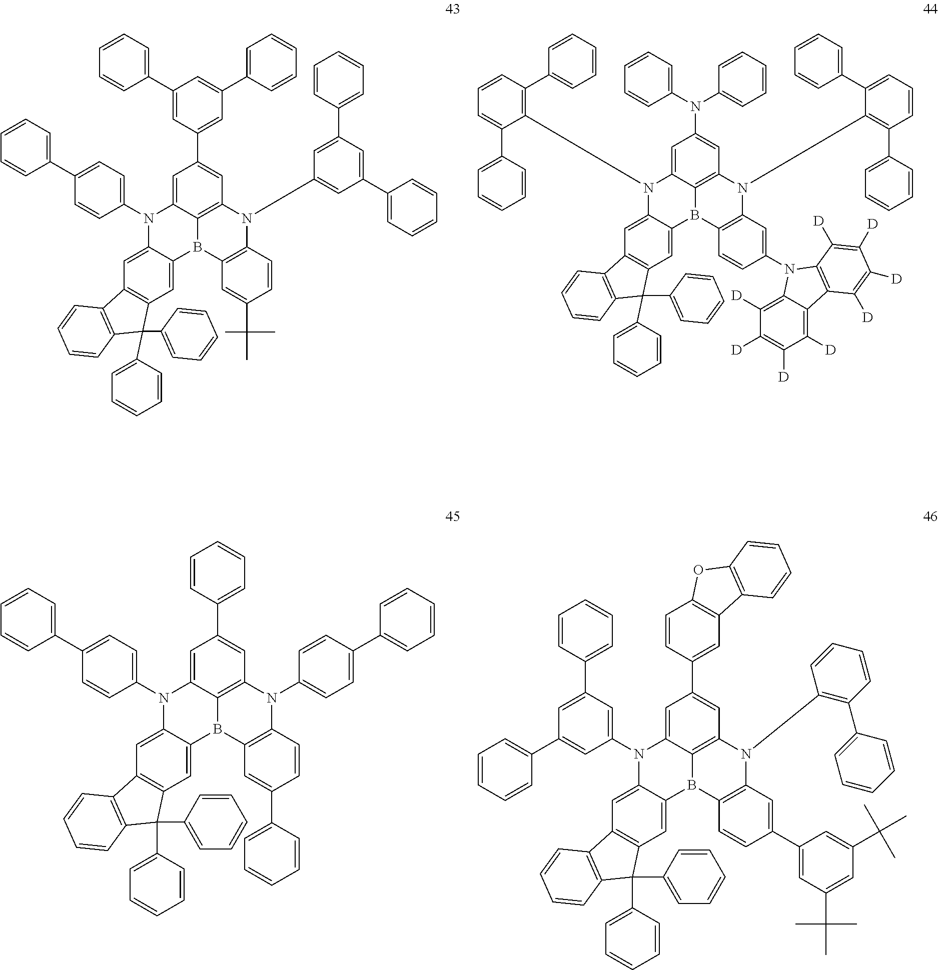 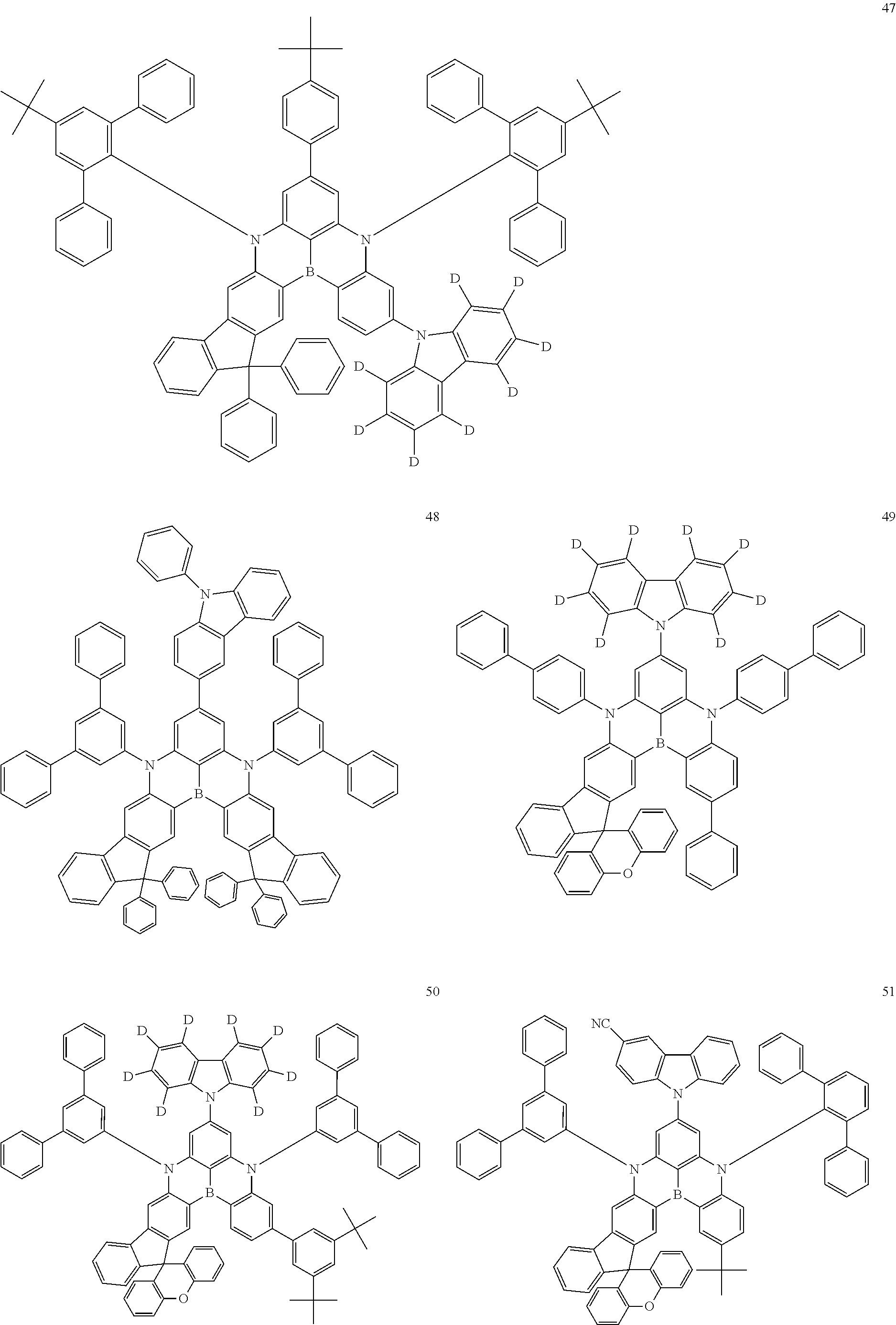 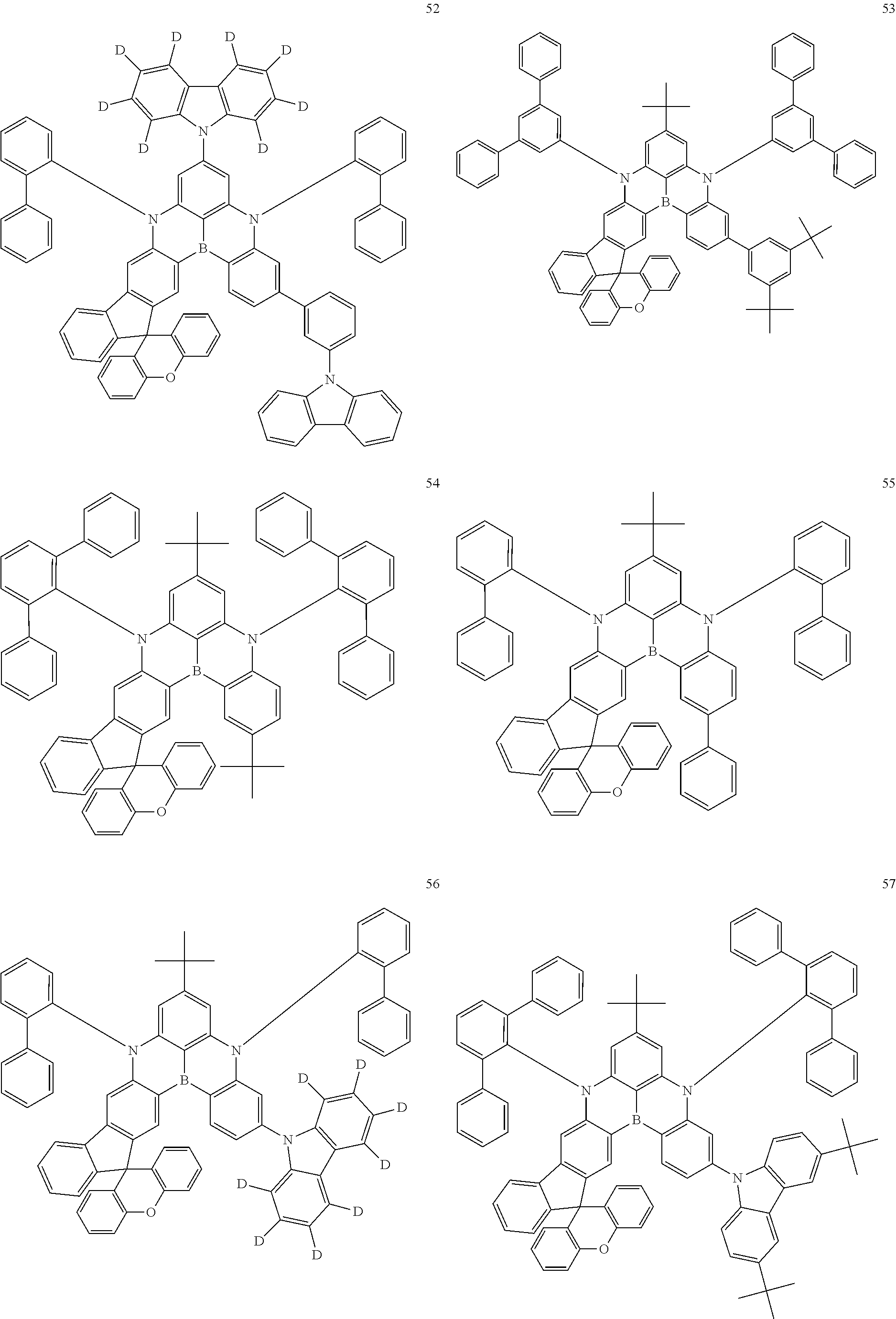 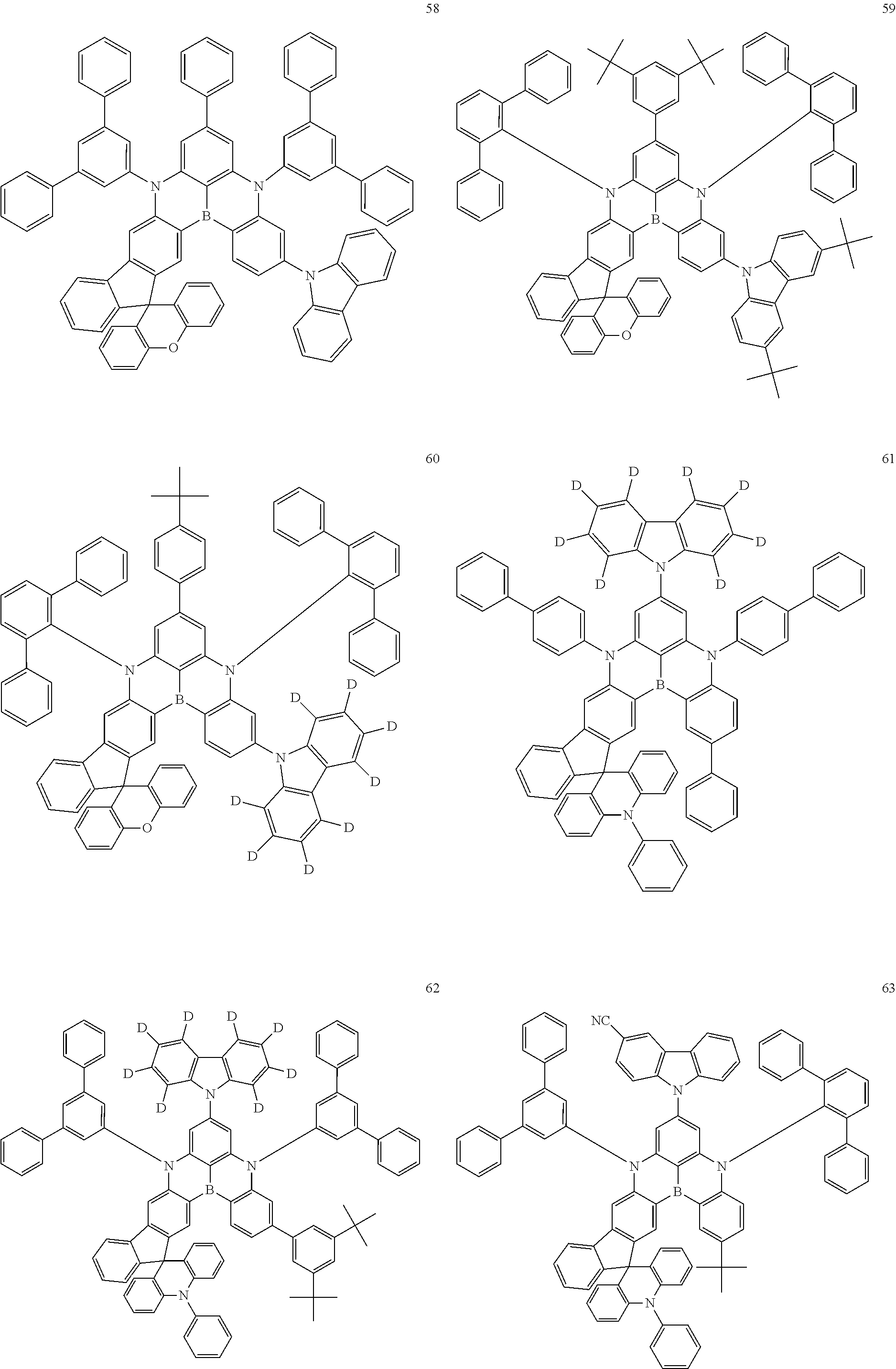 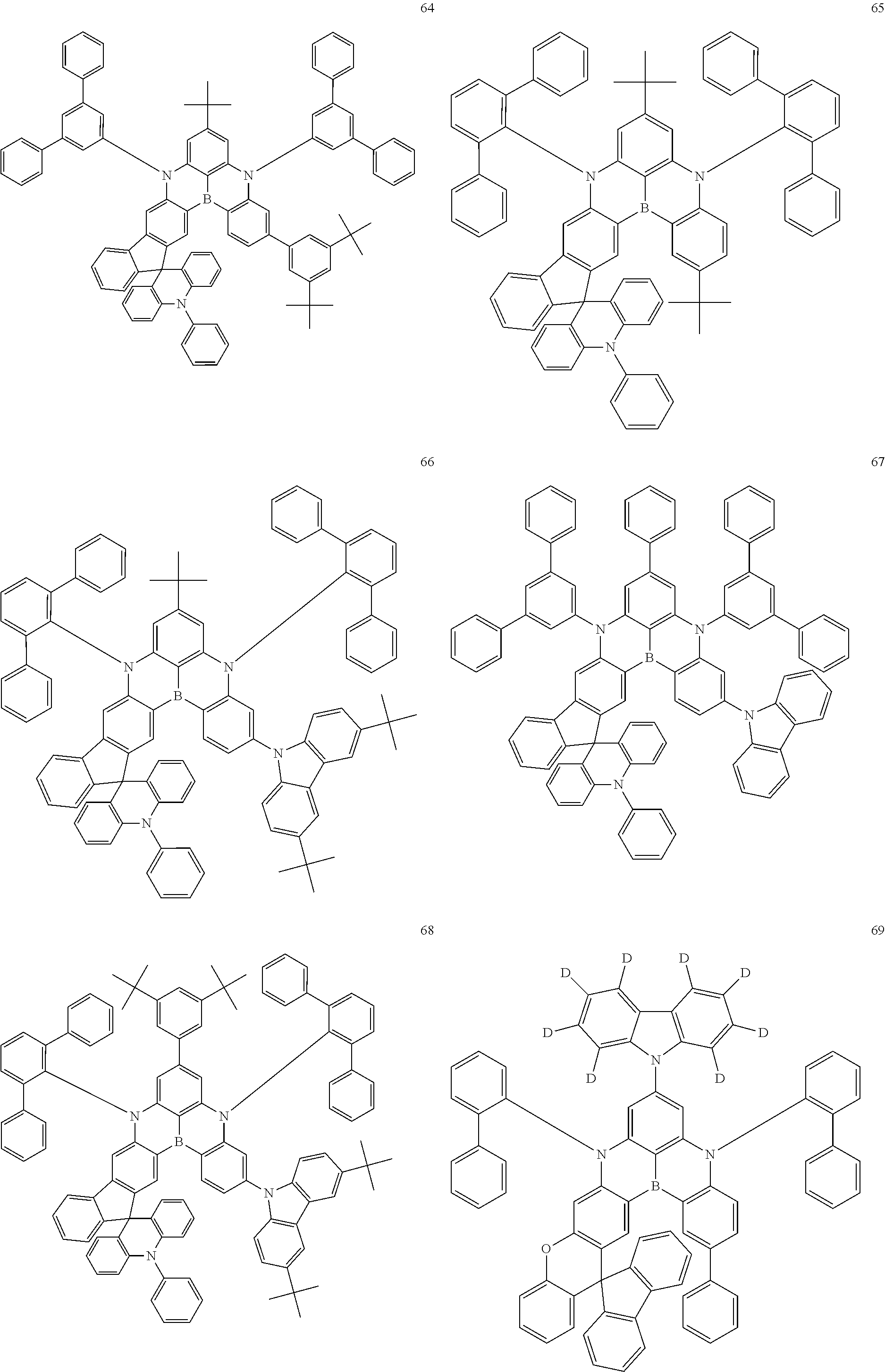 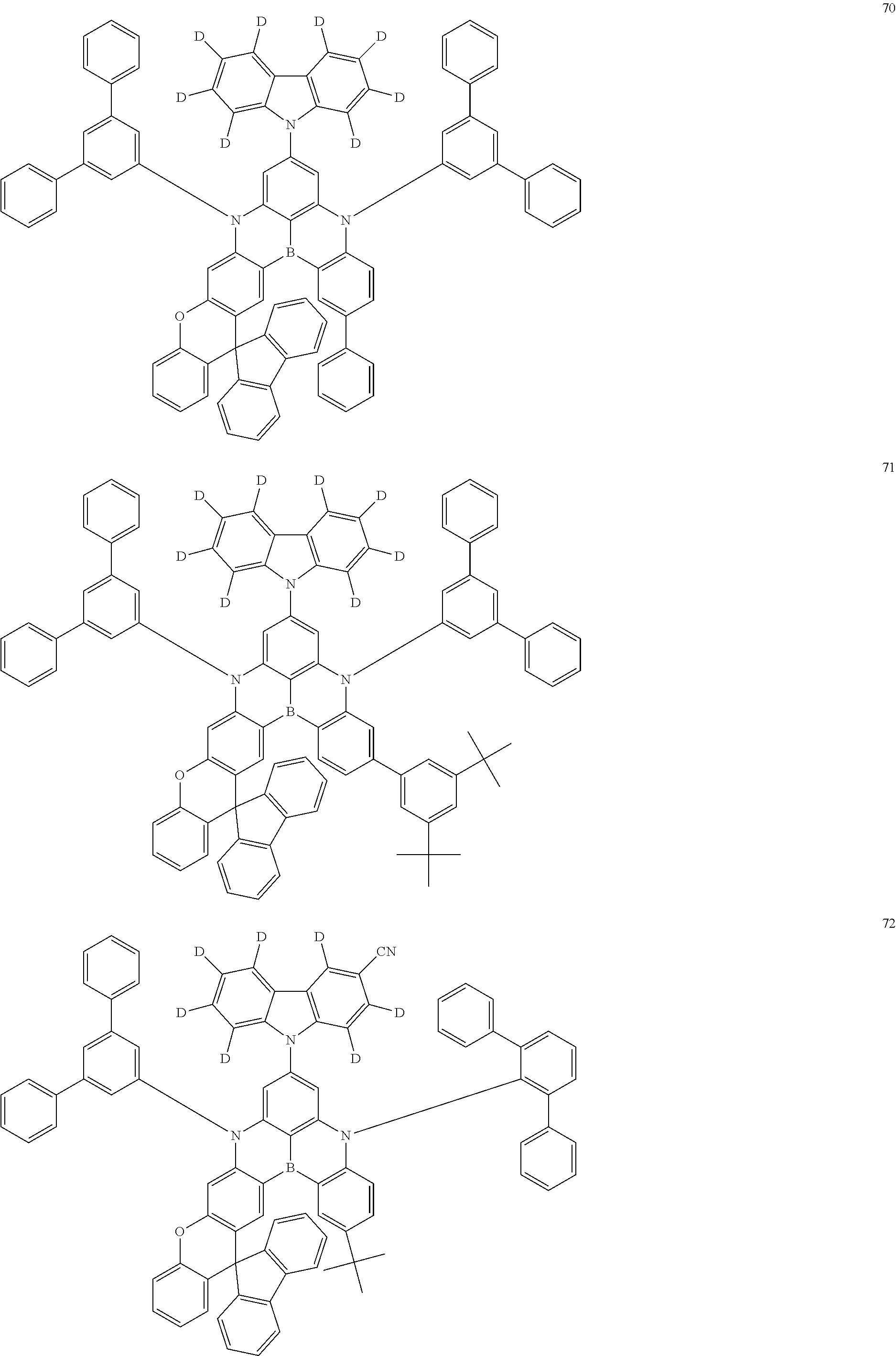 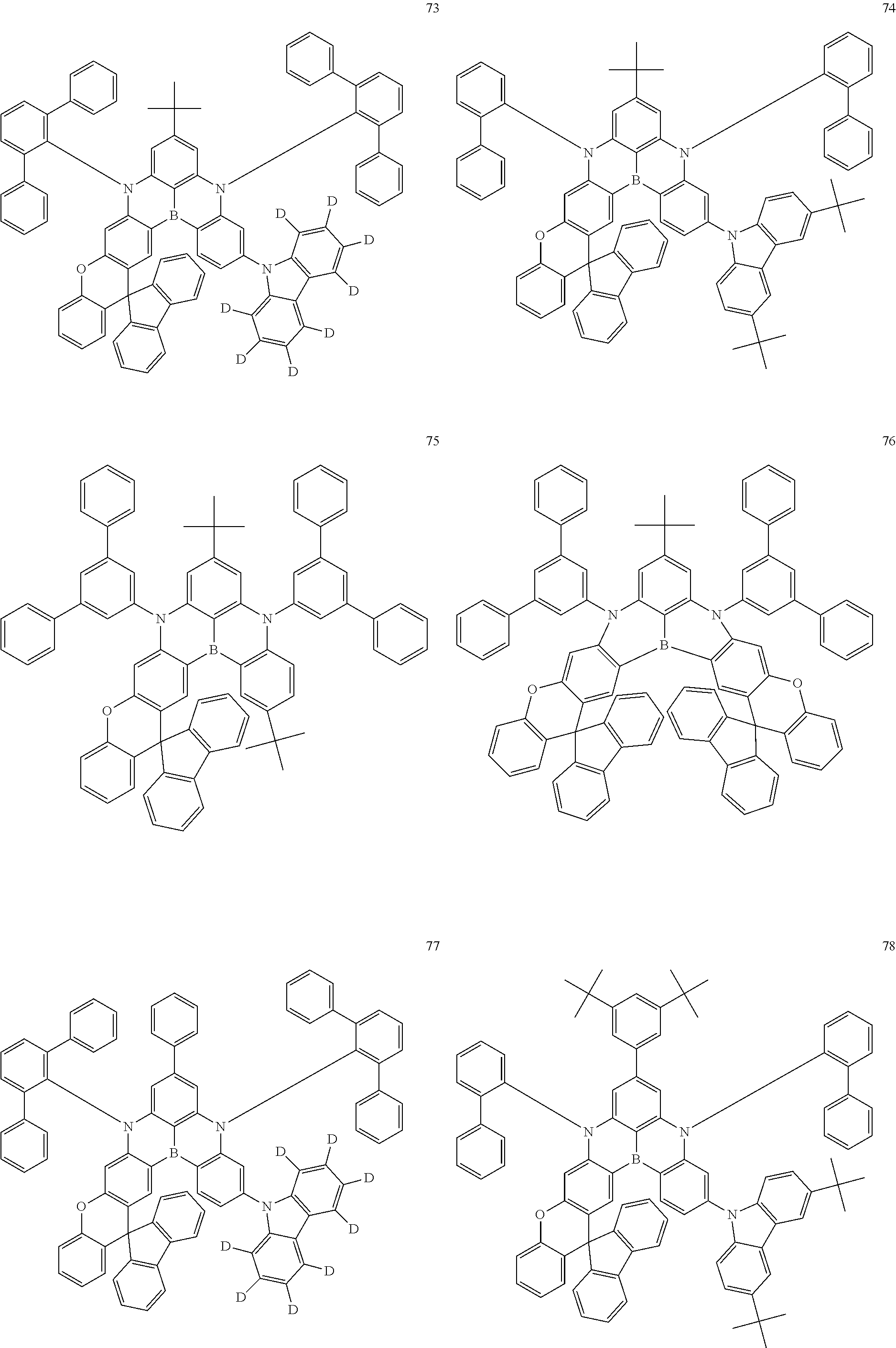 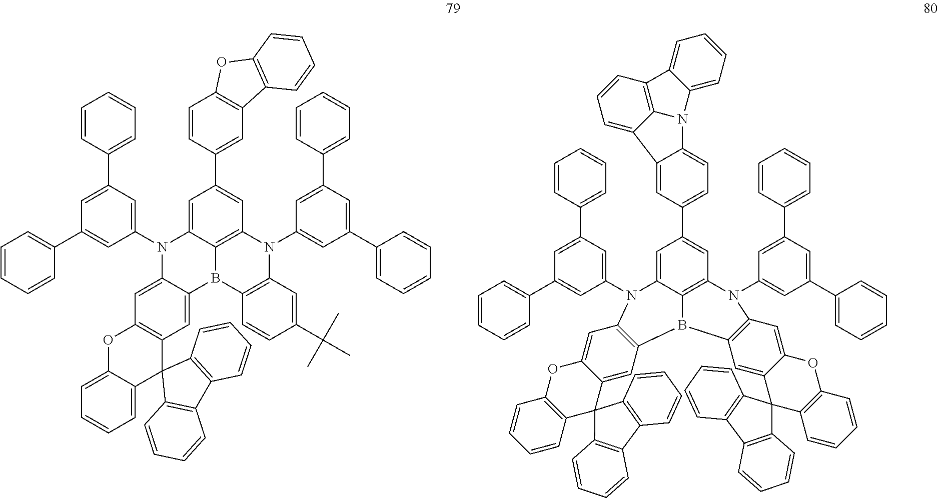 [SMILES: CC(C)(C)c1ccc2c(c1)N(c1cc(-c3ccccc3)cc(-c3ccccc3)c1)c1cc(-c3ccc4oc5ccccc5c4c3)cc3c1B2c1cc2c(cc1N3c1cc(-c3ccccc3)cc(-c3ccccc3)c1)Oc1ccccc1C21c2ccccc2-c2ccccc21 ; c1ccc(-c2cc(-c3ccccc3)cc(N3c4cc5c(cc4B4c6cc7c(cc6N(c6cc(-c8ccccc8)cc(-c8ccccc8)c6)c6cc(-c8ccc9c(c8)c8cccc%10c%11ccccc%11n9c%108)cc3c64)Oc3ccccc3C73c4ccccc4-c4ccccc43)C3(c4ccccc4O5)c4ccccc4-c4ccccc43)c2)cc1] 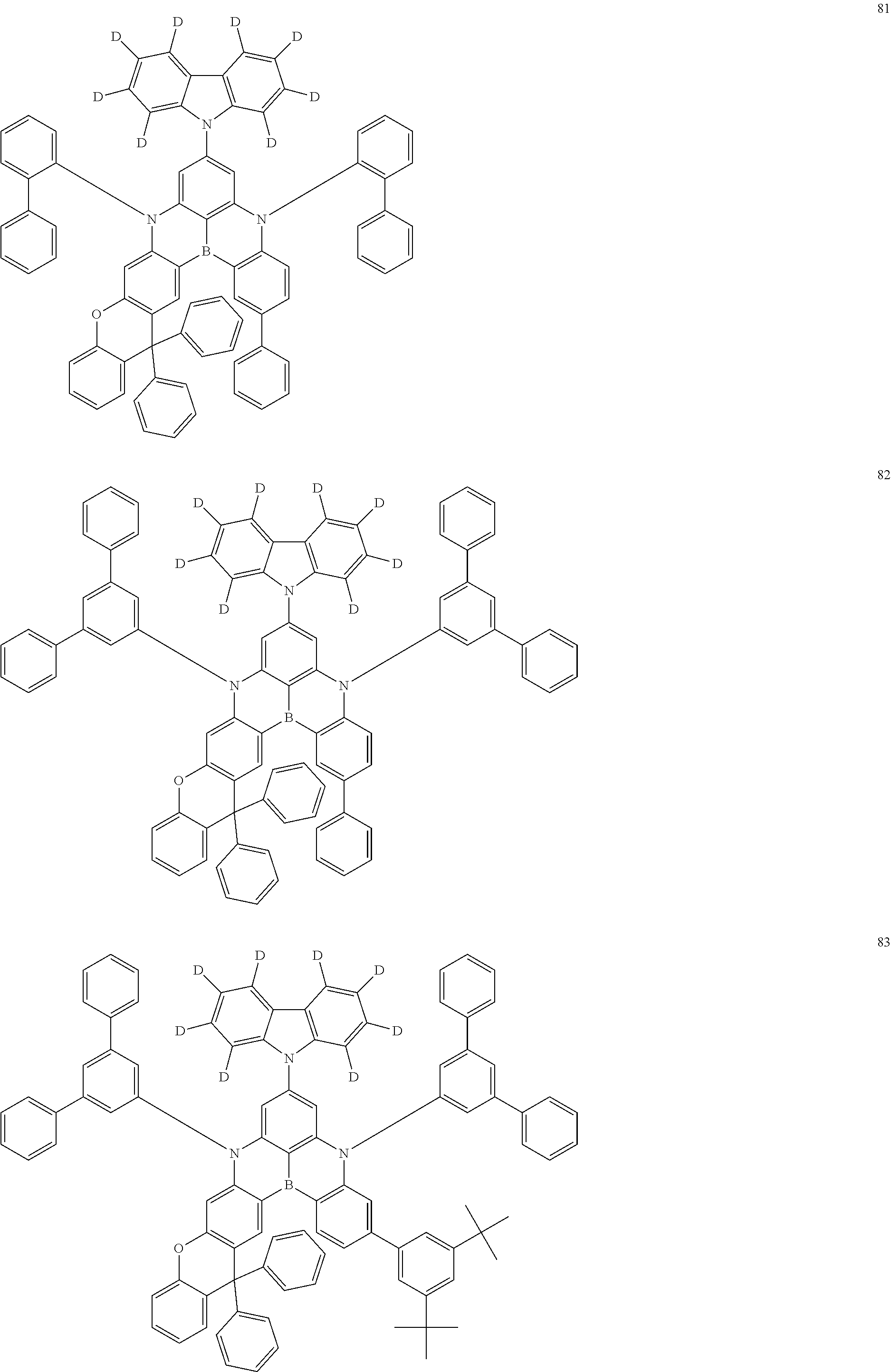 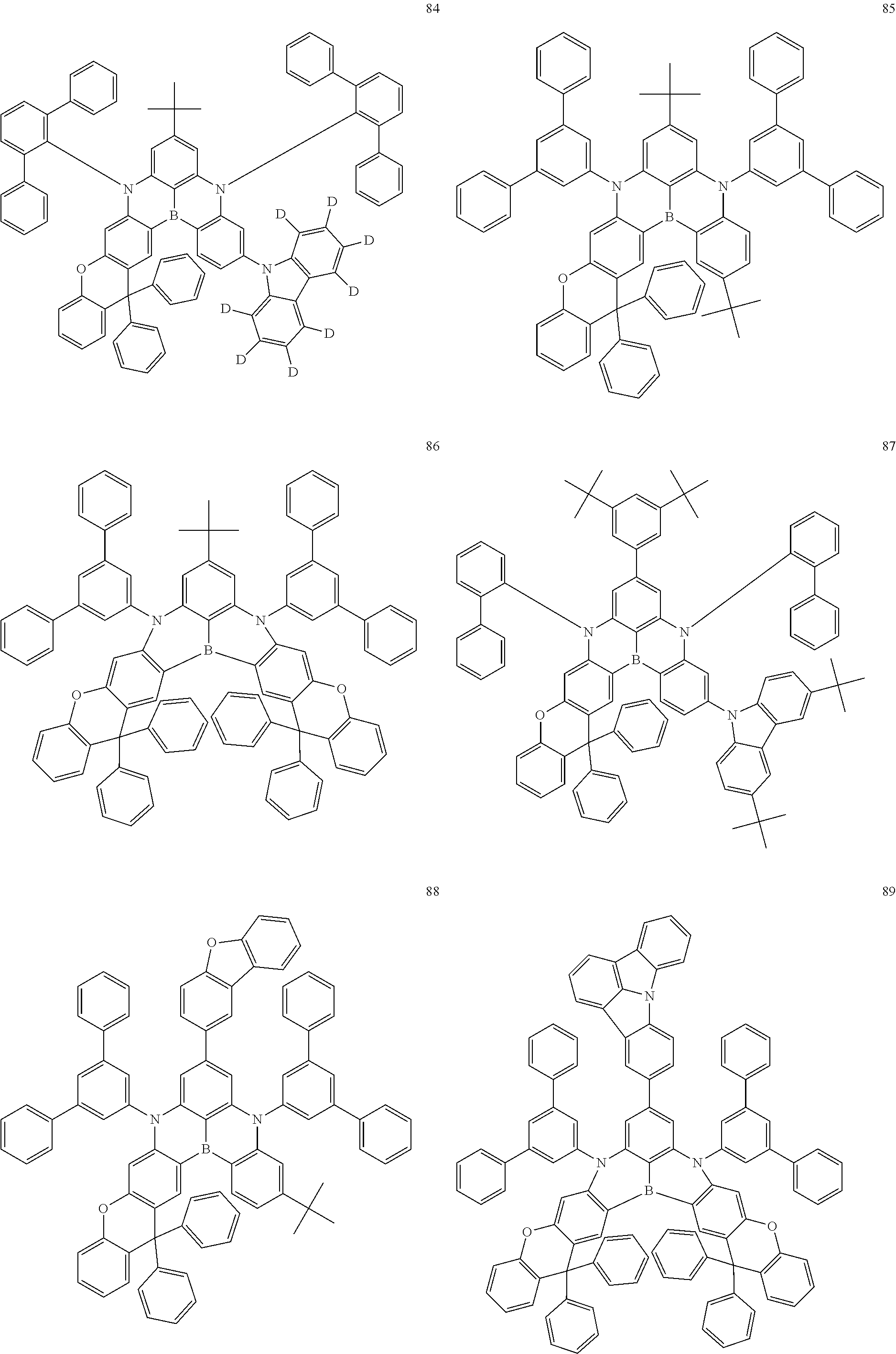 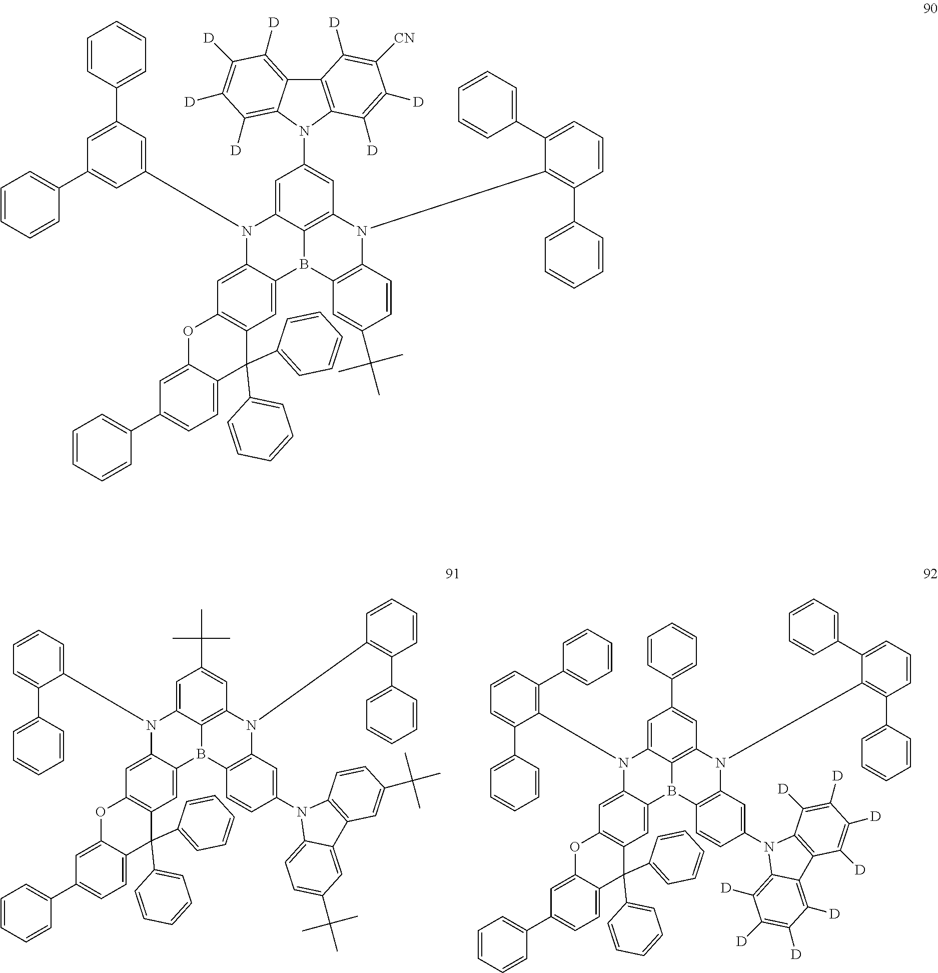 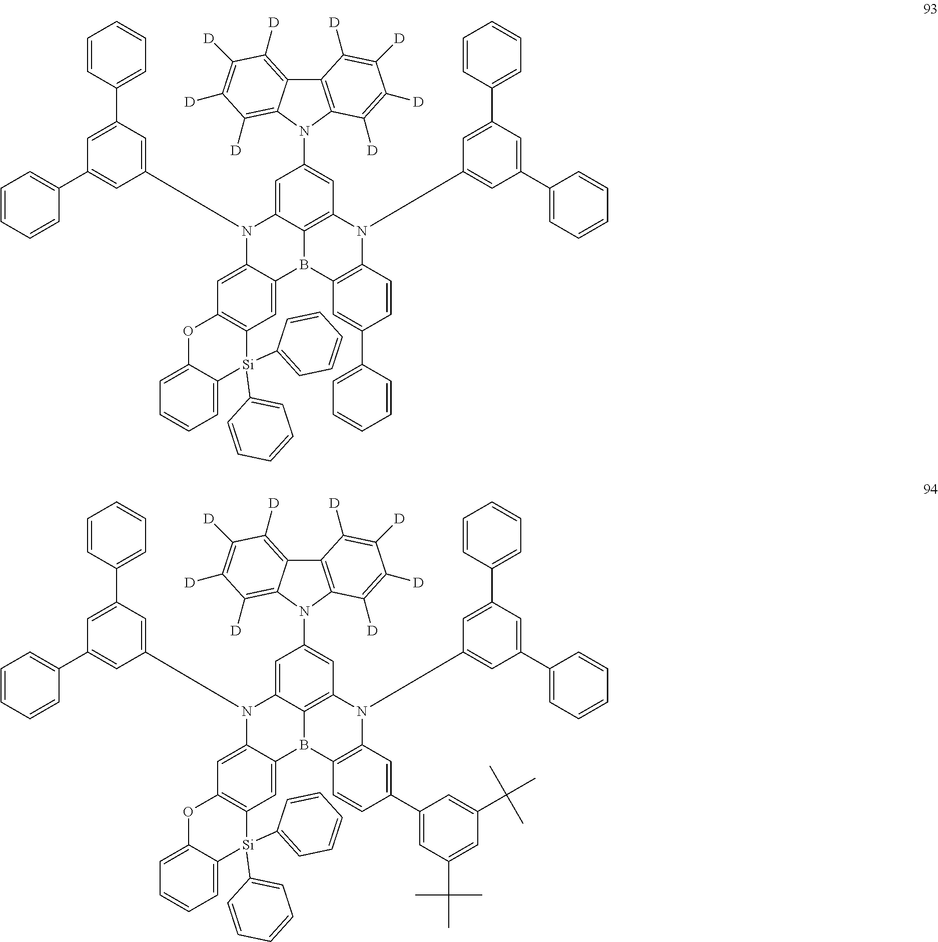 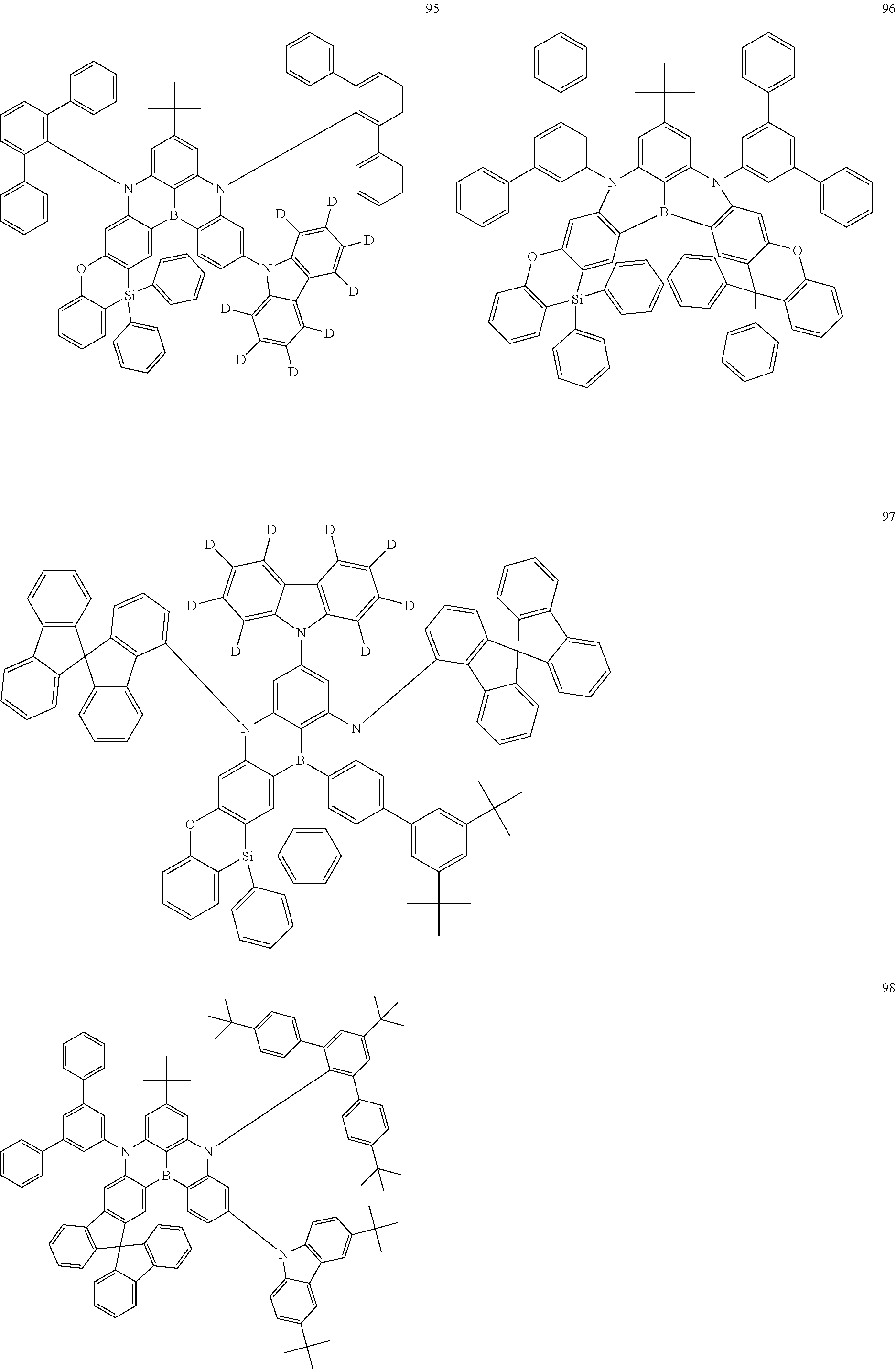
wherein in Compound Group 1,
D represents a deuterium atom.
